(19) United States
(12) Patent Application Publication
(10) Pub. No.: US 2025/0098398 A1
(43) Pub. Date: Mar. 20, 2025

(54) LIGHT-EMITTING ELEMENT, DISPLAY DEVICE, ELECTRONIC DEVICE, AND LIGHTING DEVICE

(71) Applicant: Semiconductor Energy Laboratory Co., Ltd., Atsugi-shi (JP)

(72) Inventor: Tatsuyoshi TAKAHASHI, Atsugi (JP)

(21) Appl. No.: 18/964,846

(22) Filed: Dec. 2, 2024

Related U.S. Application Data
(63) Continuation of application No. 15/453,309, filed on Mar. 8, 2017, now abandoned.

(30) Foreign Application Priority Data
Mar. 18, 2016 (JP) 2016-055246

(51) Int. Cl. H10K 50/11; H10K 50/12; H10K 50/15; H10K 50/16; H10K 59/12; H10K 59/38; H10K 85/30; H10K 85/60; H10K 101/00; H10K 101/10; H10K 101/30; H10K 101/40

(52) U.S. Cl. CPC H10K 50/11; H10K 50/15; H10K 50/16; H10K 59/12; H10K 59/38; H10K 50/12; H10K 85/322; H10K 85/324; H10K 85/615; H10K 85/622; H10K 85/624; H10K 85/626; H10K 85/631; H10K 85/633; H10K 85/636; H10K 85/654; H10K 85/6565; H10K 85/657; H10K 85/6572; H10K 85/6574; H10K 85/6576; H10K 2101/10; H10K 2101/30; H10K 2101/40; H10K 2101/90

(57) ABSTRACT

To provide a light-emitting element including an exciplex that efficiently emits light. The light-emitting element includes a first organic compound and a second organic compound. A combination of the first organic compound and the second organic compound forms an exciplex. The energy difference between the LUMO level of the first organic compound and the HOMO level of the second organic compound is greater than the emission energy of the exciplex by −0.1 eV or more and 0.4 eV or less. The lower of the lowest triplet excitation energy level of the first organic compound and the lowest triplet excitation energy level of the second organic compound has energy that is larger than the emission energy of the exciplex by −0.2 eV or more and 0.4 eV or less.

### TECHNICAL FIELD

One embodiment of the present invention relates to a light-emitting element, a display device including the light-emitting element, an electronic device including the light-emitting element, or a lighting device including the light-emitting element.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a storage device, a method of driving any of them, and a method of manufacturing any of them.

### BACKGROUND ART

In recent years, research and development have been extensively conducted on light-emitting elements using electroluminescence (EL). In the basic structure of such a light-emitting element, a layer containing a light-emitting substance (an EL layer) is interposed between a pair of electrodes. By application of a voltage between the electrodes of this element, light emission from the light-emitting substance can be obtained.

Since the above light-emitting element is a self-luminous type, a display device using this light-emitting element has advantages such as high visibility, no necessity of a backlight, and low power consumption. Furthermore, such a light-emitting element also has advantages in that the element can be manufactured to be thin and lightweight, and has high response speed.

In a light-emitting element whose EL layer contains a light-emitting organic compound as a light-emitting substance and is provided between a pair of electrodes (e.g., an organic EL element), application of a voltage between the pair of electrodes causes injection of electrons from a cathode and holes from an anode into the EL layer having a light-emitting property and thus a current flows. By recombination of the injected electrons and holes, the light-emitting organic compound is brought into an excited state to provide emission.

Note that excited states that can be formed by an organic compound are a singlet excited state (S*) or a triplet excited state (T*). Light emission from the singlet-excited state is referred to as fluorescence, and light emission from the triplet excited state is referred to as phosphorescence. The formation ratio of S* to T* in the light-emitting element is 1:3. In other words, a light-emitting element containing a compound that emits phosphorescence (phosphorescent compound) has higher luminous efficiency than a light-emitting element containing a compound that emits fluorescence (fluorescent compound). Therefore, light-emitting elements containing phosphorescent compounds capable of converting a triplet excited state into light emission have been actively developed in recent years.

Among light-emitting elements containing phosphorescent compounds, a light-emitting element that emits blue light in particular has yet been put into practical use because it is difficult to develop a stable compound having a high triplet excitation energy level. For this reason, the development of a light-emitting element containing a fluorescent compound, which is more stable, has been conducted and a technique for increasing the luminous efficiency of a light-emitting element containing a fluorescent compound (fluorescent element) has been searched.

As one of materials capable of partly converting the triplet excited state into light emission, a thermally activated delayed fluorescent (TADF) emitter has been known. In a thermally activated delayed fluorescent emitter, a singlet excited state is generated from a triplet excited state by reverse intersystem crossing, and the singlet excited state is converted into light emission.

In order to increase the luminous efficiency of a light-emitting element using a thermally activated delayed fluorescent emitter, not only efficient generation of a singlet excited state from a triplet excited state but also efficient light emission from a singlet excited state, that is, high fluorescence quantum yield are important in a thermally activated delayed fluorescent emitter.

For example, Patent Document 1 discloses a method where an exciplex formed by two organic compounds, which has a small energy difference between a singlet excited state and a triplet excited state, is used as a thermally activated delayed fluorescent emitter.

For example, Patent Document 2 discloses a method in which in a light-emitting element containing a thermally activated delayed fluorescent emitter and a fluorescent compound, singlet excitation energy of the thermally activated delayed fluorescent emitter is transferred to the fluorescent compound and light emission is obtained from the fluorescent compound.

### REFERENCE

### Patent Document

[Patent Document 1] Japanese Published Patent Application No. 2014-45184
[Patent Document 2] Japanese Published Patent Application No. 2014-45179

### DISCLOSURE OF INVENTION

In order to increase the luminous efficiency of a light-emitting element containing a thermally activated delayed fluorescent emitter, efficient generation of a singlet excited state from a triplet excited state is preferable. However, a method for increasing luminous efficiency in the case where an exciplex is used as a thermally activated delayed fluorescent emitter has not been disclosed.

In order to increase the luminous efficiency of a light-emitting element containing a thermally activated delayed fluorescent emitter and a fluorescent compound, efficient energy transfer from a singlet excited state of the thermally activated delayed fluorescent emitter to a singlet excited state of the fluorescent compound is preferable. Moreover, energy transfer from a triplet excited state of the thermally activated delayed fluorescent emitter to a triplet excited state of the fluorescent compound is preferably inhibited. To inhibit energy transfer from a triplet excited state of the thermally activated delayed fluorescent emitter to a triplet excited state of the fluorescent compound, the luminous efficiency of the thermally activated delayed fluorescent emitter is preferably high; however, a method for increasing luminous efficiency of an exciplex in the case where an exciplex is used as a thermally activated delayed fluorescent emitter has not been disclosed.

In view of the above, an object of one embodiment of the present invention is to provide a light-emitting element that has high luminous efficiency. Another object of one embodiment of the present invention is to provide a light-emitting element with low power consumption. Another object of one embodiment of the present invention is to provide a novel light-emitting element. Another object of one embodiment of the present invention is to provide a novel light-emitting device. Another object of one embodiment of the present invention is to provide a novel display device.

Note that the description of the above object does not preclude the existence of other objects. In one embodiment of the present invention, there is no need to achieve all the objects. Objects other than the above objects will be apparent from and can be derived from the description of the specification and the like.

One embodiment of the present invention is a light-emitting element including two organic compounds that form an exciplex.

One embodiment of the present invention is a light-emitting element including a first organic compound and a second organic compound. A combination of the first organic compound and the second organic compound forms an exciplex. The lower of a lowest triplet excitation energy level of the first organic compound and a lowest triplet excitation energy level of the second organic compound has energy that is larger than emission energy of the exciplex by −0.2 eV or more and 0.4 eV or less.

Another embodiment of the present invention is a light-emitting element including a first organic compound and a second organic compound. A combination of the first organic compound and the second organic compound forms an exciplex. An energy difference between a LUMO level of the first organic compound and a HOMO level of the second organic compound is greater than emission energy of the exciplex by −0.1 eV or more and 0.4 eV or less.

Another embodiment of the present invention is a light-emitting element including a first organic compound and a second organic compound. A combination of the first organic compound and the second organic compound forms an exciplex. An energy difference between a LUMO level of the first organic compound and a HOMO level of the second organic compound is greater than the emission energy of the exciplex by −0.1 eV or more and 0.4 eV or less. The lower of a lowest triplet excitation energy level of the first organic compound and a lowest triplet excitation energy level of the second organic compound has energy that is larger than the emission energy of the exciplex by −0.2 eV or more and 0.4 eV or less.

In each of the above structures, it is preferred that the light-emitting element further include a guest material, the guest material have a function of emitting light, and the exciplex have a function of supplying excitation energy to the guest material. Furthermore, it is preferred that the guest material contain a fluorescent compound and an emission spectrum of the exciplex include a region overlapping with an absorption band of the guest material on a lowest energy side.

In each of the above structures, it is preferred that the first organic compound have a function of transporting an electron and the second organic compound have a function of transporting a hole. Furthermore, it is preferred that the first organic compound include a π-electron deficient heteroaromatic ring skeleton and the second organic compound include at least one of a π-electron rich heteroaromatic ring skeleton and an aromatic amine skeleton. Furthermore, it is preferred that the first organic compound include a diazine skeleton and the second organic compound include a carbazole skeleton and a triarylamine skeleton.

Another embodiment of the present invention is a display device including the light-emitting element having any of the above structures and at least one of a color filter and a transistor. Another embodiment of the present invention is an electronic device including the display device and at least one of a housing and a touch sensor. Another embodiment of the present invention is a lighting device including the light-emitting element having any of the above structures and at least one of a housing and a touch sensor. The category of one embodiment of the present invention includes not only a light-emitting device including a light-emitting element but also an electronic device including a light-emitting device. Accordingly, the light-emitting device in this specification refers to an image display device and a light source (e.g., a lighting device). The light-emitting device may include, in its category, a display module in which a connector such as a flexible printed circuit (FPC) or a tape carrier package (TCP) is connected to a light-emitting element, a display module in which a printed wiring board is provided on the tip of a TCP, or a display module in which an integrated circuit (IC) is directly mounted on a light-emitting element by a chip on glass (COG) method.

One embodiment of the present invention can provide a light-emitting element with high luminous efficiency. Another embodiment of the present invention can provide a light-emitting element with low power consumption. Another embodiment of the present invention can provide a novel light-emitting element. Another embodiment of the present invention can provide a novel light-emitting device. Another embodiment of the present invention can provide a novel display device.

Note that the description of these effects does not disturb the existence of other effects. One embodiment of the present invention does not necessarily have all the effects described above. Other effects will be apparent from and can be derived from the description of the specification, the drawings, the claims, and the like.

### BRIEF DESCRIPTION OF DRAWINGS

In the accompanying drawings:

FIGS. 1A and 1B are schematic cross-sectional views illustrating a light-emitting element of one embodiment of the present invention;

FIGS. 2A and 2B show the correlations of energy levels in a light-emitting element of one embodiment of the present invention;

FIG. 3A is a schematic cross-sectional view of a light-emitting layer of a light-emitting element of one embodiment of the present invention and FIG. 3B is a diagram illustrating the correlation of energy levels;

FIGS. 4A and 4B are schematic cross-sectional views of a light-emitting element of one embodiment of the present invention and FIG. 4C is a diagram illustrating the correlation of energy levels in a light-emitting layer;

FIGS. 5A and 5B are schematic cross-sectional views of a light-emitting element of one embodiment of the present invention and FIG. 5C is a diagram illustrating the correlation of energy levels in a light-emitting layer;

FIGS. 6A and 6B are each a schematic cross-sectional view of a light-emitting element of one embodiment of the present invention;

FIGS. 7A and 7B are each a schematic cross-sectional view of a light-emitting element of one embodiment of the present invention;

FIGS. 8A to 8C are schematic cross-sectional views illustrating a method for manufacturing a light-emitting element of one embodiment of the present invention;

FIGS. 9A to 9C are schematic cross-sectional views illustrating a method for manufacturing a light-emitting element of one embodiment of the present invention;

FIGS. 10A and 10B are a top view and a schematic cross-sectional view illustrating a display device of one embodiment of the present invention;

FIGS. 11A and 11B are schematic cross-sectional views each illustrating a display device of one embodiment of the present invention;

FIG. 12 is a schematic cross-sectional view illustrating a display device of one embodiment of the present invention;

FIGS. 13A and 13B are schematic cross-sectional views each illustrating a display device of one embodiment of the present invention;

FIGS. 14A and 14B are schematic cross-sectional views each illustrating a display device of one embodiment of the present invention;

FIG. 15 is a schematic cross-sectional view illustrating a display device of one embodiment of the present invention;

FIGS. 16A and 16B are schematic cross-sectional views each illustrating a display device of one embodiment of the present invention;

FIG. 17 is a schematic cross-sectional view illustrating a display device of one embodiment of the present invention;

FIGS. 18A and 18B are schematic cross-sectional views each illustrating a display device of one embodiment of the present invention;

FIGS. 19A to 19D are schematic cross-sectional views illustrating a method for forming an EL layer;

FIG. 20 is a conceptual diagram illustrating a droplet discharge apparatus.

FIGS. 21A and 21B are a block diagram and a circuit diagram illustrating a display device of one embodiment of the present invention;

FIGS. 22A and 22B are perspective views of an example of a touch panel of one embodiment of the present invention;

FIGS. 23A to 23C are cross-sectional views of examples of a display device and a touch sensor of one embodiment of the present invention;

FIGS. 24A and 24B are cross-sectional views each illustrating an example of a touch panel of one embodiment of the present invention;

FIGS. 25A and 25B are a block diagram and a timing chart of a touch sensor of one embodiment of the present invention;

FIG. 26 is a circuit diagram of a touch sensor of one embodiment of the present invention;

FIGS. 27A and 27B illustrate the structure of a display device of one embodiment of the present invention;

FIG. 28 is a cross-sectional view illustrating the structure of a display device of one embodiment of the present invention;

FIG. 29 is a diagram illustrating a pixel circuit of a display device of one embodiment of the present invention;

FIGS. 30A, 30B1, and 30B2 illustrate the structures of display devices of embodiments of the present invention;

FIGS. 31A to 31G illustrate electronic devices of embodiments of the present invention.

FIGS. 32A to 32E illustrate electronic devices of embodiments of the present invention.

FIGS. 33A to 33E illustrate electronic devices of embodiments of the present invention.

FIGS. 34A to 34D illustrate electronic devices of embodiments of the present invention.

FIGS. 35A and 35B are perspective views illustrating a display device of one embodiment of the present invention;

FIGS. 36A to 36C are a perspective view and cross-sectional views illustrating a light-emitting device of one embodiment of the present invention;

FIGS. 37A to 37D are cross-sectional views each illustrating a light-emitting device of one embodiment of the present invention;

FIGS. 38A to 38C illustrate a lighting device and an electronic device of one embodiment of the present invention;

FIG. 39 illustrates lighting devices of one embodiment of the present invention;

FIG. 40 is a graph showing the luminance-current density characteristics of a light-emitting element in Example;

FIG. 41 is a graph showing the luminance-voltage characteristics of a light-emitting element in Example;

FIG. 42 is a graph showing the current efficiency-luminance characteristics of light-emitting elements in Example;

FIG. 43 is a graph showing the external quantum efficiency-luminance characteristics of light-emitting elements in Example;

FIG. 44 shows the electroluminescence spectra of light-emitting elements in Example;

FIG. 45 shows emission the spectra of thin films in Example;

FIG. 46 shows results of time-resolved fluorescence measurement of thin films in Example;

FIG. 47 shows results of time-resolved fluorescence measurement of thin films in Example;

FIG. 48 shows the emission spectra of a thin film in Example;

FIG. 49 is a graph showing the relation between the external quantum efficiency of light-emitting elements, the emission energy of the light-emitting elements, and the energy levels of their compounds, in Example;

FIG. 50 is a graph showing the relation between the external quantum efficiency of light-emitting elements, the emission energy of the light-emitting elements, and the energy levels of their compounds, in Example; and

FIG. 51 is a graph showing the relation between the external quantum efficiency of light-emitting elements and the energy difference between the emission energy of the light-emitting elements and the energy level of their compounds, in Example.

### BEST MODE FOR CARRYING OUT THE INVENTION

Embodiments and an example of the present invention will be described below with reference to the drawings. However, the present invention is not limited to the following description, and the mode and details can be variously changed unless departing from the scope and spirit of the present invention. Accordingly, the present invention should not be interpreted as being limited to the content of the embodiments below.

Note that the position, the size, the range, or the like of each structure illustrated in the drawings and the like are not accurately represented in some cases for easy understanding. Therefore, the disclosed invention is not necessarily limited to the position, size, range, or the like as disclosed in the drawings and the like.

Note that the ordinal numbers such as “first”, “second”, and the like in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

In the description of modes of the present invention in this specification and the like with reference to the drawings, the same components in different diagrams are denoted by the same reference numeral in some cases.

In this specification and the like, the terms “film” and “layer” can be interchanged with each other. For example, the term “conductive layer” can be changed into the term “conductive film” in some cases. Also, the term “insulating film” can be changed into the term “insulating layer” in some cases.

In this specification and the like, a singlet excited state (S*) refers to a singlet state having excitation energy. An S1 level means the lowest level of the singlet excitation energy level, that is, the excitation energy level of the lowest singlet excited state (S1 state). A triplet excited state (T*) refers to a triplet state having excitation energy. A T1 level means the lowest level of the triplet excitation energy level, that is, the excitation energy level of the lowest triplet excited state (T1 state). Note that in this specification and the like, simple expressions “singlet excited state” and “singlet excitation energy level” mean the S1 state and the S1 level, respectively, in some cases. In addition, expressions “triplet excited state” and “triplet excitation energy level” mean the T1 state and the T1 level, respectively, in some cases.

In this specification and the like, a fluorescent compound refers to a compound that emits light in the visible light region when the relaxation from the singlet excited state to the ground state occurs. A phosphorescent compound refers to a compound that emits light in the visible light region at room temperature when the relaxation from the triplet excited state to the ground state occurs. That is, a phosphorescent compound refers to a compound that can convert triplet excitation energy into visible light.

Note that in this specification and the like, “room temperature” refers to a temperature higher than or equal to 0° C. and lower than or equal to 40° C.

In this specification and the like, a wavelength range of blue refers to a wavelength range which is greater than or equal to 400 nm and less than 490 nm, and blue light has at least one peak in that wavelength range in an emission spectrum. A wavelength range of green refers to a wavelength range which is greater than or equal to 490 nm and less than 580 nm, and green light has at least one peak in that wavelength range in an emission spectrum. A wavelength range of red refers to a wavelength range which is greater than or equal to 580 nm and less than or equal to 680 nm, and red light has at least one peak in that wavelength range in an emission spectrum.

### Embodiment 1

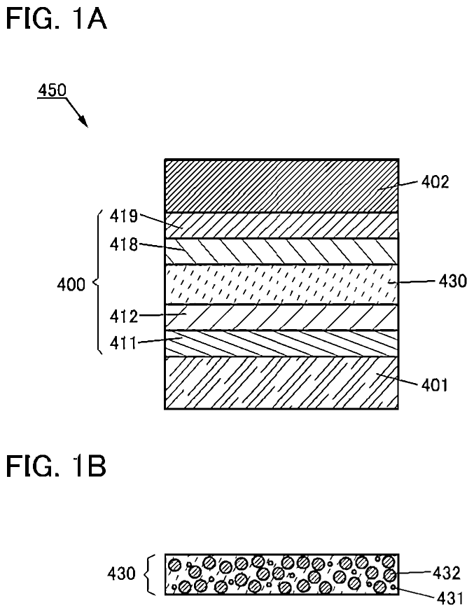

In this embodiment, a light-emitting element of one embodiment of the present invention will be described below with reference to FIGS. 1A to 3B.

### <Structural Example 1 of Light-Emitting Element>

First, the structure of the light-emitting element of one embodiment of the present invention will be described with reference to FIGS. 1A and 1B.

FIG. 1A is a schematic cross-sectional view of a light-emitting element 450 of one embodiment of the present invention.

The light-emitting element 450 includes a pair of electrodes (an electrode 401 and an electrode 402) and an EL layer 400 between the pair of electrodes. The EL layer 400 includes at least a light-emitting layer 430.

The EL layer 400 illustrated in FIG. 1A includes functional layers such as a hole-injection layer 411, a hole-transport layer 412, an electron-transport layer 418, and an electron-injection layer 419, in addition to the light-emitting layer 430.

In this embodiment, although description is given assuming that the electrode 401 and the electrode 402 of the pair of electrodes serve as an anode and a cathode, respectively, they are not limited thereto for the structure of the light-emitting element 450. That is, the electrode 401 may be a cathode, the electrode 402 may be an anode, and the stacking order of the layers between the electrodes may be reversed. In other words, the hole-injection layer 411, the hole-transport layer 412, the light-emitting layer 430, the electron-transport layer 418, and the electron-injection layer 419 may be stacked in this order from the anode side.

The structure of the EL layer 400 is not limited to the structure illustrated in FIG. 1A, and a structure including at least one layer selected from the hole-injection layer 411, the hole-transport layer 412, the electron-transport layer 418, and the electron-injection layer 419 may be employed. Alternatively, the EL layer 400 may include a functional layer which is capable of lowering a hole-or electron-injection barrier, improving a hole- or electron-transport property, inhibiting a hole- or electron-transport property, or suppressing a quenching phenomenon by an electrode, for example. Note that the functional layers can each be either a single layer or stacked layers.

FIG. 1B is a schematic cross-sectional view illustrating an example of the light-emitting layer 430 in FIG. 1A. The light-emitting layer 430 in FIG. 1B includes an organic compound 431 and an organic compound 432.

In the light-emitting element 450 of one embodiment of the present invention, voltage application between the pair of electrodes (the electrodes 401 and 402) allows electrons and holes to be injected from the cathode and the anode, respectively, into the EL layer 400 and thus a current flows. By recombination of the injected carriers (electrons and holes), excitons are formed. The ratio of singlet excitons to triplet excitons (hereinafter referred to as exciton generation probability) which are generated by carrier (electrons and holes) recombination is approximately 1:3 according to the statistically obtained probability. Accordingly, in a fluorescent light-emitting element, the probability of generation of singlet excitons, which contribute to light emission, is 25% and the probability of generation of triplet excitons, which do not contribute to light emission, is 75%. Therefore, converting the triplet excitons, which do not contribute to light emission, into singlet excitons, which contribute to light emission, is important in increasing the luminous efficiency of the light-emitting element.

### <Light Emission Mechanism of Light-Emitting Element>

Next, the light emission mechanism of the light-emitting layer 430 will be described below.

The organic compound 431 and the organic compound 432 included in the light-emitting layer 430 are preferably a combination that forms an exciplex.

Although it is acceptable as long as the combination of the organic compound 431 and the organic compound 432 can form an exciplex, it is preferable that one of them be a compound having a function of transporting holes (a hole-transport property) and the other be a compound having a function of transporting electrons (an electron-transport property). In that case, a donor-acceptor exciplex is formed easily; thus, efficient formation of an exciplex is possible. In the case where the combination of the organic compounds 431 and 432 is a combination of a compound having a hole-transport property and a compound having an electron-transport property, the carrier balance can be easily controlled by adjusting the mixture ratio. Specifically, the weight ratio of the compound having a hole-transport property to the compound having an electron-transport property is preferably within a range of 1:9 to 9:1. Since the carrier balance can be easily controlled with the structure, a carrier recombination region can also be controlled easily.

In order to efficiently form an exciplex, the combination of host materials preferably satisfies the following: the highest occupied molecular orbital (also referred to as HOMO) level of one of the organic compound 431 and the organic compound 432 is higher than the HOMO level of the other of the organic compounds, and the lowest unoccupied molecular orbital (also referred to as LUMO) level of the one of the organic compounds is higher than the LUMO level of the other of the organic compounds.

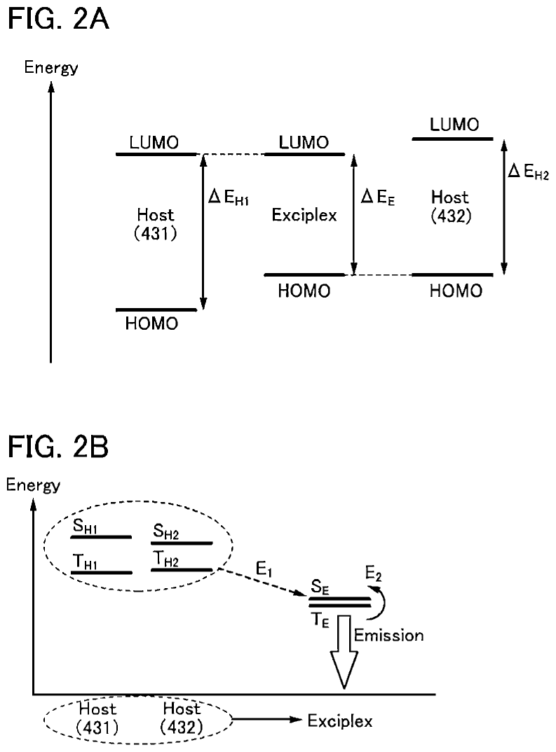

For example, when the organic compound 431 has an electron-transport property and the organic compound 432 has a hole-transport property, it is preferable that the HOMO level of the organic compound 432 be higher than the HOMO level of the organic compound 431 and the LUMO level of the organic compound 432 be higher than the LUMO level of the organic compound 431 as in an energy band diagram of FIG. 2A. Specifically, a difference in HOMO level between the organic compounds 431 and 432 is preferably greater than or equal to 0.05 eV, more preferably greater than or equal to 0.1 eV, and still more preferably greater than or equal to 0.2 eV A difference in LUMO level between the organic compounds 431 and 432 is preferably greater than or equal to 0.05 eV, more preferably greater than or equal to 0.1 eV, and still more preferably greater than or equal to 0.2 eV The energy difference is preferred because it facilitates injection of electrons and holes serving as carriers from the pair of electrodes (the electrode 401 and the electrode 402) to the organic compound 431 and the organic compound 432, respectively.

In FIG. 2A, Host (431) represents the organic compound 431; Host (432) represents the organic compound 432; ΔE_{H1} represents the energy difference between the LUMO level and the HOMO level of the organic compound 431; ΔE_{H2} represents the energy difference between the LUMO level and the HOMO level of the organic compound 432; ΔE_{E} represents the energy difference between the LUMO level of the organic compound 431 and the HOMO level of the organic compound 432.

Furthermore, in that case, an exciplex formed by the organic compound 431 and the organic compound 432 has LUMO in the organic compound 431 and HOMO in the organic compound 432. The excitation energy of the exciplex substantially corresponds to the energy difference between the LUMO level of the organic compound 431 and the HOMO level of the organic compound 432 (ΔE_{E}) and is smaller than the energy difference between the LUMO level and the HOMO level of the organic compound 431 (ΔE_{H1}) and the energy difference between the LUMO level and the HOMO level of the organic compound 432 (ΔE_{H2}). Thus, when the organic compound 431 and the organic compound 432 form an exciplex, an excited state can be formed with lower excitation energy. Having lower excitation energy, the exciplex can form a stable excited state.

FIG. 2B shows the correlation of the energy levels of the organic compound 431 and the organic compound 432 in the light-emitting layer 430. The following explains what terms and signs in FIG. 2B represent:
Host (431): the organic compound 431;
Host (432): the organic compound 432;
S_{H1}: the S1 level of the organic compound 431;
T_{H1}: the T1 level of the organic compound 431;
S_{H2}: the S1 level of the organic compound 432;
T_{H2}: the T1 level of the organic compound 432;
S_{E}: the S1 level of the exciplex; and
T_{E}: the T1 level of the exciplex.

In the light-emitting element of one embodiment of the present invention, the organic compounds 431 and 432 included in the light-emitting layer 430 form an exciplex. The S1 level of the exciplex (S_{E}) and the T1 level of the exciplex (T_{E}) are close to each other (see Route E₁ in FIG. 2B).

An exciplex is an excited state formed from two kinds of substances. In photoexcitation, the exciplex is formed by interaction between one substance in an excited state and the other substance in a ground state. The two kinds of substances that have formed the exciplex return to a ground state by emitting light and then serve as the original two kinds of substances. In electrical excitation, when one substance is brought into an excited state, the one immediately interacts with the other substance to form an exciplex. Alternatively, one substance receives a hole and the other substance receives an electron to readily form an exciplex. In this case, any of the substances can form an exciplex without forming an excited state and; accordingly, most excitons in the light-emitting layer 430 can exist as exciplexes. Because the excitation energy levels of the exciplex (S_{E} and T_{E}) are lower than the S1 levels of the organic compounds that form the exciplex (the organic compound 431 and the organic compound 432) (S_{H1} and S_{H2}), the excited state of the organic compound 431 can be formed with lower excitation energy. Accordingly, the driving voltage of the light-emitting element 450 can be reduced.

Since the S1 level and the T1 level of the exciplex (S_{E} and T_{E}) are adjacent to each other, the exciplex has a function of exhibiting thermally activated delayed fluorescence. In other words, the exciplex has a function of converting triplet excitation energy into singlet excitation energy by reverse intersystem crossing (upconversion) (see Route E₂ in FIG. 2B). Thus, the triplet excitation energy generated in the light-emitting layer 430 is partly converted into singlet excitation energy by the exciplex. In order to cause this conversion, the energy difference between the S1 level and the T1 level of the exciplex (S_{E} and T_{E}) is preferably greater than 0 eV and less than or equal to 0.2 eV, more preferably greater than 0 eV and less than or equal to 0.1 eV. Note that in order to efficiently make reverse intersystem crossing occur, the T1 level of the exciplex (T_{E}) is preferably lower than the T1 levels of the organic compounds that form an exciplex (the organic compound 431 and the organic compound 432) (T_{H1} and T_{H2}). In that case, quenching of the triplet excitation energy of the exciplex due to the organic compounds is less likely to occur, which causes reverse intersystem crossing efficiently.

Light emission can be obtained from an exciplex in the singlet excited state directly formed by carrier recombination and an exciplex in the singlet excited state formed through reverse intersystem crossing. Note that the emission energy of the exciplex (abbreviation: ΔE_{Em}) corresponds to the energy of the S1 level of the exciplex (S_{E}) and is smaller than or equal to the energy difference between the LUMO level and the HOMO level of the exciplex (ΔE_{E}) (ΔE_{E}≥ΔE_{Em}). The present inventor has found that light emission can be efficiently obtained from the exciplex formed by the organic compounds 431 and 432 when the lower of the T1 levels of the organic compounds that form an exciplex (the organic compound 431 and the organic compound 432) (T_{H1} and T_{H2}) has energy that is larger than the emission energy of the exciplex (ΔE_{Em}) by −0.2 eV or more and 0.4 eV or less, preferably by 0 eV or more and 0.4 eV or less. Thus, quenching of the triplet excitation energy of the exciplex due to the organic compounds is less likely to occur, which causes reverse intersystem crossing efficiently.

Note that the emission energy can be derived from a peak wavelength (including a maximal value or a shoulder) on the shortest wavelength side of the emission spectrum.

When the T1 levels of the organic compounds (the organic compound 431 and the organic compound 432) (T_{H1} and T_{H2}) are sufficiently higher than the T1 level of the exciplex (T_{E}), the T1 levels and the S1 levels of the organic compounds (the organic compound 431 and the organic compound 432) (T_{H1} and T_{H2}, and S_{H1} and S_{H2}) have large excitation energies, and the energy differences between the LUMO level and the HOMO level of each of the organic compounds (the organic compound 431 and the organic compound 432) (ΔE_{H1} and ΔE_{H2}) is also large. In this case, injection of carriers (electrons and holes) into the organic compound 431 and the organic compound 432 is difficult, so that an exciplex is not easily formed. In the case where carrier recombination occurs in one of the organic compound 431 and the organic compound 432 and the one organic compound forms an exciplex with the other, when the organic compound 431 and the organic compound 432 have large excitation energies, the energy difference between the excitation energy of the exciplex and each of the excitation energies of the organic compound 431 and the organic compound 432 is large. Thus, nonradiative deactivation, where energy corresponding to the energy difference is discharged, needs to occur in formation of the exciplex, which causes significant relaxation of the three-dimensional structure of molecules. When there is a noticeable difference in the three-dimensional structure of molecules between the exciplex and the organic compound 431 in the excited state or the organic compound 432 in the excited state, the rate constant of a reaction for forming the exciplex is small; thus, the exciplex is not easily formed. For this reason, the energy difference between the emission energy of the exciplex (ΔE_{Em}) and at least the lower of the T1 levels of the organic compounds that form an exciplex (the organic compound 431 and the organic compound 432) (T_{H1} and T_{H2}) is preferably small. Specifically, the energy difference between the emission energy of the exciplex (ΔE_{Em}) and the lower of the T1 levels of the organic compounds that form an exciplex (the organic compound 431 and the organic compound 432) (T_{H1} and T_{H2}) is smaller than or equal to 0.4 eV.

Thus, the lower of the T1 levels of the organic compounds that form an exciplex (the organic compound 431 and the organic compound 432) (T_{H1} and T_{H2}) preferably has energy that is larger than the emission energy of the exciplex (ΔE_{Em}) by −0.2 eV or more and 0.4 eV or less, more preferably by 0 eV or more and 0.4 eV or less.

Furthermore, the energy difference between the LUMO level of the organic compound 431 and the HOMO level of the organic compound 432 (ΔE_{E}) is greater than or equal to the emission energy of the exciplex (ΔE_{Em}) formed by the organic compounds (ΔE_{E}≥ΔE_{Em}). However, in the case where the three-dimensional structure of molecules of the exciplex (the organic compound 431 and the organic compound 432) in the excited state is noticeably different from that of molecules of the organic compound 431 and the organic compound 432 in the ground state, relaxation of the three-dimensional structure of molecules is significant in the emission process of the exciplex, and the energy difference between ΔE_{E} and ΔE_{Em} becomes larger. In that case, the rate constant of emission of the exciplex becomes smaller, which might decrease the luminous efficiency of the exciplex. Accordingly, the energy difference between the emission energy of the exciplex formed by the organic compounds (ΔE_{Em}) and the energy difference between the LUMO level of the organic compound 431 and the HOMO level of the organic compound 432 (ΔE_{E}) is preferably small. Specifically, the energy difference between the LUMO level of the organic compound 431 and the HOMO level of the organic compound 432 (ΔE_{E}) is preferably greater than ΔE_{Em} by −0.1 eV or more and 0.4 eV or less (ΔE_{Em}−0.1 eV≥ΔE_{E}≥ΔE_{Em}+0.4 eV), more preferably by 0 eV or more and 0.4 eV or less (ΔE_{Em}≥ΔE_{E}≥ΔE_{Em}+0.4 eV).

Note that the LUMO levels and the HOMO levels of the organic compounds can be derived from the electrochemical characteristics (the reduction potentials and the oxidation potentials) of the organic compounds that are measured by cyclic voltammetry (CV).

### <Structural Example 2 of Light-Emitting Element>

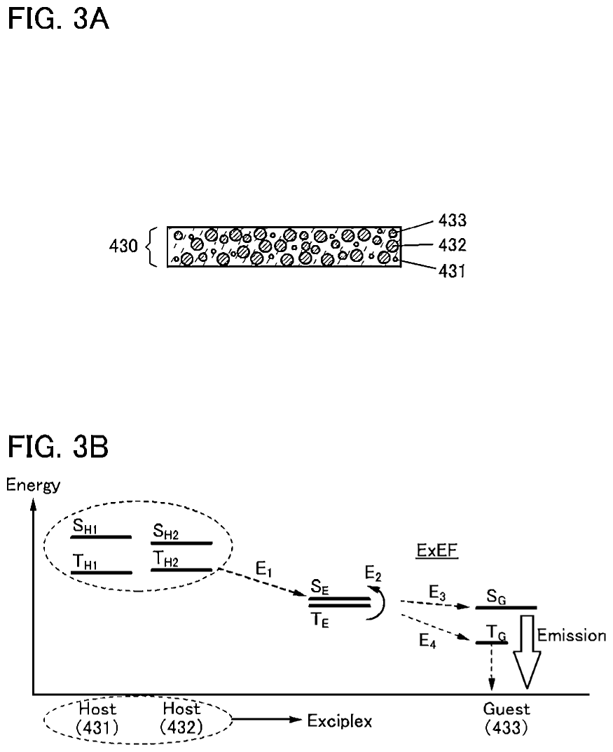

Next, a structural example different from the light-emitting layer illustrated in FIG. 1B will be described below with reference to FIG. 3A.

FIG. 3A is a schematic cross-sectional view illustrating an example of the light-emitting layer 430 in FIG. 1A. The light-emitting layer 430 in FIG. 3A includes the organic compound 431, the organic compound 432, and a guest material 433.

The guest material 433 may be a light-emitting organic compound, and the light-emitting organic compound is preferably a substance capable of emitting fluorescence (hereinafter also referred to as a fluorescent compound). A structure in which a fluorescent compound is used as the guest material 433 will be described below. The guest material 433 may be referred to as the fluorescent compound.

### <Light Emission Mechanism 2 of Light-Emitting Element>

FIG. 3B shows the correlation of the energy levels of the organic compound 431, the organic compound 432, and the guest material 433 in the light-emitting layer 430 in FIG. 3A. The following explains what terms and signs in FIG. 3B represent:
Host (431): the organic compound 431;
Host (432): the organic compound 432;
Guest (433): guest material 433 (fluorescent compound)
S_{H1}: the S1 level of the organic compound 431;
T_{H1}: the T1 level of the organic compound 431;
S_{H2}: the S1 level of the organic compound 432;
T_{H2}: the T1 level of the organic compound 432;
S_{G}: the S1 level of the guest material 433 (fluorescent compound);
T_{G}: the T1 level of the guest material 433 (fluorescent compound);
S_{E}: the S1 level of the exciplex; and
T_{E}: the T1 level of the exciplex.

In the light-emitting layer 430, the host material (the organic compounds 431 and 432) is present in the highest proportion by weight, and the guest material 433 (fluorescent compound) is dispersed in the host material (the organic compounds 431 and 432). The S1 level of the host material (the organic compounds 431 and 432) (S_{H1} and S_{H2}) of the light-emitting layer 430 is preferably higher than the S1 level of the guest material 433 (fluorescent compound) (S_{G}) of the light-emitting layer 430. In addition, the T1 level of the host material (the organic compounds 431 and 432) (T_{H1} and T_{H2}) of the light-emitting layer 430 is preferably higher than the T1 level of the guest material 433 (fluorescent compound) (T_{G}) of the light-emitting layer 430.

Furthermore, the S1 level of the exciplex (S_{E}) is preferably higher than the S1 level of the guest material 433 (S_{G}). In that case, the singlet excitation energy of the formed exciplex can be transferred from the S1 level of the exciplex (S_{E}) to the S1 level of the guest material 433 (S_{G}), so that the guest material 433 is brought into the singlet excited state, causing light emission (see Route E₃ in FIG. 3B).

To obtain efficient light emission from the singlet excited state of the guest material 433, the fluorescence quantum yield of the guest material 433 is preferably high, and specifically, 50% or higher, more preferably 70% or higher, still more preferably 90% or higher.

Note that since direct transition from a singlet ground state to a triplet excited state in the guest material 433 is forbidden, energy transfer from the S1 level of the exciplex (S_{E}) to the T1 level of the guest material 433 (T_{G}) is unlikely to be a main energy transfer process.

When transfer of the triplet excitation energy from the T1 level of the exciplex (T_{E}) to the T1 level of the guest material 433 (T_{G}) occurs, the triplet excitation energy is deactivated (see Route E₄ in FIG. 3B). Thus, it is preferable that the energy transfer of Route E₄ be less likely to occur because the efficiency of generating the triplet excited state of the guest material 433 can be decreased and thermal deactivation can be reduced. In order to make this condition, the weight ratio of the guest material 433 to the total of the organic compounds 431 and 432 is preferably low, specifically, preferably greater than or equal to 0.001 and less than or equal to 0.05, more preferably greater than or equal to 0.001 and less than or equal to 0.01.

Note that when the direct carrier recombination process in the guest material 433 is dominant, a large number of triplet excitons are generated in the light-emitting layer 430, resulting in decreased luminous efficiency due to thermal deactivation. Thus, it is preferable that the probability of the energy transfer process through the exciplex formation process (Routes E₂ and E₃ in FIG. 3B) be higher than the probability of the direct carrier recombination process in the guest material 433 because the efficiency of generating the triplet excited state of the guest material 433 can be decreased and thermal deactivation can be reduced. Therefore, as described above, the weight ratio of the guest material 433 to the total of the organic compounds 431 and 432 is preferably low, specifically, preferably greater than or equal to 0.001 and less than or equal to 0.05, more preferably greater than or equal to 0.001 and less than or equal to 0.01.

By making all the energy transfer processes of Routes E₂ and E₃ efficiently occur in the above-described manner, both the singlet excitation energy and the triplet excitation energy of the organic compound 431 can be efficiently converted into the singlet excitation energy of the guest material 433, whereby the light-emitting element 450 can emit light with high luminous efficiency.

The above-described processes through Routes E₁, E₂, and E₃ may be referred to as exciplex-singlet energy transfer (ExSET) or exciplex-enhanced fluorescence (ExEF) in this specification and the like. In other words, in the light-emitting layer 430, excitation energy is transferred from the exciplex to the guest material 433.

When the light-emitting layer 430 has the above-described structure, light emission from the guest material 433 of the light-emitting layer 430 can be obtained efficiently.

### <Energy Transfer Mechanism>

Next, factors that control the processes of intermolecular energy transfer between the host material (the organic compounds 431 and 432) and the guest material 433 will be described. As mechanisms of the intermolecular energy transfer, two mechanisms, i.e., the Forster mechanism (dipole-dipole interaction) and the Dexter mechanism (electron exchange interaction), have been proposed. Although the intermolecular energy transfer process between the host material and the guest material 433 is described here, the same can apply to the case where the host material is an exciplex.

### <<Forster Mechanism>>

In the Forster mechanism, energy transfer does not require direct contact between molecules and energy is transferred through a resonant phenomenon of dipolar oscillation between the host material and the guest material 433. By the resonant phenomenon of dipolar oscillation, the host material provides energy to the guest material 433, and thus, the host material in an excited state is brought to a ground state and the guest material 433 in a ground state is brought to an excited state. Note that the rate constant k_{h*→g} of the Forster mechanism is expressed by Formula (1).

$$\begin{matrix}[ Formula 1 ] & \\ {k}_{{h}^{*} \to g} = \frac{{9000}_{c}^{4} {K}^{2} ϕ ln 10}{{128}_{π}^{5} {n}^{4} N {τ}_{R}^{6}} \int \frac{{f}_{h}^{′} ( v ) {ε}_{g} ( v )}{{v}^{4}} dv & ( 1 )\end{matrix}$$

In Formula (1), v represents a frequency, f′ₕ(v) represents a normalized emission spectrum of the host material (a fluorescent spectrum in the case where energy transfer from a singlet excited state is discussed, and a phosphorescent spectrum in the case where energy transfer from a triplet excited state is discussed), ε_{g}(v) represents the molar absorption coefficient of the guest material 433, N represents Avogadro's number, n represents the refractive index of a medium, R represents an intermolecular distance between the host material and the guest material 433, τ represents a measured lifetime of an excited state (fluorescence lifetime or phosphorescence lifetime), c represents the speed of light, ϕ represents a luminescence quantum yield (a fluorescence quantum yield in the case where energy transfer from a singlet excited state is discussed, and a phosphorescence quantum yield in the case where energy transfer from a triplet excited state is discussed), and K² represents a coefficient (0 to 4) of orientation of a transition dipole moment between the host material and the guest material 433. Note that K² is ⅔ in the case of random orientation.

### <<Dexter Mechanism>>

In the Dexter mechanism, the host material and the guest material 433 are close to a contact effective range where their orbitals overlap with each other, and the host material in an excited state and the guest material 433 in a ground state exchange their electrons, which leads to energy transfer. Note that the rate constant k_{h*→g} of the Dexter mechanism is expressed by Formula (2).

$$\begin{matrix}[ Formula 2 ] & \\ {k}_{{h}^{*} \to g} = ( \frac{2 π}{h} ) {K}^{2} exp ( - \frac{2 R}{L} ) \int {f}_{h}^{′} ( v ) {ε}_{g}^{′} ( v ) dv & ( 2 )\end{matrix}$$

In Formula (2), h represents a Planck constant, K represents a constant having an energy dimension, v represents a frequency, f′ₕ(v) represents a normalized emission spectrum of the host material (a fluorescent spectrum in the case where energy transfer from a singlet excited state is discussed, and a phosphorescent spectrum for energy transfer in the case where energy transfer from a triplet excited state is discussed), ε′_{g}(v) represents the normalized absorption spectrum of the guest material 433, L represents an effective molecular radius, and R represents an intermolecular distance between the host material and the guest material 433.

Here, the efficiency of energy transfer from the host material to the guest material 433 (energy transfer efficiency ϕ_{ET}) is expressed by Formula (3). In the formula, kᵣ represents the rate constant of a light-emission process (a fluorescent light-emission process in the case where energy transfer from a singlet excited state is discussed, and a phosphorescent light-emission process in the case where energy transfer from a triplet excited state is discussed) of the host material, kₙ represents the rate constant of a non-light-emission process (thermal deactivation or intersystem crossing) of the host material, and τ represents a measured lifetime of an excited state of the host material.

$$\begin{matrix}[ Formula 3 ] & \\ {ϕ}_{E T} = \frac{{k}_{{h}^{*} \to g}}{{k}_{r} + {k}_{n} + {k}_{{h}^{*} \to g}} = \frac{{k}_{{h}^{*} \to g}}{( \frac{1}{τ} ) + {k}_{{h}^{*} \to g}} & ( 3 )\end{matrix}$$

According to Formula (3), it is found that the energy transfer efficiency d_{ET} can be increased by increasing the rate constant k_{h*→g} of energy transfer so that another competing rate constant kᵣ+kₙ (=1/τ) becomes relatively small.

### <<Concept for Promoting Energy Transfer>>

First, an energy transfer by the Forster mechanism will be described. When Formula (1) is substituted into Formula (3), τ can be eliminated. Thus, in Förster mechanism, the energy transfer efficiency ϕ_{ET} does not depend on the lifetime τ of the excited state of the host material. In addition, it can be said that the energy transfer efficiency ϕ_{ET} is higher when the luminescence quantum yield ϕ (here, the fluorescence quantum yield because energy transfer from a singlet excited state is discussed) is higher. In general, the luminescence quantum yield of an organic compound in a triplet excited state is extremely low at room temperature. Thus, in the case where the host material is in a triplet excited state, a process of energy transfer by the Forster mechanism can be ignored, and a process of energy transfer by the Forster mechanism is considered only in the case where the host material is in a singlet excited state.

Furthermore, it is preferable that the emission spectrum (the fluorescent spectrum in the case where energy transfer from a singlet excited state is discussed) of the host material largely overlap with the absorption spectrum (absorption corresponding to the transition from the singlet ground state to the singlet excited state) of the guest material 433. Moreover, it is preferable that the molar absorption coefficient of the guest material 433 be also high. This means that the emission spectrum of the host material overlaps with the absorption band of the guest material 433 which is on the longest wavelength side. Since direct transition from the singlet ground state to the triplet excited state of the guest material 433 is forbidden, the molar absorption coefficient of the guest material 433 in the triplet excited state can be ignored. Thus, a process of energy transfer to a triplet excited state of the guest material 433 by the Forster mechanism can be ignored, and only a process of energy transfer to a singlet excited state of the guest material 433 is considered. That is, in the Forster mechanism, a process of energy transfer from the singlet excited state of the host material to the singlet excited state of the guest material 433 is considered.

Next, an energy transfer by the Dexter mechanism will be described. According to Formula (2), in order to increase the rate constant k_{h*→g}, it is preferable that the emission spectrum of the host material (a fluorescent spectrum in the case where energy transfer from a singlet excited state is discussed) largely overlap with an absorption spectrum of the guest material 433 (absorption corresponding to transition from a singlet ground state to a singlet excited state). Therefore, the energy transfer efficiency can be optimized by making the emission spectrum of the host material overlap with the absorption band of the guest material 433 which is on the longest wavelength side.

When Formula (2) is substituted into Formula (3), it is found that the energy transfer efficiency ϕ_{ET} in the Dexter mechanism depends on τ. In the Dexter mechanism, which is a process of energy transfer based on the electron exchange, as well as the energy transfer from the singlet excited state of the host material to the singlet excited state of the guest material 433, energy transfer from the triplet excited state of the host material to the triplet excited state of the guest material 433 occurs.

In the light-emitting element of one embodiment of the present invention in which the guest material 433 is a fluorescent compound, the efficiency of energy transfer to the triplet excited state of the guest material 433 is preferably low. That is, the energy transfer efficiency based on the Dexter mechanism from the host material to the guest material 433 is preferably low and the energy transfer efficiency based on the Forster mechanism from the host material to the guest material 433 is preferably high.

To increase the energy transfer efficiency based on the Förster mechanism from the host material to the guest material 433, the fluorescence quantum yield (also referred to as luminous efficiency) of the host material is preferably increased.

As described above, the energy transfer efficiency in the Forster mechanism does not depend on the lifetime τ of the excited state of the host material. In contrast, the energy transfer efficiency in the Dexter mechanism depends on the excitation lifetime τ of the host material. To reduce the energy transfer efficiency in the Dexter mechanism, the excitation lifetime τ of the host material is preferably short.

In a manner similar to that of the energy transfer from the host material to the guest material 433, the energy transfer by both the Forster mechanism and the Dexter mechanism also occurs in the energy transfer process from the exciplex to the guest material 433.

Accordingly, one embodiment of the present invention provides a light-emitting element including, as the host material, the organic compound 431 and the organic compound 432 which are a combination for forming an exciplex functioning as an energy donor capable of efficiently transferring energy to the guest material 433. The exciplex formed by the organic compound 431 and the organic compound 432 has the S1 level and the T1 level which are close to each other; accordingly, transition from a triplet exciton generated in the light-emitting layer 430 to a singlet exciton (reverse intersystem crossing) is likely to occur. This can increase the efficiency of generating singlet excitons in the light-emitting layer 430. Furthermore, in order to facilitate energy transfer from the singlet excited state of the exciplex to the singlet excited state of the guest material 433 functioning as an energy acceptor, it is preferable that the emission spectrum of the exciplex overlap with the absorption band of the guest material 433 which is on the longest wavelength side (lowest energy side). In that case, the efficiency of generating the singlet excited state of the guest material 433 can be increased.

To increase the luminous efficiency of the exciplex, the lower of the T1 levels of the organic compounds that form an exciplex (the organic compound 431 and the organic compound 432) (T_{H1} and T_{H2}) preferably has energy that is larger than the emission energy of the exciplex (ΔE_{Em}) by −0.2 eV or more and 0.4 eV or less, as described above. The energy difference between the LUMO level of the organic compound 431 and the HOMO level of the organic compound 432 (ΔE_{E}) is preferably greater than ΔE_{Em} by −0.1 eV or more and 0.4 eV or less, more preferably by 0 eV or more and 0.4 eV or less.

In addition, the fluorescence lifetime of a thermally activated delayed fluorescent component in light emitted from the exciplex is preferably short, and specifically, preferably 10 ns or longer and 50 μs or shorter, more preferably 10 ns or longer and 40 μs or shorter, still more preferably 10 ns or longer and 30 μs or shorter.

The proportion of a thermally activated delayed fluorescent component in the light emitted from the exciplex is preferably high. Specifically, the proportion of a thermally activated delayed fluorescent component in the light emitted from the exciplex is preferably higher than or equal to 5%, more preferably higher than or equal to 8%, still more preferably higher than or equal to 10%.

### <Material>

Next, components of a light-emitting element of one embodiment of the present invention will be described in detail below.

### <<Light-Emitting Layer>>

Next, materials that can be used for the light-emitting layer 430 will be described below.

Although there is no particular limitation as long as the combination of the organic compound 431 and the organic compound 432 can form an exciplex, it is preferable that one of them have a function of transporting electrons and the other have a function of transporting holes. Furthermore, it is preferred that one of the organic compound 431 and the organic compound 432 include a π-electron deficient heteroaromatic ring skeleton and the other include at least one of a π-electron rich heteroaromatic ring skeleton and an aromatic amine skeleton.

As the aromatic amine skeleton included in the organic compound 431 or 432, tertiary amine not including an NH bond, in particular, a triarylamine skeleton is preferably used. As an aryl group of a triarylamine skeleton, a substituted or unsubstituted aryl group having 6 to 13 carbon atoms included in a ring is preferably used and examples thereof include a phenyl group, a naphthyl group, and a fluorenyl group.

As the π-electron rich heteroaromatic ring skeleton included in the organic compound 431 or 432, one or more of a furan skeleton, a thiophene skeleton, and a pyrrole skeleton are preferable because of their high stability and reliability. As a furan skeleton, a dibenzofuran skeleton is preferable. As a thiophene skeleton, a dibenzothiophene skeleton is preferable. Note that as a pyrrole skeleton, an indole skeleton or a carbazole skeleton, in particular, a 3-(9-phenyl-9H-carbazol-3-yl)-9H-carbazole skeleton is preferable. Each of these skeletons may further have a substituent.

A structure including a π-electron rich heteroaromatic ring skeleton and an aromatic amine skeleton, which has an excellent hole-transport property and thus is stable and highly reliable, is particularly preferred. An example of such a structure is a structure including a carbazole skeleton and an arylamine skeleton.

As examples of the above-described aromatic amine skeleton and π-electron rich heteroaromatic ring skeleton, skeletons represented by the following general formulae (101) to (117) are given. Note that X in the general formulae (115) to (117) represents an oxygen atom or a sulfur atom.

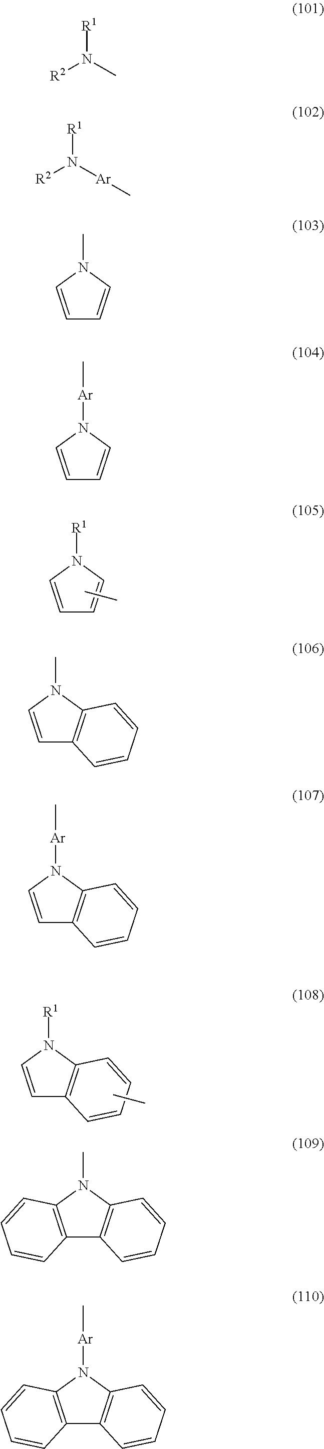

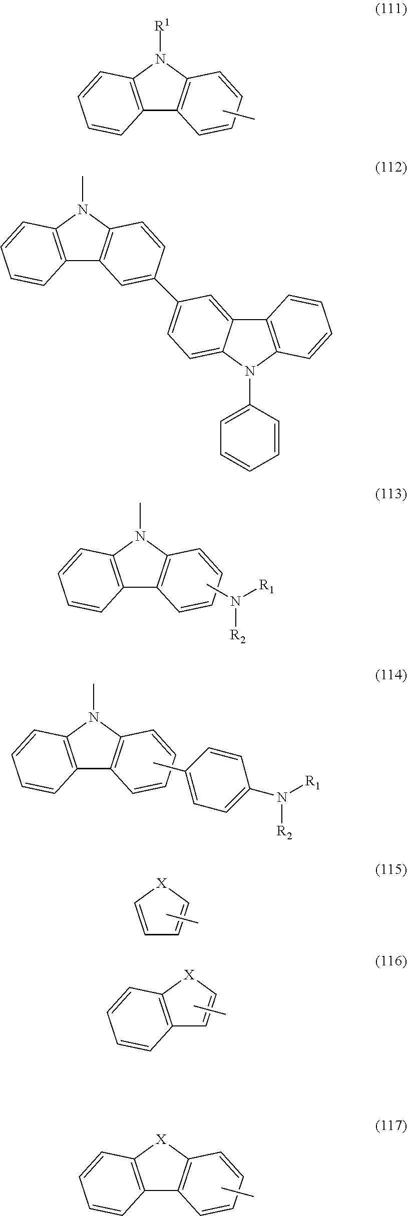

Among the π-electron deficient heteroaromatic ring skeletons, a pyridine skeleton, a diazine skeleton (a pyrimidine skeleton, a pyrazine skeleton, or a pyridazine skeleton), or a triazine skeleton is preferred; in particular, the diazine skeleton or the triazine skeleton is preferred because of its high stability and reliability.

As examples of the above-described it-electron deficient heteroaromatic ring skeleton, skeletons represented by the following general formulae (201) to (218) are given. Note that X in General Formulae (209) to (211) represents an oxygen atom or a sulfur atom.

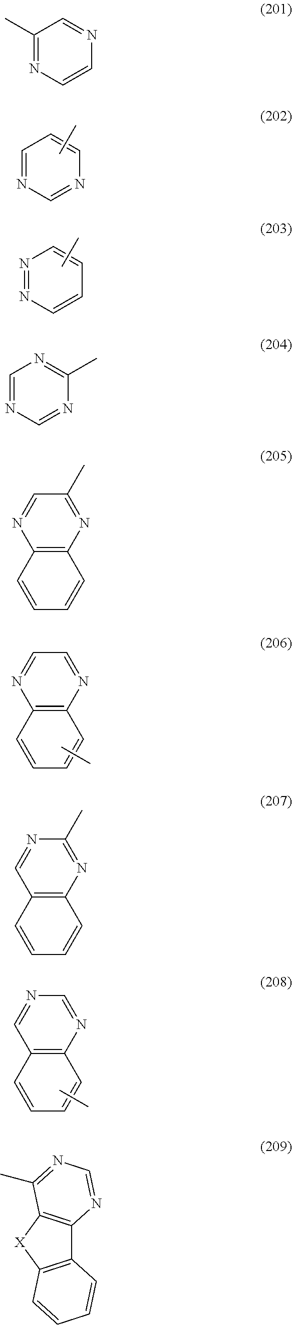

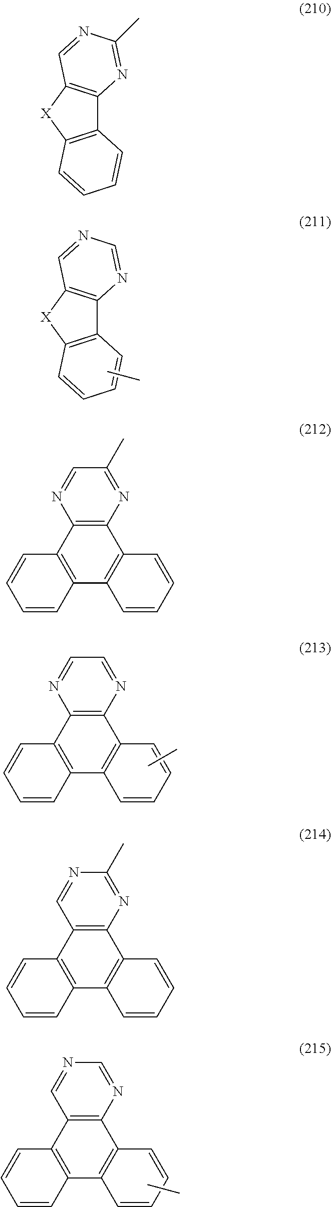

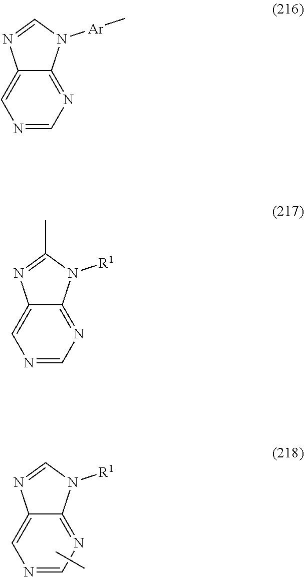

Alternatively, a compound may be used in which a skeleton having a hole-transport property (e.g., at least one of a π-electron rich heteroaromatic ring skeleton and an aromatic amine skeleton) and a skeleton having an electron-transport property (e.g., a π-electron deficient heteroaromatic ring skeleton) are bonded to each other directly or through an arylene group. Examples of the above-described arylene group include a phenylene group, a biphenyldiyl group, a naphthalenediyl group, and a fluorenediyl group.

As examples of a bonding group which bonds the above skeleton having a hole-transport property and the above skeleton having an electron-transport property, groups represented by the following general formulae (301) to (315) are given.

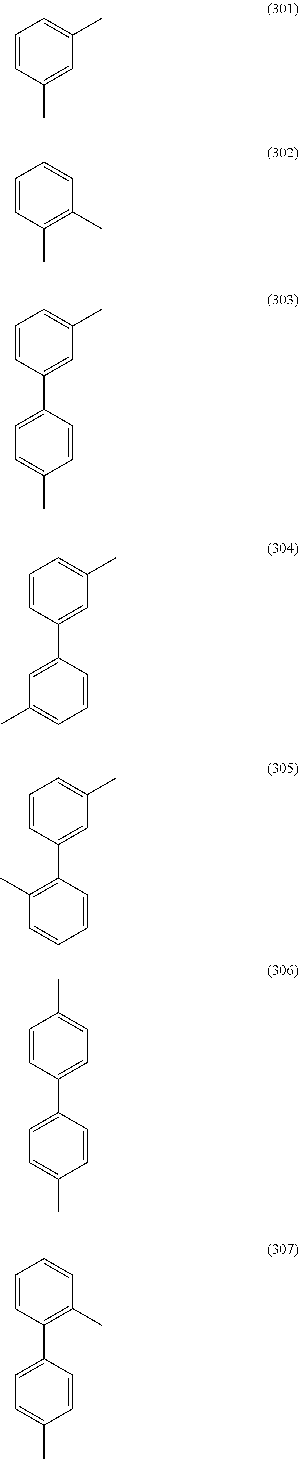

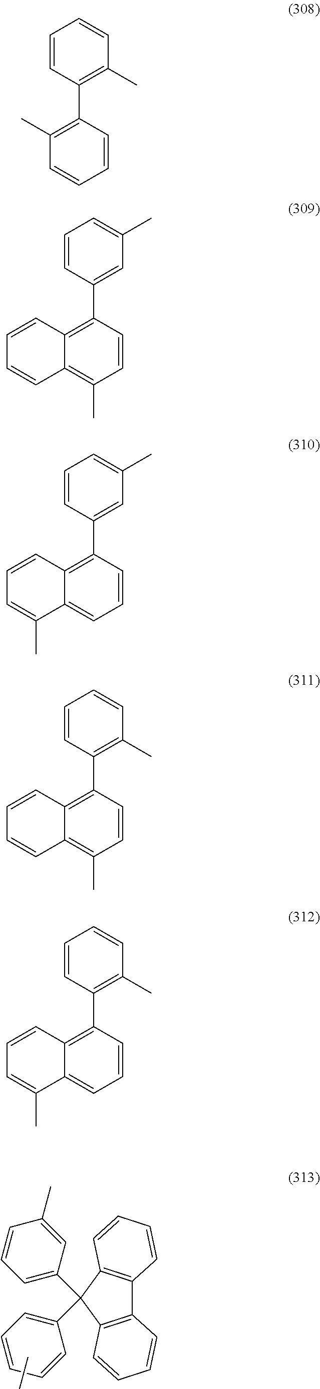

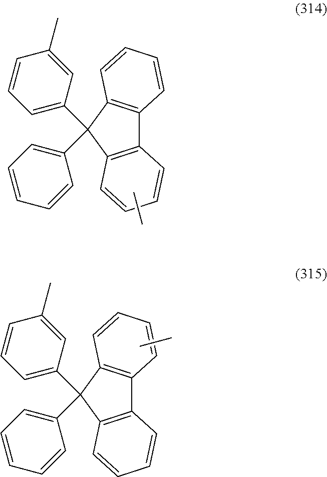

The above aromatic amine skeleton (e.g., the triarylamine skeleton), the above π-electron rich heteroaromatic ring skeleton (e.g., a ring including the furan skeleton, the thiophene skeleton, or the pyrrole skeleton), and the above π-electron deficient heteroaromatic ring skeleton (e.g., a ring including the diazine skeleton or the triazine skeleton) or the above general formulae (101) to (115), (201) to (218), and (301) to (315) may each have a substituent. As the substituent, an alkyl group having 1 to 6 carbon atoms, a cycloalkyl group having 3 to 6 carbon atoms, or a substituted or unsubstituted aryl group having 6 to 13 carbon atoms can be selected. Specific examples of the alkyl group having 1 to 6 carbon atoms include a methyl group, an ethyl group, a propyl group, an isopropyl group, a butyl group, an isobutyl group, a tert-butyl group, an n-hexyl group, and the like. Specific examples of a cycloalkyl group having 3 to 6 carbon atoms include a cyclopropyl group, a cyclobutyl group, a cyclopentyl group, a cyclohexyl group, and the like. Specific examples of the aryl group having 6 to 13 carbon atoms are a phenyl group, a naphthyl group, a biphenyl group, and the like. The above substituents may be bonded to each other to form a ring. For example, in the case where a carbon atom at the 9-position in a fluorene skeleton has two phenyl groups as substituents, the phenyl groups are bonded to form a spirofluorene skeleton. Note that an unsubstituted group has an advantage in easy synthesis and an inexpensive raw material.

Furthermore, Ar represents a single-bond arylene group or an arylene group having 6 to 13 carbon atoms. The arylene group may include one or more substituents and the substituents may be bonded to each other to form a ring. For example, a carbon atom at the 9-position in a fluorenyl group has two phenyl groups as substituents and the phenyl groups are bonded to form a spirofluorene skeleton. Specific examples of the arylene group having 6 to 13 carbon atoms are a phenylene group, a naphthalenediyl group, a biphenyldiyl group, a fluorenediyl group, and the like. In the case where the arylene group has a substituent, as the substituent, an alkyl group having 1 to 6 carbon atoms, a cycloalkyl group having 3 to 6 carbon atoms, or an aryl group having 6 to 13 carbon atoms can be selected. Specific examples of the alkyl group having 1 to 6 carbon atoms include a methyl group, an ethyl group, a propyl group, an isopropyl group, a butyl group, an isobutyl group, a tert-butyl group, an n-hexyl group, and the like. Specific examples of a cycloalkyl group having 3 to 6 carbon atoms include a cyclopropyl group, a cyclobutyl group, a cyclopentyl group, a cyclohexyl group, and the like. Specific examples of the aryl group having 6 to 13 carbon atoms are a phenyl group, a naphthyl group, a biphenyl group, and the like.

As the arylene group represented by Ar, for example, groups represented by structural formulae (Ar-1) to (Ar-18) below can be used. Note that the group that can be used as Ar is not limited to these.

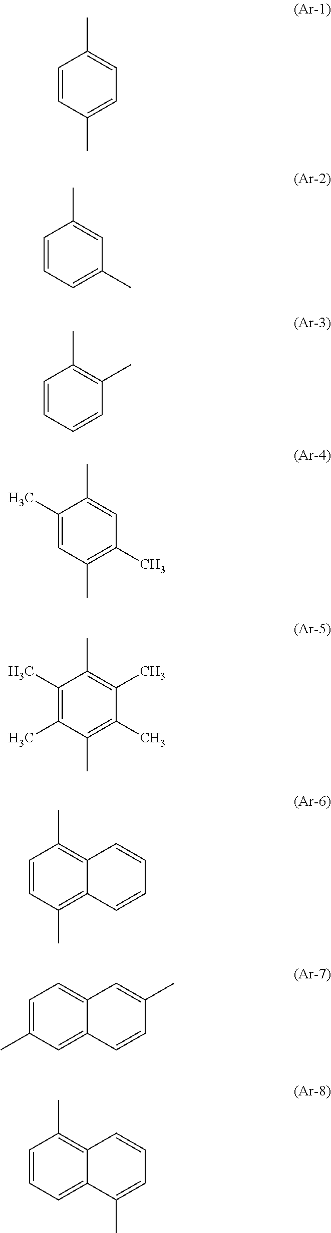

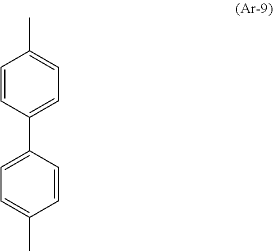

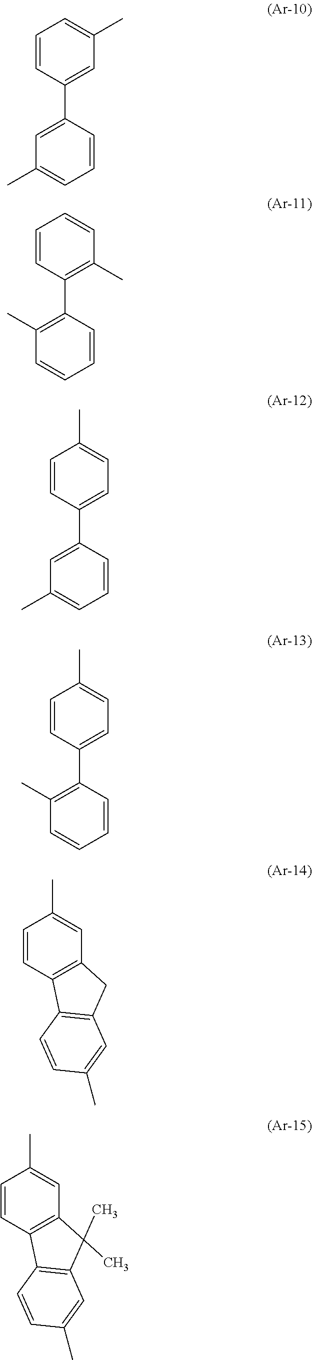

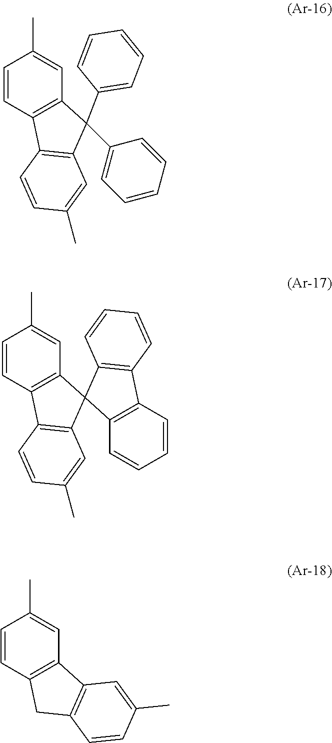

Furthermore, R¹ and R² each independently represent any of hydrogen, an alkyl group having 1 to 6 carbon atoms, a cycloalkyl group having 3 to 6 carbon atoms, and a substituted or unsubstituted aryl group having 6 to 13 carbon atoms. Specific examples of the alkyl group having 1 to 6 carbon atoms include a methyl group, an ethyl group, a propyl group, an isopropyl group, a butyl group, an isobutyl group, a tert-butyl group, an n-hexyl group, and the like. Specific examples of a cycloalkyl group having 3 to 6 carbon atoms include a cyclopropyl group, a cyclobutyl group, a cyclopentyl group, a cyclohexyl group, and the like. Specific examples of the aryl group having 6 to 13 carbon atoms are a phenyl group, a naphthyl group, a biphenyl group, a fluorenyl group, and the like. The above aryl group or phenyl group may include substituents, and the substituents may be bonded to each other to form a ring. As the substituent, an alkyl group having 1 to 6 carbon atoms, a cycloalkyl group having 3 to 6 carbon atoms, or an aryl group having 6 to 13 carbon atoms can be selected. Specific examples of the alkyl group having 1 to 6 carbon atoms include a methyl group, an ethyl group, a propyl group, an isopropyl group, a butyl group, an isobutyl group, a tert-butyl group, an n-hexyl group, and the like. Specific examples of a cycloalkyl group having 3 to 6 carbon atoms include a cyclopropyl group, a cyclobutyl group, a cyclopentyl group, a cyclohexyl group, and the like. Specific examples of the aryl group having 6 to 13 carbon atoms include a phenyl group, a naphthyl group, a biphenyl group, and the like.

For example, groups represented by structural formulae (R-1) to (R-29) below can be used as the alkyl group or aryl group represented by R¹ and R². Note that the groups which can be used as an alkyl group or an aryl group are not limited thereto.

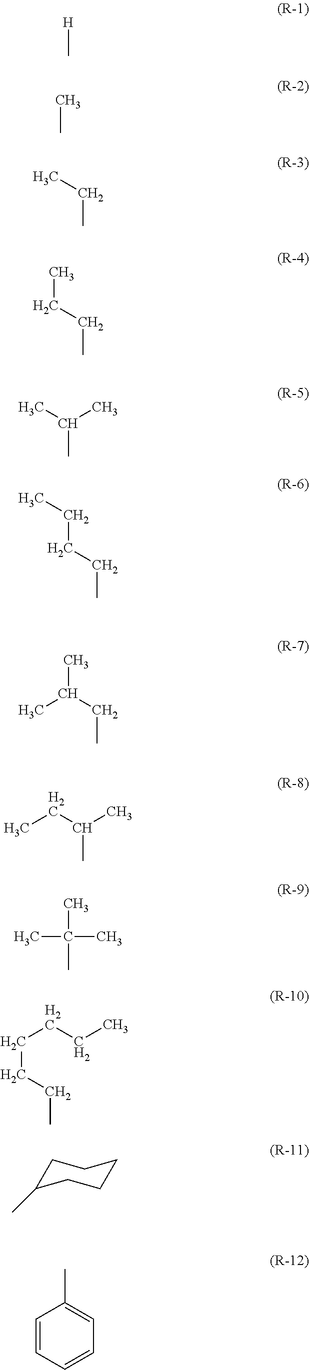

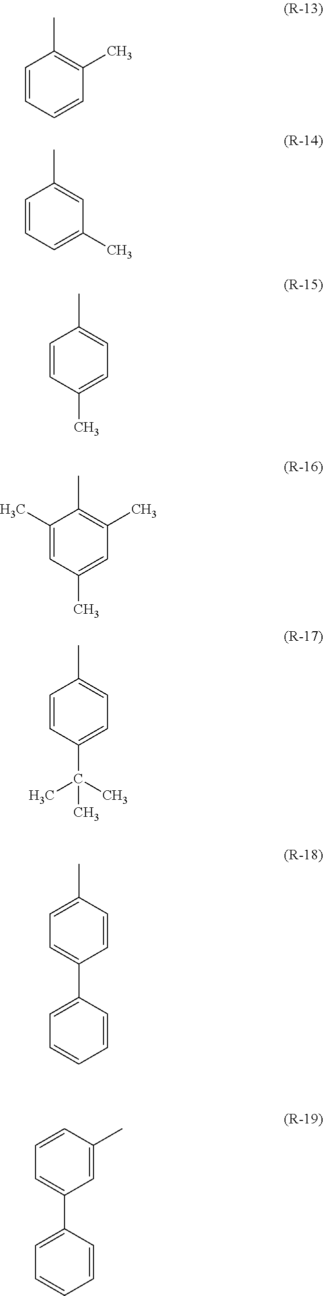

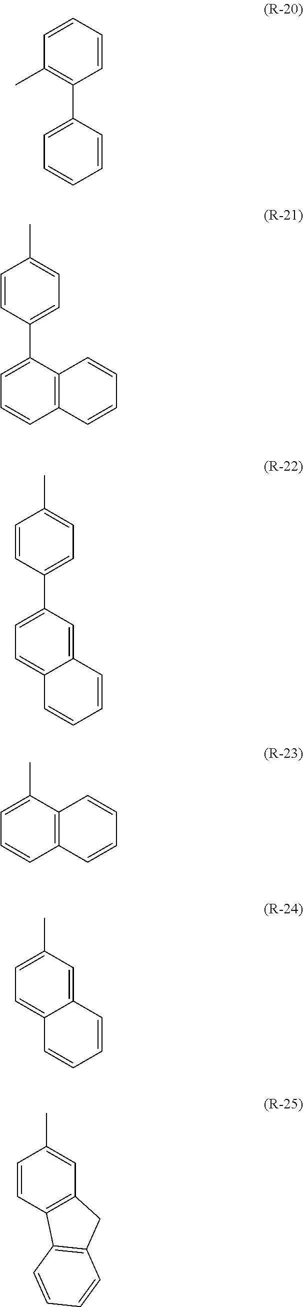

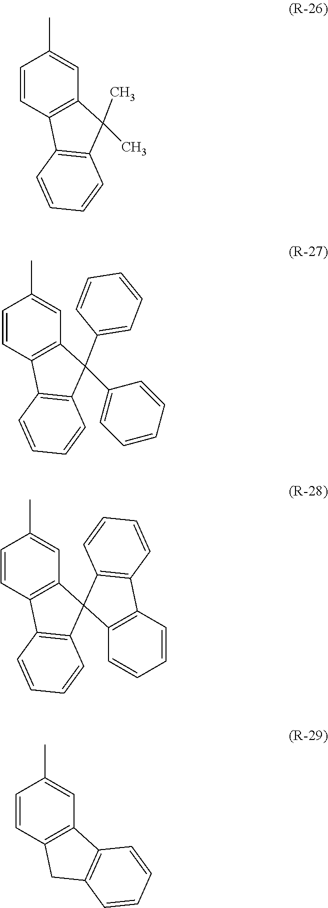

As a substituent that can be included in the general formulae (101) to (117), (201) to (218), and (301) to (315), Ar, R¹, and R², the alkyl group or aryl group represented by the above structural formulae (R-1) to (R-24) can be used, for example. Note that the group which can be used as an alkyl group or an aryl group is not limited thereto.

Examples of the organic compound 431 include a zinc- or aluminum-based metal complex, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, and the like. Other examples are an aromatic amine, a carbazole derivative, and the like.

Any of the following hole-transport materials and electron-transport materials can be used.

A material having a property of transporting more holes than electrons can be used as the hole-transport material, and a material having a hole mobility of 1×10⁻⁶ cm²/Vs or higher is preferable. Specifically, an aromatic amine, a carbazole derivative, or the like can be used. Furthermore, the hole-transport material may be a high molecular compound.

Examples of the aromatic amine compound, which has a high hole-transport property, include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), and the like.

Specific examples of the carbazole derivative are 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), and the like.

Other examples of the carbazole derivative are 4,4′-di(N-carbazolyl)biphenyl (abbreviation: CBP), 1,3,5-tris[4-(N-carbazolyl)phenyl]benzene (abbreviation: TCPB), 1,4-bis[4-(N-carbazolyl)phenyl]-2,3,5,6-tetraphenylbenzene, and the like.

Examples of the material having an excellent hole-transport property are aromatic amine compounds such as 4,4′-bis[N-(1-naphthyl)-N-phenylamino]biphenyl (abbreviation: NPB or α-NPD), N,N-bis(3-methylphenyl)-N,N-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N-bis(9-phenylcarbazol-3-yl)-N,N-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), 2-[N-(9-phenylcarbazol-3-yl)-N-phenylamino]spiro-9,9′-bifluorene (abbreviation: PCASF), 2,7-bis[N-(4-diphenylaminophenyl)-N-phenylamino]-spiro-9,9′-bifluorene (abbreviation: DPA2SF), N-[4-(9H-carbazol-9-yl)phenyl]-N-(4-phenyl)phenylaniline (abbreviation: YGA1BP), and N,N′-bis[4-(carbazol-9-yl)phenyl]-N,N′-diphenyl-9,9-dimethylfluorene-2,7-diamine (abbreviation: YGA2F). Other examples are amine compounds, carbazole compounds, thiophene compounds, furan compounds, fluorene compounds; triphenylene compounds; phenanthrene compounds, and the like such as 3-[4-(1-naphthyl)-phenyl]-9-phenyl-9H-carbazole (abbreviation: PCPN), 3-[4-(9-phenanthryl)-phenyl]-9-phenyl-9H-carbazole (abbreviation: PCPPn), 3,3′-bis(9-phenyl-9H-carbazole) (abbreviation: PCCP), 1,3-bis(N-carbazolyl)benzene (abbreviation: mCP), 3,6-bis(3,5-diphenylphenyl)-9-phenylcarbazole (abbreviation: CzTP), 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), 1,3,5-tri(dibenzothiophen-4-yl)-benzene (abbreviated as DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylen-2-yl)phenyl]dibenzothiophene (abbreviation: mDBTPTp-II). The substances described here are mainly substances having a hole mobility of 1×10⁻⁶ cm²/Vs or higher. Note that other than these substances, any substance that has a property of transporting more holes than electrons may be used.

Other examples of the material having an excellent hole-transport property are 10,15-dihydro-5,10,15-tribiphenyl-5H-diindolo[3,2-a:3′,2′-c]carbazole (abbreviation: BP3Dic), 2,8-di(9H-carbazol-9-yl)-dibenzothiophene (abbreviation: Cz2DBT), N-phenyl-N-[4′-diphenylaminobiphenyl-4-yl)-spiro-9,9′-bifluoren-2-amine (abbreviation: DPBASF), 9,9-bis(4-diphenylaminophenyl)fluorene (abbreviation: DPhA2FLP), 3,5-di(carbazol-9-yl)-N,N-diphenylaniline (abbreviation: DPhAmCP), N,N-di(4-biphenyl)-N,N-bis(9,9-dimethylfluoren-2-yl)-1,4-phenylenediamine (abbreviation: FBi2P), N-(4-biphenyl)-N-{4-[(9-phenyl)-9H-fluoren-9-yl]-phenyl}-9,9-dimethyl-9H-fluoren-2-amine (abbreviation: FBiFLP), 5,10-diphenyl-furo[3,2-c:4,5-c′]dicarbazole (abbreviation: Fdcz), N-(1,1′-biphenyl-4-yl)-N-[4-(dibenzofuran-4-yl)phenyl]-9,9-dimethyl-9H-fluoren-2-amine (abbreviation: FrBBiF-II), N-(4-biphenyl)-N-(9,9-dimethyl-9H-fluoren-2-yl)dibenzofuran-4-amine (abbreviation: FrBiF), N-(4-biphenyl)-N-(9,9-dimethyl-9H-fluoren-2-yl)dibenzofuran-2-amine (abbreviation: FrBiF-02), 9-[3-(9-phenyl-9H-fluoren-9-yl)phenyl]-9H-carbazole (abbreviation: mCzFLP), 12-[3-(9H-carbazol-9-yl)phenyl]-5,12-dihydro-5-phenylindolo[3,2-a]carbazole (abbreviation: mCzPICz), 1,3-bis(9-phenyl-9H-carbazol-3-yl)benzene (abbreviation: mPC2P), N-(3-biphenyl)-N-(9,9-dimethyl-9H-fluoren-2-yl)-9-phenyl-9H-carbazol-3-amine (abbreviation: mPCBiF), 10,15-dihydro-5,10,15-triphenyl-5H-diindolo[3,2-a:3′,2′-c]carbazole (abbreviation: P3Dic), N,N-bis(9-phenyl-9H-carbazol-3-yl)-N,N′-diphenyl-spiro-9,9′-bifluorene-2,7-diamine (abbreviation: PCA2SF), N-(1,1′-biphenyl-4-yl)-N-[4-(9-phenyl-9H-carbazol-3-yl)phenyl]-9,9-dimethyl-9H-fluoren-3-amine (abbreviation: PCBBiF-02), N-(1,1′-biphenyl-4-yl)-N-[4-(9-phenyl-9H-carbazol-3-yl)phenyl]-9H-fluoren-2-amine (abbreviation: PCBBiF-03), N-(1,1′-biphenyl-4-yl)-N-[4-(9-phenyl-9H-carbazol-3-yl)phenyl]-9,9′-spirobi[9H-fluoren]-2-amine (abbreviation: PCBBiSF), N-(4-biphenyl)-N-(9,9-dimethyl-9H-fluoren-2-yl)-9-phenyl-9H-carbazol-2-amine (abbreviation: PCBiF-02), N-(4-biphenyl)-N-(9,9′-spirobi-9H-fluoren-2-yl)-9-phenyl-9H-carbazol-3-amine (abbreviation: PCBiSF), 9,9-dimethyl-N-[4-(1-naphthyl)phenyl]-N-[4-(9-phenyl-9H-carbazol-3-yl)phenyl]-9H-fluoren-2-amine (abbreviation: PCBNBF), 9-phenyl-9′-(triphenylen-2-yl)-3,3′-bi-9H-carbazole (abbreviation: PCCzTp), bis(biphenyl-4-yl)[4′-(9-phenyl-9H-carbazol-3-yl)biphenyl-4-yl]amine (abbreviation: PCTBi1BP), N,N-di(biphenyl-4-yl)-N-(9-phenyl-9H-carbazol-3-yl)amine (abbreviation: PCzBBA1), 3-[N-(9,9-dimethyl-9H-fluoren-2-yl)-N-(9-phenylcarbazol-3-yl)amino]-9-phenylcarbazole (abbreviation: PCzPCFL), 3,6-di(9H-carbazol-9-yl)-9-phenyl-9H-carbazole (abbreviation: PhCzGI), 1,1-bis[4-bis(4-methyl-phenyl)-amino-phenyl]-cyclohexane (abbreviation: TAPC), 5,10-diphenyl-thieno[3,2-c:4,5-c′]dicarbazole (abbreviation: Tdcz), N-(1,1′-biphenyl-4-yl)-N-[4-(dibenzothiophen-4-yl)phenyl]-9,9-dimethyl-9H-fluoren-2-amine (abbreviation: ThBBiF), N,N-bis{4-(9H-carbazol-9-yl)phenyl}-N,N-diphenyl-spiro-9,9′-bifluoren-2,7-diamine (abbreviation: YGA2SF), N-phenyl-N-[4′-(9H-carbazol-9-yl)biphenyl-4-yl]-spiro-9,9′-bifluoren-2-amine (abbreviation: YGBASF), N-(biphenyl-4-yl)-N-[4′-(9H-carbazol-9-yl)biphenyl-4-yl]-9,9-dimethyl-9H-fluoren-2-amine (abbreviation: YGBBiF), N,N-di(biphenyl-4-yl)-N-(9H-carbazol-9-yl)phenyl-4-amine (abbreviation: YGBi1BP), and N-(4-biphenyl)-N-[4-(9H-carbazol-9-yl)phenyl]-9,9-dimethyl-9H-fluoren-2-amine (abbreviation: YGBiF).

As the electron-transport material, a material having a property of transporting more electrons than holes can be used, and a material having an electron mobility of 1×10⁻⁶ cm²/Vs or higher is preferable. A π-electron deficient heteroaromatic ring compound such as a nitrogen-containing heteroaromatic ring compound, a metal complex, or the like can be used as the material which easily accepts electrons (the material having an electron-transport property). Specific examples include a metal complex having a quinoline ligand, a benzoquinoline ligand, an oxazole ligand, or a thiazole ligand, an oxadiazole derivative, a triazole derivative, a phenanthroline derivative, a pyridine derivative, a bipyridine derivative, a pyrimidine derivative, and the like.

Examples include metal complexes having a quinoline or benzoquinoline skeleton, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), and the like. Alternatively, a metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), can be used. Other than such metal complexes, any of the following can be used: heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), bathophenanthroline (abbreviation: BPhen), bathocuproine (abbreviation: BCP), and 2,9-bis(naphthalen-2-yl)-4,7-diphenyl-1,10-phenanthroline (abbreviation: NBphen); heterocyclic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), and 4,6-bis[3-(9H-carbazol-9-yl)phenyl]pyrimidine (abbreviation: 4,6mCzP2Pm); heterocyclic compounds having a triazine skeleton, such as 2-{4-[3-(N-phenyl-9H-carbazol-3-yl)-9H-carbazol-9-yl]phenyl}-4,6-diphenyl-1,3,5-triazine (abbreviation: PCCzPTzn); heterocyclic compounds having a pyridine skeleton, such as 3,5-bis[3-(9H-carbazol-9-yl)phenyl]pyridine (abbreviation: 35DCzPPy) and 1,3,5-tri[3-(3-pyridyl)phenyl]benzene (abbreviation: TmPyPB); and heteroaromatic ring compounds such as 4,4′-bis(5-methylbenzoxazol-2-yl)stilbene (abbreviation: BzOs). Still alternatively, a high molecular compound such as poly(2,5-pyridinediyl) (abbreviation: PPy), poly[(9,9-dihexylfluorene-2,7-diyl)-co-(pyridine-3,5-diyl)](abbreviation: PF-Py), or poly[(9,9-dioctylfluorene-2,7-diyl)-co-(2,2′-bipyridine-6,6′-diyl)](abbreviation: PF-BPy) can be used. The substances described here are mainly substances having an electron mobility of 1×10⁻⁶ cm²/Vs or higher. Note that other substances may also be used as long as their electron-transport properties are more excellent than their hole-transport properties.

Other examples are 9,9′-(2,4-pyridinediyl-3,1-phenylene)bis-9H-carbazol (abbreviation: (abbreviation: 2,4mCzP2Py), 2,5-[3-(dibenzofuran-4-yl)phenyl]pyrimidine (abbreviation: 2,5mDBFP2Pm-II), 2,2′-(pyridine-2,6-diyl)bis(4,6-diphenylpyrimidine) (abbreviation: 2,6(P2Pm)2Py), 2,2′-[(dibenzofuran-2,8-diyl)di(3,1-phenylene)]di(dibenzo[f,h]quinoxaline) (abbreviation: 2,8DBqP2DBf), 2,2′-[(dibenzothiophene-2,8-diyl)di(3,1-phenylene)]di(dibenzo[f,h]quinoxaline) (abbreviation: 2,8mDBqP2DBT), 2,6-bis(3-9H-carbazol-9-yl-phenyl)pyridine (abbreviation: 26DCzPPy), 2-[6-(dibenzothiophen-4-yl)dibenzothiophen-4-yl]dibenzo[f,h]quinoxaline (abbreviation: 2DBtDBq-02), 2-[3″-(dibenzothiophen-4-yl)-3,1′:4′,1″-terphenyl-1-yl]dibenzo[f,h]quinoxaline (abbreviation: 2DBtTPDBq), 2-[4″-(dibenzothiophen-4-yl)-4,1′:3′,1″-terphenyl-1-yl]dibenzo[f,h]quinoxaline (abbreviation: 2DBtTPDBq-02), 2-[4″-(dibenzothiophen-4-yl)-3,1′: 4′, 1″-terphenyl-1-yl]dibenzo[f,h]quinoxaline (abbreviation: 2DBtTPDBq-03), 2-[4″-(dibenzothiophen-4-yl)-3,1′: 3′, 1″-terphenyl-1-yl]dibenzo[f,h]quinoxaline (abbreviation: 2DBtTPDBq-04), 2-[3′-(benzo[1,2-b:5,6-b′]bisbenzofuran-4-yl)-1,1′-biphenyl-3-yl]dibenzo[f,h]quinoxaline (abbreviation: 2mBbf(III)BPDBq), 2-[3′-(benzo[b]naphtho[2,3-d]furan-8-yl)biphenyl-3-yl]dibenzo[f,h]quinoxaline (abbreviation: 2mBnf(II)BPDBq), 2-{3-[3-(benzo[b]naphtho[1,2-d]furan-8-yl)phenyl]phenyl}dibenzo[f,h]quinoxaline (abbreviation: 2mBnfBPDBq), 2-(3-9H-carbazol-9-yl-phenyl)dibenzo[f,h]quinoxaline (abbreviation: 2mCzPDBq), 2-{3-[3-(2,8-diphenyldibenzofuran-4-yl)phenyl]phenyl}dibenzo[f,h]quinoxaline (abbreviation: 2mDBfBPDBq-02), 2-(3-{dispiro[9H-fluorene-9,9′(10′H)-anthracene-10′,9″-(9H)fluoren]2′-yl}phenyl)dibenzo[f,h]quinoxaline (abbreviation: 2mDBqPDfha), 2-{3-[3-(2,8-diphenyldibenzothiophen-4-yl)phenyl]phenyl}dibenzo[f,h]quinoxaline (abbreviation: 2mDBTBPDBq-III), 2-(3-{3-[6-(9,9-dimethylfluoren-2-yl)dibenzothiophen-4-yl]phenyl}phenyl)dibenzo[f,h]quinoxaline (abbreviation: 2mDBtBPDBq-VIII), 2-[3′-(dibenzothiophen-4-yl)(1,1′-biphenyl-3-yl)]dibenzo[f,h]quinazoline (abbreviation: 2mDBtBPDBqz), 2-[3″-(dibenzothiophen-4-yl)-3,1′:3′,1″-terphenyl-1-yl]dibenzo[f,h]quinoxaline (abbreviation: 2mDBtTPDBq-II), 2-{3-[3-(9,9-dimethylfluoren-2-yl)phenyl]phenyl}dibenzo[f,h]quinoxaline (abbreviation: 2mFBPDBq), 2-{3-[6-(9,9-dimethylfluoren-2-yl)dibenzothiophen-4-yl]phenyl}dibenzo[f,h]quinoxaline (abbreviation: 2mFDBtPDBq), 2-{3-[3-(9-phenyl-9H-carbazol-3-yl)phenyl]phenyl}dibenzo[f,h]quinoxaline (abbreviation: 2mPCBPDBq), 2-{3-[3-(N-phenyl-9H-carbazol-3-yl)-9H-carbazol-9-yl]phenyl}dibenzo[f,h]quinoxaline (abbreviation: 2mPCCzPDBq), 2-{3-[2-(N-phenyl-9H-carbazol-3-yl)-9H-carbazol-9-yl]phenyl}dibenzo[f,h]quinoxaline (abbreviation: 2mPCCzPDBq-02), 2-[3-(9-phenyl-9H-carbazol-3-yl)phenyl]dibenzo[f,h]quinoxaline (abbreviation: 2mPCPDBq), 2-{4-[3-(N-phenyl-9H-carbazol-3-yl)-9H-carbazol-9-yl]phenyl}dibenzo[f,h]quinoxaline (abbreviation: 2PCCzPDBq), 2-{4-[2-(N-phenyl-9H-carbazol-3-yl)-9H-carbazol-9-yl]phenyl}dibenzo[f,h]quinoxaline (abbreviation: 2PCCzPDBq-02), 9,9′-[(2-phenyl-pyrimidine-4,6-diyl)bis(biphenyl-3,3′-diyl)]bis(9H-carbazole) (abbreviation: 2Ph-4,6mCzBP2Pm), 2-phenyl-4,6-bis[3-(9H-carbazol-9-yl)phenyl]pyrimidine (abbreviation: 2Ph-4,6mCzP2Pm), 2-phenyl-4-[3-{3′-(9H-carbazol-9-yl)}biphenyl-3-yl]benzofuro[3,2-d]pyrimidine (abbreviation: 2Ph-4mCzBPBfpm), 2-{4-[3-(2,8-diphenyldibenzothiophen-4-yl)phenyl]phenyl}dibenzo[f,h]quinoxaline (abbreviation: 2pmDBtBPDBq-02), 2-{4-[3-(dibenzothiophen-4-yl)phenyl]phenyl}dibenzo[f,h]quinoxaline (abbreviation: 2pmDBTBPDBq-II), 2-{4-[3-(9-phenyl-9H-carbazol-3-yl)phenyl]phenyl}dibenzo[f,h]quinoxaline (abbreviation: 2pmPCBPDBq), 2-[3′-(dibenzothiophen-4-yl)biphenyl-3-yl]-3-phenyldibenzo[f,h]quinoxaline (abbreviation: 3Ph-2mDBtBPDBq), tris(2,4,6-trimethyl-3-(pyridin-3-yl)phenyl)borane (abbreviation: 3TPYMB), 4,4′-bis[3-(dibenzofuran-4-yl)phenyl]-2,2′-bipyridine (abbreviation: 4,4′DBfP2BPy-II), 4,4′-bis[3-(9H-carbazol-9-yl)phenyl]-2,2′-bipyridine (abbreviation: 4,4′mCzP2BPy), 4,4′-bis[3-(dibenzothiophen-4-yl)phenyl]-2,2′-bipyridine (abbreviation: 4,4′mDBTP2BPy-II), 9,9′-[pyrimidine-4,6-diylbis(biphenyl-3,3′-diyl)]bis(9H-carbazole) (abbreviation: 4,6mCzBP2Pm), 4,6-bis[3-(dibenzofuran-4-yl)phenyl]pyrimidine (abbreviation: 4,6mDBFP2Pm-II), 4,6-bis{3-[3-(9,9-dimethylfluoren-2-yl)phenyl]phenyl}pyrimidine (abbreviation: 4,6mFBP2Pm), 4,6-bis[3-(9,9-dimethylfluoren-2-yl)phenyl]pyrimidine (abbreviation: 4,6mFP2Pm), 4,6-bis[3-(9-phenyl-9H-carbazol-3-yl)phenyl]pyrimidine (abbreviation: 4,6mPCP2Pm), 4,6-bis[3-(triphenylen-2-yl)phenyl]pyrimidine (abbreviation: 4,6mTpP2Pm), 4,8-bis[3-(9H-carbazol-9-yl)phenyl]-[1]benzofuro[3,2-d]pyrimidine (abbreviation: 4,8mCzP2Bfpm), 4,8-bis[3-(dibenzothiophen-4-yl)phenyl]-[1]benzofuro[3,2-d]pyrimidine (abbreviation: 4,8mDBtP2Bfpm), 4-{3-[3′-(9H-carbazol-9-yl)]biphenyl-3-yl}benzofuro[3,2-d]pyrimidine (abbreviation: 4mCzBPBfPm), 4-[3′-(9H-carbazol-9-yl)biphenyl-3-yl]benzothieno[3,2-d]pyrimidine (abbreviation: 4mCzBPBtpm), 4-[3′-(dibenzothiophen-4-yl)biphenyl-3-yl]benzofuro[3,2-d]pyrimidine (abbreviation: 4mDBTBPBfpm-II), 4-[3′-(dibenzothiophen-4-yl)-1,1′-biphenyl-3-yl]-6-(9,9-dimethylfluoren-2-yl)pyrimidine (abbreviation: 6FL-4mDBtBPPm), 2-phenyl-4-[3′-(dibenzothiophen-4-yl)-1,1′-biphenyl-3-yl]-6-(9,9-dimethylfluoren-2-yl)pyrimidine (abbreviation: 6FL-4mDBtBPPm-02), 6-[3-(3′-dibenzothiophen-4-yl)biphenyl]dibenzo[f,h]quinoxaline (abbreviation: 6mDBTBPDBq-II), 4-[3′-(4-dibenzothienyl)-1,1′-biphenyl-3-yl]-6-phenylpyrimidine (abbreviation: 6Ph-4mDBTBPPm-II), 5-{3-[3-(dibenzo[f,h]quinoxalin-7-yl)phenyl]phenyl}indolo[3,2,1-jk]carbazole (abbreviation: 7mIcBPDBq), 9-[4-(3,5-diphenyl-1H-pyrazol-1-yl)phenyl]-9H-carbazole (abbreviation: CzPz), 4-[3′-(9H-carbazol-9-yl)-1,1′-biphenyl-3-yl]-2,6-diphenylpyrimidine (abbreviation: 2,6Ph-4mCzBPPm), 3-[3-(9H-carbazol-9-yl)phenyl]-1,2,4-triazolo[4,3-j]phenanthridine (abbreviation: mCzTPt), 2,2′-(1,1′-biphenyl-3,3′-diyl)di(dibenzo[f,h]quinoxaline) (abbreviation: mDBq2BP), 2,2′-[(9,9-dimethyl-9H-fluorene-2,7-diyl)di(3,1-phenylene)]di(dibenzo[f,h]quinoxaline) (abbreviation: mDBqP2F), 2,2′-(1,1′:3′,1″-terphenylene-3,3″-diyl)di(dibenzo[f,h]quinoxaline) (abbreviation: mDBqP2P), 9-[3-(4,6-diphenyl-1,3,5-triazin-2-yl)phenyl]-9′-phenyl-2,3′-bi-9H-carbazole (abbreviation: mPCCzPTzn-02), 4-(dibenzo[f,h]quinoxalin-2-yl)-4′-(9-phenyl-9H-carbazol-3-yl)triphenylamine (abbreviation: PCBAPDBq), 2-[4-(9-phenyl-9H-carbazol-3-yl)phenyl]dibenzo[f,h]quinoxaline (abbreviation: PCPDBq), 2,7-bis(diphenylphosphoryl)-9-phenyl-9H-carbazole (abbreviation: PP027), 2,2′-(dibenzofuran-2,8-diyl)bis[4-(2-pyridyl)pyrimidine](abbreviation: PyPm2DBF-01), and 2,4,6-tris(3′-(pyridin-3-yl)biphenyl-3-yl)-1,3,5-triazine (abbreviation: TmPPPyTz).

As the organic compound 432, a substance which can form an exciplex together with the organic compound 431 is used. Specifically, any of the above hole-transport materials and the above electron-transport materials can be used. In the case where the guest material 433 (fluorescent compound) is used for the light-emitting layer, it is preferable that the organic compound 431, the organic compound 432, and the guest material 433 (fluorescent compound) be selected such that the emission peak of the exciplex formed by the organic compound 431 and the organic compound 432 overlaps with an absorption band on the longest wavelength side (lowest energy side) of the guest material 433 (the fluorescent compound). This makes it possible to provide a light-emitting element with drastically improved luminous efficiency.

Note that the lower of the T1 levels of the organic compounds that form an exciplex (the organic compound 431 and the organic compound 432) preferably has energy that is larger thanthe emission energy of the exciplex by −0.2 eV or more and 0.4 eV or less.

The energy difference between the LUMO level of the organic compound 431 and the HOMO level of the organic compound 432 is preferably greater than the emission energy of the exciplex formed by the organic compounds by −0.1 eV or more and 0.4 eV or less, more preferably by 0 eV or more and 0.4 eV or less.

As the host material (the organic compound 431 and the organic compound 432) included in the light-emitting layer 430, a material having a function of converting triplet excitation energy into singlet excitation energy is preferable. As the material having a function of converting triplet excitation energy into singlet excitation energy, a thermally activated delayed fluorescent (TADF) material can be given in addition to the exciplex. Therefore, the term “exciplex” in the description can be read as the term “thermally activated delayed fluorescent material”. Note that the thermally activated delayed fluorescent material is a material having a small difference between the T1 level and the S1 level and a function of converting triplet excitation energy into singlet excitation energy by reverse intersystem crossing. Thus, the thermally activated delayed fluorescent material can up-convert a triplet excited state into a singlet excited state (i.e., reverse intersystem crossing) using a little thermal energy and efficiently exhibit light emission (fluorescence) from the singlet excited state. Thermally activated delayed fluorescence is efficiently obtained under the condition where the difference between the T1 level and the S1 level is more than 0 eV and less than or equal to 0.2 eV, preferably more than 0 eV and less than or equal to 0.1 eV.

The material that exhibits thermally activated delayed fluorescence may be a material that can form a singlet excited state by itself from a triplet excited state by reverse intersystem crossing. In the case where the thermally activated delayed fluorescent material is composed of one kind of material, any of the following materials can be used, for example.

First, a fullerene, a derivative thereof, an acridine derivative such as proflavine, eosin, and the like can be given. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂(OEP)).

As the thermally activated delayed fluorescent material composed of one kind of material, a heterocyclic compound having a π-electron rich heteroaromatic ring and a π-electron deficient heteroaromatic ring can be used. Specifically, 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. The heterocyclic compound is preferable because of having the π-electron rich heteroaromatic ring and the π-electron deficient heteroaromatic ring, for which the electron-transport property and the hole-transport property are excellent. Note that a substance in which the π-electron rich heteroaromatic ring is directly bonded to the π-electron deficient heteroaromatic ring is particularly preferable because the donor property of the π-electron rich heteroaromatic ring and the acceptor property of the π-electron deficient heteroaromatic ring are both increased and the difference between the S1 level and the T1 level becomes small.

In the light-emitting layer 430, the guest material 433 is preferably, but not particularly limited to, an anthracene derivative, a tetracene derivative, a chrysene derivative, a phenanthrene derivative, a pyrene derivative, a perylene derivative, a stilbene derivative, an acridone derivative, a coumarin derivative, a phenoxazine derivative, a phenothiazine derivative, or the like, and for example, any of the following fluorescent compounds can be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,NA-bis(3-methylphenyl)-N,N-bis[3-(9-phenyl-9H-fluoren-9-yl)phenyl]pyrene-1,6-diamine (abbreviation: 1,6mMemFLPAPrn), N,N′-bis[4-(9-phenyl-9H-fluoren-9-yl)phenyl]-N,N-bis(4-tert-butylphenyl)pyrene-1,6-diamine (abbreviation: 1,6tBu-FLPAPrn), NN-bis[4-(9-phenyl-9H-fluoren-9-yl)phenyl]-N,N-diphenyl-3,8-dicyclohexylpyrene-1,6-diamine (abbreviation: ch-1,6FLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N-triphenyl-1,4-phenylenediamine (abbreviation: 2DPAPPA), NNN,N,N′,N′,N″N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N,N,N-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 6, coumarin 545T, N,N-diphenylquinacridone (abbreviation: DPQd), rubrene, 2,8-di-tert-butyl-5,11-bis(4-tert-butylphenyl)-6,12-diphenyltetracene (abbreviation: TBRb), Nile red, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and 5,10,15,20-tetraphenylbisbenzo[5,6]indeno[1,2,3-cd:1′, 2′, 3′-/m]perylene.

Alternatively, any of the thermally activated delayed fluorescent materials described above can be used as the guest material 433.

As described above, the energy transfer efficiency based on the Dexter mechanism from the host material (or the exciplex) to the guest material 433 is preferably low. The rate constant of the Dexter mechanism is inversely proportional to the exponential function of the distance between the two molecules. Thus, when the distance between the two molecules is approximately 1 nm or less, the Dexter mechanism is dominant, and when the distance is approximately 1 nm or more, the Forster mechanism is dominant. To reduce the energy transfer efficiency in the Dexter mechanism, the distance between the host material (or the exciplex) and the guest material 433 is preferably large, and specifically, 0.7 nm or more, preferably 0.9 nm or more, more preferably 1 nm or more. In view of the above, the guest material 433 preferably has a substituent that prevents the proximity to the host material. The substituent is preferably aliphatic hydrocarbon, more preferably an alkyl group, still more preferably a branched alkyl group. Specifically, the guest material 433 preferably includes at least two alkyl groups each having 2 or more carbon atoms. Alternatively, the guest material 433 preferably includes at least two branched alkyl groups each having 3 to 10 carbon atoms. Alternatively, the guest material 433 preferably includes at least two cycloalkyl groups each having 3 to 10 carbon atoms.

The light-emitting layer 430 may include two or more layers. For example, in the case where the light-emitting layer 430 is formed by stacking a first light-emitting layer and a second light-emitting layer in this order from the hole-transport layer side, the first light-emitting layer is formed using a substance having a hole-transport property as the host material and the second light-emitting layer is formed using a substance having an electron-transport property as the host material.

The light-emitting layer 430 may include a material other than the organic compound 431, the organic compound 432, and the guest material 433.

### <<Pair of Electrodes>>

The electrode 401 and the electrode 402 have functions of injecting holes and electrons into the light-emitting layer 430. The electrode 401 and the electrode 402 can be formed using a metal, an alloy, or a conductive compound, a mixture or a stack thereof, or the like. A typical example of the metal is aluminum (Al); besides, a transition metal such as silver (Ag), tungsten, chromium, molybdenum, copper, or titanium, an alkali metal such as lithium (Li) or cesium, or a Group 2 metal such as calcium or magnesium (Mg) can be used. As a transition metal, a rare earth metal such as ytterbium (Yb) may be used. An alloy containing any of the above metals can be used as the alloy, and MgAg and AlLi can be given as examples. Examples of the conductive compound include metal oxides such as indium tin oxide (hereinafter referred to as ITO), indium tin oxide containing silicon or silicon oxide (ITSO), indium zinc oxide, indium oxide containing tungsten and zinc, and the like. It is also possible to use an inorganic carbon-based material such as graphene as the conductive compound. As described above, the electrode 401 and/or the electrode 402 may be formed by stacking two or more of these materials.

Light emitted from the light-emitting layer 430 is extracted through the electrode 401 and/or the electrode 402. Therefore, at least one of the electrodes 401 and 402 transmits visible light. As the conductive material transmitting light, a conductive material having a visible light transmittance higher than or equal to 40% and lower than or equal to 100%, preferably higher than or equal to 60% and lower than or equal to 100%, and a resistivity lower than or equal to 1×10⁻² Ω·cm can be used. The electrode on the light extraction side may be formed using a conductive material having functions of transmitting light and reflecting light. As the conductive material, a conductive material having a visible light reflectivity higher than or equal to 20% and lower than or equal to 80%, preferably higher than or equal to 40% and lower than or equal to 70%, and a resistivity lower than or equal to 1×10⁻² Ω·cm can be used. In the case where the electrode through which light is extracted is formed using a material with low light transmittance, such as metal or alloy, the electrode 401 and/or the electrode 402 is formed to a thickness that is thin enough to transmit visible light (e.g., a thickness of 1 nm to 10 nm).

In this specification and the like, as the electrode transmitting light, a material that transmits visible light and has conductivity is used. Examples of the material include, in addition to the above-described oxide conductor layer typified by an ITO, an oxide semiconductor layer and an organic conductor layer containing an organic substance. Examples of the organic conductive layer containing an organic substance include a layer containing a composite material in which an organic compound and an electron donor (donor material) are mixed and a layer containing a composite material in which an organic compound and an electron acceptor (acceptor material) are mixed. The resistivity of the transparent conductive layer is preferably lower than or equal to 1×10⁵Ω·cm, more preferably lower than or equal to 1×10⁴Ω·cm.

As the method for forming the electrode 401 and the electrode 402, a sputtering method, an evaporation method, a printing method, a coating method, a molecular beam epitaxy (MBE) method, a CVD method, a pulsed laser deposition method, an atomic layer deposition (ALD) method, or the like can be used as appropriate.

### <<Hole-Injection Layer>>

The hole-injection layer 411 has a function of reducing a barrier for hole injection from one of the pair of electrodes (the electrode 401 or the electrode 402) to promote hole injection and is formed using a transition metal oxide, a phthalocyanine derivative, or an aromatic amine, for example. As the transition metal oxide, molybdenum oxide, vanadium oxide, ruthenium oxide, tungsten oxide, manganese oxide, or the like can be given. As the phthalocyanine derivative, phthalocyanine, metal phthalocyanine, or the like can be given. As the aromatic amine, a benzidine derivative, a phenylenediamine derivative, or the like can be given. It is also possible to use a high molecular compound such as polythiophene or polyaniline; a typical example thereof is poly(ethylenedioxythiophene)/poly(styrenesulfonic acid), which is self-doped polythiophene.

As the hole-injection layer 411, a layer containing a composite material of a hole-transport material and a material having a property of accepting electrons from the hole-transport material can also be used. Alternatively, a stack of a layer containing a material having an electron accepting property and a layer containing a hole-transport material may also be used. In a steady state or in the presence of an electric field, electric charge can be transferred between these materials. As examples of the material having an electron-accepting property, organic acceptors such as a quinodimethane derivative, a chloranil derivative, and a hexaazatriphenylene derivative can be given. A specific example is a compound having an electron-withdrawing group (a halogen group or a cyano group), such as 7,7,8,8-tetracyano-2,3,5,6-tetrafluoroquinodimethane (abbreviation: F₄-TCNQ), chloranil, or 2,3,6,7,10,11-hexacyano-1,4,5,8,9,12-hexaazatriphenylene (abbreviation: HAT-CN). Alternatively, a transition metal oxide such as an oxide of a metal from Group 4 to Group 8 can also be used. Specifically, vanadium oxide, niobium oxide, tantalum oxide, chromium oxide, molybdenum oxide, tungsten oxide, manganese oxide, rhenium oxide, or the like can be used. In particular, molybdenum oxide is preferable because it is stable in the air, has a low hygroscopic property, and is easily handled.

A material having a property of transporting more holes than electrons can be used as the hole-transport material, and a material having a hole mobility of 1×10⁻⁶ cm²/Vs or higher is preferable. Specifically, any of the above aromatic amines, the above carbazole derivatives, the above aromatic hydrocarbons, the above stilbene derivatives, and the like as examples of the hole-transport material that can be used in the light-emitting layer 430 can be used. Furthermore, the hole-transport material may be a high molecular compound.

Examples of the aromatic hydrocarbon are 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, and the like. Other examples are pentacene, coronene, and the like. The aromatic hydrocarbon having a hole mobility of 1×10⁻⁶ cm²/Vs or higher and having 14 to 42 carbon atoms is particularly preferable.

The aromatic hydrocarbon may have a vinyl skeleton. Examples of the aromatic hydrocarbon having a vinyl group are 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

Other examples are high molecular compounds such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), and poly[N,N-bis(4-butylphenyl)-N,N-bis(phenyl)benzidine](abbreviation: poly-TPD).

### <<Hole-Transport Layer>>

The hole-transport layer 412 is a layer containing a hole-transport material and can be formed using any of the materials given as examples of the material of the hole-injection layer 411. In order that the hole-transport layer 412 has a function of transporting holes injected into the hole-injection layer 411 to the light-emitting layer 430, the HOMO level of the hole-transport layer 412 is preferably equal or close to the HOMO level of the hole-injection layer 411.

As the hole-transport material, any of the materials given as examples of the material of the hole-injection layer 411 can be used. As the hole-transport material, a substance having a hole mobility of 1×10⁻⁶ cm²/Vs or higher is preferably used. Note that any substance other than the above substances may be used as long as the hole-transport property is more excellent than the electron-transport property. The layer including a substance having an excellent hole-transport property is not limited to a single layer, and two or more layers containing the aforementioned substances may be stacked.

### <<Electron-Transport Layer>>

The electron-transport layer 418 has a function of transporting, to the light-emitting layer 430, electrons injected from the other of the pair of electrodes (the electrode 401 or the electrode 402) through the electron-injection layer 419. A material having a property of transporting more electrons than holes can be used as the electron-transport material, and a material having an electron mobility of 1×10⁻⁶ cm²/Vs or higher is preferable. As the compound which easily accepts electrons (the material having an electron-transport property), a π-electron deficient heteroaromatic ring compound such as a nitrogen-containing heteroaromatic ring compound, a metal complex, or the like can be used, for example. Specifically, a metal complex having a quinoline ligand, a benzoquinoline ligand, an oxazole ligand, or a thiazole ligand, which are described as the electron-transport materials that can be used in the light-emitting layer 430, can be given. Further, an oxadiazole derivative; a triazole derivative, a phenanthroline derivative, a pyridine derivative, a bipyridine derivative, a pyrimidine derivative, and the like can be given. A substance having an electron mobility of higher than or equal to 1×10⁻⁶ cm²/Vs is preferable. Note that other than these substances, any substance that has a property of transporting more electrons than holes may be used for the electron-transport layer. The electron-transport layer 418 is not limited to a single layer, and may include stacked two or more layers containing the aforementioned substances.

Between the electron-transport layer 418 and the light-emitting layer 430, a layer that controls transfer of electron carriers may be provided. This is a layer formed by addition of a small amount of a substance having an excellent electron-trapping property to a material having an excellent electron-transport property described above, and the layer is capable of adjusting carrier balance by suppressing transfer of electron carriers. Such a structure is very effective in preventing a problem (such as a reduction in element lifetime) caused when electrons pass through the light-emitting layer.

### <<Electron-Injection Layer>>

The electron-injection layer 419 has a function of reducing a barrier for electron injection from the electrode 402 to promote electron injection and can be formed using a Group 1 metal or a Group 2 metal, or an oxide, a halide, or a carbonate of any of the metals, for example. Alternatively, a composite material containing an electron-transport material (described above) and a material having a property of donating electrons to the electron-transport material can also be used. As the material having an electron-donating property, a Group 1 metal, a Group 2 metal, an oxide of any of the metals, or the like can be given. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. Alternatively, a rare earth metal compound like erbium fluoride (ErF₃) can be used. Electride may be used for the electron-injection layer 419. Examples of the electride include a substance in which electrons are added at high concentration to calcium oxide-aluminum oxide. The electron-injection layer 419 can be formed using the substance that can be used for the electron-transport layer 418.

A composite material in which an organic compound and an electron donor (donor) are mixed may be used for the electron-injection layer 419. Such a composite material is excellent in an electron-injection property and an electron-transport property because electrons are generated in the organic compound by the electron donor. In this case, the organic compound is preferably a material that is excellent in transporting the generated electrons. Specifically, the above-listed substances for forming the electron-transport layer 418 (e.g., the metal complexes and heteroaromatic ring compounds) can be used, for example. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, ytterbium, and the like are given. In addition, an alkali metal oxide or an alkaline earth metal oxide is preferable, and lithium oxide, calcium oxide, barium oxide, and the like are given. A Lewis base such as magnesium oxide may be used. An organic compound such as tetrathiafulvalene (abbreviation: TTF) may be used.

Note that the light-emitting layer, the hole-injection layer, the hole-transport layer, the electron-transport layer, and the electron-injection layer described above can each be formed by an evaporation method (including a vacuum evaporation method), an inkjet method, a coating method, a nozzle printing method, a gravure printing method, or the like. Other than the above-mentioned materials, an inorganic compound such as a quantum dot or a high molecular compound (e.g., an oligomer, a dendrimer, and a polymer) may be used in the light-emitting layer, the hole-injection layer, the hole-transport layer, the electron-transport layer, and the electron-injection layer.

### <<Quantum Dot>>

Examples of a material of a quantum dot include a Group 14 element in the periodic table, a Group 15 element in the periodic table, a Group 16 element in the periodic table, a compound of a plurality of Group 14 elements in the periodic table, a compound of an element belonging to any of Groups 4 to 14 in the periodic table and a Group 16 element in the periodic table, a compound of a Group 2 element in the periodic table and a Group 16 element in the periodic table, a compound of a Group 13 element in the periodic table and a Group 15 element in the periodic table, a compound of a Group 13 element in the periodic table and a Group 17 element in the periodic table, a compound of a Group 14 element in the periodic table and a Group 15 element in the periodic table, a compound of a Group 11 element in the periodic table and a Group 17 element in the periodic table, iron oxides, titanium oxides, spinel chalcogenides, and various semiconductor clusters.

Specific examples include, but are not limited to, cadmium selenide (CdSe); cadmium sulfide (CdS); cadmium telluride (CdTe); zinc selenide (ZnSe); zinc oxide (ZnO); zinc sulfide (ZnS); zinc telluride (ZnTe); mercury sulfide (HgS); mercury selenide (HgSe); mercury telluride (HgTe); indium arsenide (InAs); indium phosphide (InP); gallium arsenide (GaAs); gallium phosphide (GaP); indium nitride (InN); gallium nitride (GaN); indium antimonide (InSb); gallium antimonide (GaSb); aluminum phosphide (AlP); aluminum arsenide (AlAs); aluminum antimonide (AlSb); lead(II) selenide (PbSe); lead(II) telluride (PbTe); lead(II) sulfide (PbS); indium selenide (In₂S₃); indium telluride (In₂Te₃); indium sulfide (In₂S₃); gallium selenide (Ga₂S₃); arsenic(III) sulfide (As₂S3); arsenic(III) selenide (As₂Se₃); arsenic(III) telluride (As₂Te₃); antimony(III) sulfide (Sb₂S₃); antimony(III) selenide (Sb₂Se₃); antimony(III) telluride (Sb₂Te₃); bismuth(III) sulfide (Bi₂S₃); bismuth(III) selenide (Bi₂Se₃); bismuth(III) telluride (Bi₂Te₃); silicon (Si); silicon carbide (SiC); germanium (Ge); tin (Sn); selenium (Se); tellurium (Te); boron (B); carbon (C); phosphorus (P); boron nitride (BN); boron phosphide (BP); boron arsenide (BAs); aluminum nitride (AlN); aluminum sulfide (Al₂S₃); barium sulfide (BaS); barium selenide (BaSe); barium telluride (BaTe); calcium sulfide (CaS); calcium selenide (CaSe); calcium telluride (CaTe); beryllium sulfide (BeS); beryllium selenide (BeSe); beryllium telluride (BeTe); magnesium sulfide (MgS); magnesium selenide (MgSe); germanium sulfide (GeS); germanium selenide (GeSe); germanium telluride (GeTe); tin(IV) sulfide (SnS₂); tin(II) sulfide (SnS); tin(II) selenide (SnSe); tin(II) telluride (SnTe); lead(II) oxide (PbO); copper(I) fluoride (CuF); copper(I) chloride (CuCl); copper(I) bromide (CuBr); copper(I) iodide (CuI); copper(I) oxide (Cu₂O); copper(I) selenide (Cu₂Se); nickel(II) oxide (NiO); cobalt(II) oxide (CoO); cobalt(II) sulfide (CoS); triiron tetraoxide (Fe₃O₄); iron(II) sulfide (FeS); manganese(II) oxide (MnO); molybdenum(IV) sulfide (MoS₂); vanadium(II) oxide (VO); vanadium(IV) oxide (VO₂); tungsten(IV) oxide (WO₂); tantalum(V) oxide (Ta₂O₅); titanium oxide (e.g., TiO₂, Ti₂O₅, Ti₂O₃, or Ti₅O₉); zirconium oxide (ZrO₂); silicon nitride (Si₃N₄); germanium nitride (Ge₃N₄); aluminum oxide (Al₂O₃); barium titanate (BaTiO₃); a compound of selenium, zinc, and cadmium (CdZnSe); a compound of indium, arsenic, and phosphorus (InAsP); a compound of cadmium, selenium, and sulfur (CdSeS); a compound of cadmium, selenium, and tellurium (CdSeTe); a compound of indium, gallium, and arsenic (InGaAs); a compound of indium, gallium, and selenium (InGaSe); a compound of indium, selenium, and sulfur (InSeS); a compound of copper, indium, and sulfur (e.g., CuInS₂); and combinations thereof. What is called an alloyed quantum dot, whose composition is represented by a given ratio, may be used. For example, an alloyed quantum dot represented by CdSₓSe₁₋ₓ (where x is any number between 0 and 1 inclusive) is a means effective in obtaining blue light because the emission wavelength can be changed by changing x.

As the quantum dot, any of a core-type quantum dot, a core-shell quantum dot, a core-multishell quantum dot, and the like can be used. Note that when a core is covered with a shell formed of another inorganic material having a wider band gap, the influence of defects and dangling bonds existing at the surface of a nanocrystal can be reduced. Since such a structure can significantly improve the quantum efficiency of light emission, it is preferable to use a core-shell or core-multishell quantum dot. Examples of the material of a shell include zinc sulfide (ZnS) and zinc oxide (ZnO).

Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability. Examples of the protective agent (or the protective group) include polyoxyethylene alkyl ethers such as polyoxyethylene lauryl ether, polyoxyethylene stearyl ether, and polyoxyethylene oleyl ether; trialkylphosphines such as tripropylphosphine, tributylphosphine, trihexylphosphine, and trioctylphoshine; polyoxyethylene alkylphenyl ethers such as polyoxyethylene n-octylphenyl ether and polyoxyethylene n-nonylphenyl ether; tertiary amines such as tri(n-hexyl)amine, tri(n-octyl)amine, and tri(n-decyl)amine; organophosphorus compounds such as tripropylphosphine oxide, tributylphosphine oxide, trihexylphosphine oxide, trioctylphosphine oxide, and tridecylphosphine oxide; polyethylene glycol diesters such as polyethylene glycol dilaurate and polyethylene glycol distearate; organic nitrogen compounds such as nitrogen-containing aromatic compounds, e.g., pyridines, lutidines, collidines, and quinolines; aminoalkanes such as hexylamine, octylamine, decylamine, dodecylamine, tetradecylamine, hexadecylamine, and octadecylamine; dialkylsulfides such as dibutylsulfide; dialkylsulfoxides such as dimethylsulfoxide and dibutylsulfoxide; organic sulfur compounds such as sulfur-containing aromatic compounds, e.g., thiophene; higher fatty acids such as a palmitin acid, a stearic acid, and an oleic acid; alcohols; sorbitan fatty acid esters; fatty acid modified polyesters; tertiary amine modified polyurethanes; and polyethyleneimines.

The quantum dots may be quantum rods, which are rod-like shape quantum dots. A quantum rod emits directional light polarized in the c-axis direction; thus, quantum rods can be used as a light-emitting material to obtain a light-emitting element with higher external quantum efficiency.

In the case of using quantum dots as the light-emitting material in the light-emitting layer, the thickness of the light-emitting layer is set to 3 nm to 100 nm, preferably 10 nm to 100 nm, and the light-emitting layer is made to contain 1 volume % to 100 volume % of the quantum dots. Note that it is preferable that the light-emitting layer be composed of the quantum dots. To form a light-emitting layer in which the quantum dots are dispersed as light-emitting materials in host materials, the quantum dots may be dispersed in the host materials, or the host materials and the quantum dots may be dissolved or dispersed in an appropriate liquid medium, and then a wet process (e.g., a spin coating method, a casting method, a die coating method, blade coating method, a roll coating method, an ink-jet method, a printing method, a spray coating method, a curtain coating method, or a Langmuir-Blodgett method) may be employed.

An example of the liquid medium used for the wet process is an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like.

Examples of the high molecular compound that can be used for the light-emitting layer include a phenylenevinylene (PPV) derivative such as poly[2-methoxy-5-(2-ethylhexyloxy)-1,4-phenylenevinylene](abbreviation: MEH-PPV) or poly(2,5-dioctyl-1,4-phenylenevinylene); a polyfluorene derivative such as poly(9,9-di-n-octylfluorenyl-2,7-diyl) (abbreviation: PF8), poly[(9,9-di-n-octylfluorenyl-2,7-diyl)-alt-(benzo[2,1,3]thiadiazole-4,8-diyl)](abbreviation: F8BT), poly(9,9-di-n-octylfluorenyl-2,7-diyl)-alt-(2,2′-bithiophene-5,5′-diyl)](abbreviation: F8T2), poly[(9,9-dioctyl-2,7-divinylenefluorenylene)-alt-(9,10-anthracene)], or poly[(9,9-dihexylfluorene-2,7-diyl)-alt-(2,5-dimethyl-1,4-phenylene)]; a polyalkylthiophene (PAT) derivative such as poly(3-hexylthiophen-2,5-diyl) (abbreviation: P3HT); and a polyphenylene derivative. These high molecular compounds, poly(9-vinylcarbazole) (abbreviation: PVK), poly(2-vinylnaphthalene), poly[bis(4-phenyl) (2,4,6-trimethylphenyl)amine](abbreviation: PTAA), or the like may be doped with a light-emitting low molecular compound and used for the light-emitting layer. As the light-emitting low molecular compound, any of the above-described fluorescent compounds can be used.

### <<Substrate>>

A light-emitting element in one embodiment of the present invention can be formed over a substrate of glass, plastic, or the like. As the way of stacking layers over the substrate, layers can be sequentially stacked either from the electrode 401 side or from the electrode 402 side.

For the substrate over which the light-emitting element of one embodiment of the present invention can be formed, glass, quartz, plastic, or the like can be used, for example. Alternatively, a flexible substrate can be used. The flexible substrate is a substrate that can be bent, such as a plastic substrate made of polycarbonate or polyarylate, for example. A film, an inorganic film formed by evaporation, or the like can also be used. Another material may be used as long as the substrate functions as a support in a manufacturing process of the light-emitting element or the optical element. Another material having a function of protecting the light-emitting element or the optical element may be used.

In this specification and the like, a light-emitting element can be formed using any of a variety of substrates, for example. The type of a substrate is not limited particularly. Examples of the substrate include a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, cellulose nanofiber (CNF) and paper which include a fibrous material, a base material film, and the like. As an example of a glass substrate, a barium borosilicate glass substrate, an aluminoborosilicate glass substrate, a soda lime glass substrate, or the like can be given. Examples of the flexible substrate, the attachment film, the base material film, and the like are substrates of plastics typified by polyethylene terephthalate (PET), polyethylene naphthalate (PEN), polyether sulfone (PES), and polytetrafluoroethylene (PTFE). Another example is a resin such as acrylic. Alternatively, polypropylene, polyester, polyvinyl fluoride, polyvinyl chloride, or the like can be used. Alternatively, polyamide, polyimide, aramid, epoxy, an inorganic film formed by evaporation, paper, or the like can be used.

Alternatively, a flexible substrate may be used as the substrate, and a transistor or a light-emitting element may be provided directly on the flexible substrate. Still alternatively, a separation layer may be provided between the substrate and the light-emitting element. The separation layer can be used when part or the whole of a light-emitting element formed over the separation layer is separated from the substrate and transferred onto another substrate. In such a case, the light-emitting element can be transferred to a substrate having low heat resistance or a flexible substrate as well. For the above separation layer, a stack including inorganic films, which are a tungsten film and a silicon oxide film, or a structure in which a resin film of polyimide or the like is formed over a substrate can be used, for example.

In other words, after the light-emitting element is formed using a substrate, the light-emitting element may be transferred to another substrate. Examples of a substrate to which the light-emitting element is transferred include, in addition to the above-described substrates, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a light-emitting element with high durability, high heat resistance, reduced weight, or reduced thickness can be formed.

The light-emitting element 450 may be formed over an electrode electrically connected to a field-effect transistor (FET), for example, which is formed over any of the above-described substrates. In that case, an active matrix display device in which the FET controls the driving of the light-emitting element can be manufactured.

In this embodiment, one embodiment of the present invention has been described. Other embodiments of the present invention will be described in the other embodiments. Note that one embodiment of the present invention is not limited thereto. In other words, various embodiments of the invention are described in this embodiment and the other embodiments, and one embodiment of the present invention is not limited to a particular embodiment. The example in which one embodiment of the present invention is used in a light-emitting element is described; however, one embodiment of the present invention is not limited thereto. For example, depending on circumstances or conditions, one embodiment of the present invention is not necessarily used in a light-emitting element. The example in which a light-emitting element of one embodiment of the present invention includes two organic compounds that form an exciplex is described; however, one embodiment of the present invention is not limited thereto. Depending on circumstances or conditions, in one embodiment of the present invention, two organic compounds that form an exciplex are not necessarily included, for example. Two organic compounds do not necessarily form an exciplex. The example in which the lower of the T1 levels of the two organic compounds has energy that is larger than the emission energy of the exciplex by −0.2 eV or more and 0.4 eV or less, is described; however, one embodiment of the present invention is not limited thereto. Depending on circumstances or conditions, in one embodiment of the present invention, the lower of the T1 levels of the two organic compounds may have energy more than 0.4 eV greater than the emission energy of the exciplex. The example in which the energy difference between the LUMO level and the HOMO level of the exciplex is greater than the emission energy of the exciplex by −0.1 eV or more and 0.4 eV or less, is described; however, one embodiment of the present invention is not limited thereto. Depending on circumstances or conditions, in one embodiment of the present invention, the energy difference between the LUMO level and the HOMO level of the exciplex may be more than 0.4 eV greater than the emission energy of the exciplex.

The structure described above in this embodiment can be combined as appropriate with any of the structures described in the other embodiments and the example.

### Embodiment 2

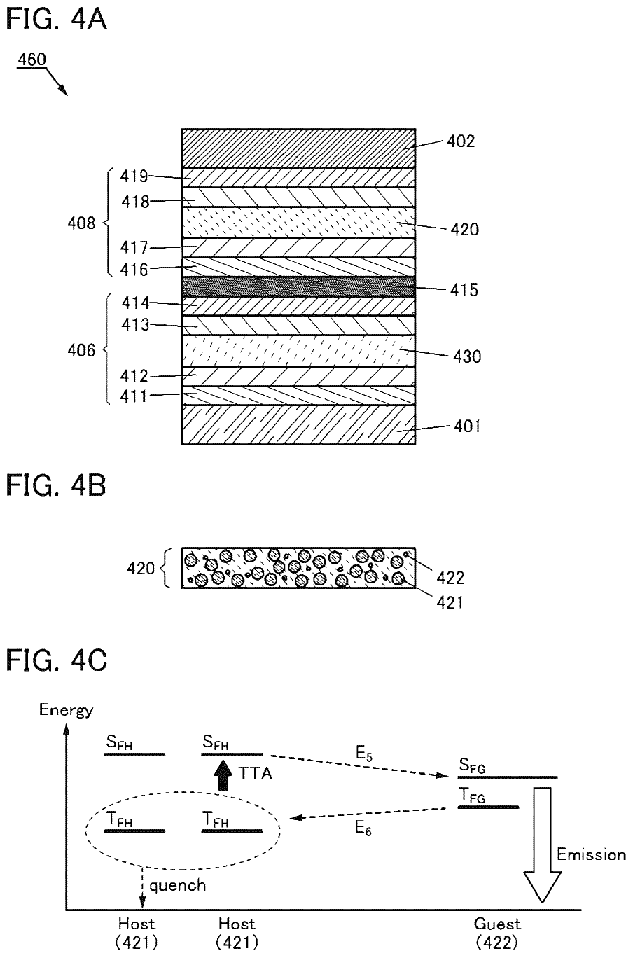

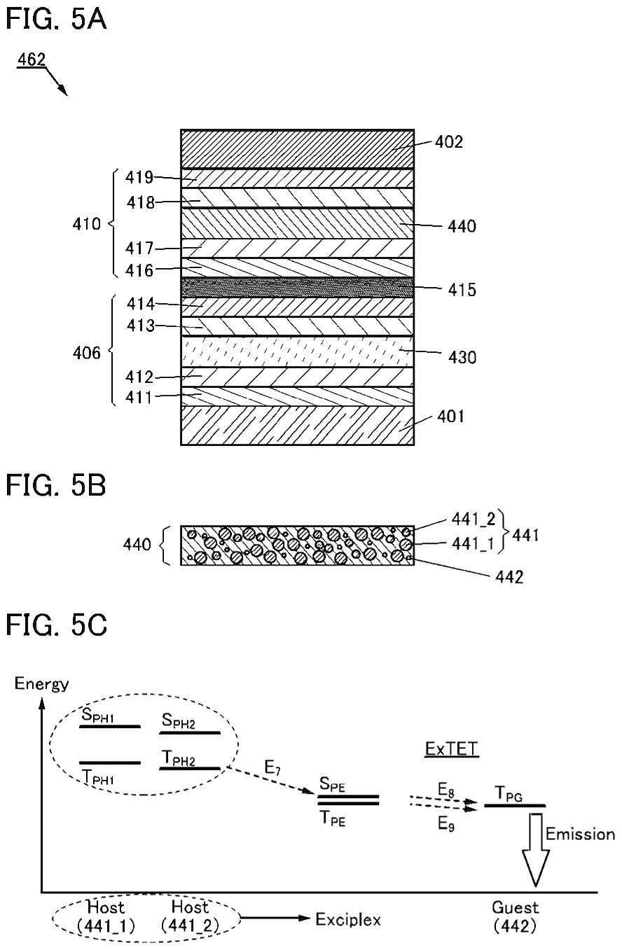

In this embodiment, light-emitting elements having structures different from that described in Embodiment 1 and light emission mechanisms of the light-emitting elements will be described below with reference to FIGS. 4 Ato 4C and FIGS. 5 Ato 5C. In FIGS. 4 Ato 4C and FIGS. 5 Ato 5C, a portion having a function similar to that in FIG. 1A is represented by the same hatch pattern as that in FIG. 1A and not particularly denoted by a reference numeral in some cases. In addition, common reference numerals are used for portions having similar functions, and a detailed description of the portions is omitted in some cases.

### <Structural Example 1 of Light-Emitting Element>

FIG. 4A is a schematic cross-sectional view of a light-emitting element 460.

The light-emitting element 460 illustrated in FIG. 4A includes a plurality of light-emitting units (a light-emitting unit 406 and a light-emitting unit 408 in FIG. 4A) between a pair of electrodes (the electrode 401 and the electrode 402). One light-emitting unit has the same structure as the EL layer 400 illustrated in FIG. 1A. That is, the light-emitting element 450 in FIG. 1A includes one light-emitting unit, while the light-emitting element 460 includes a plurality of light-emitting units. Note that the electrode 401 functions as an anode and the electrode 402 functions as a cathode in the following description of the light-emitting element 460; however, the functions may be interchanged in the light-emitting element 460.

In the light-emitting element 460 illustrated in FIG. 4A, the light-emitting unit 406 and the light-emitting unit 408 are stacked, and a charge-generation layer 415 is provided between the light-emitting unit 406 and the light-emitting unit 408. Note that the light-emitting unit 406 and the light-emitting unit 408 may have the same structure or different structures. For example, it is preferable that the EL layer 400 illustrated in FIG. 1A be used in the light-emitting unit 408.

The light-emitting element 460 includes a light-emitting layer 420 and the light-emitting layer 430. The light-emitting unit 406 includes the hole-injection layer 411, the hole-transport layer 412, an electron-transport layer 413, and an electron-injection layer 414 in addition to the light-emitting layer 430. The light-emitting unit 408 includes a hole-injection layer 416, a hole-transport layer 417, an electron-transport layer 418, and an electron-injection layer 419 in addition to the light-emitting layer 420.

The charge-generation layer 415 may have either a structure in which an acceptor substance that is an electron acceptor is added to a hole-transport material or a structure in which a donor substance that is an electron donor is added to an electron-transport material. Alternatively, both of these structures may be stacked.

In the case where the charge-generation layer 415 contains a composite material of an organic compound and an acceptor substance, the composite material that can be used for the hole-injection layer 411 described in Embodiment 1 may be used for the composite material. As the organic compound, a variety of compounds such as an aromatic amine compound, a carbazole compound, an aromatic hydrocarbon, and a high molecular compound (such as an oligomer, a dendrimer, or a polymer) can be used. A substance having a hole mobility of 1×10⁻⁶ cm²/Vs or higher is preferably used as the organic compound. Note that any other material may be used as long as it has a property of transporting more holes than electrons. Since the composite material of an organic compound and an acceptor substance has excellent carrier-injection and carrier-transport properties, low-voltage driving or low-current driving can be achieved. Note that when a surface of a light-emitting unit on the anode side is in contact with the charge-generation layer 415 as in the case of the light-emitting unit 408, the charge-generation layer 415 can also serve as a hole-injection layer or a hole-transport layer of the light-emitting unit; thus, a hole-injection layer or a hole-transport layer need not be included in the light-emitting unit.

The charge-generation layer 415 may have a stacked structure of a layer containing the composite material of an organic compound and an acceptor substance and a layer containing another material. For example, the charge-generation layer 415 may be formed using a combination of a layer containing the composite material of an organic compound and an acceptor substance with a layer containing one compound selected from among electron-donating materials and a compound having an excellent electron-transport property. Furthermore, the charge-generation layer 415 may be formed using a combination of a layer containing the composite material of an organic compound and an acceptor substance with a layer containing a transparent conductive material.

The charge-generation layer 415 provided between the light-emitting unit 406 and the light-emitting unit 408 may have any structure as long as electrons can be injected to the light-emitting unit on one side and holes can be injected into the light-emitting unit on the other side when a voltage is applied between the electrode 401 and the electrode 402. For example, in FIG. 4A, the charge-generation layer 415 injects electrons into the light-emitting unit 406 and holes into the light-emitting unit 408 when a voltage is applied such that the potential of the electrode 401 is higher than that of the electrode 402.

Note that in terms of light extraction efficiency, the charge-generation layer 415 preferably has a visible light transmittance (specifically, a visible light transmittance of higher than or equal to 40%). The charge-generation layer 415 functions even if it has lower conductivity than the pair of electrodes (the electrodes 401 and 402). In the case where the conductivity of the charge-generation layer 415 is as high as those of the pair of electrodes, carriers generated in the charge-generation layer 415 flow toward the film surface direction, so that light is emitted in a region where the electrode 401 and the electrode 402 do not overlap with each other, in some cases. To suppress such a defect, the charge-generation layer 415 is preferably formed using a material whose conductivity is lower than those of the pair of electrodes.

Note that forming the charge-generation layer 415 by using any of the above materials can suppress an increase in drive voltage caused by the stack of the light-emitting layers.

The light-emitting element having two light-emitting units is described with reference to FIG. 4A; however, a similar structure can be applied to a light-emitting element in which three or more light-emitting units are stacked. With a plurality of light-emitting units partitioned by the charge-generation layer between a pair of electrodes as in the light-emitting element 460, it is possible to provide a light-emitting element which can emit light with high luminance with the current density kept low and has a long lifetime. A light-emitting element with low power consumption can be provided.

When the structure of the EL layer 400 illustrated in FIG. 1A is used for at least one of the plurality of units, a light-emitting element with high luminous efficiency can be provided.

It is preferable that the light-emitting layer 430 included in the light-emitting unit 406 have the structure described in Embodiment 1, in which case the light-emitting element 460 has high luminous efficiency.

Furthermore, the light-emitting layer 420 included in the light-emitting unit 408 contains a host material 421 and a guest material 422 as illustrated in FIG. 4B. Note that the guest material 422 is described below as a fluorescent compound.

### <Light Emission Mechanism of Light-Emitting Layer 420>

The light emission mechanism of the light-emitting layer 420 will be described below.

By recombination of the electrons and holes injected from the pair of electrodes (the electrode 401 and the electrode 402) or the charge-generation layer 415 in the light-emitting layer 420, excitons are formed. Because the amount of the host material 421 is larger than that of the guest material 422, the host material 421 is brought into an excited state by the exciton generation.

Note that the term “exciton” refers to a carrier (electron and hole) pair. Since excitons have energy, a material where excitons are generated is brought into an excited state.

In the case where the formed excited state of the host material 421 is a singlet excited state, singlet excitation energy transfers from the S1 level of the host material 421 to the S1 level of the guest material 422, thereby forming the singlet excited state of the guest material 422.

Since the guest material 422 is a fluorescent compound, when a singlet excited state is formed in the guest material 422, the guest material 422 readily emits light. To obtain high luminous efficiency in this case, the fluorescence quantum yield of the guest material 422 is preferably high. The same can apply to a case where a singlet excited state is formed by recombination of carriers in the guest material 422.

Next, a case where recombination of carriers forms a triplet excited state of the host material 421 will be described. The correlation of energy levels of the host material 421 and the guest material 422 in this case is shown in FIG. 4C. The following explains what terms and signs in FIG. 4C represent. Note that because it is preferable that the T1 level of the host material 421 be lower than the T1 level of the guest material 422, FIG. 4C shows this preferable case. However, the T1 level of the host material 421 may be higher than the T1 level of the guest material 422.
Host (421): the host material 421;
Guest (422): the guest material 422 (the fluorescent compound);
S_{FH}: the S1 level the host material 421;
T_{FH}: the T1 level of the host material 421;
S_{FG}: the S1 level of the guest material 422 (the fluorescent compound); and
T_{FG}: the T1 level of the guest material 422 (the fluorescent compound).

As illustrated in FIG. 4C, triplet excitons formed by carrier recombination become adjacent to each other, and a reaction in which one of the triplet excitons is converted into a singlet exciton having energy of the S1 level of the host material 421 (S_{F}H), or triplet-triplet annihilation (TTA), is caused (see TTA in FIG. 4C). The singlet excitation energy of the host material 421 is transferred from S_{F}H to the S1 level of the guest material 422 (S_{FG}) having a lower energy than S_{F}H (see Route E₅ in FIG. 4C), and a singlet excited state of the guest material 422 is formed, whereby the guest material 422 emits light.

Note that in the case where the density of triplet excitons in the light-emitting layer 420 is sufficiently high (e.g., 1×10¹² cm⁻³ or more), only the reaction of two triplet excitons close to each other can be considered whereas deactivation of a single triplet exciton can be ignored.

In the case where a triplet excited state of the guest material 422 is formed by carrier recombination, the triplet excited state of the guest material 422 is thermally deactivated and is difficult to use for light emission. However, in the case where the T1 level of the host material 421 (T_{FH}) is lower than the T1 level of the guest material 422 (T_{FG}), the triplet excitation energy of the guest material 422 can be transferred from the T1 level of the guest material 422 (T_{FG}) to the T1 level of the host material 421 (T_{FH}) (see Route E₆ in FIG. 4C) and then is utilized for TTA.

In other words, the host material 421 preferably has a function of converting triplet excitation energy into singlet excitation energy by causing TTA, so that the triplet excitation energy generated in the light-emitting layer 420 can be partly converted into singlet excitation energy by TTA in the host material 421. The singlet excitation energy can be transferred to the guest material 422 and extracted as fluorescence. In order to achieve this, the S1 level of the host material 421 (S_{FH}) is preferably higher than the S1 level of the guest material 422 (S_{FG}). In addition, the T1 level of the host material 421 (T_{FH}) is preferably lower than the T1 level of the guest material 422 (T_{FG}).

Note that particularly in the case where the T1 level of the guest material 422 (T_{FG}) is lower than the T1 level of the host material 421 (T_{FH}), the weight ratio of the guest material 422 to the host material 421 is preferably low. Specifically, the weight ratio of the guest material 422 to the host material 421 is preferably greater than 0 and less than or equal to 0.05, in which case, the probability of carrier recombination in the guest material 422 can be reduced. In addition, the probability of energy transfer from the T1 level of the host material 421 (T_{FH}) to the T1 level of the guest material 422 (T_{FG}) can be reduced.

Note that the host material 421 may be composed of a single compound or a plurality of compounds.

Note that in each of the above-described structures, the guest materials (fluorescent compounds) used in the light-emitting unit 406 and the light-emitting unit 408 may be the same or different. In the case where the same guest material is used for the light-emitting unit 406 and the light-emitting unit 408, the light-emitting element 460 can exhibit high emission luminance at a small current value, which is preferable. In the case where different guest materials are used for the light-emitting unit 406 and the light-emitting unit 408, the light-emitting element 460 can exhibit multi-color light emission, which is preferable. It is particularly favorable to select the guest materials so that white light emission with high color rendering properties or light emission of at least red, green, and blue can be obtained.

### <Structural Example 2 of Light-Emitting Element>

FIG. 5A is a schematic cross-sectional view of a light-emitting element 462.

The light-emitting element 462 illustrated in FIG. 5A includes, like the light-emitting element 460 described above, a plurality of light-emitting units (a light-emitting unit 406 and a light-emitting unit 410 in FIG. 5A) between a pair of electrodes (the electrode 401 and the electrode 402). One light-emitting unit has the same structure as the EL layer 400 illustrated in FIG. 1A. Note that the light-emitting unit 406 and the light-emitting unit 410 may have the same structure or different structures.

In the light-emitting element 462 illustrated in FIG. 5A, the light-emitting unit 406 and the light-emitting unit 410 are stacked, and a charge-generation layer 415 is provided between the light-emitting unit 406 and the light-emitting unit 410. For example, it is preferable that the EL layer 400 illustrated in FIG. 1A be used in the light-emitting unit 406.

The light-emitting element 462 includes the light-emitting layer 430 and a light-emitting layer 440. The light-emitting unit 406 includes the hole-injection layer 411, the hole-transport layer 412, the electron-transport layer 413, and the electron-injection layer 414 in addition to the light-emitting layer 430. The light-emitting unit 410 includes the hole-injection layer 416, the hole-transport layer 417, the electron-transport layer 418, and the electron-injection layer 419 in addition to the light-emitting layer 440.

In addition, the light-emitting layer of the light-emitting unit 410 preferably contains a phosphorescent compound. That is, it is preferable that the light-emitting layer 430 included in the light-emitting unit 406 have the structure described in Embodiment 1 and the light-emitting layer 440 included in the light-emitting unit 410 contain a phosphorescent compound. A structural example of the light-emitting element 462 in this case will be described below.

Furthermore, the light-emitting layer 440 included in the light-emitting unit 410 contains a host material 441 and a guest material 442 as illustrated in FIG. 5B. The host material 441 contains an organic compound 441_1 and an organic compound 441_2. Note that the guest material 442 included in the light-emitting layer 440 will be described below as a phosphorescent compound.

### <Light Emission Mechanism of Light-Emitting Layer 440>

Next, the light emission mechanism of the light-emitting layer 440 will be described below.

The organic compound 441_1 and the organic compound 441_2 which are included in the light-emitting layer 440 form an exciplex.

It is acceptable as long as the combination of the organic compound 441_1 and the organic compound 441_2 can form an exciplex in the light-emitting layer 440, and it is preferred that one organic compound have a hole-transport property and the other organic compound have an electron-transport property.

FIG. 5C illustrates the correlation of energy levels of the organic compound 441_1, the organic compound 441_2, and the guest material 442 in the light-emitting layer 440. The following explains what terms and signs in FIG. 5C represent:
Host (441_1): the organic compound 441_1 (host material);
Host (441_2): the organic compound 441_2 (host material);
Guest (442): the guest material 442 (phosphorescent compound);
S_{PH}: the S1 level of the organic compound 4411 (host material);
T_{PH}: the T1 level of the organic compound 4411 (host material);
T_{PG}: the T1 level of the guest material 442 (phosphorescent compound);
S_{PE}: the S1 level of the exciplex; and
T_{PE}: the T1 level of the exciplex.

The S1 level of the exciplex (S_{PE}) formed by the organic compounds 441_1 and 441_2 and the T1 level of the exciplex (T_{PE}) are close to each other (see Route E₇ in FIG. 5C).

One of the organic compound 441_1 and the organic compound 441_2 receives a hole and the other receives an electron to readily form an exciplex. Alternatively, one of the organic compounds brought into an excited state immediately interacts with the other organic compound to form an exciplex. Therefore, most excitons in the light-emitting layer 440 exist as exciplexes. Because the excitation energy levels (S_{PE} and S_{TE}) of the exciplex are less than the S1 levels (S_{PH1}and S_{PH2}) of the organic compounds that form the exciplex (the organic compounds 441_1 and 441_2), an excited state can be formed in the light-emitting layer with lower excitation energy. This can reduce the driving voltage of the light-emitting element.

Both energies of S_{PE} and T_{PE} of the exciplex are then transferred to the T1 level of the guest material 442 (phosphorescent compound); thus, light emission is obtained (see Routes E₈ and E₉ in FIG. 5C).

Note that the above-described processes through Routes E₇, E₈, and E₉ may be referred to as exciplex-triplet energy transfer (ExTET) in this specification and the like.

Furthermore, the T1 level of the exciplex (T_{PE}) is preferably higher than the T1 level of the guest material 442 (T_{PG}). In this way, the singlet excitation energy and the triplet excitation energy of the formed exciplex can be transferred from the S1 level and the T1 level of the exciplex (S_{PE} and T_{PE}) to the T1 level of the guest material 442 (T_{PG}).

Note that in order to efficiently transfer excitation energy from the exciplex to the guest material 442, the T1 level of the exciplex (T_{PE}) is preferably lower than or equal to the T1 levels of the organic compounds that form an exciplex (the organic compound 441_1 and the organic compound 4412) (T_{PH1} and T_{PH2}). Thus, quenching of the triplet excitation energy of the exciplex due to the organic compounds (the organic compounds 441_1 and 441_2) is less likely to occur, resulting in efficient energy transfer from the exciplex to the guest material 442.

When the light-emitting layer 440 has the above structure, light emission from the guest material 442 (phosphorescent compound) of the light-emitting layer 440 can be efficiently obtained.

Note that light emitted from the light-emitting layer 430 preferably has a peak on the shorter wavelength side than light emitted from the light-emitting layer 440. Since the luminance of a light-emitting element using a phosphorescent compound that emits light with a short wavelength tends to be degraded quickly, fluorescence with a short wavelength is employed so that a light-emitting element with less degradation of luminance can be provided.

Furthermore, the light-emitting layer 430 and the light-emitting layer 440 may be made to emit light with different emission wavelengths, so that the light-emitting element can be a multicolor light-emitting element. In that case, the emission spectrum of the light-emitting element is formed by combining light having different emission peaks, and thus has at least two peaks.

The above structure is also suitable for obtaining white light emission. When the light-emitting layer 430 and the light-emitting layer 440 emit light of complementary colors, white light emission can be obtained.

In addition, white light emission with a high color rendering property that is formed of three primary colors or four or more colors can be obtained by using a plurality of light-emitting materials that emit light with different wavelengths for one of the light-emitting layers 430 and 440 or both. In that case, one of the light-emitting layers 430 and 440 or both may be divided into layers and each of the divided layers may contain a light-emitting material different from the others.

<Examples of Materials that can be Used in Light-Emitting Layers>

Next, materials that can be used in the light-emitting layers 420, 430, and 440 will be described.

<<Material that can be Used in Light-Emitting Layer 430>>

As a material that can be used in the light-emitting layer 430, a material that can be used in the light-emitting layer 430 in Embodiment 1 may be used. Thus, a light-emitting element with high luminous efficiency can be fabricated.

<<Material that can be Used in Light-Emitting Layer 420>>

In the light-emitting layer 420, the host material 421 is present in the largest proportion by weight, and the guest material 422 (fluorescent compound) is dispersed in the host material 421. The S1 level of the host material 421 is preferably higher than the S1 level of the guest material 422 (fluorescent compound) while the T1 level of the host material 421 is preferably lower than the T1 level of the guest material 422 (fluorescent compound).

In the light-emitting layer 420, although the guest material 422 is not particularly limited, for example, any of materials which are described as examples of the guest material 433 in Embodiment 1 can be used.

Although there is no particular limitation on a material that can be used as the host material 421 in the light-emitting layer 420, any of the following materials can be used, for example: metal complexes such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)-tris(1-phenyl-1H-benzimidazole) (abbreviation: TPBI), bathophenanthroline (abbreviation: BPhen), bathocuproine (abbreviation: BCP), 2,9-bis(naphthalen-2-yl)-4,7-diphenyl-1,10-phenanthroline (abbreviation: NBPhen), and 9-[4-(5-phenyl-1,3,4-oxadiazol-2-yl)phenyl]-9H-carbazole (abbreviation: CO11); and aromatic amine compounds such as 4,4′-bis[N-(1-naphthyl)-N-phenylamino]biphenyl (abbreviation: NPB or α-NPD), N,N-bis(3-methylphenyl)-N,N-diphenyl-[1,1′-biphenyl]-4,4′-diamine (abbreviation: TPD), and 4,4′-bis[N-(spiro-9,9′-bifluoren-2-yl)-N-phenylamino]biphenyl (abbreviation: BSPB). In addition, condensed polycyclic aromatic compounds such as anthracene derivatives, phenanthrene derivatives, pyrene derivatives, chrysene derivatives, and dibenzo[g,p]chrysene derivatives can be given, and specific examples are 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), 4-(9H-carbazol-9-yl)-4′-(10-phenyl-9-anthryl)triphenylamine (abbreviation: YGAPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N,9-diphenyl-N-(9,10-diphenyl-2-anthryl)-9H-carbazol-3-amine (abbreviation: 2PCAPA), 6,12-dimethoxy-5,11-diphenylchrysene, N,N,N,N,N′,N′,N″,N″-octaphenyldibenzo[g,p]chrysene-2,7,10,15-tetramine (abbreviation: DBC1), 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 7-[4-(10-phenyl-9-anthryl)phenyl]-7H-dibenzo[c,g]carbazole (abbreviation: cgDBCzPA), 9-phenyl-3-[4-(10-phenyl-9-anthryl)phenyl]-9H-carbazole (abbreviation: PCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), and the like. One or more substances having a wider energy gap than the guest material 422 are selected from these substances and known substances.

The light-emitting layer 420 can have a structure in which two or more layers are stacked. For example, in the case where the light-emitting layer 420 is formed by stacking a first light-emitting layer and a second light-emitting layer in this order from the hole-transport layer side, the first light-emitting layer is formed using a substance having a hole-transport property as the host material and the second light-emitting layer is formed using a substance having an electron-transport property as the host material.

In the light-emitting layer 420, the host material 421 may be composed of one kind of compound or a plurality of compounds. Alternatively, the light-emitting layer 420 may contain a material other than the host material 421 and the guest material 422.

<<Material that can be Used in Light-Emitting Layer 440>>

In the light-emitting layer 440, the host material 441 exists in the largest proportion in weight ratio, and the guest material 442 (phosphorescent compound) is dispersed in the host material 441. The T1 level of the host material 441 (organic compounds 441_1 and 4412) of the light-emitting layer 440 is preferably higher than the T1 level of the guest material (guest material 442) of the light-emitting layer 440.

Examples of the organic compound 441_1 include a zinc- or aluminum-based metal complex, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, and the like. Other examples are an aromatic amine, a carbazole derivative, and the like. Specifically, the electron-transport material and the hole-transport material described in Embodiment 1 can be used.

As the organic compound 4412, a substance which can form an exciplex together with the organic compound 441_1 is preferably used. Specifically, the electron-transport material and the hole-transport material described in Embodiment 1 can be used. In that case, it is preferable that the organic compound 441_1, the organic compound 441_2, and the guest material 442 (phosphorescent compound) be selected such that the emission peak of the exciplex formed by the organic compound 441_1 and the organic compound 441_2 overlaps with an absorption band, specifically an absorption band on the longest wavelength side, of a triplet metal to ligand charge transfer (MILCT) transition of the guest material 442 (phosphorescent compound). This makes it possible to provide a light-emitting element with drastically improved luminous efficiency. Note that in the case where a thermally activated delayed fluorescent material is used instead of the phosphorescent compound, it is preferable that the absorption band on the longest wavelength side be a singlet absorption band.

As the guest material 442 (phosphorescent compound), an iridium-, rhodium-, or platinum-based organometallic complex or metal complex can be used; in particular, an organoiridium complex such as an iridium-based ortho-metalated complex is preferable. As an ortho-metalated ligand, a 4H-triazole ligand, a 1H-triazole ligand, an imidazole ligand, a pyridine ligand, a pyrimidine ligand, a pyrazine ligand, an isoquinoline ligand, and the like can be given. As the metal complex, a platinum complex having a porphyrin ligand and the like can be given.

Examples of the substance that has an emission peak in the blue or green wavelength range include organometallic iridium complexes having a 4H-triazole skeleton, such as tris{2-[5-(2-methylphenyl)-4-(2,6-dimethylphenyl)-4H-1,2,4-triazol-3-yl-xN2]phenyl-xC}iridium(III) (abbreviation: Ir(mpptz-dmp)₃), tris(5-methyl-3,4-diphenyl-4H-1,2,4-triazolato)iridium(III) (abbreviation: Ir(Mptz)₃), tris[4-(3-biphenyl)-5-isopropyl-3-phenyl-4H-1,2,4-triazolato]iridium(III) (abbreviation: Ir(iPrptz-3)₃), and tris[3-(5-biphenyl)-5-isopropyl-4-phenyl-4H-1,2,4-triazolato]iridium(III) (abbreviation: Ir(iPr5btz)₃); organometallic iridium complexes having a 1H-triazole skeleton, such as tris[3-methyl-1-(2-methylphenyl)-5-phenyl-1H-1,2,4-triazolato]iridium(III) (abbreviation: Ir(Mptzl-mp)₃) and tris(1-methyl-5-phenyl-3-propyl-1H-1,2,4-triazolato)iridium(III) (abbreviation: Ir(Prptzl-Me)₃); organometallic iridium complexes having an imidazole skeleton, such as fac-tris[l-(2,6-diisopropylphenyl)-2-phenyl-1H-imidazole]iridium(III) (abbreviation: Ir(iPrpmi)₃) and tris[3-(2,6-dimethylphenyl)-7-methylimidazo[1,2-f]phenanthridinato]iridium(III) (abbreviation: Ir(dmpimpt-Me)₃); and organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C²′}iridium(III)picolinate (abbreviation: Ir(CF₃ppy)₂(pic)), and bis[2-(4′,6′-difluorophenyl)pyridinato-N,C^{2′}]iridium(III) acetylacetonate (abbreviation: FIr(acac)). Among the materials given above, the organometallic iridium complexes having a 4H-triazole skeleton have high reliability and high luminous efficiency and are thus especially preferable.

Examples of the substance that has an emission peak in the green or yellow wavelength range include organometallic iridium complexes having a pyrimidine skeleton, such as tris(4-methyl-6-phenylpyrimidinato)iridium(III) (abbreviation: Ir(mppm)₃), tris(4-t-butyl-6-phenylpyrimidinato)iridium(III) (abbreviation: Ir(tBuppm)₃), (acetylacetonato)bis(6-methyl-4-phenylpyrimidinato)iridium(III) (abbreviation: Ir(mppm)₂(acac)), (acetylacetonato)bis(6-tert-butyl-4-phenylpyrimidinato)iridium(III) (abbreviation: Ir(tBuppm)₂(acac)), (acetylacetonato)bis[4-(2-norbornyl)-6-phenylpyrimidinato]iridium(III) (abbreviation: Ir(nbppm)₂(acac)), (acetylacetonato)bis[5-methyl-6-(2-methylphenyl)-4-phenylpyrimidinato]iridium(III) (abbreviation: Ir(mpmppm)₂(acac)), (acetylacetonato)bis{4,6-dimethyl-2-[6-(2,6-dimethylphenyl)-4-pyrimidinyl-κN3]phenyl-κC}iridium(III) (abbreviation: Ir(dmppm-dmp)₂(acac)), and (acetylacetonato)bis(4,6-diphenylpyrimidinato)iridium(III) (abbreviation: Ir(dppm)₂(acac)); organometallic iridium complexes having a pyrazine skeleton, such as (acetylacetonato)bis(3,5-dimethyl-2-phenylpyrazinato)iridium(III) (abbreviation: Ir(mppr-Me)₂(acac)) and (acetylacetonato)bis(5-isopropyl-3-methyl-2-phenylpyrazinato)iridium(III) (abbreviation: Ir(mppr-iPr)₂(acac)); organometallic iridium complexes having a pyridine skeleton, such as tris(2-phenylpyridinato-N,C′)iridium(III) (abbreviation: Ir(ppy)₃), bis(2-phenylpyridinato-N,C^{2′})iridium(III) acetylacetonate (abbreviation: Ir(ppy)₂(acac)), bis(benzo[h]quinolinato)iridium(III) acetylacetonate (abbreviation: Ir(bzq)₂(acac)), tris(benzo[h]quinolinato)iridium(III) (abbreviation: Ir(bzq)₃), tris(2-phenylquinolinato-N,C^{2′})iridium(III) (abbreviation: Ir(pq)₃), and bis(2-phenylquinolinato-N,C²)iridium(III) acetylacetonate (abbreviation: Ir(pq)₂(acac)); organometallic iridium complexes such as bis(2,4-diphenyl-1,3-oxazolato-N,C^{2′})iridium(III) acetylacetonate (abbreviation: Ir(dpo)₂(acac)), bis{2-[4′-(perfluorophenyl)phenyl]pyridinato-N,C^{2′}}iridium(III) acetylacetonate (abbreviation: Ir(p-PF-ph)₂(acac)), and bis(2-phenylbenzothiazolato-N,C^{2′})iridium(III) acetylacetonate (abbreviation: Ir(bt)₂(acac)); and a rare earth metal complex such as tris(acetylacetonato)(monophenanthroline)terbium(III) (abbreviation: Tb(acac)₃(Phen)). Among the materials given above, the organometallic iridium complexes having a pyrimidine skeleton have distinctively high reliability and luminous efficiency and are thus particularly preferable.

Examples of the substance that has an emission peak in the yellow or red wavelength range include organometallic iridium complexes having a pyrimidine skeleton, such as (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), and bis[4,6-di(naphthalen-1-yl)pyrimidinato](dipivaloylmethanato)iridium(III) (abbreviation: Ir(d1npm)₂(dpm)); organometallic iridium complexes having a pyrazine skeleton, such as (acetylacetonato)bis(2,3,5-triphenylpyrazinato)iridium(III) (abbreviation: Ir(tppr)₂(acac)), bis(2,3,5-triphenylpyrazinato) (dipivaloylmethanato)iridium(III) (abbreviation: Ir(tppr)₂(dpm)), and (acetylacetonato)bis[2,3-bis(4-fluorophenyl)quinoxalinato]iridium(III) (abbreviation: Ir(Fdpq)₂(acac)); organometallic iridium complexes having a pyridine skeleton, such as tris(1-phenylisoquinolinato-N,C^{2′})iridium(III) (abbreviation: Ir(piq)₃) and bis(1-phenylisoquinolinato-N,C^{2′})iridium(III) acetylacetonate (abbreviation: Ir(piq)₂(acac)); a platinum complex such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: Eu(DBM)₃(Phen)) and tris[1-(2-thenoyl)-3,3,3-trifluoroacetonato](monophenanthroline)europium(III) (abbreviation: Eu(TTA)₃(Phen)). Among the materials given above, the organometallic iridium complexes having a pyrimidine skeleton have distinctively high reliability and luminous efficiency and are thus particularly preferable. Furthermore, the organometallic iridium complexes having a pyrazine skeleton can provide red light emission with favorable chromaticity.

As the light-emitting material included in the light-emitting layer 440, any material can be used as long as the material can convert the triplet excitation energy into light emission. As an example of the material that can convert the triplet excitation energy into light emission, a thermally activated delayed fluorescent (TADF) material can be given in addition to a phosphorescent compound. Therefore, it is acceptable that the “phosphorescent compound” in the description is replaced with the “thermally activated delayed fluorescent material”.

In the case where the material that exhibits thermally activated delayed fluorescence is formed of one kind of material, any of the thermally activated delayed fluorescent materials described in Embodiment 1 can be specifically used.

In the case where the thermally activated delayed fluorescent material is used as the host material, it is preferable to use a combination of two kinds of compounds which form an exciplex. In this case, it is particularly preferable to use the above-described combination of a compound which easily accepts electrons and a compound which easily accepts holes, which form an exciplex.

There is no limitation on the emission colors of the light-emitting materials contained in the light-emitting layers 420, 430, and 440, and they may be the same or different. Light emitted from the light-emitting materials is mixed and extracted out of the element; therefore, for example, in the case where their emission colors are complementary colors, the light-emitting element can emit white light. In consideration of the reliability of the light-emitting element, the emission peak wavelength of the light-emitting material included in the light-emitting layer 420 is preferably shorter than that of the light-emitting material included in the light-emitting layer 440.

Note that the light-emitting units 406, 408, and 410 and the charge-generation layer 415 can be formed by an evaporation method (including a vacuum evaporation method), an ink-jet method, a coating method, gravure printing, or the like.

Note that the structure described in this embodiment can be combined as appropriate with any of the structures described in the other embodiments and the example.

### Embodiment 3

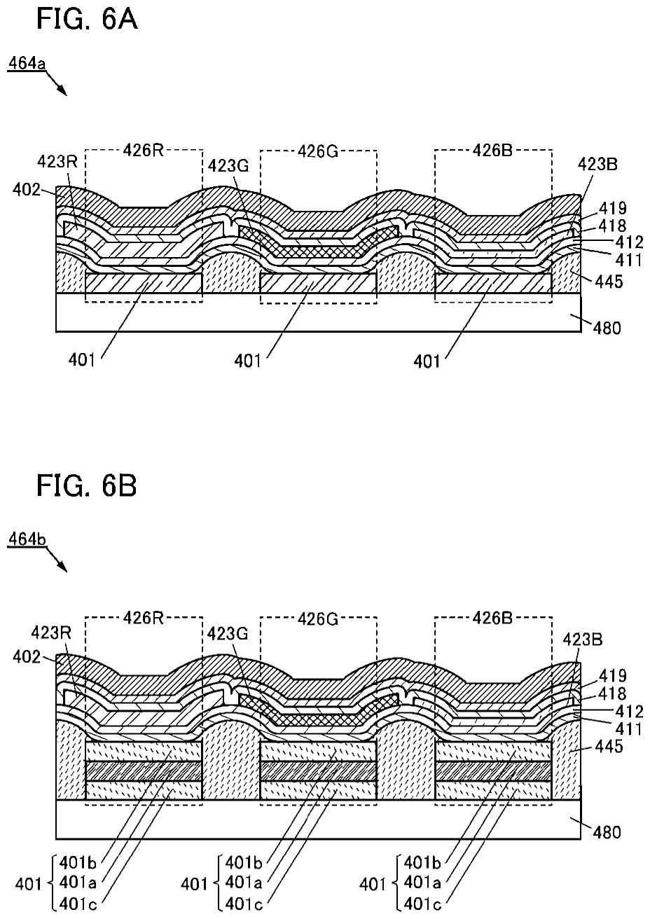

In this embodiment, examples of light-emitting elements having structures different from those described in Embodiments 1 and 2 will be described below with reference to FIGS. 6A to 9C.

### <Structural Example 1 of Light-Emitting Element>

FIGS. 6A and 6B are cross-sectional views each illustrating a light-emitting element of one embodiment of the present invention. In FIGS. 6A and 6B, a portion having a function similar to that in FIG. 1A is represented by the same hatch pattern as that in FIG. 1A and not especially denoted by a reference numeral in some cases. In addition, common reference numerals are used for portions having similar functions, and a detailed description of the portions is omitted in some cases.

Light-emitting elements 464a and 464b in FIGS. 6A and 6B may have a bottom-emission structure in which light is extracted through the substrate 480 or may have a top-emission structure in which light is extracted in the direction opposite to the substrate 480. However, one embodiment of the present invention is not limited to this structure, and a light-emitting element having a dual-emission structure in which light emitted from the light-emitting element is extracted in both top and bottom directions of the substrate 480 may be used.

In the case where the light-emitting elements 464a and 464b each have a bottom emission structure, the electrode 401 preferably has a function of transmitting light and the electrode 402 preferably has a function of reflecting light. Alternatively, in the case where the light-emitting elements 464a and 464b each have a top emission structure, the electrode 401 preferably has a function of reflecting light and the electrode 402 preferably has a function of transmitting light.

The light-emitting elements 464a and 464b each include the electrode 401 and the electrode 402 over the substrate 480. Between the electrodes 401 and 402, a light-emitting layer 423B, a light-emitting layer 423G, and a light-emitting layer 423R are provided. The hole-injection layer 411, the hole-transport layer 412, the electron-transport layer 418, and the electron-injection layer 419 are also provided.

The light-emitting element 464b includes, as part of the electrode 401, a conductive layer 401a, a conductive layer 401b over the conductive layer 401a, and a conductive layer 401c under the conductive layer 401a. In other words, the light-emitting element 464b includes the electrode 401 having a structure in which the conductive layer 401a is sandwiched between the conductive layer 401b and the conductive layer 401c.

In the light-emitting element 464b, the conductive layer 401b and the conductive layer 401c can be formed with either different materials or the same material. The conductive layer 401b and the conductive layer 401c are preferably formed using the same conductive material, in which case patterning by etching can be performed easily.

In the light-emitting element 464b, the electrode 401 may include only one of the conductive layer 401b and the conductive layer 401c.

For each of the conductive layers 401a, 401b, and 401c, which are included in the electrode 401, the structure and materials of the electrode 401 or 402 described in Embodiment 1 can be used.

In FIGS. 6A and 6B, a partition 445 is provided between a region 426B, a region 426G, and a region 426R, which are sandwiched between the electrode 401 and the electrode 402. The partition 445 has an insulating property. The partition 445 covers end portions of the electrode 401 and has openings overlapping with the electrode. With the partition 445, the electrode 401 provided over the substrate 480 in the regions can be divided into island shapes.

Note that the light-emitting layer 423B and the light-emitting layer 423G may overlap with each other in a region where they overlap with the partition 445. The light-emitting layer 423G and the light-emitting layer 423R may overlap with each other in a region where they overlap with the partition 445. The light-emitting layer 423R and the light-emitting layer 423B may overlap with each other in a region where they overlap with the partition 445.

The partition 445 has an insulating property and is formed using an inorganic or organic material. Examples of the inorganic material include silicon oxide, silicon oxynitride, silicon nitride oxide, silicon nitride, aluminum oxide, and aluminum nitride. Examples of the organic material include photosensitive resin materials such as an acrylic resin and a polyimide resin.

The light-emitting layers 423R, 423G, and 423B preferably contain light-emitting materials having functions of emitting light of different colors. For example, when the light-emitting layer 423R contains a light-emitting material having a function of emitting red light, the region 426R emits red light. When the light-emitting layer 423G contains a light-emitting material having a function of emitting green light, the region 426G emits green light. When the light-emitting layer 423B contains a light-emitting material having a function of emitting blue light, the region 426B emits blue light. The light-emitting element 464a or 464b having such a structure is used in a pixel of a display device, whereby a full-color display device can be fabricated. The thicknesses of the light-emitting layers may be the same or different.

Any one or more of the light-emitting layers 423B, 423G, and 423R preferably include the light-emitting layer 430 described in Embodiment 1, in which case a light-emitting element with high luminous efficiency can be fabricated.

One or more of the light-emitting layers 423B, 423G, and 423R may include two or more stacked layers.

When at least one light-emitting layer includes the light-emitting layer described in Embodiment 1 as described above and the light-emitting element 464a or 464b including the light-emitting layer is used in pixels in a display device, a display device with high luminous efficiency can be fabricated. The display device including the light-emitting element 464a or 464b can thus have reduced power consumption.

By providing a color filter over the electrode through which light is extracted, the color purity of each of the light-emitting elements 464a and 464b can be improved. Therefore, the color purity of a display device including the light-emitting element 464a or 464b can be improved.

By providing a polarizing plate over the electrode through which light is extracted, the reflection of external light by each of the light-emitting elements 464a and 464b can be reduced. Therefore, the contrast ratio of a display device including the light-emitting element 464a or 464b can be improved.

For the other components of the light-emitting elements 464a and 464b, the components of the light-emitting element in Embodiment 1 can be referred to.

### <Structural Example 2 of Light-Emitting Element>

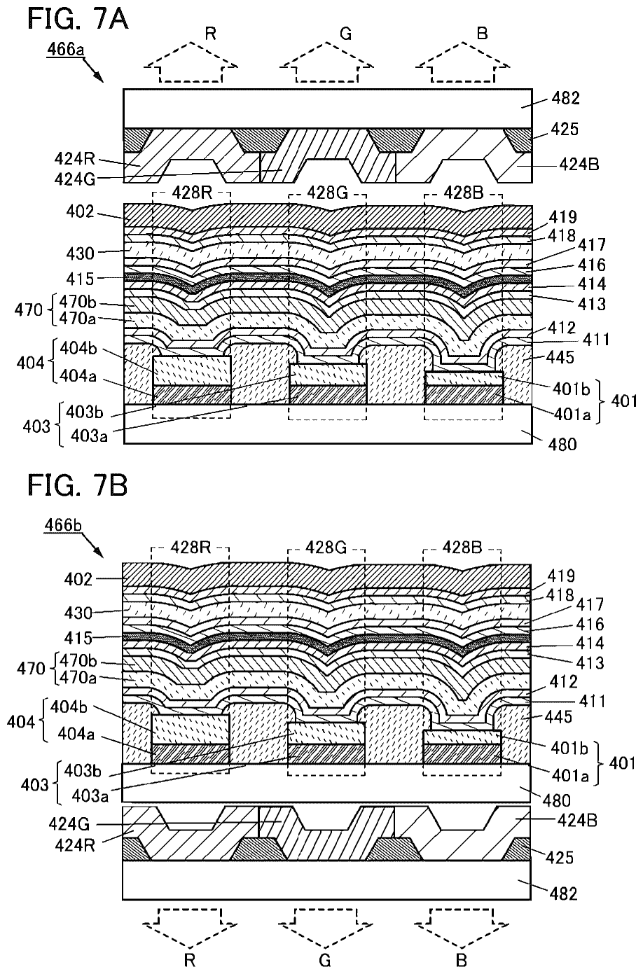

Next, structural examples different from the light-emitting elements illustrated in FIGS. 6A and 6B will be described below with reference to FIGS. 7A and 7B.

FIGS. 7A and 7B are cross-sectional views of a light-emitting element of one embodiment of the present invention. In FIGS. 7A and 7B, a portion having a function similar to that in FIGS. 6A and 6B is represented by the same hatch pattern as that in FIGS. 6A and 6B and not especially denoted by a reference numeral in some cases. In addition, common reference numerals are used for portions having similar functions, and a detailed description of such portions is not repeated in some cases.

FIGS. 7A and 7B illustrate structural examples of a light-emitting element including the light-emitting layer between a pair of electrodes. A light-emitting element 466a illustrated in FIG. 7A has a top-emission structure in which light is extracted in a direction opposite to the substrate 480, and a light-emitting element 466b illustrated in FIG. 7B has a bottom-emission structure in which light is extracted to the substrate 480 side. However, one embodiment of the present invention is not limited to these structures and may have a dual-emission structure in which light emitted from the light-emitting element is extracted in both top and bottom directions with respect to the substrate 480 over which the light-emitting element is formed.

The light-emitting elements 466a and 466b each include the electrode 401, the electrode 402, an electrode 403, and an electrode 404 over the substrate 480. At least a light-emitting layer 430 and the charge-generation layer 415 are provided between the electrode 401 and the electrode 402, between the electrode 402 and the electrode 403, and between the electrode 402 and the electrode 404. The hole-injection layer 411, the hole-transport layer 412, a light-emitting layer 470, the electron-transport layer 413, the electron-injection layer 414, the hole-injection layer 416, the hole-transport layer 417, the electron-transport layer 418, and the electron-injection layer 419 are further provided.

The electrode 401 includes a conductive layer 401a and a conductive layer 401b over and in contact with the conductive layer 401a. The electrode 403 includes a conductive layer 403a and a conductive layer 403b over and in contact with the conductive layer 403a. The electrode 404 includes a conductive layer 404a and a conductive layer 404b over and in contact with the conductive layer 404a.

The light-emitting element 466a illustrated in FIG. 7A and the light-emitting element 466b illustrated in FIG. 7B each include a partition 445 between a region 428B sandwiched between the electrode 401 and the electrode 402, a region 428G sandwiched between the electrode 402 and the electrode 403, and a region 428R sandwiched between the electrode 402 and the electrode 404. The partition 445 has an insulating property. The partition 445 covers end portions of the electrodes 401, 403, and 404 and has openings overlapping with the electrodes. With the partition 445, the electrodes provided over the substrate 480 in the regions can be separated into island shapes.

The light-emitting elements 466a and 466b each include a substrate 482 provided with an optical element 424B, an optical element 424G, and an optical element 424R in the direction in which light emitted from the region 428B, light emitted from the region 428G, and light emitted from the region 428R are extracted. The light emitted from each region is emitted outside the light-emitting element through each optical element. In other words, the light from the region 428B, the light from the region 428G, and the light from the region 428R are emitted through the optical element 424B, the optical element 424G, and the optical element 424R, respectively.

The optical elements 424B, 424G, and 424R each have a function of selectively transmitting light of a particular color out of incident light. For example, the light emitted from the region 428B through the optical element 424B is blue light, the light emitted from the region 428G through the optical element 424G is green light, and the light emitted from the region 428R through the optical element 424R is red light.

For example, a coloring layer (also referred to as color filter), a band pass filter, a multilayer filter, or the like can be used for the optical elements 424R, 424G, and 424B. Alternatively, color conversion elements can be used as the optical elements. A color conversion element is an optical element that converts incident light into light having a longer wavelength than the incident light. As the color conversion elements, quantum-dot elements can be favorably used. The use of the quantum-dot type can increase color reproducibility of the display device.

A plurality of optical elements may also be stacked over each of the optical elements 424R, 424G, and 424B. As another optical element, a circularly polarizing plate, an anti-reflective film, or the like can be provided, for example. A circularly polarizing plate provided on the side where light emitted from the light-emitting element of the display device is extracted can prevent a phenomenon in which light incident from the outside of the display device is reflected inside the display device and returned to the outside. An anti-reflective film can weaken external light reflected by a surface of the display device. This leads to clear observation of light emitted from the display device.

Note that in FIGS. 7A and 7B, blue light (B), green light (G), and red light (R) emitted from the regions through the optical elements are schematically illustrated by arrows of dashed lines.

A light-blocking layer 425 is provided between the optical elements. The light-blocking layer 425 has a function of blocking light emitted from the adjacent regions. Note that a structure without the light-blocking layer 425 may also be employed.

The light-blocking layer 425 has a function of reducing the reflection of external light. The light-blocking layer 425 has a function of preventing mixture of light emitted from an adjacent light-emitting element. For the light-blocking layer 425, a metal, a resin containing black pigment, carbon black, a metal oxide, a composite oxide containing a solid solution of a plurality of metal oxides, or the like can be used.

For the substrate 480 and the substrate 482 provided with the optical elements, the substrate in Embodiment 1 can be referred to.

Furthermore, the light-emitting elements 466a and 466b have a microcavity structure.

### <<Microcavity Structure>>

Light emitted from the light-emitting layer 430 and the light-emitting layer 470 resonates between a pair of electrodes (e.g., the electrode 401 and the electrode 402). The light-emitting layer 430 and the light-emitting layer 470 are formed at such a position as to intensify the light of a desired wavelength among light to be emitted. For example, by adjusting the optical length from a reflective region of the electrode 401 to the light-emitting region of the light-emitting layer 430 and the optical length from a reflective region of the electrode 402 to the light-emitting region of the light-emitting layer 430, the light of a desired wavelength among light emitted from the light-emitting layer 430 can be intensified. By adjusting the optical length from the reflective region of the electrode 401 to the light-emitting region of the light-emitting layer 470 and the optical length from the reflective region of the electrode 402 to the light-emitting region of the light-emitting layer 470, the light of a desired wavelength among light emitted from the light-emitting layer 470 can be intensified. In the case of a light-emitting element in which a plurality of light-emitting layers (here, the light-emitting layers 430 and 470) are stacked, the optical lengths of the light-emitting layers 430 and 470 are preferably optimized.

In each of the light-emitting elements 466a and 466b, by adjusting the thicknesses of the conductive layers (the conductive layer 401b, the conductive layer 403b, and the conductive layer 404b) in each region, the light of a desired wavelength among light emitted from the light-emitting layers 430 and 470 can be intensified. Note that the thickness of at least one of the hole-injection layer 411 and the hole-transport layer 412 may differ between the regions to intensify the light emitted from the light-emitting layers 430 and 470.

For example, in the case where the refractive index of the conductive material having a function of reflecting light in the electrodes 401 to 404 is lower than the refractive index of the light-emitting layer 430 or 470, the thickness of the conductive layer 401b of the electrode 401 is adjusted so that the optical length between the electrode 401 and the electrode 402 is m_{B}λ_{B}/2 (m_{B} is a natural number and kB is the wavelength of light intensified in the region 428B). Similarly, the thickness of the conductive layer 403b of the electrode 403 is adjusted so that the optical length between the electrode 403 and the electrode 402 is m_{G}λ_{G}/2 (m_{G} is a natural number and λ_{G} is the wavelength of light intensified in the region 428G). Furthermore, the thickness of the conductive layer 404b of the electrode 404 is adjusted so that the optical length between the electrode 404 and the electrode 402 is m_{R}λ_{R}/2 (m_{R} is a natural number and λ_{R} is the wavelength of light intensified in the region 428R).

In the above manner, with the microcavity structure, in which the optical length between the pair of electrodes in the respective regions is adjusted, scattering and absorption of light in the vicinity of the electrodes can be suppressed, resulting in high light extraction efficiency. In the above structure, the conductive layers 401b, 403b, and 404b preferably have a function of transmitting light. The materials of the conductive layers 401b, 403b, and 404b may be the same or different. Each of the conductive layers 401b, 403b, and 404b may have a stacked structure of two or more layers.

Since the light-emitting element 466a illustrated in FIG. 7A has a top-emission structure, it is preferable that the conductive layer 401a, the conductive layer 403a, and the conductive layer 404a have a function of reflecting light. In addition, it is preferable that the electrode 402 have functions of transmitting light and reflecting light.

Since the light-emitting element 466b illustrated in FIG. 7B has a bottom-emission structure, it is preferable that the conductive layer 401a, the conductive layer 403a, and the conductive layer 404a have functions of transmitting light and reflecting light. In addition, it is preferable that the electrode 402 have a function of reflecting light.

In each of the light-emitting elements 466a and 466b, the conductive layers 401a, 403a, and 404a may be formed of different materials or the same material. When the conductive layers 401a, 403a, and 404a are formed of the same material, manufacturing cost of the light-emitting elements 466a and 466b can be reduced. Note that each of the conductive layers 401a, 403a, and 404a may have a stacked structure including two or more layers.

The light-emitting layer 430 in the light-emitting elements 466a and 466b preferably has the structure described in Embodiment 1, in which case light-emitting elements with high luminous efficiency can be fabricated.

Either or both of the light-emitting layers 430 and 470 may have a stacked structure of two layers, like a light-emitting layer 470a and a light-emitting layer 470b. The two light-emitting layers including two kinds of light-emitting materials (a first light-emitting material and a second light-emitting material) for emitting different colors of light enable light emission of a plurality of colors. It is particularly preferable to select the light-emitting materials of the light-emitting layers so that white light can be obtained by combining light emissions from the light-emitting layers 430 and 470.

Either or both of the light-emitting layers 430 and 470 may have a stacked structure of three or more layers, in which a layer not including a light-emitting material may be included.

In the above-described manner, the light-emitting element 466a or 466b including the light-emitting layer which has the structure described in Embodiment 1 is used in pixels in a display device, whereby a display device with high luminous efficiency can be fabricated. Accordingly, the display device including the light-emitting element 466a or 466b can have low power consumption.

For the other components of the light-emitting elements 466a and 466b, the components of the light-emitting element 464a or 464b or the light-emitting element in Embodiment 1 or 2 can be referred to.

### <Fabrication Method of Light-Emitting Element>

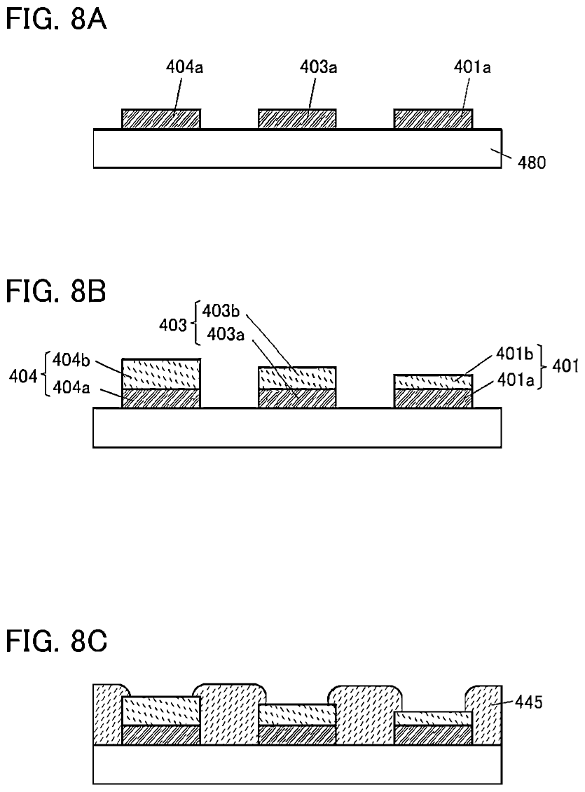

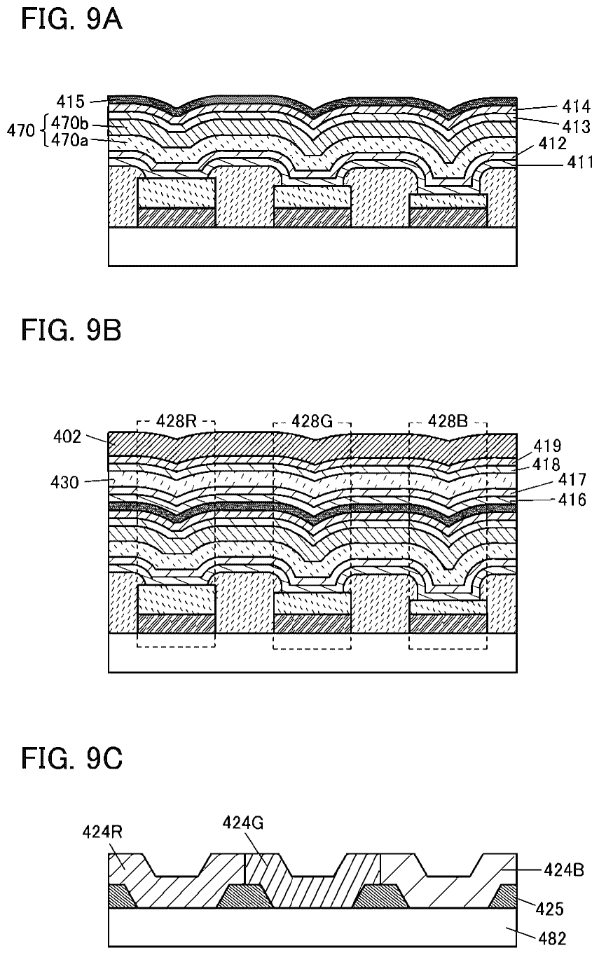

Next, a method for fabricating a light-emitting element of one embodiment of the present invention will be described below with reference to FIGS. 8A to 9C. Here, a method for fabricating the light-emitting element 466a illustrated in FIG. 7A will be described.

FIGS. 8A to 9C are cross-sectional views illustrating a method for fabricating the light-emitting element of one embodiment of the present invention.

The method for manufacturing the light-emitting element 466a described below includes first to seventh steps.

### <<First Step>>

In the first step, the electrodes (specifically the conductive layer 401a of the electrode 401, the conductive layer 403a of the electrode 403, and the conductive layer 404a of the electrode 404) of the light-emitting elements are formed over the substrate 480 (see FIG. 8A).

In this embodiment, a conductive layer having a function of reflecting light is formed over the substrate 480 and processed into a desired shape, whereby the conductive layers 401a, 403a, and 404a are formed. As the conductive layer having a function of reflecting light, an alloy film of silver, palladium, and copper (also referred to as an Ag—Pd—Cu film and APC) is used. The conductive layers 401a, 403a, and 404a are preferably formed through a step of processing the same conductive layer, because the manufacturing cost can be reduced.

Note that a plurality of transistors may be formed over the substrate 480 before the first step. The plurality of transistors may be electrically connected to the conductive layers 401a, 403a, and 404a.

### <<Second Step>>

In the second step, the conductive layer 401b having a function of transmitting light is formed over the conductive layer 401a of the electrode 401, the conductive layer 403b having a function of transmitting light is formed over the conductive layer 403a of the electrode 403, and the conductive layer 404b having a function of transmitting light is formed over the conductive layer 404a of the electrode 404 (see FIG. 8B).

In this embodiment, the conductive layers 401b, 403b, and 404b each having a function of transmitting light are formed over the conductive layers 401a, 403a, and 404a each having a function of reflecting light, respectively, whereby the electrode 401, the electrode 403, and the electrode 404 are formed. As the conductive layers 401b, 403b, and 404b, ITSO films are used.

The conductive layers 401b, 403b, and 404b having a function of transmitting light may be formed through a plurality of steps. When the conductive layers 401b, 403b, and 404b having a function of transmitting light are formed through a plurality of steps, they can be formed to have thicknesses which enable microcavity structures appropriate in the respective regions.

### <<Third Step>>

In the third step, the partition 445 that covers end portions of the electrodes of the light-emitting element is formed (see FIG. 8C).

The partition 445 includes an opening overlapping with the electrode. The conductive film exposed by the opening functions as the anode of the light-emitting element. As the partition 445, a polyimide resin is used in this embodiment.

In the first to third steps, since there is no possibility of damaging the EL layer (a layer containing an organic compound), a variety of film formation methods and fine processing technologies can be employed. In this embodiment, a reflective conductive layer is formed by a sputtering method, a pattern is formed over the conductive layer by a lithography method, and then the conductive layer is processed into an island shape by a dry etching method or a wet etching method to form the conductive layer 401a of the electrode 401, the conductive layer 403a of the electrode 403, and the conductive layer 404a of the electrode 404. Then, a transparent conductive film is formed by a sputtering method, a pattern is formed over the transparent conductive film by a lithography method, and then the transparent conductive film is processed into island shapes by a wet etching method to form the electrodes 401, 403, and 404.

### <<Fourth Step>>

In the fourth step, the hole-injection layer 411, the hole-transport layer 412, the light-emitting layer 470, the electron-transport layer 413, the electron-injection layer 414, and the charge-generation layer 415 are formed (see FIG. 9A).

The hole-injection layer 411 can be formed by depositing a hole-transport material and a material containing an acceptor substance by co-evaporation. Note that a co-evaporation method is an evaporation method in which a plurality of different substances are concurrently vaporized from respective different evaporation sources. The hole-transport layer 412 can be formed by depositing a hole-transport material by evaporation.

The light-emitting layer 470 can be formed by depositing, by evaporation, the guest material that emits light of at least one of blue, blue green, green, yellow green, yellow, orange, and red. As the guest material, a fluorescent or phosphorescent organic compound can be used. In addition, the light-emitting layer having any of the structures described in Embodiments 1 and 2 is preferably used. The light-emitting layer 470 may have a two-layer structure. In that case, the two light-emitting layers preferably contain light-emitting substances that emit light of different colors.

The electron-transport layer 413 can be formed by depositing a substance having an excellent electron-transport property by evaporation. The electron-injection layer 414 can be formed by depositing a substance having an excellent electron-injection property by evaporation.

The charge-generation layer 415 can be formed by depositing, by evaporation, a material obtained by adding an electron acceptor (acceptor) to a hole-transport material or a material obtained by adding an electron donor (donor) to an electron-transport material.

### <<Fifth Step>>

In the fifth step, the hole-injection layer 416, the hole-transport layer 417, the light-emitting layer 430, the electron-transport layer 418, the electron-injection layer 419, and the electrode 402 are formed (see FIG. 9B).

The hole-injection layer 416 can be formed by using a material and a method which are similar to those of the hole-injection layer 411. The hole-transport layer 417 can be formed by using a material and a method which are similar to those of the hole-transport layer 412.

The light-emitting layer 430 can be formed by depositing, by evaporation, a compound that emits light of at least one color selected from blue, blue green, green, yellow green, yellow, orange, and red. As the compound, a plurality of compounds may be deposited by evaporation so as to be mixed with each other, or a single compound may be deposited by evaporation. For example, the fluorescent organic compound may be used as a guest material, and the guest material may be dispersed into a host material having higher excitation energy than the guest material.

The electron-transport layer 418 can be formed by using a material and a method which are similar to those of the electron-transport layer 413. The electron-injection layer 419 can be formed by using a material and a method which are similar to those of the electron-injection layer 414.

The electrode 402 can be formed by stacking a reflective conductive film and a light-transmitting conductive film. The electrode 402 may have a single-layer structure or a stacked structure.

Through the above-described steps, the light-emitting element including the region 428B, the region 428G, and the region 428R over the electrode 401, the electrode 403, and the electrode 404, respectively, is formed over the substrate 480.

### <<Sixth Step>>

In the sixth step, the light-blocking layer 425, the optical element 424B, the optical element 424G, and the optical element 424R are formed over the substrate 482 (see FIG. 9C).

As the light-blocking layer 425, a resin film containing black pigment is formed in a desired region. Then, the optical element 424B, the optical element 424G, and the optical element 424R are formed over the substrate 482 and the light-blocking layer 425. As the optical element 424B, a resin film containing blue pigment is formed in a desired region. As the optical element 424G, a resin film containing green pigment is formed in a desired region. As the optical element 424R, a resin film containing red pigment is formed in a desired region.

### <<Seventh Step>>

In the seventh step, the light-emitting element formed over the substrate 480 is attached to the light-blocking layer 425, the optical element 424B, the optical element 424G, and the optical element 424R formed over the substrate 482, and sealed with a sealant (not illustrated).

Through the above-described steps, the light-emitting element 466a illustrated in FIG. 7A can be formed.

Note that the structure described in this embodiment can be combined as appropriate with any of the structures described in the other embodiments and the example.

### Embodiment 4

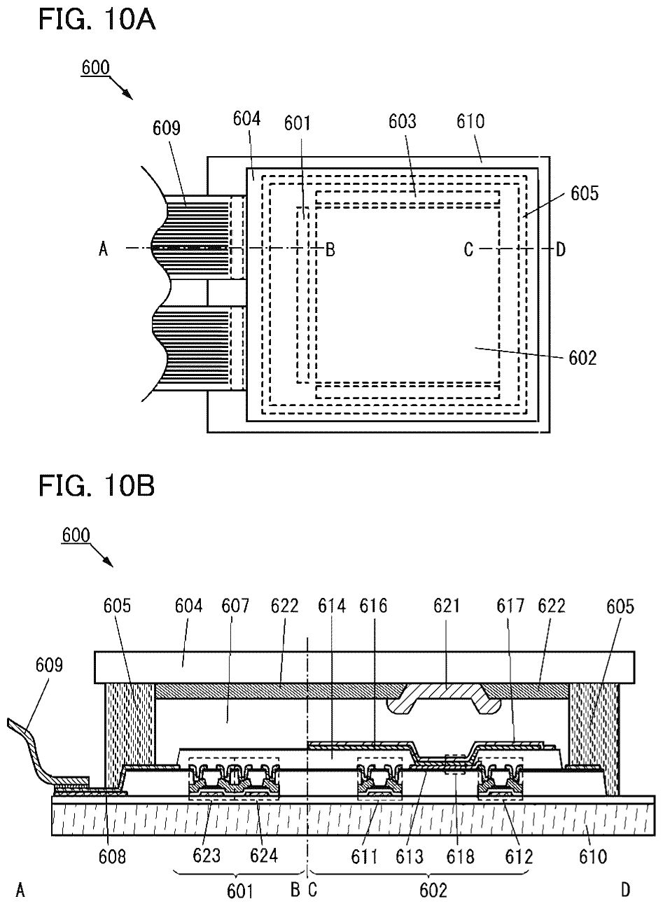

In this embodiment, a display device including the light-emitting element of one embodiment of the present invention will be described with reference to FIGS. 10A to 20.

### <Structural Example 1 of Display Device>

FIG. 10A is a top view illustrating a display device 600 and FIG. 10B is a cross-sectional view taken along the dashed-dotted line A-B and the dashed-dotted line C-D in FIG. 10A. The display device 600 includes driver circuit portions (a signal line driver circuit portion 601 and a scan line driver circuit portion 603) and a pixel portion 602. Note that the signal line driver circuit portion 601, the scan line driver circuit portion 603, and the pixel portion 602 have a function of controlling light emission of a light-emitting element.

The display device 600 also includes an element substrate 610, a sealing substrate 604, a sealant 605, a region 607 surrounded by the sealant 605, a lead wiring 608, and an FPC 609.

Note that the lead wiring 608 is a wiring for transmitting signals to be input to the signal line driver circuit portion 601 and the scan line driver circuit portion 603 and for receiving a video signal, a clock signal, a start signal, a reset signal, and the like from the FPC 609 serving as an external input terminal. Although only the FPC 609 is illustrated here, the FPC 609 may be provided with a printed wiring board (PWB).

As the signal line driver circuit portion 601, a CMOS circuit in which an n-channel transistor 623 and a p-channel transistor 624 are combined is formed. As the signal line driver circuit portion 601 or the scan line driver circuit portion 603, various types of circuits such as a CMOS circuit, a PMOS circuit, or an NMOS circuit can be used. Although a driver in which a driver circuit portion is formed and a pixel are formed over the same surface of a substrate in the display device of this embodiment, the driver circuit portion is not necessarily formed over the substrate and can be formed outside the substrate.

The pixel portion 602 includes a switching transistor 611, a current control transistor 612, and a lower electrode 613 electrically connected to a drain of the current control transistor 612. Note that a partition 614 is formed to cover end portions of the lower electrode 613. As the partition 614, for example, a positive type photosensitive acrylic resin film can be used.

In order to obtain favorable coverage by a film which is formed over the partition 614, the partition 614 is formed to have a curved surface with curvature at its upper or lower end portion. For example, in the case of using a positive photosensitive acrylic as a material of the partition 614, it is preferable that only the upper end portion of the partition 614 have a curved surface with curvature (a curvature radius of 0.2 μm to 3 μm inclusive). As the partition 614, either a negative photosensitive resin or a positive photosensitive resin can be used.

Note that there is no particular limitation on the structure of each of the transistors (the transistors 611, 612, 623, and 624). For example, a staggered transistor can be used. In addition, there is no particular limitation on the polarity of these transistors. For these transistors, n-channel and p-channel transistors may be used, or either n-channel transistors or p-channel transistors may be used, for example. Furthermore, there is no particular limitation on the crystallinity of a semiconductor film used for these transistors. For example, an amorphous semiconductor film or a crystalline semiconductor film may be used. Examples of a semiconductor material include Group 14 semiconductors (e.g., a semiconductor including silicon), compound semiconductors (including oxide semiconductors), organic semiconductors, and the like. For example, it is preferable to use an oxide semiconductor that has an energy gap of 2 eV or more, preferably 2.5 eV or more and more preferably 3 eV or more, for the transistors, so that the off-state current of the transistors can be reduced. Examples of the oxide semiconductor include an In—Ga oxide and an In-M-Zn oxide (M is aluminum (Al), gallium (Ga), yttrium (Y), zirconium (Zr), lanthanum (La), cerium (Ce), tin (Sn), hafnium (Hf), or neodymium (Nd)).

An EL layer 616 and an upper electrode 617 are formed over the lower electrode 613. Here, the lower electrode 613 functions as an anode and the upper electrode 617 functions as a cathode.

In addition, the EL layer 616 is formed by various methods such as an evaporation method with an evaporation mask (e.g., a vacuum evaporation method), a droplet discharge method (also referred to as an ink-jet method), a coating method such as a spin coating method, and a gravure printing method. As another material included in the EL layer 616, a low molecular compound or a high molecular compound (including an oligomer or a dendrimer) may be used.

Note that a light-emitting element 618 is formed with the lower electrode 613, the EL layer 616, and the upper electrode 617. The light-emitting element 618 preferably has any of the structures described in Embodiments 1 to 3. In the case where the pixel portion includes a plurality of light-emitting elements, the pixel portion may include both any of the light-emitting elements described in Embodiments 1 to 3 and a light-emitting element having a different structure.

When the sealing substrate 604 and the element substrate 610 are attached to each other with the sealant 605, the light-emitting element 618 is provided in the region 607 surrounded by the element substrate 610, the sealing substrate 604, and the sealant 605. The region 607 is filled with a filler. In some cases, the region 607 is filled with an inert gas (nitrogen, argon, or the like) or filled with an ultraviolet curable resin or a thermosetting resin which can be used for the sealant 605. For example, a polyvinyl chloride (PVC)-based resin, an acrylic-based resin, a polyimide-based resin, an epoxy-based resin, a silicone-based resin, a polyvinyl butyral (PVB)-based resin, or an ethylene vinyl acetate (EVA)-based resin can be used. It is preferable that the sealing substrate be provided with a recessed portion and the desiccant be provided in the recessed portion, in which case deterioration due to influence of moisture can be inhibited.

An optical element 621 is provided below the sealing substrate 604 to overlap with the light-emitting element 618. A light-blocking layer 622 is provided below the sealing substrate 604. The structures of the optical element 621 and the light-blocking layer 622 can be the same as those of the optical element and the light-blocking layer in Embodiment 3, respectively.

An epoxy-based resin or glass frit is preferably used for the sealant 605. It is preferable that such a material not transmit moisture or oxygen as much as possible. As the sealing substrate 604, a glass substrate, a quartz substrate, or a plastic substrate formed of fiber reinforced plastic (FRP), poly(vinyl fluoride) (PVF), polyester, acrylic, or the like can be used.

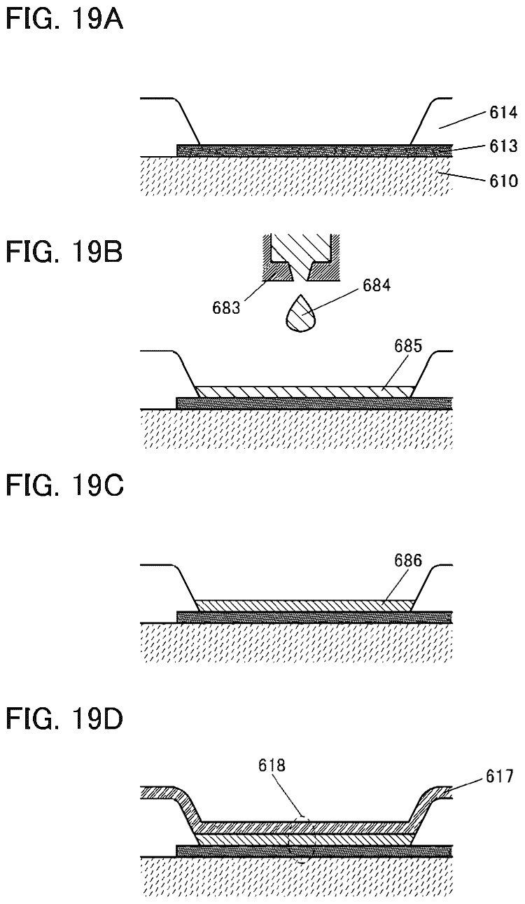

Formation method of light-emitting element by droplet discharge method Here, a method for forming the EL layer 616 by a droplet discharge method will be described with reference to FIGS. 19A to 19D. FIGS. 19A to 19D are cross-sectional views illustrating the method for forming the EL layer 616.

First, the element substrate 610 over which the lower electrode 613 and the partition 614 are formed is illustrated in FIG. 19A. However, as in FIG. 10B, the lower electrode 613 and the partition 614 may be formed over an insulating film over a substrate.

Next, in a portion where the lower electrode 613 is exposed, which is an opening of the partition 614, a droplet 684 is discharged from a droplet discharge apparatus 683 to form a layer 685 containing a composition. The droplet 684 is a composition containing a solvent and is attached to the lower electrode 613 (see FIG. 19B).

Note that the step of discharging the droplet 684 may be performed under reduced pressure.

Then, the solvent is removed from the layer 685 containing the composition, and the resulting layer is solidified to form the EL layer 616 (see FIG. 19C).

The solvent may be removed by drying or heating.

Next, the upper electrode 617 is formed over the EL layer 616, and the light-emitting element 618 is formed (see FIG. 19D).

When the EL layer 616 is formed by a droplet discharge method as described above, the composition can be selectively discharged, and accordingly, loss of materials can be reduced. Furthermore, a lithography process or the like for shaping is not needed, and thus, the process can be simplified and cost reduction can be achieved.

Note that FIGS. 19A to 19D illustrate a process for forming the EL layer 616 as a single layer. When the EL layer 616 includes functional layers in addition to the light-emitting layer, the layers are formed sequentially from the lower electrode 613 side. In that case, the hole-transport layer, and the hole-injection layer, the light-emitting layer, electron-injection layer, and the electron-transport layer may be formed by a droplet discharge method. Alternatively, the hole-transport layer, the hole-injection layer, and the light-emitting layer may be formed by a droplet discharge method, whereas the electron-injection layer and the electron-transport layer may be formed by an evaporation method or the like. The light-emitting layer may be formed by a combination of a droplet discharge method and an evaporation method or the like.

The hole-injection layer can be formed using poly(ethylenedioxythiophene)/poly(styrenesulfonic acid) by a coating method, such as a droplet discharge method or a spin coating method, for example. The hole-transport layer can be formed using a hole-transport material, e.g., polyvinylcarbazole, by a coating method, such as a droplet discharge method or a spin coating method, for example. After the formation of the hole-injection layer and after the formation of the hole-transport layer, heat treatment may be performed under an air atmosphere or an inert gas atmosphere such as nitrogen.

The light-emitting layer can be formed using a high molecular compound or a low molecular compound that emits at least one of violet light, blue light, blue green light, green light, yellow green light, yellow light, orange light, and red light. As the high molecular compound and the low molecular compound, a fluorescent or phosphorescent organic compound can be used. With use of a solvent in which the high molecular compound and the low molecular compound are dissolved, the light-emitting layer can be formed by a coating method, such as a droplet discharge method or a spin coating method. After the formation of the light-emitting layer, heat treatment may be performed under an air atmosphere or an inert gas atmosphere such as a nitrogen atmosphere. Note that the fluorescent or phosphorescent organic compound used as a guest material may be dispersed into a high molecular compound or a low molecular compound that has higher excitation energy than the guest material. The light-emitting organic compound may be deposited alone or the light-emitting organic compound mixed with another material may be deposited. The light-emitting layer may have a two-layered structure. In such a case, the two light-emitting layers each preferably contain a light-emitting organic compound that emits light of a different color. When the light-emitting layer is formed using a low molecular compound, an evaporation method can be used.

The electron-transport layer can be formed using a substance having an excellent electron-transport property. The electron-injection layer can be formed using a substance having an excellent electron-injection property. Note that the electron-transport layer and the electron-injection layer can be formed by an evaporation method.

The upper electrode 617 can be formed by an evaporation method. The upper electrode 617 can be formed using a reflective conductive film. Alternatively, the upper electrode 617 may have a stack including a reflective conductive film and a light-transmitting conductive film.

The droplet discharge method described above is a general term for a means including a nozzle equipped with a composition discharge opening or a means to discharge droplets, such as a head having one or a plurality of nozzles.

### <<Droplet Discharge Apparatus>>

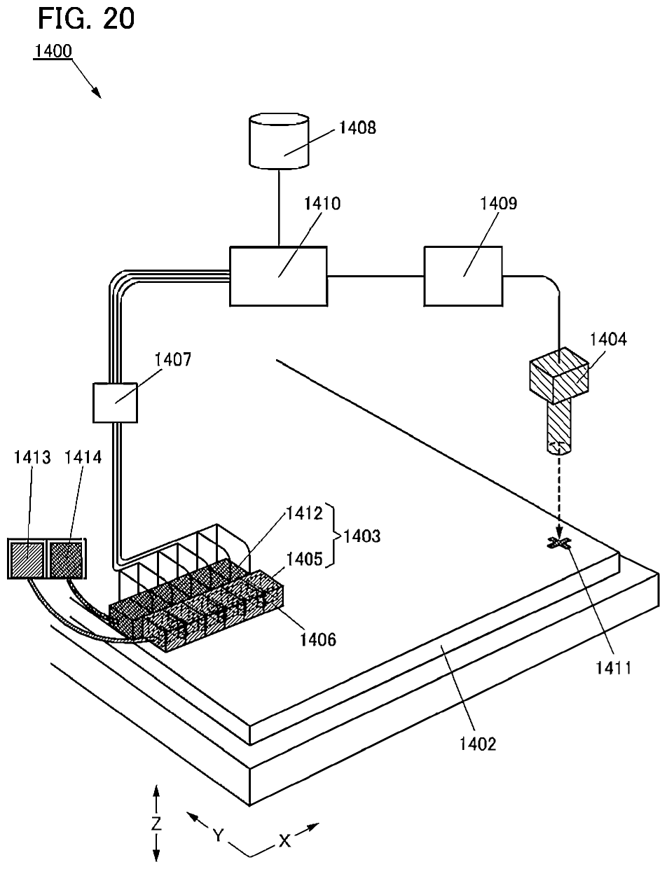

Next, a droplet discharge apparatus used for the droplet discharge method will be described with reference to FIG. 20. FIG. 20 is a conceptual diagram illustrating a droplet discharge apparatus 1400.

The droplet discharge apparatus 1400 includes a droplet discharge means 1403. In addition, the droplet discharge means 1403 is equipped with a head 1405 and a head 1412.

The heads 1405 and 1412 are connected to a control means 1407, and this control means 1407 is controlled by a computer 1410; thus, a preprogrammed pattern can be drawn.

The drawing may be conducted at a timing, for example, based on a marker 1411 formed over a substrate 1402. Alternatively, the reference point may be determined on the basis of an outer edge of the substrate 1402. Here, the marker 1411 is detected by an imaging means 1404 and converted into a digital signal by an image processing means 1409. Then, the digital signal is recognized by the computer 1410, and then, a control signal is generated and transmitted to the control means 1407.

An image sensor or the like using a charge coupled device (CCD) or a complementary metal-oxide-semiconductor (CMOS) can be used as the imaging means 1404. Note that information on a pattern to be formed over the substrate 1402 is stored in a storage medium 1408, and the control signal is transmitted to the control means 1407 on the basis of the information, whereby the head 1405 and the head 1412 of the droplet discharge means 1403 can be separately controlled. The heads 1405 and 1412 are supplied with a material to be discharged from material supply sources 1413 and 1414 through pipes, respectively.

Inside the head 1405, a space 1406 filled with a liquid material as indicated by a dotted line and a nozzle serving as a discharge opening are provided. Although not shown, an inside structure of the head 1412 is similar to that of the head 1405. When the nozzle sizes of the heads 1405 and 1412 are different from each other, different materials with different widths can be discharged simultaneously. Each head can discharge and draw a plurality of light-emitting materials or the like. In the case of drawing over a large area, the same material can be simultaneously discharged to be drawn from a plurality of nozzles in order to improve throughput. When a large substrate is used, the heads 1405 and 1412 can freely scan the substrate in directions indicated by arrows X, Y, and Z in FIG. 20, and a region in which a pattern is drawn can be freely set. Thus, a plurality of the same patterns can be drawn over one substrate.

Furthermore, a step of discharging the composition may be performed under reduced pressure. Also, a substrate may be heated when the composition is discharged. After discharging the composition, either drying or baking or the both is performed. Both the drying and baking are heat treatments but different in purpose, temperature, and time period. The steps of drying and baking are performed under normal pressure or under reduced pressure by laser irradiation, rapid thermal annealing, heating using a heating furnace, or the like. Note that the timing of the heat treatment and the number of times of the heat treatment are not particularly limited. The temperature for performing each of the steps of drying and baking in a favorable manner depends on the materials of the substrate and the properties of the composition.

As described above, the EL layer 616 can be formed with use of a droplet discharge apparatus.

In the above-described manner, the display device including any of the light-emitting elements and the optical elements which are described in Embodiments 1 to 3 can be obtained.

### <Structural Example 2 of Display Device>

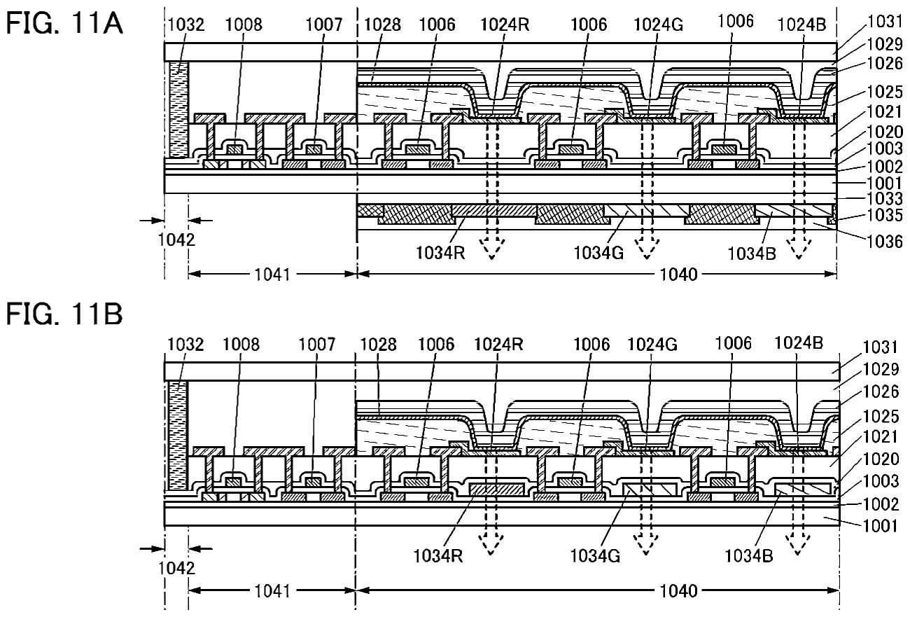

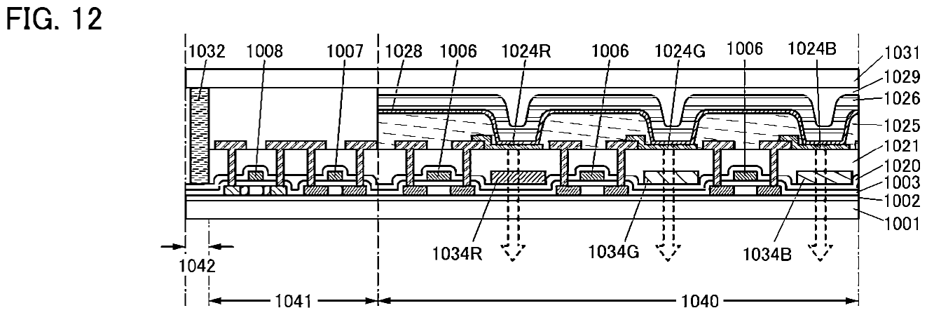

Next, another example of the display device will be described with reference to FIGS. 11A and 11B and FIG. 12. Note that FIGS. 11A and 11B and FIG. 12 are each a cross-sectional view of a display device of one embodiment of the present invention.

In FIG. 11A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, lower electrodes 1024R, 1024G, and 1024B of light-emitting elements, a partition 1025, an EL layer 1028, an upper electrode 1026 of the light-emitting elements, a sealing layer 1029, a sealing substrate 1031, a sealant 1032, and the like are illustrated.

In FIG. 11A, as examples of the optical elements, coloring layers (a red coloring layer 1034R, a green coloring layer 1034G, and a blue coloring layer 1034B) are provided on a transparent base material 1033. Furthermore, a light-blocking layer 1035 may be provided. The transparent base material 1033 provided with the coloring layers and the light-blocking layer is positioned and fixed to the substrate 1001. Note that the coloring layers and the light-blocking layer are covered with an overcoat layer 1036. In the structure in FIG. 11A, red light, green light, and blue light transmit the coloring layers, and thus an image can be displayed with the use of pixels of three colors.

FIG. 11B illustrates an example in which, as examples of the optical elements, the coloring layers (the red coloring layer 1034R, the green coloring layer 1034G, and the blue coloring layer 1034B) are provided between the gate insulating film 1003 and the first interlayer insulating film 1020. As in this structure, the coloring layers may be provided between the substrate 1001 and the sealing substrate 1031.

FIG. 12 illustrates an example in which, as examples of the optical elements, the coloring layers (the red coloring layer 1034R, the green coloring layer 1034G, and the blue coloring layer 1034B) are provided between the first interlayer insulating film 1020 and the second interlayer insulating film 1021. As in this structure, the coloring layers may be provided between the substrate 1001 and the sealing substrate 1031.

The above-described display device has a structure in which light is extracted from the substrate 1001 side where the transistors are formed (a bottom-emission structure), but may have a structure in which light is extracted from the sealing substrate 1031 side (a top-emission structure).

### <Structural Example 3 of Display Device>

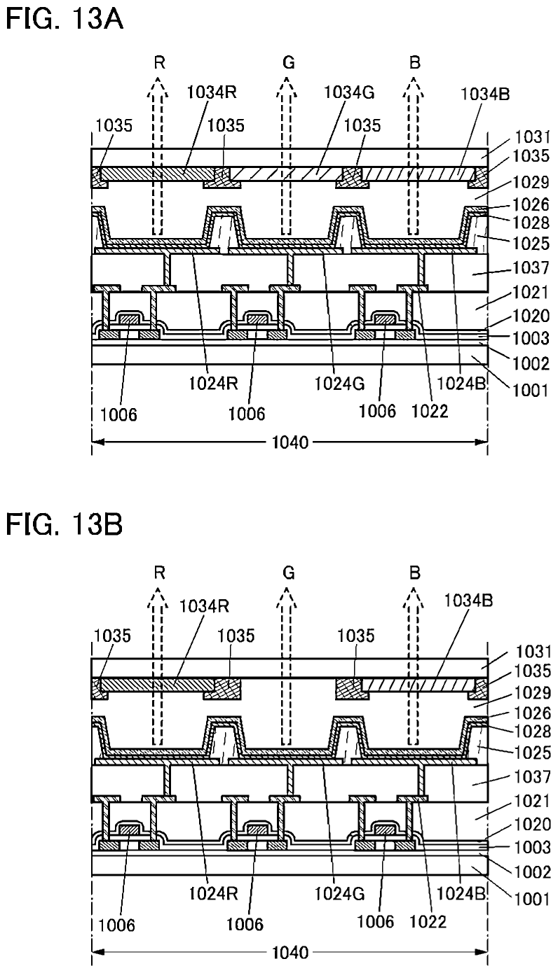

FIGS. 13A and 13B are each an example of a cross-sectional view of a display device having a top emission structure. Note that FIGS. 13A and 13B are each a cross-sectional view illustrating the display device of one embodiment of the present invention, and the driver circuit portion 1041, the peripheral portion 1042, and the like, which are illustrated in FIGS. 11A and 11B and FIG. 12, are not illustrated therein.

In this case, a substrate which does not transmit light can be used as the substrate 1001. The process up to the step of forming a connection electrode which connects the transistor and the cathode of the light-emitting element is performed in a manner similar to that of the display device having a bottom-emission structure. Then, a third interlayer insulating film 1037 is formed to cover an electrode 1022. This insulating film may have a planarization function. The third interlayer insulating film 1037 can be formed using a material similar to that of the second interlayer insulating film, or can be formed using any other various materials.

The lower electrodes 1024R, 1024G, and 1024B of the light-emitting elements each function as a cathode here, but may function as an anode. In the case of a display device having a top-emission structure as illustrated in FIGS. 13A and 13B, the lower electrodes 1024R, 1024G, and 1024B preferably have a function of reflecting light. The upper electrode 1026 is provided over the EL layer 1028. It is preferable that the upper electrode 1026 have a function of reflecting light and a function of transmitting light and that a microcavity structure be used between the upper electrode 1026 and the lower electrodes 1024R, 1024G, and 1024B, in which case the intensity of light having a specific wavelength is increased.

In the case of such a top-emission structure as is illustrated in FIG. 13A, sealing can be performed with the sealing substrate 1031 on which the coloring layers (the red coloring layer 1034R, the green coloring layer 1034G, and the blue coloring layer 1034B) are provided. The sealing substrate 1031 may be provided with the light-blocking layer 1035 which is positioned between pixels. Note that a light-transmitting substrate is favorably used as the sealing substrate 1031.

FIG. 13A illustrates the structure provided with the light-emitting elements and the coloring layers for the light-emitting elements as an example; however, the structure is not limited thereto. For example, as shown in FIG. 13B, a structure including the red coloring layer 1034R and the blue coloring layer 1034B but not including a green coloring layer may be employed to achieve full color display with the three colors of red, green, and blue. The structure where the light-emitting elements are provided with the coloring layers as illustrated in FIG. 13A is effective to suppress reflection of external light. In contrast, the structure where the light-emitting elements are provided with the red coloring layer and the blue coloring layer and without the green coloring layer as illustrated in FIG. 13B is effective to reduce power consumption because of small energy loss of light emitted from the green light-emitting element.

### <Structural Example 4 of Display Device>

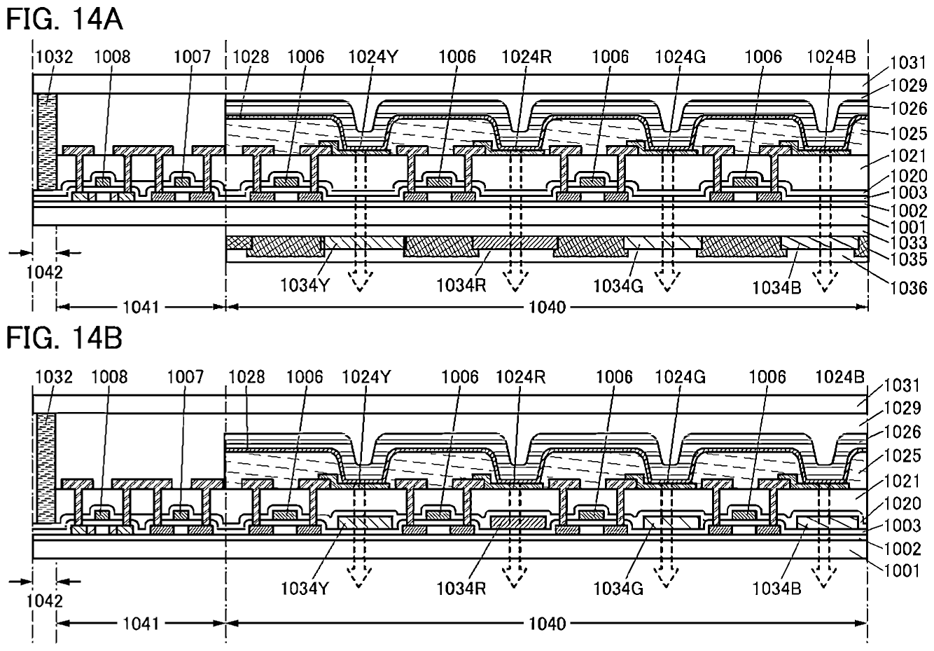

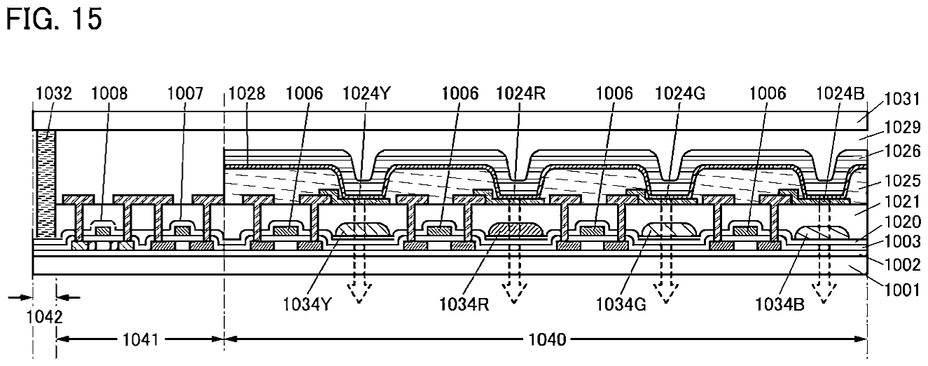

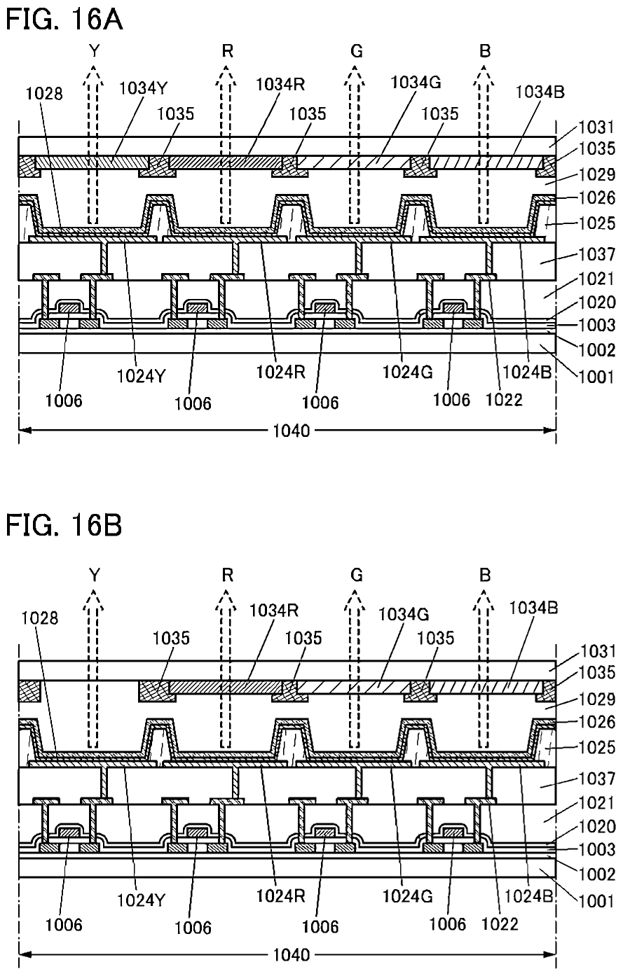

Although a display device including sub-pixels of three colors (red, green, and blue) is described above, the number of colors of sub-pixels may be four (red, green, blue, and yellow, or red, green, blue, and white). FIGS. 14A to 16B illustrate the structures of display devices each including the lower electrodes 1024R, 1024G, 1024B, and 1024Y FIGS. 14A and 14B and FIG. 15 each illustrate a display device having a structure in which light is extracted from the substrate 1001 side on which transistors are formed (bottom-emission structure), and FIGS. 16A and 16B each illustrate a display device having a structure in which light is extracted from the sealing substrate 1031 side (top-emission structure).

FIG. 14A illustrates an example of a display device in which optical elements (the coloring layer 1034R, the coloring layer 1034G, the coloring layer 1034B, and a coloring layer 1034Y) are provided on the transparent base material 1033. FIG. 14B illustrates an example of a display device in which optical elements (the coloring layer 1034R, the coloring layer 1034G, the coloring layer 1034B, and the coloring layer 1034Y) are provided between the gate insulating film 1003 and the first interlayer insulating film 1020. FIG. 15 illustrates an example of a display device in which optical elements (the coloring layer 1034R, the coloring layer 1034G, the coloring layer 1034B, and the coloring layer 1034Y) are provided between the first interlayer insulating film 1020 and the second interlayer insulating film 1021.

The coloring layer 1034R transmits red light, the coloring layer 1034G transmits green light, and the coloring layer 1034B transmits blue light. The coloring layer 1034Y transmits yellow light or transmits light of a plurality of colors selected from blue, green, yellow, and red. When the coloring layer 1034Y can transmit light of a plurality of colors selected from blue, green, yellow, and red, light having passed through the coloring layer 1034Y may be white light. Since the light-emitting element which transmits yellow or white light has high emission efficiency, the display device including the coloring layer 1034Y can have lower power consumption.

In the top-emission display devices illustrated in FIGS. 16A and 16B, a light-emitting element including the lower electrode 1024Y preferably has a microcavity structure between the lower electrode 1024Y and the upper electrode 1026 as in the display device illustrated in FIG. 13A. In the display device illustrated in FIG. 16A, sealing can be performed with the sealing substrate 1031 on which the coloring layers (the red coloring layer 1034R, the green coloring layer 1034G, the blue coloring layer 1034B, and the yellow coloring layer 1034Y) are provided.

Light emitted through the microcavity and the yellow coloring layer 1034Y has an emission spectrum in a yellow region. Since yellow is a color with a high luminosity factor, a light-emitting element that emits yellow light has high emission efficiency. Therefore, the display device having the structure of FIG. 16A can reduce power consumption.

FIG. 16A illustrates the structure provided with the light-emitting elements and the coloring layers for the light-emitting elements as an example; however, the structure is not limited thereto. For example, a structure including the red coloring layer 1034R, the green coloring layer 1034G, and the blue coloring layer 1034B but not including a yellow coloring layer as shown in FIG. 16B may be employed to achieve full color display with the four colors of red, green, blue, and yellow or of red, green, blue, and white. The structure where the light-emitting elements are provided with the coloring layers as illustrated in FIG. 16A is effective to suppress reflection of external light. In contrast, the structure where the light-emitting elements are provided with the red coloring layer, the green coloring layer, and the blue coloring layer and without the yellow coloring layer as illustrated in FIG. 16B is effective to reduce power consumption because of small energy loss of light emitted from the yellow or white light-emitting element.

### <Structural Example 5 of Display Device>

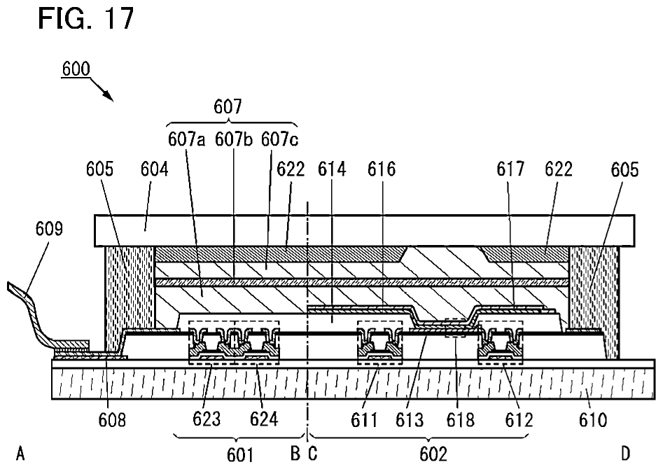

Next, a display device of another embodiment of the present invention will be described with reference to FIG. 17. FIG. 17 is a cross-sectional view taken along the dashed-dotted line A-B and the dashed-dotted line C-D in FIG. 10A. Note that in FIG. 17, portions having functions similar to those of portions in FIG. 10B are given the same reference numerals as those in FIG. 10B, and a detailed description of the portions is omitted.

The display device 600 in FIG. 17 includes a sealing layer 607a, a sealing layer 607b, and a sealing layer 607c in a region 607 surrounded by the element substrate 610, the sealing substrate 604, and the sealant 605. For one or more of the sealing layer 607a, the sealing layer 607b, and the sealing layer 607c, a resin such as a polyvinyl chloride (PVC) based resin, an acrylic-based resin, a polyimide-based resin, an epoxy-based resin, a silicone-based resin, a polyvinyl butyral (PVB) based resin, or an ethylene vinyl acetate (EVA) based resin can be used. Alternatively, an inorganic material such as silicon oxide, silicon oxynitride, silicon nitride oxide, silicon nitride, aluminum oxide, or aluminum nitride can be used. The formation of the sealing layers 607a, 607b, and 607c can prevent deterioration of the light-emitting element 618 due to impurities such as water, which is preferable. In the case where the sealing layers 607a, 607b, and 607c are formed, the sealant 605 is not necessarily provided.

Alternatively, any one or two of the sealing layers 607a, 607b, and 607c may be provided or four or more sealing layers may be formed. When the sealing layer has a multilayer structure, the impurities such as water can be effectively prevented from entering the light-emitting element 618 which is inside the display device from the outside of the display device 600. In the case where the sealing layer has a multilayer structure, a resin and an inorganic material are preferably stacked.

### <Structural Example 6 of Display Device>

Although the display devices in the structural examples 1 to 4 in this embodiment each have a structure including optical elements, one embodiment of the present invention does not necessarily include an optical element.

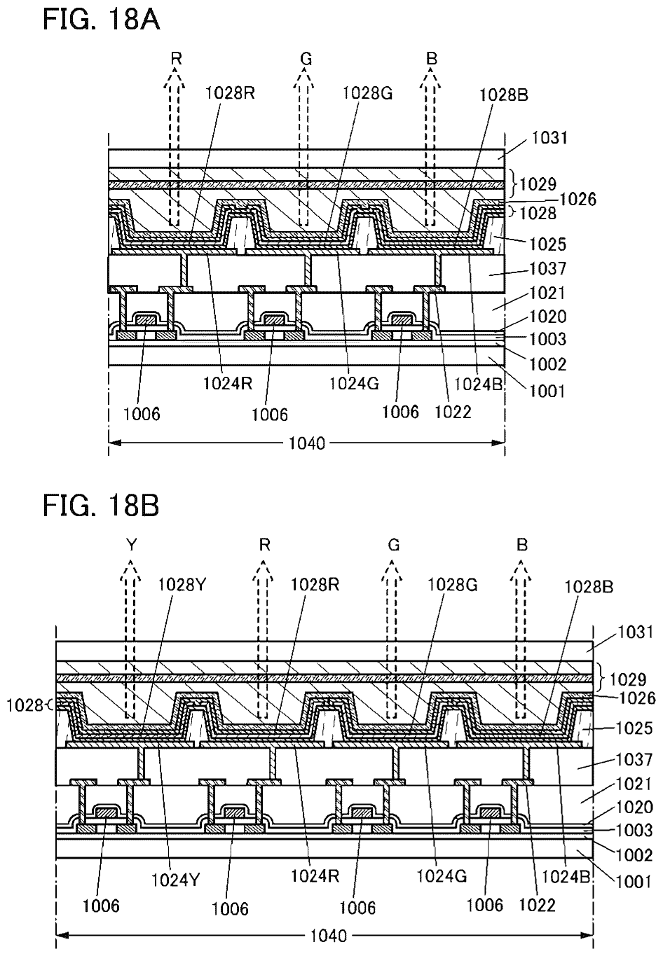

FIGS. 18A and 18B each illustrate a display device having a structure in which light is extracted from the sealing substrate 1031 side (a top-emission display device). FIG. 18A illustrates an example of a display device including a light-emitting layer 1028R, a light-emitting layer 1028G, and a light-emitting layer 1028B. FIG. 18B illustrates an example of a display device including a light-emitting layer 1028R, a light-emitting layer 1028G, a light-emitting layer 1028B, and a light-emitting layer 1028Y

The light-emitting layer 1028R has a function of exhibiting red light, the light-emitting layer 1028G has a function of exhibiting green light, and the light-emitting layer 1028B has a function of exhibiting blue light. The light-emitting layer 1028Y has a function of exhibiting yellow light or a function of exhibiting light of a plurality of colors selected from blue, green, and red. The light-emitting layer 1028Y may exhibit white light. Since the light-emitting element which exhibits yellow or white light has high light emission efficiency, the display device including the light-emitting layer 1028Y can have lower power consumption.

Each of the display devices in FIGS. 18A and 18B does not necessarily include coloring layers serving as optical elements because EL layers exhibiting light of different colors are included in sub-pixels.

For the sealing layer 1029, a resin such as a polyvinyl chloride (PVC) based resin, an acrylic-based resin, a polyimide-based resin, an epoxy-based resin, a silicone-based resin, a polyvinyl butyral (PVB) based resin, or an ethylene vinyl acetate (EVA) based resin can be used. Alternatively, an inorganic material such as silicon oxide, silicon oxynitride, silicon nitride oxide, silicon nitride, aluminum oxide, or aluminum nitride can be used. The formation of the sealing layer 1029 can prevent deterioration of the light-emitting element due to impurities such as water, which is preferable.

Alternatively, the sealing layer 1029 may have a single-layer or two-layer structure, or four or more sealing layers may be formed as the sealing layer 1029. When the sealing layer has a multilayer structure, the impurities such as water can be effectively prevented from entering the inside of the display device from the outside of the display device. In the case where the sealing layer has a multilayer structure, a resin and an inorganic material are preferably stacked.

Note that the sealing substrate 1031 has a function of protecting the light-emitting element. Thus, for the sealing substrate 1031, a flexible substrate or a film can be used.

The structures described in this embodiment can be combined as appropriate with any of the other structures in this embodiment and the other embodiments and the example.

### Embodiment 5

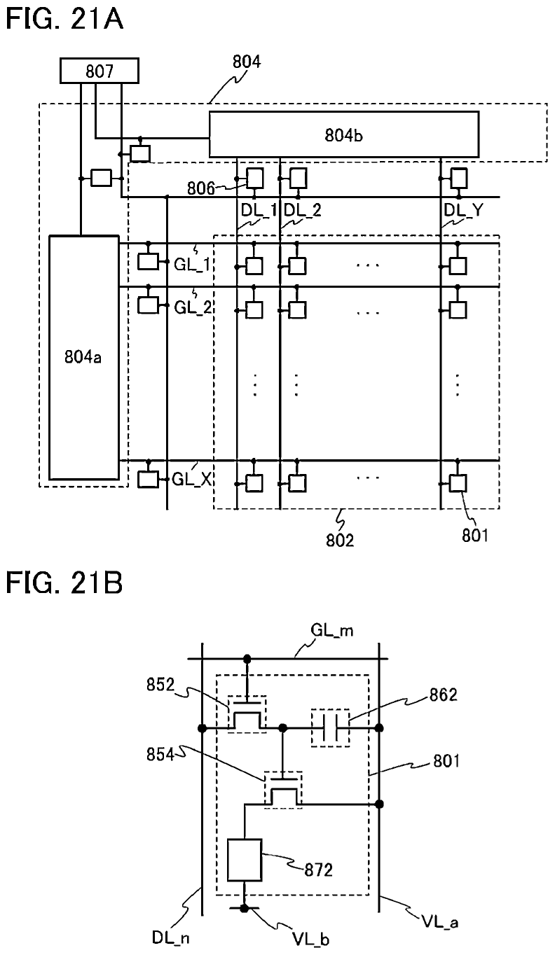

In this embodiment, a display device including the light-emitting device of one embodiment of the present invention will be described with reference to FIGS. 21A and 21B.

FIG. 21 Ais a block diagram illustrating the display device of one embodiment of the present invention, and FIG. 21B is a circuit diagram illustrating a pixel circuit of the display device of one embodiment of the present invention.

### <Display Device>

The display device illustrated in FIG. 21A includes a region including display elements in pixels (hereinafter referred to as a pixel portion 802), a circuit portion (hereinafter referred to as a driver circuit portion 804) and including a circuit for driving the pixels, circuits each having a function of protecting elements (hereinafter referred to as protection circuits 806), and a terminal portion 807. Note that the protection circuits 806 are not necessarily provided.

A part or the whole of the driver circuit portion 804 is preferably formed over a substrate over which the pixel portion 802 is formed. Thus, the number of components and the number of terminals can be reduced. When a part or the whole of the driver circuit portion 804 is not formed over the substrate over which the pixel portion 802 is formed, the part or the whole of the driver circuit portion 804 can be mounted by COG or tape automated bonding (TAB).

The pixel portion 802 includes circuits for driving the plurality of display elements in X(X is a natural number of 2 or more) rows and Y columns (Yis a natural number of 2 or more) (hereinafter, such circuits are referred to as pixel circuits 801). The driver circuit portion 804 includes driver circuits such as a circuit for outputting a signal (scan signal) to select a pixel (hereinafter the circuit is referred to as a scan line driver circuit 804a) and a circuit for supplying a signal (data signal) to drive a display element in a pixel (hereinafter, the circuit is referred to as a signal line driver circuit 804b).

The scan line driver circuit 804a includes a shift register or the like. The scan line driver circuit 804a receives a signal for driving the shift register through the terminal portion 807 and outputs a signal. For example, the scan line driver circuit 804a receives a start pulse signal, a clock signal, or the like and outputs a pulse signal. The scan line driver circuit 804a has a function of controlling the potentials of wirings supplied with scan signals (hereinafter, such wirings are referred to as scan lines GL_1 to GL_X). Note that the plurality of scan line driver circuits 804a may be provided to separately control the scan lines GL_1 to GL_X. Alternatively, the scan line driver circuit 804a has, but is not limited to, a function of supplying an initialization signal. The scan line driver circuit 804a may supply another signal.

The signal line driver circuit 804b includes a shift register or the like. The signal line driver circuit 804b receives a signal (image signal) from which a data signal is derived, as well as a signal for driving the shift register, through the terminal portion 807. The signal line driver circuit 804b has a function of generating a data signal to be written in the pixel circuits 801 based on the image signal. In addition, the signal line driver circuit 804b has a function of controlling output of a data signal in response to a pulse signal produced by input of a start pulse, a clock signal, or the like. Furthermore, the signal line driver circuit 804b has a function of controlling the potentials of wirings supplied with data signals (hereinafter such wirings are referred to as data lines DL_1 to DL_Y). Alternatively, the signal line driver circuit 804b has, but is not limited to, a function of supplying an initialization signal. The signal line driver circuit 804b may supply another signal.

Alternatively, the signal line driver circuit 804b is formed using a plurality of analog switches or the like, for example. The signal line driver circuit 804b can output signals obtained by time-dividing an image signal as the data signals by sequentially turning on the plurality of analog switches. The signal line driver circuit 804b may be formed using a shift register or the like.

A pulse signal and a data signal are input to each of the plurality of the pixel circuits 801 through one of the plurality of scan lines GL supplied with scan signals and one of the plurality of data lines DL supplied with data signals, respectively. Writing and holding of the data signal in each of the plurality of pixel circuits 801 are performed by the scan line driver circuit 804a. For example, to the pixel circuit 801 in the m-th row and the n-th column (m is a natural number of less than or equal to X, and n is a natural number of less than or equal to Y), a pulse signal is input from the scan line driver circuit 804a through the scan line GL_m, and a data signal is input from the signal line driver circuit 804b through the data line DL_n in accordance with the potential of the scan line GL_m.

The protection circuit 806 illustrated in FIG. 21A is connected to the scan line GL making a connection between the scan line driver circuit 804a and the pixel circuit 801. Alternatively, the protection circuit 806 is connected to a data line DL making a connection between the signal line driver circuit 804b and the pixel circuit 801. Alternatively, the protection circuit 806 can be connected to a wiring making a connection between the scan line driver circuit 804a and the terminal portion 807. Alternatively, the protection circuit 806 can be connected to a wiring making a connection between the signal line driver circuit 804b and the terminal portion 807. Note that the terminal portion 807 means a portion having terminals for inputting power, control signals, and image signals to the display device from external circuits.

The protection circuit 806 is a circuit which electrically connects a wiring connected to the protection circuit to another wiring when a potential out of a certain range is supplied to the wiring connected to the protection circuit.

As illustrated in FIG. 21A, the protection circuits 806 are connected to the pixel portion 802 and the driver circuit portion 804, so that the resistance of the display device to overcurrent generated by electrostatic discharge (ESD) or the like can be improved. Note that the configuration of the protection circuits 806 is not limited thereto, and for example, a configuration in which the protection circuits 806 are connected to the scan line driver circuit 804a or a configuration in which the protection circuits 806 are connected to the signal line driver circuit 804b may be employed. Alternatively, a configuration in which the terminal portion 807 is connected to the protection circuit 806 may be employed.

Although FIG. 21A illustrates an example in which the driver circuit portion 804 includes the scan line driver circuit 804a and the signal line driver circuit 804b, the structure is not limited thereto. For example, only the scan line driver circuit 804a may be formed and a separately prepared substrate where a signal line driver circuit is formed (e.g., a driver circuit substrate formed with a single crystal semiconductor film or a polycrystalline semiconductor film) may be mounted.

### <Structural Example of Pixel Circuit>

Each of the plurality of pixel circuits 801 in FIG. 21A can have a structure illustrated in FIG. 21B, for example.

The pixel circuit 801 illustrated in FIG. 21B includes a transistor 852, a transistor 854, a capacitor 862, and a light-emitting element 872.

One of a source electrode and a drain electrode of the transistor 852 is electrically connected to a wiring to which a data signal is supplied (a data line DL_n). A gate electrode of the transistor 852 is electrically connected to a wiring to which a gate signal is supplied (a scan line GL_m).

The transistor 852 has a function of controlling whether to write a data signal.

One of a pair of electrodes of the capacitor 862 is electrically connected to a wiring to which a potential is supplied (hereinafter referred to as a potential supply line VL_a), and the other is electrically connected to the other of the source electrode and the drain electrode of the transistor 852.

The capacitor 862 functions as a storage capacitor for storing written data.

One of a source electrode and a drain electrode of the transistor 854 is electrically connected to the potential supply line VL_a. Furthermore, a gate electrode of the transistor 854 is electrically connected to the other of the source electrode and the drain electrode of the transistor 852.

One of an anode and a cathode of the light-emitting element 872 is electrically connected to a potential supply line VL_b, and the other is electrically connected to the other of the source electrode and the drain electrode of the transistor 854.

As the light-emitting element 872, any of the light-emitting elements described in Embodiments 1 to 3 can be used.

Note that a high power supply potential VDD is supplied to one of the potential supply line VL_a and the potential supply line VL_b, and a low power supply potential VSS is supplied to the other.

In the display device including the pixel circuits 801 in FIG. 21B, the pixel circuits 801 are sequentially selected row by row by the scan line driver circuit 804a in FIG. 21A, for example, whereby the transistors 852 are turned on and a data signal is written.

When the transistors 852 are turned off, the pixel circuits 801 in which the data has been written are brought into a holding state. Furthermore, the amount of current flowing between the source electrode and the drain electrode of the transistor 854 is controlled in accordance with the potential of the written data signal. The light-emitting element 872 emits light with a luminance corresponding to the amount of flowing current. This operation is sequentially performed row by row; thus, an image is displayed.

Alternatively, the pixel circuit can have a function of compensating variation in threshold voltages or the like of a transistor.

A light-emitting element of one embodiment of the present invention can be used for an active matrix method in which an active element is included in a pixel of a display device or a passive matrix method in which an active element is not included in a pixel of a display device.

In an active matrix method, as an active element (a non-linear element), not only a transistor but also various active elements (non-linear elements) can be used. For example, a metal insulator metal (MIM), a thin film diode (TFD), or the like can also be used. Since such an element has few numbers of manufacturing steps, manufacturing cost can be reduced or yield can be improved. Alternatively, since the size of the element is small, the aperture ratio can be improved, so that power consumption can be reduced or higher luminance can be achieved.

As a method other than the active matrix method, the passive matrix method in which an active element (a non-linear element) is not used can also be used. Since an active element (a non-linear element) is not used, the number of manufacturing steps is small, so that manufacturing cost can be reduced or yield can be improved. Alternatively, since an active element (a non-linear element) is not used, the aperture ratio can be improved, so that power consumption can be reduced or higher luminance can be achieved, for example.

The structure described in this embodiment can be used in appropriate combination with the structure described in any of the other embodiments and the example.

### Embodiment 6

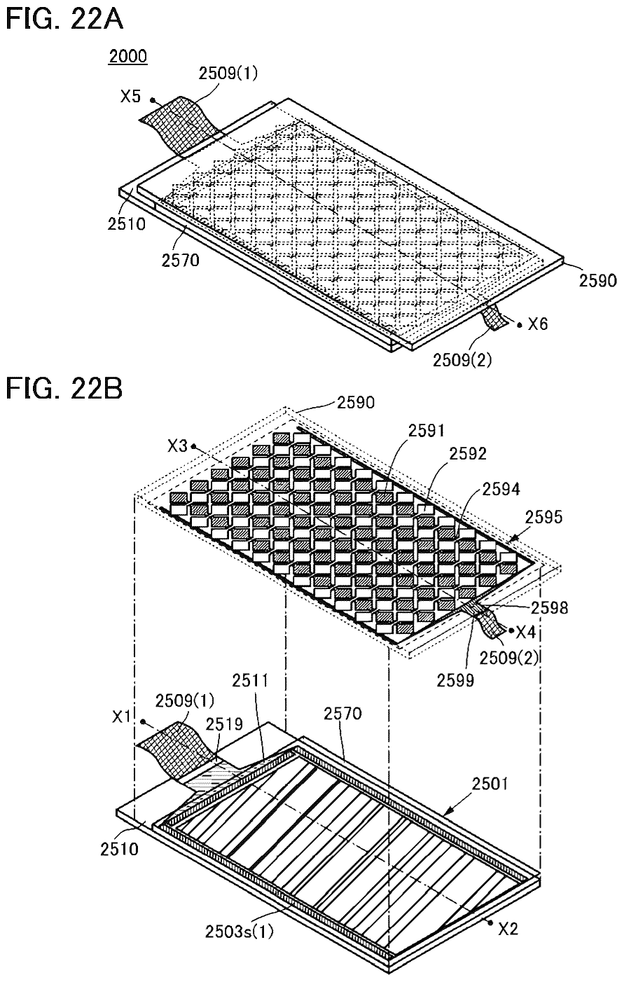

In this embodiment, a display device including the light-emitting element of one embodiment of the present invention and an electronic device in which the display device is provided with an input device will be described with reference to FIGS. 22A to 26.

### <Description 1 of Touch Panel>

In this embodiment, a touch panel 2000 including a display device and an input device will be described as an example of an electronic device. In addition, an example in which a touch sensor is included as an input device will be described.

FIGS. 22A and 22B are perspective views of the touch panel 2000. Note that FIGS. 22A and 22B illustrate only main components of the touch panel 2000, for simplicity.

The touch panel 2000 includes a display device 2501 and a touch sensor 2595 (see FIG. 22B). Furthermore, the touch panel 2000 includes a substrate 2510, a substrate 2570, and a substrate 2590. Note that the substrate 2510, the substrate 2570, and the substrate 2590 each have flexibility. Note that one or all of the substrates 2510, 2570, and 2590 may be inflexible.

The display device 2501 includes a plurality of pixels over the substrate 2510 and a plurality of wirings 2511 through which signals are supplied to the pixels. The plurality of wirings 2511 is led to a peripheral portion of the substrate 2510, and part of the plurality of wirings 2511 forms a terminal 2519. The terminal 2519 is electrically connected to an FPC 2509(1). The plurality of wirings 2511 can supply signals from a signal line driver circuit 2503s(1) to the plurality of pixels.

The substrate 2590 includes the touch sensor 2595 and a plurality of wirings 2598 electrically connected to the touch sensor 2595. The plurality of wirings 2598 is led to a peripheral portion of the substrate 2590, and part of the plurality of wirings 2598 forms a terminal. The terminal is electrically connected to an FPC 2509(2). Note that in FIG. 22B, electrodes, wirings, and the like of the touch sensor 2595 provided on the back side of the substrate 2590 (the side facing the substrate 2510) are indicated by solid lines for clarity.

As the touch sensor 2595, a capacitive touch sensor can be used, for example. Examples of the capacitive touch sensor include a surface capacitive touch sensor and a projected capacitive touch sensor.

Examples of the projected capacitive touch sensor include a self capacitive touch sensor and a mutual capacitive touch sensor, which differ mainly in the driving method. The use of a mutual capacitive type is preferred because multiple points can be sensed simultaneously.

Note that the touch sensor 2595 illustrated in FIG. 22B is an example of using a projected capacitive touch sensor.

Note that a variety of sensors that can sense the proximity or touch of a sensing target such as a finger can be used as the touch sensor 2595.

The projected capacitive touch sensor 2595 includes electrodes 2591 and electrodes 2592. The electrodes 2591 are electrically connected to any of the plurality of wirings 2598, and the electrodes 2592 are electrically connected to any of the other wirings 2598.

The electrodes 2592 each have a shape of a plurality of quadrangles arranged in one direction with one corner of a quadrangle connected to one corner of another quadrangle as illustrated in FIGS. 22A and 22B.

The electrodes 2591 each have a quadrangular shape and are arranged in the direction intersecting with the direction in which the electrodes 2592 extend.

A wiring 2594 electrically connects two electrodes 2591 between which the electrode 2592 is positioned. The intersecting area of the electrode 2592 and the wiring 2594 is preferably as small as possible. Such a structure allows a reduction in the area of a region where the electrodes are not provided, reducing unevenness in transmittance. As a result, unevenness in luminance of light transmitted through the touch sensor 2595 can be reduced.

Note that the shapes of the electrodes 2591 and the electrodes 2592 are not limited to the above-mentioned shapes and can be any of a variety of shapes. For example, the plurality of electrodes 2591 may be provided so that space between the electrodes 2591 are reduced as much as possible, and a plurality of electrodes 2592 may be provided with an insulating layer sandwiched between the electrodes 2591 and the electrodes 2592 and may be spaced apart from each other to form a region not overlapping with the electrodes 2591. In that case, between two adjacent electrodes 2592, a dummy electrode which is electrically insulated from these electrodes is preferably provided, whereby the area of a region having a different transmittance can be reduced.

### <Description of Display Device>

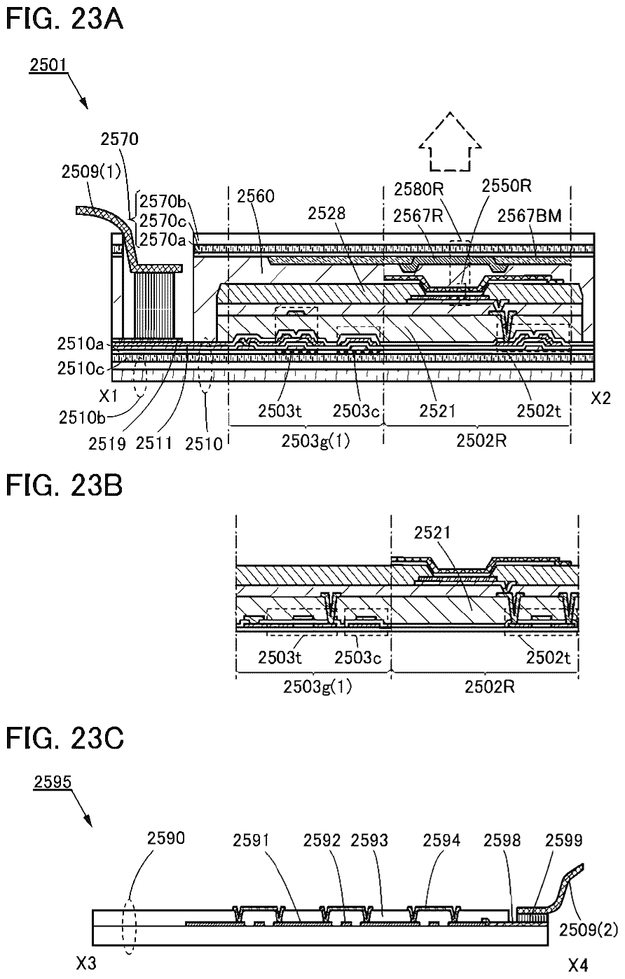

Next, the display device 2501 will be described in detail with reference to FIG. 23A. FIG. 23A corresponds to a cross-sectional view taken along dashed-dotted line X1-X2 in FIG. 22B.

The display device 2501 includes a plurality of pixels arranged in a matrix. Each of the pixels includes a display element and a pixel circuit for driving the display element.

In the following description, an example of using a light-emitting element that emits white light as a display element will be described; however, the display element is not limited to such an element. For example, light-emitting elements that emit light of different colors may be included so that the light of different colors can be emitted from adjacent pixels.

For the substrate 2510 and the substrate 2570, for example, a flexible material with a vapor permeability lower than or equal to 1×10⁻⁵ g·m⁻²·day⁻¹, preferably lower than or equal to 1×10⁻⁶ g·m⁻² day⁻¹ can be favorably used. Note that materials whose thermal expansion coefficients are substantially equal to each other are preferably used for the substrate 2510 and the substrate 2570. For example, the coefficient of linear expansion of the materials are preferably lower than or equal to 1×10⁻³/K, more preferably lower than or equal to 5×10⁻⁵/K, and still more preferably lower than or equal to 1×10⁻⁵/K.

Note that the substrate 2510 is a stacked body including an insulating layer 2510a for preventing impurity diffusion into the light-emitting element, a flexible substrate 2510b, and an adhesive layer 2510c for attaching the insulating layer 2510a and the flexible substrate 2510b to each other. The substrate 2570 is a stacked body including an insulating layer 2570a for preventing impurity diffusion into the light-emitting element, a flexible substrate 2570b, and an adhesive layer 2570c for attaching the insulating layer 2570a and the flexible substrate 2570b to each other.

For the adhesive layer 2510c and the adhesive layer 2570c, for example, polyester, polyolefin, polyamide (e.g., nylon, aramid), polyimide, polycarbonate, or an acrylic resin, polyurethane, or an epoxy resin can be used. Alternatively, a material that includes a resin having a siloxane bond, such as silicone, can be used.

A sealing layer 2560 is provided between the substrate 2510 and the substrate 2570. A sealing layer 2560 preferably has a higher refractive index than the air. In the case where light is extracted to the sealing layer 2560 side as illustrated in FIG. 23A, the sealing layer 2560 can also serve as an optical adhesive layer.

A sealant may be formed in the peripheral portion of the sealing layer 2560. With use of the sealant, a light-emitting element 2550R can be provided in a region surrounded by the substrate 2510, the substrate 2570, the sealing layer 2560, and the sealant. Note that an inert gas (such as nitrogen or argon) may be used instead of the sealing layer 2560. A drying agent may be provided in the inert gas so as to adsorb moisture or the like. A resin such as an acrylic resin or an epoxy resin may be used. For example, an epoxy-based resin or a glass frit is preferably used as the sealant. As a material used for the sealant, a material which is impermeable to moisture or oxygen is preferably used.

The display device 2501 includes a pixel 2502R. The pixel 2502R includes a light-emitting module 2580R.

The pixel 2502R includes a light-emitting element 2550R and a transistor 2502t that can supply power to the light-emitting element 2550R. Note that the transistor 2502t functions as part of the pixel circuit. The light-emitting module 2580R includes the light-emitting element 2550R and a coloring layer 2567R.

The light-emitting element 2550R includes a lower electrode, an upper electrode, and an EL layer between the lower electrode and the upper electrode. As the light-emitting element 2550R, any of the light-emitting elements described in Embodiments 1 to 3 can be used, for example.

A microcavity structure may be employed between the lower electrode and the upper electrode so as to increase the intensity of light having a specific wavelength.

In the case where the sealing layer 2560 is provided on the light extraction side, the sealing layer 2560 is in contact with the light-emitting element 2550R and the coloring layer 2567R.

The coloring layer 2567R overlaps with the light-emitting element 2550R. Accordingly, part of light emitted from the light-emitting element 2550R passes through the coloring layer 2567R and is emitted to the outside of the light-emitting module 2580R as indicated by an arrow in FIG. 23A.

The display device 2501 includes a light-blocking layer 2567BM on the light extraction side. The light-blocking layer 2567BM is provided so as to surround the coloring layer 2567R.

The coloring layer 2567R is a coloring layer having a function of transmitting light in a particular wavelength region. For example, a color filter for transmitting light in a red wavelength region, a color filter for transmitting light in a green wavelength region, a color filter for transmitting light in a blue wavelength region, a color filter for transmitting light in a yellow wavelength region, or the like can be used. Each color filter can be formed with any of various materials by a printing method, an inkjet method, an etching method using a photolithography technique, or the like.

An insulating layer 2521 is provided in the display device 2501. The insulating layer 2521 covers the transistor 2502t. With the insulating layer 2521, unevenness caused by the pixel circuit is reduced. The insulating layer 2521 may serve also as a layer for preventing diffusion of impurities. This can prevent a reduction in the reliability of the transistor 2502t or the like due to diffusion of impurities.

The light-emitting element 2550R is formed above the insulating layer 2521. A partition 2528 is provided so as to overlap with end portions of the lower electrode in the light-emitting element 2550R. Note that a spacer for controlling the distance between the substrate 2510 and the substrate 2570 may be provided over the partition 2528.

A scan line driver circuit 2503g(1) includes a transistor 2503t and a capacitor 2503c. Note that the driver circuit can be formed in the same process and over the same substrate as those of the pixel circuits.

Over the substrate 2510, the wirings 2511 through which a signal can be supplied are provided. Over the wirings 2511, the terminal 2519 is provided. The FPC 2509(1) is electrically connected to the terminal 2519. The FPC 2509(1) has a function of supplying a video signal, a clock signal, a start signal, a reset signal, or the like. Note that a printed wiring board (PWB) may be attached to the FPC 2509(1).

In the display device 2501, transistors with any of a variety of structures can be used. FIG. 23A illustrates an example of using bottom-gate transistors; however, the present invention is not limited to this example, and top-gate transistors may be used in the display device 2501 as illustrated in FIG. 23B.

In addition, there is no particular limitation on the polarity of the transistor 2502t and the transistor 2503t. For these transistors, n-channel and p-channel transistors may be used, or either n-channel transistors or p-channel transistors may be used, for example. Furthermore, there is no particular limitation on the crystallinity of a semiconductor film used for the transistors 2502t and 2503t. For example, an amorphous semiconductor film or a crystalline semiconductor film can be used. Examples of semiconductor materials include Group 14 semiconductors (e.g., a semiconductor including silicon), compound semiconductors (including oxide semiconductors), organic semiconductors, and the like. An oxide semiconductor that has an energy gap of 2 eV or more, preferably 2.5 eV or more, more preferably 3 eV or more is preferably used for one of the transistors 2502t and 2503t or both, so that the off-state current of the transistors can be reduced. Examples of the oxide semiconductors include an In—Ga oxide, an In-M-Zn oxide (M represents Al, Ga, Y, Zr, La, Ce, Sn, Hf, or Nd), and the like.

### <Touch Sensor>

Next, the touch sensor 2595 will be described in detail with reference to FIG. 23C. FIG. 23C corresponds to a cross-sectional view taken along dashed-dotted line X3-X4 in FIG. 22B.

The touch sensor 2595 includes the electrodes 2591 and the electrodes 2592 provided in a staggered arrangement on the substrate 2590, an insulating layer 2593 covering the electrodes 2591 and the electrodes 2592, and the wiring 2594 that electrically connects the adjacent electrodes 2591 to each other.

The electrodes 2591 and the electrodes 2592 are formed using a light-transmitting conductive material. As a light-transmitting conductive material, a conductive oxide such as indium oxide, indium tin oxide, indium zinc oxide, zinc oxide, or zinc oxide to which gallium is added can be used. Note that a film including graphene can be used as well. The film including graphene can be formed, for example, by reducing a film containing graphene oxide. As a reducing method, a method with application of heat or the like can be employed.

The electrodes 2591 and the electrodes 2592 may be formed by, for example, depositing a light-transmitting conductive material on the substrate 2590 by a sputtering method and then removing an unnecessary portion by any of various pattern forming techniques such as a photolithography method.

Examples of a material for the insulating layer 2593 are a resin such as an acrylic resin or an epoxy resin, a resin having a siloxane bond, such as silicon, and an inorganic insulating material such as silicon oxide, silicon oxynitride, or aluminum oxide.

Openings reaching the electrodes 2591 are formed in the insulating layer 2593, and the wiring 2594 electrically connects the adjacent electrodes 2591. A light-transmitting conductive material can be favorably used for the wiring 2594 because the aperture ratio of the touch panel can be increased. Moreover, a material having higher conductivity than the electrodes 2591 and 2592 can be favorably used for the wiring 2594 because electric resistance can be reduced.

One electrode 2592 extends in one direction, and a plurality of electrodes 2592 are provided in the form of stripes. The wiring 2594 intersects with the electrode 2592.

Adjacent electrodes 2591 are provided with one electrode 2592 provided therebetween. The wiring 2594 electrically connects the adjacent electrodes 2591.

Note that the plurality of electrodes 2591 are not necessarily arranged in the direction orthogonal to one electrode 2592 and may be arranged to intersect with one electrode 2592 at an angle of more than 0 degrees and less than 90 degrees.

One wiring 2598 is electrically connected to any of the electrodes 2591 and 2592. Part of the wiring 2598 functions as a terminal. For the wiring 2598, a metal material such as aluminum, gold, platinum, silver, nickel, titanium, tungsten, chromium, molybdenum, iron, cobalt, copper, or palladium or an alloy material containing any of these metal materials can be used.

Note that an insulating layer that covers the insulating layer 2593 and the wiring 2594 may be provided to protect the touch sensor 2595.

A connection layer 2599 electrically connects the wiring 2598 to the FPC 2509(2).

As the connection layer 2599, an anisotropic conductive film (ACF), an anisotropic conductive paste (ACP), or the like can be used.

### <Description 2 of Touch Panel>

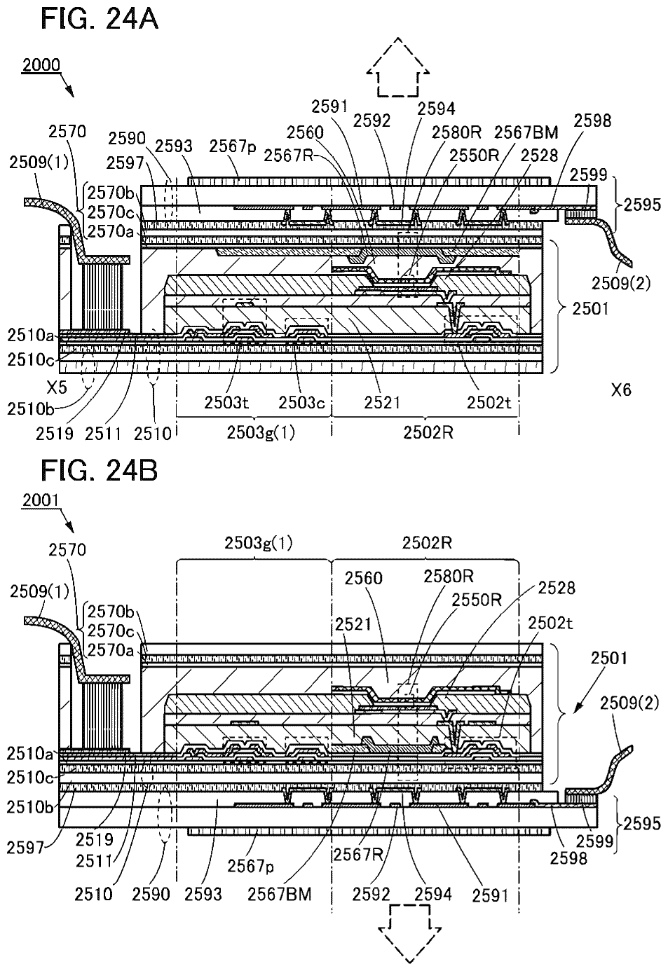

Next, the touch panel 2000 will be described in detail with reference to FIG. 24A. FIG. 24A corresponds to a cross-sectional view taken along dashed-dotted line X5-X6 in FIG. 22A.

In the touch panel 2000 illustrated in FIG. 24A, the display device 2501 described with reference to FIG. 23A and the touch sensor 2595 described with reference to FIG. 23C are attached to each other.

The touch panel 2000 illustrated in FIG. 24A includes an adhesive layer 2597 and an anti-reflective layer 2567p in addition to the components described with reference to FIGS. 23A and 23C.

The adhesive layer 2597 is provided in contact with the wiring 2594. Note that the adhesive layer 2597 attaches the substrate 2590 to the substrate 2570 so that the touch sensor 2595 overlaps with the display device 2501. The adhesive layer 2597 preferably has a light-transmitting property. A heat curable resin or an ultraviolet curable resin can be used for the adhesive layer 2597. For example, an acrylic resin, a urethane-based resin, an epoxy-based resin, or a siloxane-based resin can be used.

The anti-reflective layer 2567p is positioned in a region overlapping with pixels. As the anti-reflective layer 2567p, a circular polarizing plate can be used, for example.

Next, a touch panel having a structure different from that illustrated in FIG. 24A will be described with reference to FIG. 24B.

FIG. 24B is a cross-sectional view of a touch panel 2001. The touch panel 2001 illustrated in FIG. 24B differs from the touch panel 2000 illustrated in FIG. 24A in the position of the touch sensor 2595 relative to the display device 2501. Different structures will be described in detail below, and the above description of the touch panel 2000 can be referred to for the other similar structures.

The coloring layer 2567R overlaps with the light-emitting element 2550R. The light-emitting element 2550R illustrated in FIG. 24B emits light to the side where the transistor 2502t is provided. Accordingly, part of light emitted from the light-emitting element 2550R passes through the coloring layer 2567R and is emitted to the outside of the light-emitting module 2580R as indicated by an arrow in FIG. 24B.

The touch sensor 2595 is provided on the substrate 2510 side of the display device 2501.

The adhesive layer 2597 is provided between the substrate 2510 and the substrate 2590 and attaches the touch sensor 2595 to the display device 2501.

As illustrated in FIG. 24A or 24B, light may be emitted from the light-emitting element through one or both of the substrate 2510 and the substrate 2570.

<Method for Driving Touch Panel>

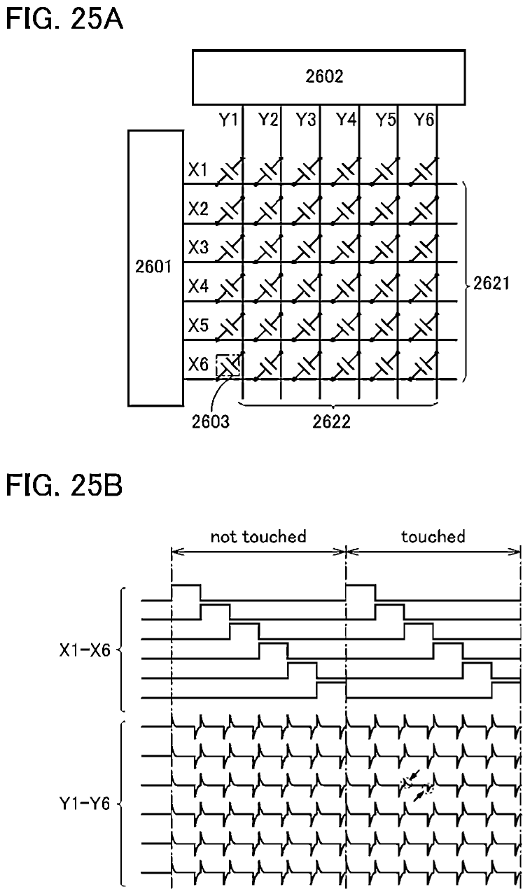

Next, an example of a method for driving a touch panel will be described with reference to FIGS. 25A and 25B.

FIG. 25A is a block diagram illustrating the structure of a mutual capacitive touch sensor. FIG. 25A illustrates a pulse voltage output circuit 2601 and a current sensing circuit 2602. Note that in FIG. 25A, six wirings X1 to X6 represent the electrodes 2621 to which a pulse voltage is applied, and six wirings Y1 to Y6 represent the electrodes 2622 that detect changes in current. FIG. 25A also illustrates capacitors 2603 that are each formed in a region where the electrodes 2621 and 2622 overlap with each other. Note that functional replacement between the electrodes 2621 and 2622 is possible.

The pulse voltage output circuit 2601 is a circuit for sequentially applying a pulse voltage to the wirings X1 to X6. By application of a pulse voltage to the wirings X1 to X6, an electric field is generated between the electrodes 2621 and 2622 of the capacitor 2603. When the electric field between the electrodes is shielded, for example, a change occurs in the capacitor 2603 (mutual capacitance). The approach or contact of a sensing target can be sensed by utilizing this change.

The current sensing circuit 2602 is a circuit for detecting changes in current flowing through the wirings Y1 to Y6 that are caused by the change in mutual capacitance in the capacitor 2603. No change in current value is sensed in the wirings Y1 to Y6 when there is no approach or contact of a sensing target, whereas a decrease in current value is sensed when mutual capacitance is decreased owing to the approach or contact of a sensing target. Note that an integrator circuit or the like is used for sensing of current.

FIG. 25B is a timing chart showing input and output waveforms in the mutual capacitive touch sensor illustrated in FIG. 25A. In FIG. 25B, sensing of a sensing target is performed in all the rows and columns in one frame period. FIG. 25B shows a period when a sensing target is not sensed (not touched) and a period when a sensing target is sensed (touched). In FIG. 25B, sensed current values of the wirings Y1 to Y6 are shown as the waveforms of voltage values.

A pulse voltage is sequentially applied to the wirings X1 to X6, and the waveforms of the wirings Y1 to Y6 change in accordance with the pulse voltage. When there is no approach or contact of a sensing target, the waveforms of the wirings Y1 to Y6 change uniformly in accordance with changes in the voltages of the wirings X1 to X6. The current value is decreased at the point of approach or contact of a sensing target and accordingly the waveform of the voltage value changes.

By sensing a change in mutual capacitance in this manner, the approach or contact of a sensing target can be sensed.

### <Sensor Circuit>

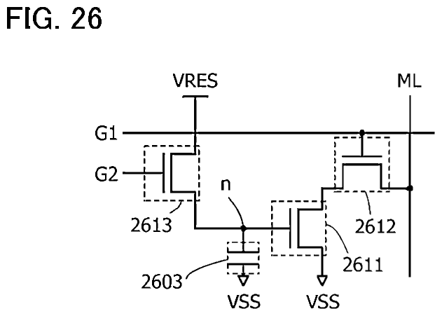

Although FIG. 25A illustrates a passive matrix type touch sensor in which only the capacitor 2603 is provided as a touch sensor at the intersection of wirings, an active matrix type touch sensor including a transistor and a capacitor may be used. FIG. 26 illustrates an example of a sensor circuit included in an active matrix type touch sensor.

The sensor circuit in FIG. 26 includes the capacitor 2603 and transistors 2611, 2612, and 2613.

A signal G2 is input to a gate of the transistor 2613. A voltage VRES is applied to one of a source and a drain of the transistor 2613, and one electrode of the capacitor 2603 and a gate of the transistor 2611 are electrically connected to the other of the source and the drain of the transistor 2613. One of a source and a drain of the transistor 2611 is electrically connected to one of a source and a drain of the transistor 2612, and a voltage VSS is applied to the other of the source and the drain of the transistor 2611. The signal G1 is input to a gate of the transistor 2612, and a wiring ML is electrically connected to the other of the source and the drain of the transistor 2612. The voltage VSS is applied to the other electrode of the capacitor 2603.

Next, the operation of the sensor circuit in FIG. 26 will be described. First, a potential for turning on the transistor 2613 is supplied as the signal G2, and a potential with respect to the voltage VRES is thus applied to the node n connected to the gate of the transistor 2611. Then, a potential for turning off the transistor 2613 is applied as the signal G2, whereby the potential of the node n is maintained.

Then, mutual capacitance of the capacitor 2603 changes owing to the approach or contact of a sensing target such as a finger, and accordingly the potential of the node n is changed from VRES.

In reading operation, a potential for turning on the transistor 2612 is supplied as the signal G1. A current flowing through the transistor 2611, that is, a current flowing through the wiring ML is changed in accordance with the potential of the node n. By sensing this current, the approach or contact of a sensing target can be sensed.

In each of the transistors 2611, 2612, and 2613, an oxide semiconductor layer is preferably used as a semiconductor layer in which a channel region is formed. In particular, such a transistor is preferably used as the transistor 2613 so that the potential of the node n can be held for a long time and the frequency of operation of resupplying VRES to the node n (refresh operation) can be reduced.

The structure described in this embodiment can be used in appropriate combination with the structure described in any of the other embodiments and the example.

### Embodiment 7

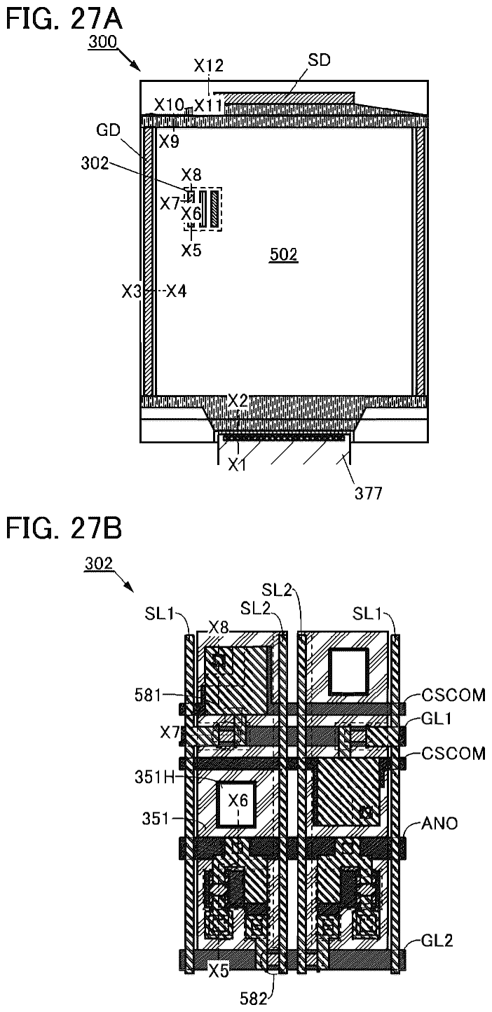

In this embodiment, a display device including the light-emitting element of one embodiment of the present invention and a reflective liquid crystal element, which can display images in both a transmissive mode and a reflective mode, will be described with reference to FIGS. 27A to 30B2.

FIG. 27A is a bottom view illustrating the structure of a display device 300 of one embodiment of the present invention. FIG. 27B is a bottom view illustrating part of FIG. 27A. Note that in FIG. 27B, some components are not illustrated in order to avoid complexity of the drawing.

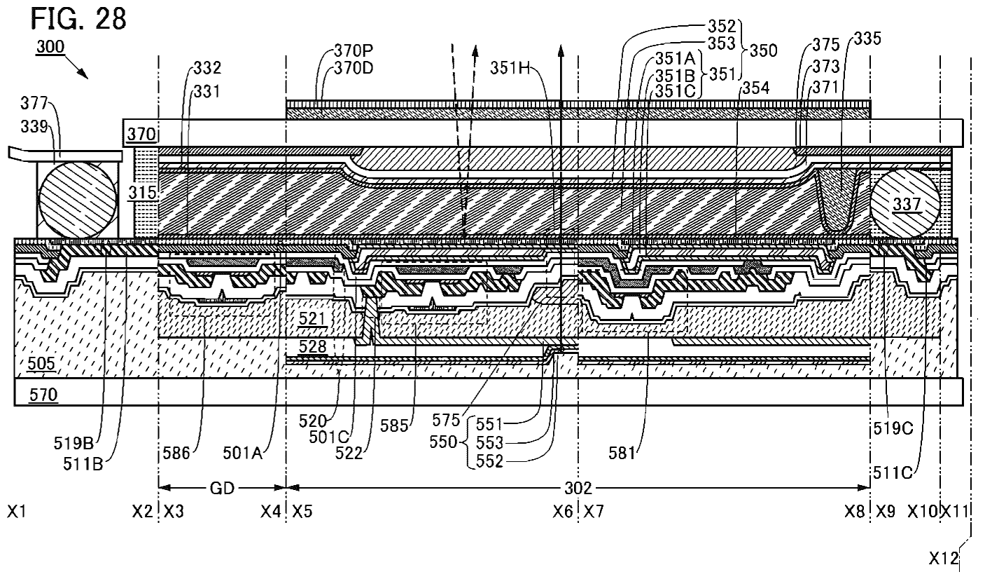

FIG. 28 is a cross-sectional view illustrating the structure of the display device 300 of one embodiment of the present invention. FIG. 28 is a cross-sectional view taken along dashed-dotted lines X1-X2, X3-X4, X5-X6, X7-X8, X9-X10, and X11-X12 in FIG. 27A.

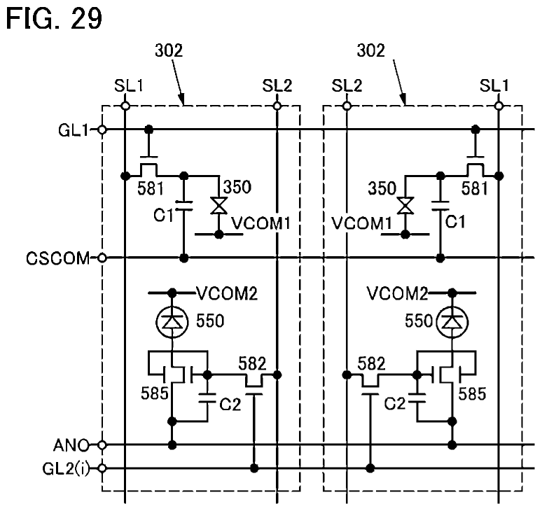

FIG. 29 illustrates a circuit of a pixel 302 included in the display device 300 of one embodiment of the present invention.

### <Structural Example of Display Device>

As illustrated in FIG. 27A, the display device 300 of one embodiment of the present invention includes a pixel portion 502, and a driver circuit GD and a driver circuit SD placed outside the pixel portion 502. The pixel portion 502 includes the pixel 302.

The pixel 302 includes a liquid crystal element 350 and a light-emitting element 550. In addition, the pixel 302 includes a transistor 581. Moreover, the pixel 302 includes a transistor 585 and a transistor 586 (see FIG. 28).

The liquid crystal element 350 and the light-emitting element 550 perform display in the same direction. For example, a dashed line arrow in FIG. 28 denotes the direction in which the liquid crystal element 350 performs display by controlling the intensity of external light reflection. A solid line arrow in FIG. 28 denotes the direction in which the light-emitting element 550 performs display.

The liquid crystal element 350 thus includes a reflective film 351B having a function of reflecting incident light and a liquid crystal layer 353 containing a material having a function of adjusting the intensity of the reflected light. The liquid crystal element 350 has a function of reflecting incident light and a function of adjusting the intensity of the reflected light.

A reflective liquid crystal element is preferably used as the liquid crystal element 350. Specifically, the liquid crystal element 350 preferably includes a liquid crystal layer 353, an electrode 351, and an electrode 352. The electrode 351 includes the reflective film 351B having a function of reflecting light. In addition, the liquid crystal layer 353 contains a liquid crystal material. Note that the electrode 352 is provided so that an electric field for controlling the alignment of the liquid crystal material is generated between the electrode 352 and the electrode 351. In addition, the liquid crystal layer 353 preferably has a function of adjusting the intensity of light which enters the liquid crystal element 350 and is reflected by the reflective film 351B.

The electrode 351 is electrically connected to the transistor 581. It is preferable that the electrode 351 have a structure in which a conductive film 351A and a conductive film 351C are provided such that the reflective film 351B is interposed therebetween. Interposing the reflective film 351B between the conductive films 351A and 351C suppresses diffusion of an element contained in the reflective film 351B into another layer. Moreover, it is possible to suppress contamination of the reflective film 351B due to impurities entering from the outside.

It is preferable that the conductive films 351A and 351C each have a function of transmitting light. Light incident on the liquid crystal element 350 from the outside can be efficiently reflected by the reflective film 351B owing to the function of transmitting light of the conductive film 351A. Moreover, light emitted from the light-emitting element 550 as will be shown later can be efficiently extracted to the outside owing to the function of transmitting light of the conductive film 351C.

In addition, the display device 300 includes an alignment film 331 and an alignment film 332. The liquid crystal layer 353 is sandwiched between the alignment films 331 and 332.

The display device 300 includes a coloring layer 375, a light-blocking layer 373, an insulating film 371, a functional film 370D, and a functional film 370P in a region overlapping with the pixel 302.

The coloring layer 375 has a region overlapping with the liquid crystal element 350. The light-blocking layer 373 has an opening in a region overlapping with the liquid crystal element 350. With the coloring layer 375, light incident on the liquid crystal element 350 from the outside enters the reflective film 351B through the coloring layer 375 and light reflected by the reflective film 351B is extracted to the outside through the coloring layer 375. Accordingly, light incident on the liquid crystal element 350 from the outside and reflected can be extracted to the outside with a predetermined color.

The insulating film 371 is provided between the coloring layer 375 and the liquid crystal layer 353 or between the light-blocking layer 373 and the liquid crystal layer 353. Owing to this, impurity diffusion from the light-blocking layer 373, the coloring layer 375, or the like to the liquid crystal layer 353 can be suppressed. The insulating film 371 may be provided to eliminate unevenness due to the thickness of the coloring layer 375.

The functional films 370D and 370P each include a region overlapping with the liquid crystal element 350. A substrate 370 is interposed between the functional film 370D and the liquid crystal element 350. As the functional films 370D and 370P, a film having a function of displaying clearer images of the liquid crystal element 350 and the light-emitting element 550, a film having a function of protecting the surface of the display device 300, or the like can be used. Note that either the functional film 370D or 370P may be used.

The display device 300 includes the substrate 370, a substrate 570, and a functional layer 520.

The substrate 370 has a region overlapping with the substrate 570. The functional layer 520 is provided between the substrates 570 and 370.

The functional layer 520 includes the transistor included in the pixel 302, the light-emitting element 550, an insulating film 521, and an insulating film 528.

The insulating film 521 is provided between the transistor included in the pixel 302 and the light-emitting element 550. The insulating film 521 is preferably formed so that steps due to components overlapping with the insulating film 521 can be covered to form a flat surface.

As the structure of the light-emitting element 550, any of the structures of the light-emitting element of one embodiment of the present invention, which are shown in Embodiments 1 to 3, is preferably used.

The light-emitting element 550 includes an electrode 551, an electrode 552, and a light-emitting layer 553. The electrode 552 has a region overlapping with the electrode 551. The light-emitting layer 553 is provided between the electrodes 551 and 552. The electrode 551 is electrically connected to the transistor 585 included in the pixel 302 in a connection portion 522.

In the case where the light-emitting element 550 has a bottom-emission structure, the electrode 552 preferably has a function of reflecting light. Therefore, it is preferable that the electrode 552 include a reflective film having a function of reflecting light. The electrode 551 preferably has a function of transmitting light.

In addition, the insulating film 528 has a region sandwiched between the electrodes 551 and 552. The insulating film 528 has an insulating property and thus can avoid a short circuit between the electrodes 551 and 552. In order to avoid a short circuit, an end portion of the electrode 551 preferably has a region in contact with the insulating film 528. In addition, the insulating film 528 has an opening in a region overlapping with the light-emitting element 550. In the opening, the light-emitting element 550 emits light.

The light-emitting layer 553 preferably contains an organic material or an inorganic material as a light-emitting material. Specifically, a fluorescent organic light-emitting material or a phosphorescent organic light-emitting material can be used. In addition, an inorganic light-emitting material such as quantum dots can be used.

The reflective film 351B of the liquid crystal element 350 includes an opening 351H. The opening 351H has a region overlapping with the conductive films 351A and 351C each having a function of transmitting light. The light-emitting element 550 has a function of emitting light toward the opening 351H. In other words, the liquid crystal element 350 has a function of performing display in a region overlapping with the reflective film 351B, and the light-emitting element 550 has a function of performing display in a region overlapping with the opening 351H.

In addition, the liquid crystal element has a function of performing display in a region overlapping with the reflective film 351B, and the light-emitting element has a function of performing display in a region overlapping with the opening 351H; therefore, the light-emitting element 550 has a function of performing display in a region surrounded by the display region of the liquid crystal element 350 (see FIG. 27B).

With the above-described structure in which a reflective liquid crystal element and a light-emitting element are used as the liquid crystal element 350 and the light-emitting element 550, respectively, the display device can perform display using the reflective liquid crystal element 350 in a bright environment, whereas using light from the light-emitting element 550 in a dark environment. Thus, a convenient display device with high visibility and low power consumption both in bright and dark environments can be provided. In addition, the display device can perform display in a dim environment using both the reflective liquid crystal element (utilizing external light) and light from the light-emitting element. Thus, a convenient display device with high visibility and low power consumption can be provided.

In the display device of one embodiment of the present invention, the coloring layer 375, the functional film 370D, and the functional film 370P each functioning as an optical element (e.g., a coloring layer, a color conversion layer (e.g., quantum dot), a polarizing plate, and an anti-reflective film) are provided in a region overlapping with the light-emitting element 550. Therefore, the color purity of light emitted from the light-emitting element 550 can be improved and thus the color purity of the display device 300 can be improved. Alternatively, the contrast ratio of the display device 300 can be enhanced. For example, a polarizing plate, a retardation plate, a diffusing film, an anti-reflective film, a condensing film, or the like can be used as the functional films 370D and 370P. Alternatively, a polarizing plate containing a dichromatic pigment can be used. Alternatively, an antistatic film preventing the attachment of a foreign substance, a water repellent film suppressing the attachment of stain, a hard coat film suppressing generation of a scratch in use, or the like can be used as the functional films 370D and 370P.

Furthermore, the coloring layer 575 may be provided in a region overlapping the opening 351H sandwiched between the liquid crystal element 350 and the light-emitting element 550. With such a structure, light emitted from the light-emitting element 550 is extracted to the outside through the coloring layers 575 and 375; therefore, the color purity of the light emitted from the light-emitting element 550 can be improved and the intensity of light emitted from the light-emitting element 550 can be increased.

A material that transmits light of a predetermined color can be used for the coloring layers 375 and 575. Thus, the coloring layers 375 and 575 can be used as, for example, a color filter. For example, the coloring layers 375 and 575 can be formed using a material transmitting light of blue, green, red, yellow, or white.

A touch panel may be provided in the display device 300 illustrated in FIG. 28. As the touch panel, a capacitive touch panel (a surface capacitive touch panel or a projected capacitive touch panel) can be preferably used.

### <Arrangement Example of Pixel and Wiring>

The driver circuit GD is electrically connected to scan lines GL1 and GL2. The driver circuit GD includes a transistor 586, for example. Specifically, a transistor including a semiconductor film which can be formed through the same process as the transistor included in the pixel 302 (e.g., the transistor 581) can be used as the transistor 586 (see FIG. 28).

The driver circuit SD is electrically connected to signal lines SL1 and SL2. The driver circuit SD is electrically connected to a terminal which can be formed in the same process as the terminal 519B or 519C with a conductive material, for example.

The pixel 302 is electrically connected to a signal line SL1 (see FIG. 29). Note that it is preferable that one of a source electrode and a drain electrode of the transistor 581 be electrically connected to the signal line SL1 (see FIGS. 28 and 29).

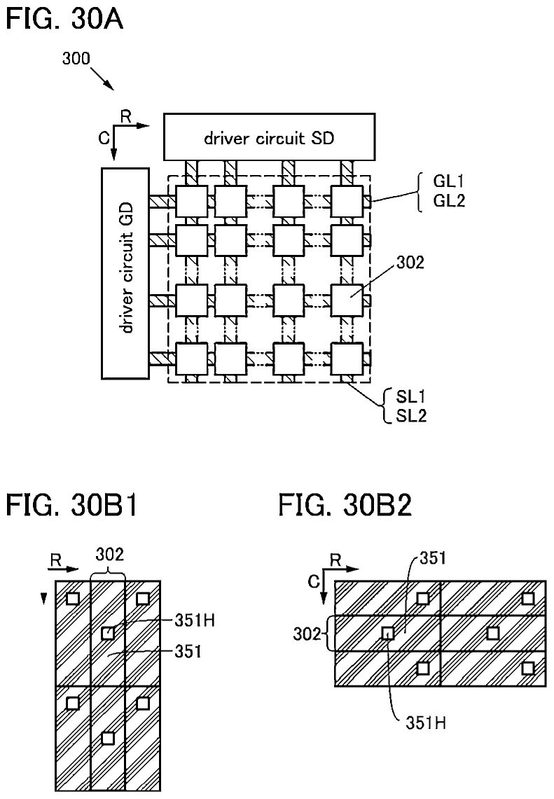

FIG. 30A is a block diagram illustrating arrangement of pixel circuits, wirings, and the like which can be used for the display device 300 of one embodiment of the present invention. FIGS. 30B1 and 30B2 are schematic views illustrating arrangement of the openings 351H which can be included in the display device 300 of one embodiment of the present invention.

The display device 300 of one embodiment of the present invention includes a plurality of pixels 302. Each pixel 302 includes the liquid crystal element 350, the light-emitting element 550, the transistor 581, the transistor 585, and the like. The pixels 302 are provided in the row direction (the direction indicated by an arrow R in FIG. 30A) and in the column direction (the direction indicated by an arrow C in FIG. 30A) that intersects the row direction.

The group of pixels 302 arranged in the row direction are electrically connected to the scan line GL1. The group of pixels 302 arranged in the column direction are electrically connected to the signal line SL1.

For example, the pixel adjacent to the pixel 302 in the row direction (the direction indicated by the arrow R in FIG. 30B1) includes an opening that does not align with the opening 351H in the pixel 302. In addition, for example, the pixel adjacent to the pixel 302 in the column direction (the direction indicated by an arrow C in FIG. 30B2) includes an opening that does not align with the opening 351H in the pixel 302.

The opening 351H can have a polygonal shape (e.g., a quadrangular shape or a cross-like shape), an elliptical shape, a circular shape, or the like. The opening 351H may have a stripe shape, a slit-like shape, or a checkered pattern. The opening 351H may be moved to the side of an adjacent pixel. Preferably, the opening 351H is provided to the side of another pixel for emitting light of the same color. With this structure, a phenomenon in which light emitted from the light-emitting element 550 enters a coloring film of the adjacent pixel (i.e., cross talk), can be suppressed.

As described above, the display device 300 of one embodiment of the present invention includes the pixel 302; the pixel 302 includes the liquid crystal element 350 and the light-emitting element 550; the electrode 351 included in the liquid crystal element 350 is electrically connected to the transistor 581 included in the pixel 302; the electrode 551 included in the light-emitting element 550 is electrically connected to the transistor 585 included in the pixel 302; the light-emitting element 550 has a function of emitting light through the opening 351H; and the liquid crystal element 350 has a function of reflecting light entering the display device 300.

Thus, the liquid crystal element 350 and the light-emitting element 550 can be driven using transistors that can be formed through the same process, for example.

### <Components of Display Device>

The pixel 302 is electrically connected to the signal line SL1, a signal line SL2, the scan line GL1, a scan line GL2, a wiring CSCOM, and a wiring ANO (see FIG. 29).

In the case where the voltage of a signal supplied to the signal line SL2 is different from the voltage of a signal supplied to the signal line SL1 of an adjacent pixel, the signal line SL1 of the adjacent pixel is positioned apart from the signal line SL2. Specifically, the signal line SL2 is positioned adjacent to the signal line SL2 of an adjacent pixel.

The pixel 302 includes the transistor 581, a capacitor C1, a transistor 582, the transistor 585, and a capacitor C2.

For example, a transistor including a gate electrode electrically connected to the scan line GL1 and a first electrode (one of a source electrode and a drain electrode) electrically connected to the signal line SL1 can be used as the transistor 581.

The capacitor C1 includes a first electrode electrically connected to a second electrode (the electrode corresponds to the other of the source electrode and the drain electrode of the transistor 581) and a second electrode electrically connected to the wiring CSCOM.

For example, a transistor including a gate electrode electrically connected to the scan line GL2 and a first electrode (one of a source electrode and a drain electrode) electrically connected to the signal line SL2 can be used as the transistor 582.

The transistor 585 includes a gate electrode electrically connected to a second electrode (the electrode corresponds to the other of the source electrode and the drain electrode of the transistor 582) and a first electrode (one of a source electrode and a drain electrode) electrically connected to the wiring ANO.

A transistor in which a semiconductor film is sandwiched between a conductive film and a gate electrode can be used as the transistor 585. For example, a conductive film electrically connected to the wiring capable of supplying a potential equal to that supplied to the first electrode (the one of the source electrode and the drain electrode) of the transistor 585 can be used.

The capacitor C2 includes a first electrode electrically connected to a second electrode of the transistor 582 (the electrode corresponds to the other of the source electrode and the drain electrode) and a second electrode electrically connected to the first electrode (the one of the source electrode and the drain electrode) of the transistor 585.

Note that a first electrode of the liquid crystal element 350 is electrically connected to the second electrode (the other of the source electrode and the drain electrode) of the transistor 581, and a second electrode of the liquid crystal element 350 is electrically connected to a wiring VCOM1. This enables the liquid crystal element 350 to be driven.

In addition, a first electrode of the light-emitting element 550 is electrically connected to the second electrode (the other of the source electrode and the drain electrode) of the transistor 585, and a second electrode of the light-emitting element 550 is electrically connected to a wiring VCOM2. This enables the light-emitting element 550 to be driven.

### <<Components of Pixel>>>

The pixel 302 includes the insulating film 501C and an intermediate film 354. In addition, the pixel 302 includes a transistor 581. In addition, the pixel 302 includes the transistor 585 and the transistor 586. The semiconductor film used for these transistors is preferably an oxide semiconductor.

The display device 300 includes a terminal 519B, and the terminal 519B includes the conductive film 511B and the intermediate film 354. In addition, the display device 300 includes a terminal 519C and a conductor 337, and the terminal 519C includes the conductive film 511C and the intermediate film 354 (see FIG. 28). For example, a material having a function of allowing hydrogen passage and supplying hydrogen can be used for the intermediate film 354. A conductive material can be used for the intermediate film 354. A light-transmitting material can be used for the intermediate film 354.

The insulating film 501C has a region sandwiched between an insulating film 501A and a conductive film 511B.

The conductive film 511B is electrically connected to the pixel 302. For example, when the electrode 351 or the first conductive film is used as the reflective film 351B, a surface functioning as a contact with the terminal 519B is oriented in the same direction as a surface of the electrode 351 facing light incident on the liquid crystal element 350.

A flexible printed board 377 can be electrically connected to the terminal 519B with the conductive material 339. Thus, power or signals can be supplied to the pixel 302 through the terminal 519B.

The conductive film 511C is electrically connected to the pixel 302. For example, when the electrode 351 or the first conductive film is used as the reflective film 351B, a surface functioning as a contact with the terminal 519C is oriented in the same direction as a surface of the electrode 351 facing light incident on the liquid crystal element 350.

The conductor 337 is sandwiched between the terminal 519C and the electrode 352 to electrically connect them. A conductive particle can be used as the conductor 337, for example.

The display device 300 includes a bonding layer 505, a sealant 315 and a structure body 335.

The bonding layer 505 is provided between the functional layer 520 and the substrate 570 to bond them together. For the bonding layer 505, a material that can be used for the sealant 315 can be used, for example.

The sealant 315 is provided between the functional layer 520 and the substrate 370 to bond them together.

The structure body 335 has a function of making a predetermined gap between the functional layer 520 and the substrate 570.

An organic material, an inorganic material, or a composite material of an organic material and an inorganic material can be used for the structure body 335. Accordingly, components between which the structure body 335 or the like is interposed can have a predetermined gap. Specifically, polyester, polyolefin, polyamide, polyimide, polycarbonate, polysiloxane, an acrylic resin, or the like, or a composite material of a plurality of kinds of resins selected from these can be used. Alternatively, a photosensitive material may be used.

### <<Components of Liquid Crystal Element>>

Next, a structural example of the liquid crystal element that forms the display device of one embodiment of the present invention will be described.

The liquid crystal element 350 has a function of controlling transmission or reflection of light. For example, a combined structure of a polarizing plate and a liquid crystal element or a MEMS shutter display element can be used. The use of a reflective display element can reduce power consumption of a display device. Specifically, a reflective liquid crystal element is preferably used as the liquid crystal element 350.

Specifically, a liquid crystal element that can be driven by any of the following driving methods can be used: an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, and the like.

In addition, a liquid crystal element that can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

Other examples of the driving method of the liquid crystal element 350 include a polymer dispersed liquid crystal (PDLC) mode, a polymer network liquid crystal (PNLC) mode, and a guest-host mode. Note that one embodiment of the present invention is not limited thereto, and various liquid crystal elements and driving methods can be used.

A liquid crystal material or the like which can be used for a liquid crystal element is used for the liquid crystal element 350. For example, thermotropic liquid crystal, low-molecular liquid crystal, high-molecular liquid crystal, polymer dispersed liquid crystal, ferroelectric liquid crystal, or anti-ferroelectric liquid crystal can be used. Alternatively, a liquid crystal material which exhibits a cholesteric phase, a smectic phase, a cubic phase, a chiral nematic phase, an isotropic phase, or the like can be used. Alternatively, a liquid crystal material which exhibits a blue phase can be used.

Alternatively, liquid crystal that exhibits a blue phase for which an alignment film is not involved may be used. A blue phase is one of liquid crystal phases, which is generated just before a cholesteric phase changes into an isotropic phase while the temperature of cholesteric liquid crystal is increased. Since the blue phase is only generated within a narrow range of temperatures, a liquid crystal composition containing a chiral material at 5 wt % or more is used for the liquid crystal layer in order to improve the temperature range. The liquid crystal composition including the liquid crystal that exhibits a blue phase and a chiral material has a short response time of 1 msec or less, and has optical isotropy, which makes the alignment process unnecessary and the viewing angle dependence small. An alignment film does not need to be provided and rubbing treatment is thus not necessary; accordingly, electrostatic discharge damage caused by the rubbing treatment can be prevented and defects and damage of the liquid crystal display device in the manufacturing process can be reduced. Thus, productivity of the liquid crystal display device can be increased.

Moreover, it is possible to use a method called domain multiplication or multi-domain design, in which a pixel is divided into some regions (sub-pixels) and molecules are aligned in different directions in their respective regions.

### <<Components of Transistor>>

For example, a bottom-gate transistor, a top-gate transistor, or the like can be used as the transistor 581, the transistor 582, the transistor 585, the transistor 586, or the like.

For example, a semiconductor containing an element belonging to Group 14 can be used for a semiconductor film of the transistor. Specifically, a semiconductor containing silicon can be used for the semiconductor film of the transistor. For example, single crystal silicon, polysilicon, microcrystalline silicon, or amorphous silicon can be used for the semiconductor film of the transistor.

For example, a transistor whose semiconductor film includes an oxide semiconductor can be used for the transistor 581, the transistor 582, the transistor 585, the transistor 586, or the like. Specifically, an oxide semiconductor containing indium or an oxide semiconductor containing indium, gallium, and zinc can be used for a semiconductor film.

The transistor including an oxide semiconductor is used for the transistor 581, the transistor 582, the transistor 585, the transistor 586, or the like, whereby a pixel circuit can hold an image signal for a longer time than a pixel circuit including a transistor that uses amorphous silicon for a semiconductor film. Specifically, the selection signal can be supplied at a frequency of lower than 30 Hz, preferably lower than 1 Hz, more preferably lower than once per minute while flickering is suppressed. Consequently, eyestrain on a user of the information processing device can be reduced, and power consumption for driving can be reduced.

The structure and method described in this embodiment can be implemented by being combined as appropriate with structures and methods described in the other embodiments and the example.

### Embodiment 8

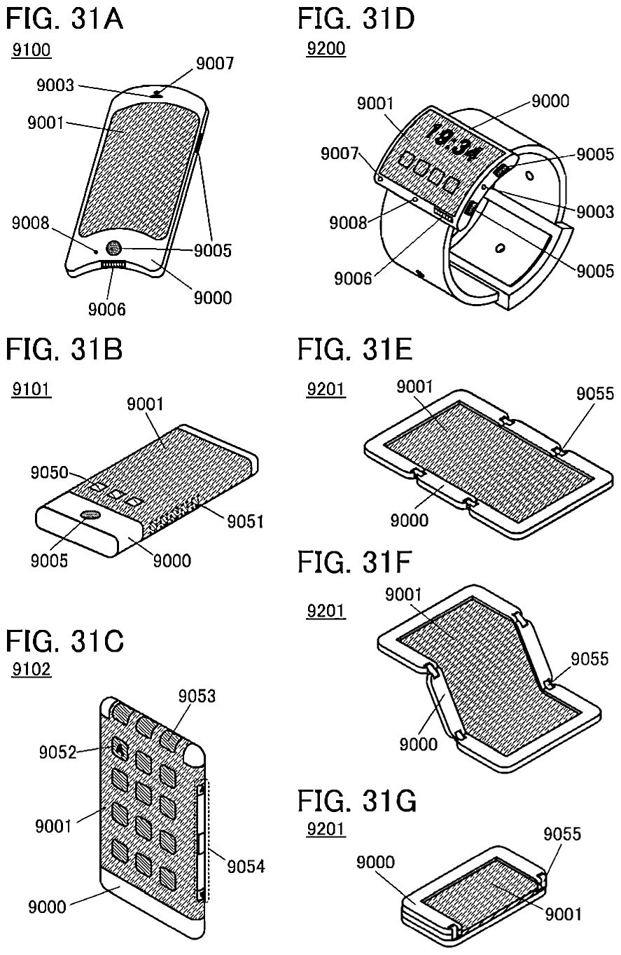

In this embodiment, a display module and electronic devices including a light-emitting element of one embodiment of the present invention will be described with reference to FIGS. 31A to 35B.

### <Electronic Device>

FIGS. 31A to 31G illustrate electronic devices. These electronic devices can include a housing 9000, a display portion 9001, a speaker 9003, operation keys 9005 (including a power switch or an operation switch), a connection terminal 9006, a sensor 9007 (a sensor having a function of measuring or sensing force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared ray), a microphone 9008, and the like. In addition, the sensor 9007 may have a function of measuring biological information like a pulse sensor and a finger print sensor.

The electronic devices illustrated in FIGS. 31A to 31G can have a variety of functions, for example, a function of displaying a variety of data (a still image, a moving image, a text image, and the like) on the display portion, a touch sensor function, a function of displaying a calendar, date, time, and the like, a function of controlling a process with a variety of software (programs), a wireless communication function, a function of being connected to a variety of computer networks with a wireless communication function, a function of transmitting and receiving a variety of data with a wireless communication function, a function of reading a program or data stored in a memory medium and displaying the program or data on the display portion, and the like. Note that functions that can be provided for the electronic devices illustrated in FIGS. 31A to 31G are not limited to those described above, and the electronic devices can have a variety of functions. Although not illustrated in FIGS. 31A to 31G, the electronic devices may include a plurality of display portions. The electronic devices may have a camera or the like and a function of taking a still image, a function of taking a moving image, a function of storing the taken image in a memory medium (an external memory medium or a memory medium incorporated in the camera), a function of displaying the taken image on the display portion, or the like.

The electronic devices illustrated in FIGS. 31A to 31G will be described in detail below.

FIG. 31A is a perspective view of a portable information terminal 9100. The display portion 9001 of the portable information terminal 9100 is flexible. Therefore, the display portion 9001 can be incorporated along a bent surface of a bent housing 9000. In addition, the display portion 9001 includes a touch sensor, and operation can be performed by touching the screen with a finger, a stylus, or the like. For example, when an icon displayed on the display portion 9001 is touched, an application can be started.

FIG. 31B is a perspective view of a portable information terminal 9101. The portable information terminal 9101 functions as, for example, one or more of a telephone set, a notebook, and an information browsing system. Specifically, the portable information terminal can be used as a smartphone. Note that the speaker 9003, the connection terminal 9006, the sensor 9007, and the like, which are not illustrated in the drawing, can be positioned in the portable information terminal 9101 as in the portable information terminal 9100 illustrated in FIG. 31A. The portable information terminal 9101 can display characters and image information on its plurality of surfaces. For example, three operation buttons 9050 (also referred to as operation icons, or simply, icons) can be displayed on one surface of the display portion 9001. Furthermore, information 9051 indicated by dashed rectangles can be displayed on another surface of the display portion 9001. Examples of the information 9051 include display indicating reception of an incoming email, social networking service (SNS) message, call, and the like; the title and sender of an email and SNS message; the date; the time; remaining battery; and display indicating the strength of a received signal such as a radio wave. Instead of the information 9051, the operation buttons 9050 or the like may be displayed on the position where the information 9051 is displayed.

As a material of the housing 9000, for example, an alloy, a plastic, or a ceramic can be used. As a plastic, a reinforced plastic can also be used. A carbon fiber reinforced plastic (CFRP), which is a kind of reinforced plastic, has advantages of lightweight and corrosion-free. Other examples of reinforced plastics include one including glass fiber and one including aramid fiber. As the alloy, an aluminum alloy and a magnesium alloy can be given. The alloy includes an aluminum alloy and a magnesium alloy. In particular, an amorphous alloy (also referred to as metal glass) containing zirconium, copper, nickel, and titanium is superior in terms of high elastic strength. This amorphous alloy includes a glass transition region at room temperature, which is also referred to as a bulk-solidifying amorphous alloy and substantially has an amorphous atomic structure. By a solidification casting method, an alloy material is molded in a mold of at least part of the housing and coagulated so that the part of the housing is formed using a bulk-solidifying amorphous alloy. The amorphous alloy may include beryllium, silicon, niobium, boron, gallium, molybdenum, tungsten, manganese, iron, cobalt, yttrium, vanadium, phosphorus, carbon, or the like in addition to zirconium, copper, nickel, and titanium. The amorphous alloy may be formed by a vacuum evaporation method, a sputtering method, an electroplating method, an electroless plating method, or the like instead of the solidification casting method. The amorphous alloy may include a microcrystal or a nanocrystal as long as a state without a long-range order (a periodic structure) is maintained as a whole. Note that the term alloy refers to both a complete solid solution alloy which has a single solid phase structure and a partial solution that has two or more phases. The housing 9000 using the amorphous alloy can have high elastic strength. Even if the portable information terminal 9101 is dropped and the impact causes temporary deformation, the use of the amorphous alloy in the housing 9000 allows a return to the original shape; thus, the impact resistance of the portable information terminal 9101 can be improved.

FIG. 31C is a perspective view of a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053) with the portable information terminal 9102 put in a breast pocket of his/her clothes. Specifically, a caller's phone number, name, or the like of an incoming call is displayed in a position that can be seen from above the portable information terminal 9102. Thus, the user can see the display without taking out the portable information terminal 9102 from the pocket and decide whether to answer the call.

FIG. 31D is a perspective view of a watch-type portable information terminal 9200. The portable information terminal 9200 is capable of executing a variety of applications such as mobile phone calls, e-mailing, viewing and editing texts, music reproduction, Internet communication, and computer games. The display surface of the display portion 9001 is bent, and images can be displayed on the bent display surface. The portable information terminal 9200 can employ near field communication that is a communication method based on an existing communication standard. In that case, for example, mutual communication between the portable information terminal and a headset capable of wireless communication can be performed, and thus hands-free calling is possible. The portable information terminal 9200 includes the connection terminal 9006, and data can be directly transmitted to and received from another information terminal via a connector. Power charging through the connection terminal 9006 is possible. Note that the charging operation may be performed by wireless power feeding without using the connection terminal 9006.

FIGS. 31E, 31F, and 31G are perspective views of a foldable portable information terminal 9201. FIG. 31E is a perspective view illustrating the portable information terminal 9201 which is opened. FIG. 31F is a perspective view illustrating the portable information terminal 9201 which is being opened or being folded. FIG. 31G is a perspective view illustrating the portable information terminal 9201 which is folded. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. By folding the portable information terminal 9201 at a connection portion between two housings 9000 with the hinges 9055, the portable information terminal 9201 can be reversibly changed in shape from an opened state to a folded state. For example, the portable information terminal 9201 can be bent with a radius of curvature greater than or equal to 1 mm and less than or equal to 150 mm.

Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a goggle-type display (head-mounted display), a portable game machine, a portable information terminal, an audio reproducing device, and a large-sized game machine such as a pachinko machine.

Furthermore, the electronic device of one embodiment of the present invention may include a secondary battery. It is preferable that the secondary battery be capable of being charged by non-contact power transmission.

Examples of the secondary battery include a lithium-ion secondary battery such as a lithium polymer battery using a gel electrolyte (lithium-ion polymer battery), a lithium-ion battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display an image, data, or the like on a display portion. When the electronic device includes a secondary battery, the antenna may be used for non-contact power transmission.

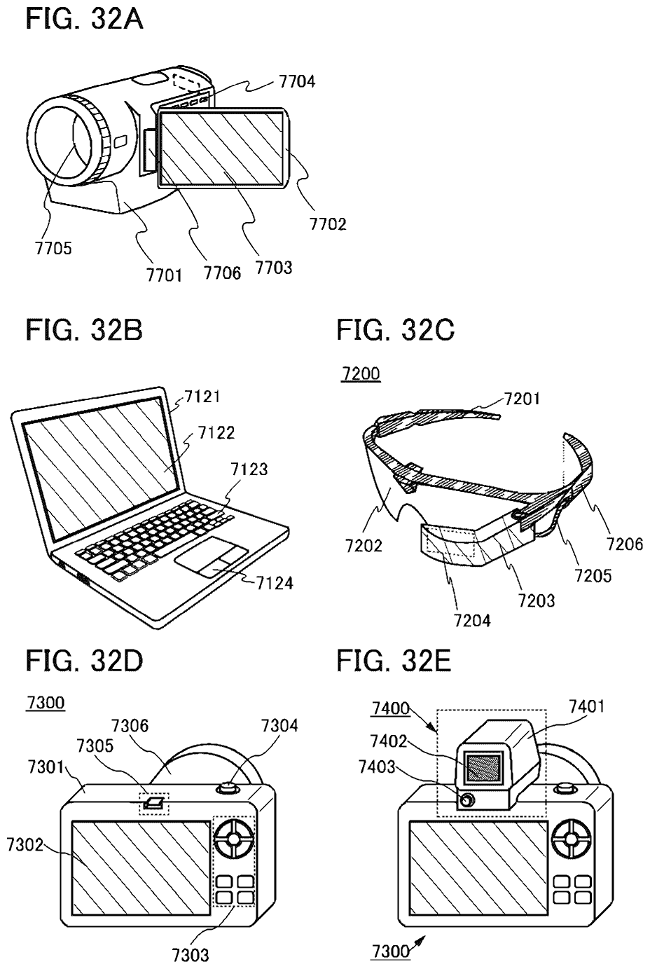

FIG. 32A illustrates a video camera including a housing 7701, a housing 7702, a display portion 7703, operation keys 7704, a lens 7705, a joint 7706, and the like. The operation keys 7704 and the lens 7705 are provided for the housing 7701, and the display portion 7703 is provided for the housing 7702. The housing 7701 and the housing 7702 are connected to each other with the joint 7706, and the angle between the housing 7701 and the housing 7702 can be changed with the joint 7706. Images displayed on the display portion 7703 may be switched in accordance with the angle at the joint 7706 between the housing 7701 and the housing 7702.

FIG. 32B illustrates a notebook personal computer including a housing 7121, a display portion 7122, a keyboard 7123, a pointing device 7124, and the like. Note that the display portion 7122 is small- or medium-sized but can perform 8k display because it has greatly high pixel density and high resolution; therefore, a significantly clear image can be obtained.

FIG. 32C is an external view of a head-mounted display 7200.

The head-mounted display 7200 includes a mounting portion 7201, a lens 7202, a main body 7203, a display portion 7204, a cable 7205, and the like. The mounting portion 7201 includes a battery 7206.

Power is supplied from the battery 7206 to the main body 7203 through the cable 7205. The main body 7203 includes a wireless receiver or the like to receive video data, such as image data, and display it on the display portion 7204. The movement of the eyeball and the eyelid of a user is captured by a camera in the main body 7203 and then coordinates of the points the user looks at are calculated using the captured data to utilize the eye point of the user as an input means.

The mounting portion 7201 may include a plurality of electrodes so as to be in contact with the user. The main body 7203 may have a function of sensing current flowing through the electrodes with the movement of the user's eyeball to recognize the direction of his or her eyes. The main body 7203 may have a function of sensing current flowing through the electrodes to monitor the user's pulse. The mounting portion 7201 may include sensors, such as a temperature sensor, a pressure sensor, or an acceleration sensor, so that the user's biological information can be displayed on the display portion 7204. The main body 7203 may sense the movement of the user's head or the like to move an image displayed on the display portion 7204 in synchronization with the movement of the user's head or the like.

FIG. 32D is an external view of a camera 7300. The camera 7300 includes a housing 7301, a display portion 7302, an operation button 7303, a shutter button 7304, a connection portion 7305, and the like. A lens 7306 can be put on the camera 7300.

The connection portion 7305 includes an electrode to connect with a finder 7400, which is described below, a stroboscope, or the like.

Although the lens 7306 of the camera 7300 here is detachable from the housing 7301 for replacement, the lens 7306 may be included in the housing 7301.

Images can be taken at the touch of the shutter button 7304. In addition, images can betaken by operation of the display portion 7302 including a touch sensor.

In the display portion 7302, the display device of one embodiment of the present invention or a touch sensor can be used.

FIG. 32E illustrates the camera 7300 with the finder 7400 connected.

The finder 7400 includes a housing 7401, a display portion 7402, a button 7403, and the like.

The housing 7401 includes a connection portion for engagement with the connection portion 7305 of the camera 7300 so that the finder 7400 can be connected to the camera 7300. The connection portion includes an electrode, and an image or the like received from the camera 7300 through the electrode can be displayed on the display portion 7402.

The button 7403 functions as a power supply button. With the button 7403, on/off of display on the display portion 7402 can be switched.

Although the camera 7300 and the finder 7400 are separate and detachable electronic devices in FIGS. 32D and 32E, the housing 7301 of the camera 7300 may include a finder having a display device of one embodiment of the present invention or a touch sensor.

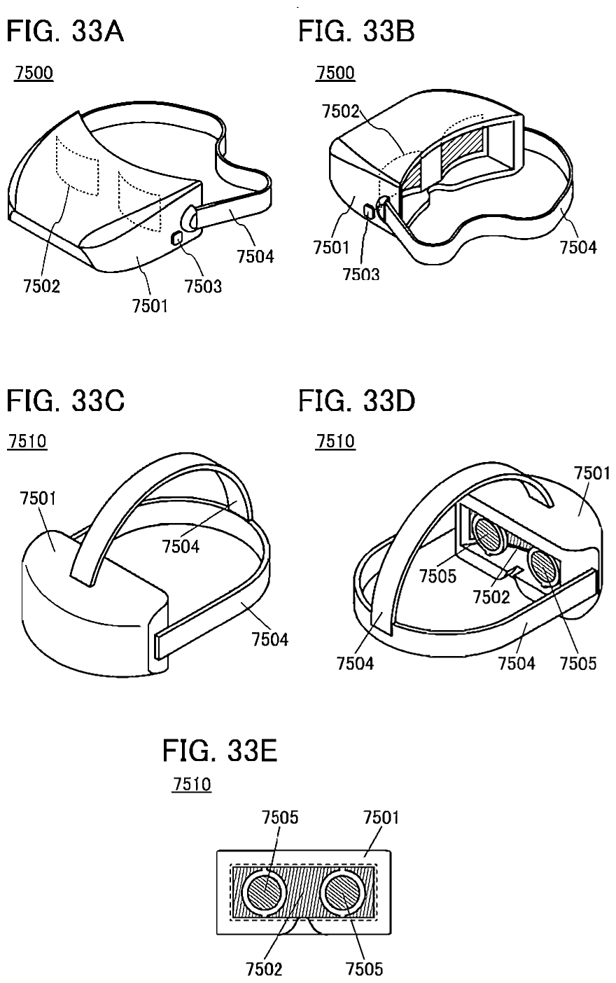

FIGS. 33A to 33E are external views of a head-mounted display 7500 and a head-mounted display 7510.

The head-mounted display 7500 includes a housing 7501, two display portions 7502, an operation button 7503, and a fixing band 7504.

The head-mounted display 7500 has the functions of the above-described head-mounted display 7200 and further includes two display portions.

With the two display portions 7502, the user can see one display portion with one eye and the other display portion with the other eye. Thus, a high-resolution image can be displayed even when three-dimensional display using parallax or the like is performed. The display portion 7502 is curved around an arc with the user's eye as an approximate center. Thus, distances between the user's eye and the display surface of the display portion are uniform; thus, the user can see a more natural image. Even when the luminance or chromaticity of light from the display portion is changed depending on the angle at which the user see it, since the user's eye is positioned in the normal direction of the display surface of the display portion, the influence of the change can be substantially ignorable and thus a more realistic image can be displayed.

The operation button 7503 serves as a power button or the like. A button other than the operation button 7503 may be included.

The head-mounted display 7510 includes the housing 7501, the display portion 7502, the fixing bands 7504, and the pair of lenses 7505.

The user can view display on the display portion 7502 through the lenses 7505. It is favorable that the display portion 7502 be curved. The curved display portion 7502 gives the user a high realistic sensation.

The display device of one embodiment of the present invention can be used in the display portion 7502. The display device of one embodiment of the present invention can have a high resolution; thus, even when an image is magnified using the lenses 7505 as illustrated in FIG. 33E, the user does not perceive pixels, and thus a more realistic image can be displayed.

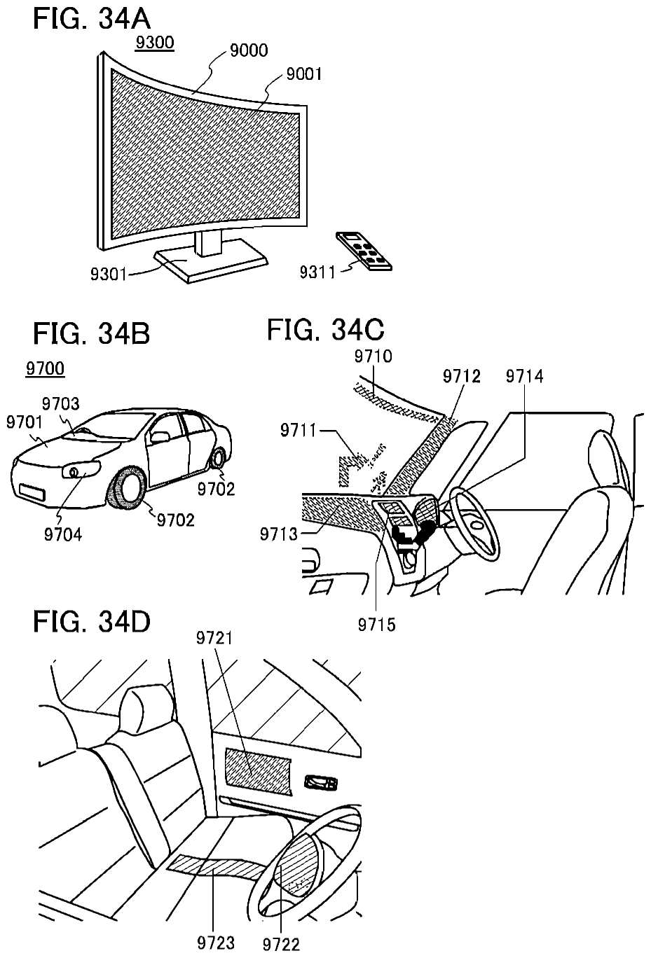

FIG. 34A illustrates an example of a television set. In a television set 9300, the display portion 9001 is incorporated into the housing 9000. Here, the housing 9000 is supported by a stand 9301.

The television set 9300 illustrated in FIG. 34A can be operated with an operation switch of the housing 9000 or a separate remote controller 9311. The display portion 9001 may include a touch sensor. The television set 9300 can be operated by touching the display portion 9001 with a finger or the like. The remote controller 9311 may be provided with a display portion for displaying data output from the remote controller 9311. With operation keys or a touch panel of the remote controller 9311, channels or volume can be controlled and images displayed on the display portion 9001 can be controlled.

The television set 9300 is provided with a receiver, a modem, or the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

The electronic device or the lighting device of one embodiment of the present invention has flexibility and therefore can be incorporated along a curved inside/outside wall surface of a house or a building or a curved interior/exterior surface of a car.

FIG. 34B is an external view of an automobile 9700. FIG. 34C illustrates a driver's seat of the automobile 9700. The automobile 9700 includes a car body 9701, wheels 9702, a dashboard 9703, lights 9704, and the like. The display device, the light-emitting device, or the like of one embodiment of the present invention can be used in a display portion or the like of the automobile 9700. For example, the display device, the light-emitting device, or the like of one embodiment of the present invention can be used in display portions 9710 to 9715 illustrated in FIG. 34C.

The display portion 9710 and the display portion 9711 are display devices provided in an automobile windshield. The display device, the light-emitting device, or the like of one embodiment of the present invention can be a see-through display device, through which the opposite side can be seen, using a light-transmitting conductive material for its electrodes and wirings. Such a see-through display portion 9710 or 9711 does not hinder driver's vision during driving the automobile 9700. Thus, the display device, the light-emitting device, or the like of one embodiment of the present invention can be provided in the windshield of the automobile 9700. Note that in the case where a transistor or the like for driving the display device, the light-emitting device, or the like is provided, a transistor having a light-transmitting property, such as an organic transistor using an organic semiconductor material or a transistor using an oxide semiconductor, is preferably used.

The display portion 9712 is a display device provided on a pillar portion. For example, the display portion 9712 can compensate for the view hindered by the pillar portion by showing an image taken by an imaging unit provided on the car body. The display portion 9713 is a display device provided on the dashboard portion. For example, the display portion 9713 can compensate for the view hindered by the dashboard portion by showing an image taken by an imaging unit provided on the car body. That is, showing an image taken by an imaging unit provided on the outside of the car body leads to elimination of blind areas and enhancement of safety. In addition, showing an image so as to compensate for the area which a driver cannot see makes it possible for the driver to confirm safety easily and comfortably.

FIG. 34D illustrates the inside of a car in which a bench seat is used as a driver seat and a front passenger seat. A display portion 9721 is a display device provided in a door portion. For example, the display portion 9721 can compensate for the view hindered by the door portion by showing an image taken by an imaging unit provided on the car body. A display portion 9722 is a display device provided in a steering wheel. A display portion 9723 is a display device provided in the middle of a seating face of the bench seat. Note that the display device can be used as a seat heater by providing the display device on the seating face or backrest and by using heat generation of the display device as a heat source.

The display portion 9714, the display portion 9715, and the display portion 9722 can display a variety of kinds of information such as navigation data, a speedometer, a tachometer, a mileage, a fuel meter, a gearshift indicator, and air-condition setting. The content, layout, or the like of the display on the display portions can be changed freely by a user as appropriate. The information listed above can also be displayed on the display portions 9710 to 9713, 9721, and 9723. The display portions 9710 to 9715 and 9721 to 9723 can also be used as lighting devices. The display portions 9710 to 9715 and 9721 to 9723 can also be used as heating devices.

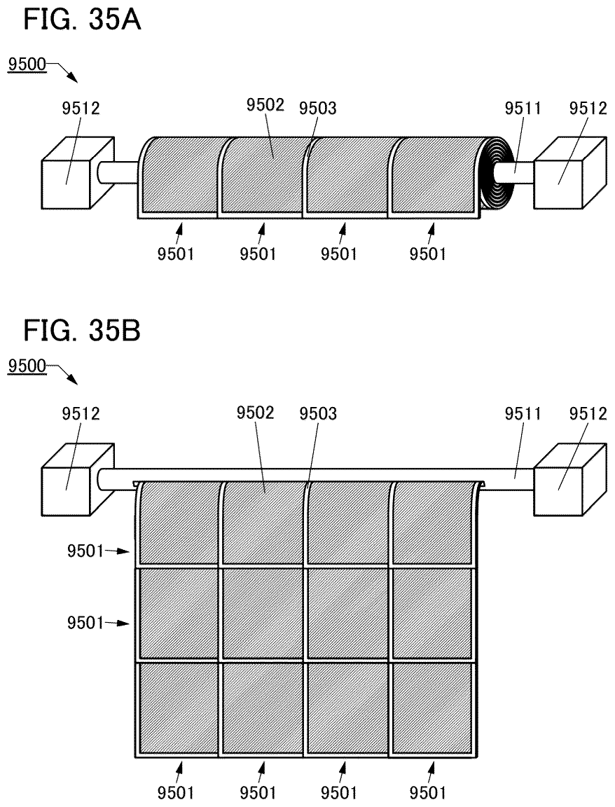

A display device 9500 illustrated in FIGS. 35A and 35B includes a plurality of display panels 9501, a hinge 9511, and a bearing 9512. The plurality of display panels 9501 each include a display region 9502 and a light-transmitting region 9503.

Each of the plurality of display panels 9501 is flexible. Two adjacent display panels 9501 are provided so as to partly overlap with each other. For example, the light-transmitting regions 9503 of the two adjacent display panels 9501 can overlap with each other. A display device having a large screen can be obtained with the plurality of display panels 9501. The display device is highly versatile because the display panels 9501 can be wound depending on its use.

Moreover, although the display regions 9502 of the adjacent display panels 9501 are separated from each other in FIGS. 35A and 35B, without limitation to this structure, the display regions 9502 of the adjacent display panels 9501 may overlap with each other without any space so that a continuous display region 9502 is obtained, for example.

The electronic devices described in this embodiment each include the display portion for displaying some sort of data. Note that the light-emitting element of one embodiment of the present invention can also be used for an electronic device which does not have a display portion. The structure in which the display portion of the electronic device described in this embodiment is flexible and display can be performed on the bent display surface or the structure in which the display portion of the electronic device is foldable is described as an example; however, the structure is not limited thereto and a structure in which the display portion of the electronic device is not flexible and display is performed on a plane portion may be employed.

The structure described in this embodiment can be used in appropriate combination with the structure described in any of the other embodiments and the example.

### Embodiment 9

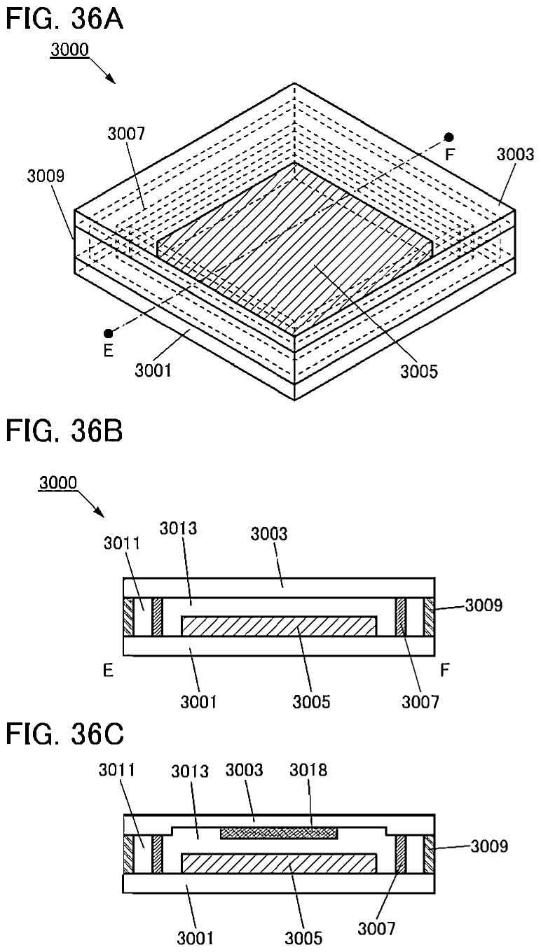

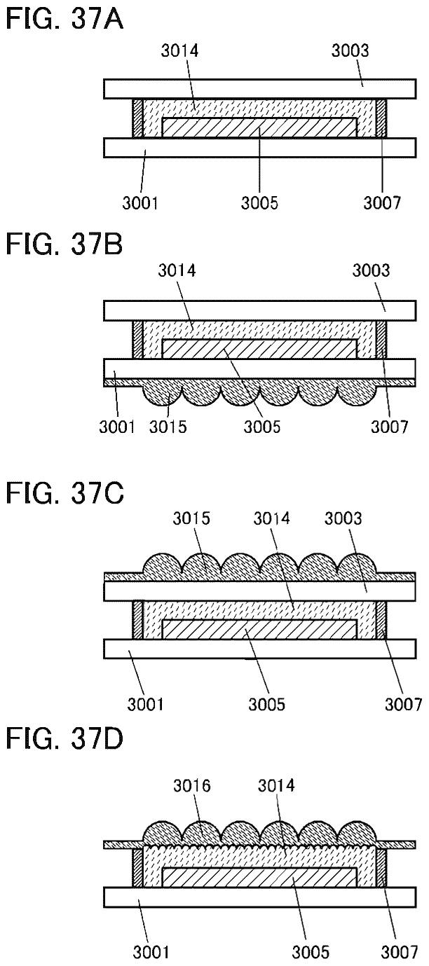

In this embodiment, a light-emitting device including the light-emitting element of one embodiment of the present invention will be described with reference to FIGS. 36A to 37D.

FIG. 36A is a perspective view of a light-emitting device 3000 shown in this embodiment, and FIG. 36B is a cross-sectional view along dashed-dotted line E-F in FIG. 36A. Note that in FIG. 36A, some components are illustrated by broken lines in order to avoid complexity of the drawing.

The light-emitting device 3000 illustrated in FIGS. 36A and 36B includes a substrate 3001, a light-emitting element 3005 over the substrate 3001, a first sealing region 3007 provided around the light-emitting element 3005, and a second sealing region 3009 provided around the first sealing region 3007.

Light is emitted from the light-emitting element 3005 through one or both of the substrate 3001 and a substrate 3003. In FIGS. 36A and 36B, a structure in which light is emitted from the light-emitting element 3005 to the lower side (the substrate 3001 side) is illustrated.

As illustrated in FIGS. 36A and 36B, the light-emitting device 3000 has a double sealing structure in which the light-emitting element 3005 is surrounded by the first sealing region 3007 and the second sealing region 3009. With the double sealing structure, entry of impurities (e.g., water, oxygen, and the like) from the outside into the light-emitting element 3005 can be favorably suppressed. Note that it is not necessary to provide both the first sealing region 3007 and the second sealing region 3009. For example, only the first sealing region 3007 may be provided.

Note that in FIG. 36B, the first sealing region 3007 and the second sealing region 3009 are each provided in contact with the substrate 3001 and the substrate 3003. However, without limitation to such a structure, for example, one or both of the first sealing region 3007 and the second sealing region 3009 may be provided in contact with an insulating film or a conductive film provided on the substrate 3001. Alternatively, one or both of the first sealing region 3007 and the second sealing region 3009 may be provided in contact with an insulating film or a conductive film provided on the substrate 3003.

The substrate 3001 and the substrate 3003 can have structures similar to those of the substrate 480 and the substrate 482 described in the above embodiment, respectively. The light-emitting element 3005 can have a structure similar to that of any of the light-emitting elements described in the above embodiments.

For the first sealing region 3007, a material containing glass (e.g., a glass frit, a glass ribbon, and the like) can be used. For the second sealing region 3009, a material containing a resin can be used. With use of the material containing glass for the first sealing region 3007, productivity and a sealing property can be improved. Moreover, with use of the material containing a resin for the second sealing region 3009, impact resistance and heat resistance can be improved. However, the materials used for the first sealing region 3007 and the second sealing region 3009 are not limited to such, and the first sealing region 3007 may be formed using the material containing a resin and the second sealing region 3009 may be formed using the material containing glass.

The glass frit may contain, for example, magnesium oxide, calcium oxide, strontium oxide, barium oxide, cesium oxide, sodium oxide, potassium oxide, boron oxide, vanadium oxide, zinc oxide, tellurium oxide, aluminum oxide, silicon dioxide, lead oxide, tin oxide, phosphorus oxide, ruthenium oxide, rhodium oxide, iron oxide, copper oxide, manganese dioxide, molybdenum oxide, niobium oxide, titanium oxide, tungsten oxide, bismuth oxide, zirconium oxide, lithium oxide, antimony oxide, lead borate glass, tin phosphate glass, vanadate glass, or borosilicate glass. The glass frit preferably contains at least one kind of transition metal to absorb infrared light.

As the above glass frits, for example, a frit paste is applied to a substrate and is subjected to heat treatment, laser light irradiation, or the like. The frit paste contains the glass frit and a resin (also referred to as a binder) diluted by an organic solvent. Note that an absorber which absorbs light having the wavelength of laser light may be added to the glass frit. For example, an Nd:YAG laser or a semiconductor laser is preferably used as the laser. The shape of laser light may be circular or quadrangular.

As the above material containing a resin, for example, polyester, polyolefin, polyamide (e.g., nylon, aramid), polyimide, polycarbonate, or an acrylic resin, polyurethane, or an epoxy resin can be used. Alternatively, a material that includes a resin having a siloxane bond, such as silicone, can be used.

Note that in the case where the material containing glass is used for one or both of the first sealing region 3007 and the second sealing region 3009, the material containing glass preferably has a thermal expansion coefficient close to that of the substrate 3001. With the above structure, generation of a crack in the material containing glass or the substrate 3001 due to thermal stress can be suppressed.

For example, the following advantageous effect can be obtained in the case where the material containing glass is used for the first sealing region 3007 and the material containing a resin is used for the second sealing region 3009.

The second sealing region 3009 is provided closer to an outer portion of the light-emitting device 3000 than the first sealing region 3007 is. In the light-emitting device 3000, distortion due to external force or the like increases toward the outer portion. Thus, the outer portion of the light-emitting device 3000 where a larger amount of distortion is generated, that is, the second sealing region 3009 is sealed using the material containing a resin and the first sealing region 3007 provided on an inner side of the second sealing region 3009 is sealed using the material containing glass, whereby the light-emitting device 3000 is less likely to be damaged even when distortion due to external force or the like is generated.

Furthermore, as illustrated in FIG. 36B, a first region 3011 corresponds to the region surrounded by the substrate 3001, the substrate 3003, the first sealing region 3007, and the second sealing region 3009. A second region 3013 corresponds to the region surrounded by the substrate 3001, the substrate 3003, the light-emitting element 3005, and the first sealing region 3007.

The first region 3011 and the second region 3013 are preferably filled with, for example, an inert gas such as a rare gas or a nitrogen gas. Alternatively, the first region 3011 and the second region 3013 are preferably filled with a resin such as an acrylic resin or an epoxy resin. Note that for the first region 3011 and the second region 3013, a reduced pressure environment is preferred to an atmospheric pressure environment.

FIG. 36C illustrates a modification example of the structure in FIG. 36B. FIG. 36C is a cross-sectional view illustrating the modification example of the light-emitting device 3000.

FIG. 36C illustrates a structure in which a desiccant 3018 is provided in a recessed portion provided in part of the substrate 3003. The other components are the same as those of the structure illustrated in FIG. 36B.

As the desiccant 3018, a substance which adsorbs moisture and the like by chemical adsorption or a substance which adsorbs moisture and the like by physical adsorption can be used. Examples of the substance that can be used as the desiccant 3018 include alkali metal oxides, alkaline earth metal oxides (e.g., calcium oxide, barium oxide, and the like), sulfate, metal halides, perchlorate, zeolite, silica gel, and the like.

Next, modification examples of the light-emitting device 3000 which is illustrated in FIG. 36B will be described with reference to FIGS. 37A to 37D. Note that FIGS. 37A to 37D are cross-sectional views illustrating the modification examples of the light-emitting device 3000 illustrated in FIG. 36B.

In each of the light-emitting devices illustrated in FIGS. 37A to 37D, the second sealing region 3009 is not provided but only the first sealing region 3007 is provided. Moreover, in each of the light-emitting devices illustrated in FIGS. 37A to 37D, a region 3014 is provided instead of the second region 3013 illustrated in FIG. 36B.

For the region 3014, for example, polyester, polyolefin, polyamide (e.g., nylon, aramid), polyimide, polycarbonate, or an acrylic resin, polyurethane, or an epoxy resin can be used. Alternatively, a material that includes a resin having a siloxane bond, such as silicone, can be used.

When the above-described material is used for the region 3014, what is called a solid-sealing light-emitting device can be obtained.

In the light-emitting device illustrated in FIG. 37B, a substrate 3015 is provided on the substrate 3001 side of the light-emitting device illustrated in FIG. 37A.

The substrate 3015 has unevenness as illustrated in FIG. 37B. With a structure in which the substrate 3015 having unevenness is provided on the side through which light emitted from the light-emitting element 3005 is extracted, the efficiency of extraction of light from the light-emitting element 3005 can be improved. Note that instead of the structure having unevenness and illustrated in FIG. 37B, a substrate having a function as a diffusion plate may be provided.

In the light-emitting device illustrated in FIG. 37C, light is extracted through the substrate 3003 side, unlike in the light-emitting device illustrated in FIG. 37A, in which light is extracted through the substrate 3001 side.

The light-emitting device illustrated in FIG. 37C includes the substrate 3015 on the substrate 3003 side. The other components are the same as those of the light-emitting device illustrated in FIG. 37B.

In the light-emitting device illustrated in FIG. 37D, the substrate 3003 and the substrate 3015 included in the light-emitting device illustrated in FIG. 37C are not provided but a substrate 3016 is provided.

The substrate 3016 includes first unevenness positioned closer to the light-emitting element 3005 and second unevenness positioned farther from the light-emitting element 3005. With the structure illustrated in FIG. 37D, the efficiency of extraction of light from the light-emitting element 3005 can be further improved.

Thus, the use of the structure described in this embodiment can provide a light-emitting device in which deterioration of a light-emitting element due to impurities such as moisture and oxygen is suppressed. Alternatively, with the structure described in this embodiment, a light-emitting device having high light extraction efficiency can be obtained.

Note that the structure described in this embodiment can be combined as appropriate with any of the structures described in the other embodiments and the example.

### Embodiment 10

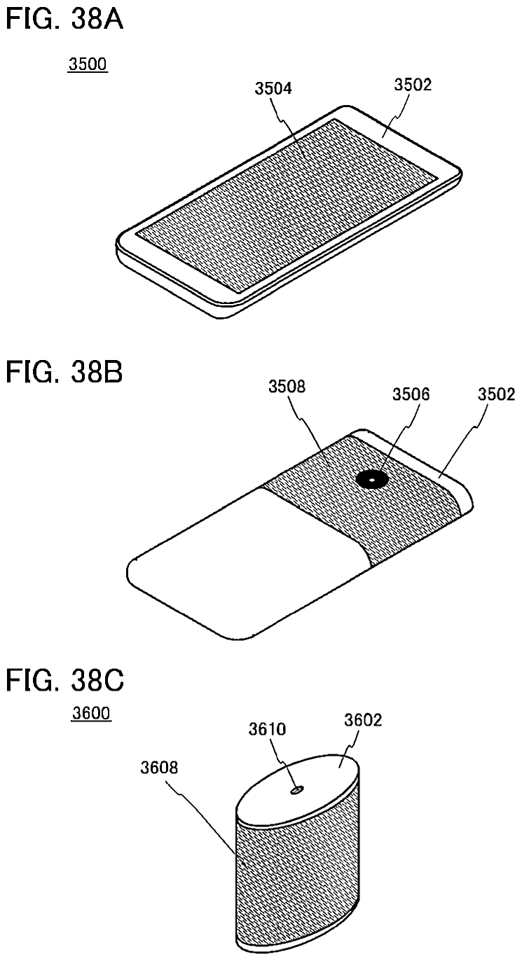

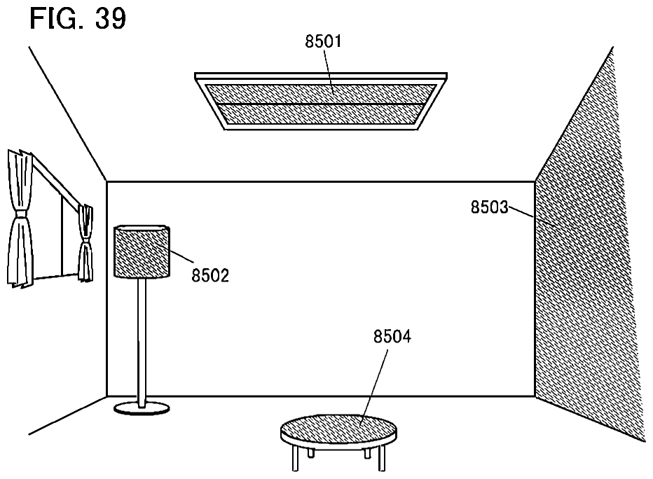

In this embodiment, examples in which the light-emitting element of one embodiment of the present invention is used for various lighting devices and electronic devices will be described with reference to FIGS. 38A to 39.

An electronic device or a lighting device that has a light-emitting region with a curved surface can be obtained with use of the light-emitting element of one embodiment of the present invention which is fabricated over a substrate having flexibility.

Furthermore, a light-emitting device to which one embodiment of the present invention is applied can also be used for lighting for motor vehicles, examples of which are lighting for a dashboard, a windshield, a ceiling, and the like.

FIG. 38A is a perspective view illustrating one surface of a multifunction terminal 3500, and FIG. 38B is a perspective view illustrating the other surface of the multifunction terminal 3500. In a housing 3502 of the multifunction terminal 3500, a display portion 3504, a camera 3506, lighting 3508, and the like are incorporated. The light-emitting device of one embodiment of the present invention can be used for the lighting 3508.

The lighting 3508 that includes the light-emitting device of one embodiment of the present invention functions as a planar light source. Thus, unlike a point light source typified by an LED, the lighting 3508 can provide light emission with low directivity. When the lighting 3508 and the camera 3506 are used in combination, for example, imaging can be performed by the camera 3506 with the lighting 3508 lighting or flashing. Because the lighting 3508 functions as a planar light source, a photograph as if taken under natural light can be taken.

Note that the multifunction terminal 3500 illustrated in FIGS. 38A and 38B can have a variety of functions as in the electronic devices illustrated in FIGS. 31A to 31G.

The housing 3502 can include a speaker, a sensor (a sensor having a function of measuring or sensing force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone, and the like. When a detection device including a sensor for detecting inclination, such as a gyroscope sensor or an acceleration sensor, is provided inside the multifunction terminal 3500, display on the screen of the display portion 3504 can be automatically switched by determining the orientation of the multifunction terminal 3500 (whether the multifunction terminal is placed horizontally or vertically for a landscape mode or a portrait mode).

The display portion 3504 may function as an image sensor. For example, an image of a palm print, a fingerprint, or the like is taken when the display portion 3504 is touched with the palm or the finger, whereby personal authentication can be performed. Furthermore, by providing a backlight or a sensing light source which emits near-infrared light in the display portion 3504, an image of a finger vein, a palm vein, or the like can be taken. Note that the light-emitting device of one embodiment of the present invention may be used for the display portion 3504.

FIG. 38C is a perspective view of a security light 3600. The light 3600 includes lighting 3608 on the outside of the housing 3602, and a speaker 3610 and the like are incorporated in the housing 3602. The light-emitting device of one embodiment of the present invention can be used for the lighting 3608.

The light 3600 emits light when the lighting 3608 is gripped or held, for example. An electronic circuit that can control the manner of light emission from the light 3600 may be provided in the housing 3602. The electronic circuit may be a circuit that enables light emission once or intermittently a plurality of times or may be a circuit that can adjust the amount of emitted light by controlling the current value for light emission. A circuit with which a loud audible alarm is output from the speaker 3610 at the same time as light emission from the lighting 3608 may be incorporated.

The light 3600 can emit light in various directions; therefore, it is possible to intimidate a thug or the like with light, or light and sound. Moreover, the light 3600 may include a camera such as a digital still camera to have a photography function.

FIG. 39 illustrates an example in which the light-emitting element is used for an indoor lighting device 8501. Since the light-emitting element can have a larger area, alighting device having a large area can also be formed. In addition, a lighting device 8502 in which a light-emitting region has a curved surface can also be formed with use of a housing with a curved surface. A light-emitting element described in this embodiment is in the form of a thin film, which allows the housing to be designed more freely. Therefore, the lighting device can be elaborately designed in a variety of ways. Furthermore, a wall of the room may be provided with a large-sized lighting device 8503. Touch sensors may be provided in the lighting devices 8501, 8502, and 8503 to control the power on/off of the lighting devices.

Moreover, when the light-emitting element is used on the surface side of a table, a lighting device 8504 which has a function as a table can be obtained. When the light-emitting element is used as part of other furniture, a lighting device which has a function as the furniture can be obtained.

As described above, lighting devices and electronic devices can be obtained by application of the light-emitting device of one embodiment of the present invention. Note that the light-emitting device can be used for electronic devices in a variety of fields without being limited to the lighting devices and the electronic devices described in this embodiment.

The structure described in this embodiment can be combined with any of the structures described in the other embodiments and the example as appropriate.

### EXAMPLE

In this example, fabrication examples of light-emitting elements of embodiments of the present invention and the characteristics of the light-emitting elements will be described. The structure of each of the light-emitting elements fabricated in this example is the same as that illustrated in FIG. 1A. Table 1 shows the detailed element structure. In addition, the structures and abbreviations of compounds used here are shown below.

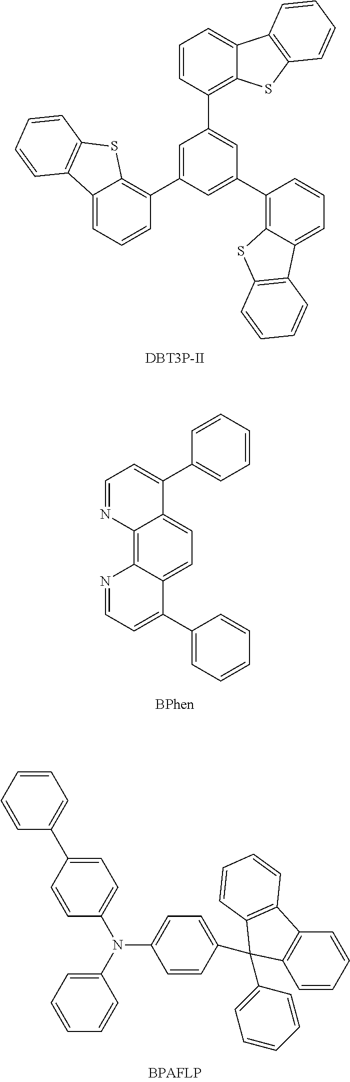 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-c2ccnc3c2ccc2c(-c4ccccc4)ccnc23)cc1 ; c1ccc(-c2ccc(N(c3ccccc3)c3ccc(C4(c5ccccc5)c5ccccc5-c5ccccc54)cc3)cc2)cc1]

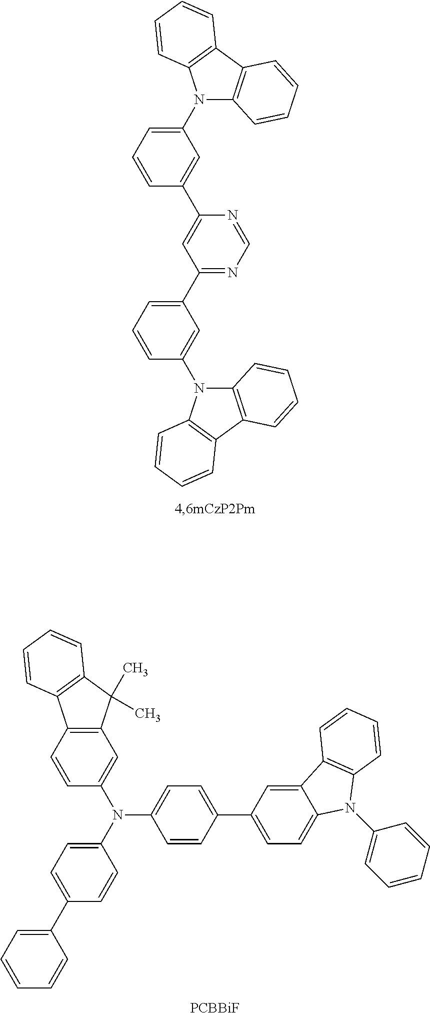 [SMILES: c1cc(-c2cc(-c3cccc(-n4c5ccccc5c5ccccc54)c3)ncn2)cc(-n2c3ccccc3c3ccccc32)c1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; "PCBBiF"]

TABLE 1

| | | Reference | Thickness | | Weight |
|---|---|---|---|---|---|
| | Layer | numeral | (nm) | Material | ratio |
| Light- | Electrode | 402 | 200 | Al | — |
| emitting | Electron-injection layer | 419 | 1 | LiF | — |
| element 1 | Electron-transport layer | 418(2) | 10 | BPhen | — |
| | | 418(1) | 20 | 4,6mCzP2Pm | — |
| | Light-emitting layer | 430 | 40 | 4,6mCzP2Pm:PCBBiF | 0.8:0.2 |
| | Hole-transport layer | 412 | 20 | BPAFLP | — |
| | Hole-injection layer | 411 | 60 | DBT3P-II:MoO₃ | 1:0.5 |
| | Electrode | 401 | 70 | ITSO | — |

### <Fabrication of Light-Emitting Element 1>

A method for fabricating a light-emitting element fabricated in this example will be described below.

As the electrode 401, an ITSO film was formed to a thickness of 70 nm over a glass substrate. The electrode area of the electrode 401 was set to 4 mm² (2 mm×2 mm).

As the hole-injection layer 411, DBT3P-II and molybdenum oxide (MoO₃) were deposited over the electrode 401 by co-evaporation at a weight ratio of 1:0.5 (DBT3P-II: MoO₃) to a thickness of 60 nm.

As the hole-transport layer 412, BPAFLP was deposited over the hole-injection layer 411 by evaporation to a thickness of 20 nm.

Next, as the light-emitting layer 430, 4,6mCzP2Pm and PCBBiF were deposited over the hole-transport layer 412 by co-evaporation at a weight ratio of 0.8:0.2 (4,6mCzP2Pm: PCBBiF) to a thickness of 40 nm. In Light-emitting element 1, 4,6mCzP2Pm and PCBBiF are referred to as the first organic compound and a second organic compound, respectively.

As the electron-transport layer 418, 4,6mCzP2Pm and BPhen were sequentially deposited by evaporation to thicknesses of 20 nm and 10 nm, respectively, over the light-emitting layer 430. Then, as the electron-injection layer 419, LiF was deposited over the electron-transport layer 418 by evaporation to a thickness of 1 nm.

As the electrode 402, aluminum (Al) was deposited over the electron-injection layer 419 to a thickness of 200 nm.

Next, in a glove box containing a nitrogen atmosphere, Light-emitting element 1 was sealed by fixing a glass substrate for sealing to a glass substrate on which the organic materials were deposited using a sealant for an organic EL device. Specifically, after the sealant was applied to surround the organic materials deposited on the glass substrate and these glass substrates were bonded to each other, irradiation with ultraviolet light having a wavelength of 365 nm at 6 J/cm² and heat treatment at 80° C. for one hour were performed. Through the above process, the light-emitting element 1 was obtained.

### <Characteristics of Light-Emitting Element 1>

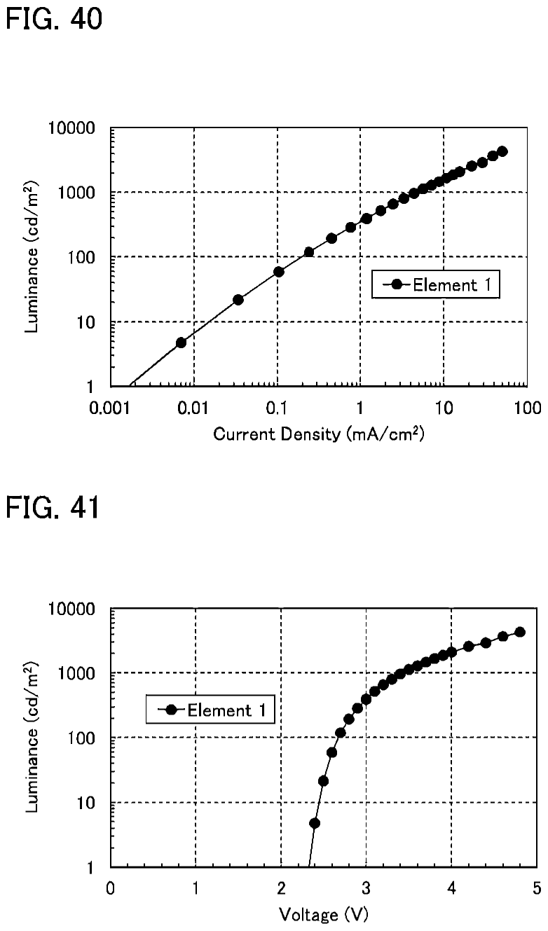

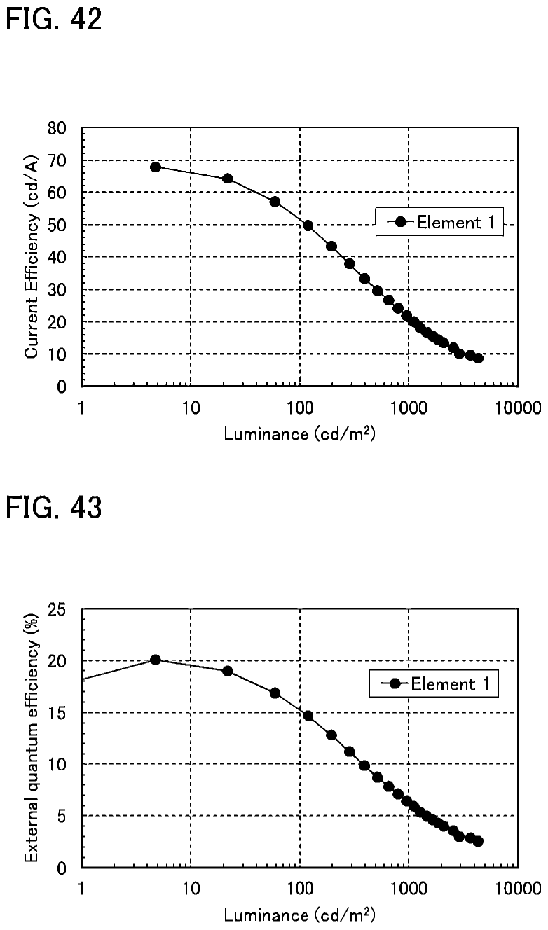

FIG. 40 shows the luminance-current density characteristics of fabricated Light-emitting element 1. FIG. 41 shows the luminance-voltage characteristics. FIG. 42 shows the current efficiency-luminance characteristics. FIG. 43 shows the external quantum efficiency-luminance characteristics. The measurement of the light-emitting elements was performed at room temperature (in an atmosphere kept at 23° C.).

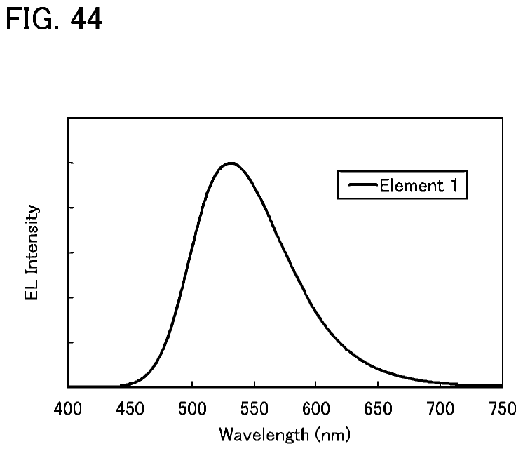

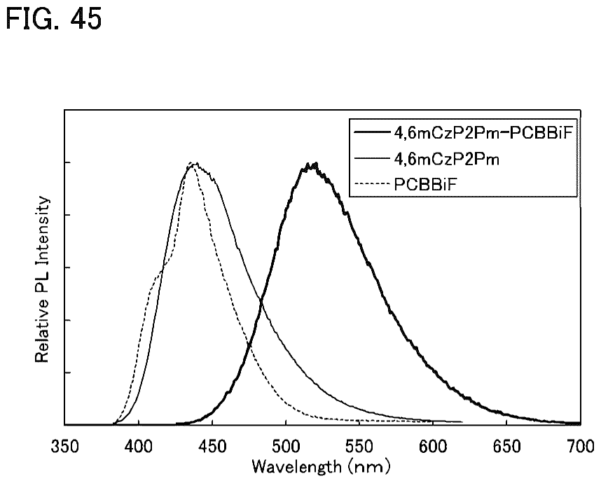

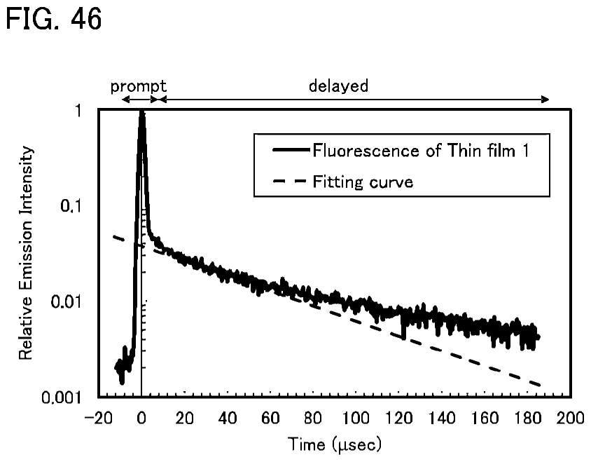

FIG. 44 shows the electroluminescence spectrum when a current at a current density of 2.5 mA/cm² is supplied to Light-emitting element 1.

Table 2 shows the element characteristics of Light-emitting element 1 at maximum current efficiency. The external quantum efficiency in this example was calculated under assumption of a perfectly diffusing surface (also referred to as Lambertian surface).

TABLE 2

| | | | | | | | External |
|---|---|---|---|---|---|---|---|
| | | Current | CIE | | Current | Power | quantum |
| | Voltage | density | chromaticity | Luminance | efficiency | efficiency | efficiency |
| | (V) | (mA/cm²) | (x, y) | (cd/m²) | (cd/A) | (lm/W) | (%) |
| Light-emitting | 2.40 | 0.00702 | (0.34, 0.59) | 4.8 | 67.9 | 88.9 | 20.1 |
| element 1 | | | | | | | |

As shown in FIG. 44, Light-emitting element 1 emits green light. The electroluminescence spectrum of Light-emitting element 1 has a peak at a wavelength of 530 nm. As described later, 4,6mCzP2Pm and PCBBiF used for the light-emitting layer of Light-emitting element 1 are each a compound that emits deep blue light, and emission energy calculated from the electroluminescence spectrum of Light-emitting element 1 substantially corresponds to the energy difference between the LUMO level of 4,6mCzP2Pm and the HOMO level of PCBBiF. Thus, it can be said that Light-emitting element 1 is a light-emitting element that emits light from an exciplex formed by 4,6mCzP2Pm as the first organic compound and PCBBiF as the second organic compound.

As shown in FIG. 40 to FIG. 43 and Table 2, the maximum external quantum efficiency of Light-emitting element 1 is greater than 20%.

Since the probability of formation of singlet excitons which are generated by recombination of carriers (holes and electrons) injected from the pair of electrodes is at most 25%, the external quantum efficiency in the case where the efficiency of light extraction to the outside is 20% is at most 5%. Light-emitting element 1 has external quantum efficiency of more than 5%. This is because Light-emitting element 1 emits, in addition to light originating from singlet excitons generated by recombination of carriers (holes and electrons) injected from the pair of electrodes, light originating from singlet excitons generated from triplet excitons by reverse intersystem crossing. These results also imply that Light-emitting element 1 is a light-emitting element that emits light from the exciplex.

Light-emitting element 1 is driven with a low driving voltage and the light emission start voltage (a voltage at which the luminance exceeds 1 cd/m²) is 2.4 V. The light emission start voltage is lower than the voltage corresponding to the energy difference between the LUMO level and the HOMO level of 4,6mCzP2Pm, lower than the voltage corresponding to the energy difference between the LUMO level and the HOMO level of PCBBiF, and substantially equal to the voltage corresponding to the energy difference between the LUMO level of 4,6mCzP2Pm and the HOMO level of PCBBiF. Thus, the use of compounds that form an exciplex for the light-emitting layer enables fabrication of a light-emitting element with a low driving voltage.

### <Fabrication of Thin-Film Samples>

For the emission spectrum measurement of the compounds used for the light-emitting layer, thin film samples were formed over a quartz substrate by a vacuum evaporation method.

To obtain Thin-film sample 1, 4,6mCzP2Pm and PCBBiF were deposited by co-evaporation such that the deposited film has a weight ratio of 4,6mCzP2Pm to PCBBiF of 0.8:0.2 and a thickness of 50 nm.

To obtain Thin-film sample 2, 4,6mCzP2Pm was deposited by evaporation such that the deposited film has a thickness of 50 nm.

To obtain Thin-film sample 3, PCBBiF was deposited by evaporation such that the deposited film has a thickness of 50 nm.

### <Measurement of Emission Spectra>

The emission spectra were measured at room temperature (in an atmosphere kept at 23° C.) with a PL-EL measurement apparatus (produced by Hamamatsu Photonics K.K.). FIG. 45 shows the measurement results of emission spectra.

As shown in FIG. 45, the emission spectra of Thin film 2 (4,6mCzP2Pm) and Thin film 3 (PCBBiF) have peaks at wavelengths of 439 nm and 436 nm, respectively. In addition, the emission spectrum of Thin film 1 (a mixed film of 4,6mCzP2Pm and PCBBiF) has a peak at a wavelength of 520 nm. Thus, the emission spectrum of Thin film 1 is different from the emission spectra of Thin film 2 (4,6mCzP2Pm) and Thin film 3 (PCBBiF). As described later, the LUMO level of 4,6mCzP2Pm is lower than that of PCBBiF, and the HOMO level of PCBBiF is higher than that of 4,6mCzP2Pm. The energy of light emission from Thin film 1, which is the mixed film of 4,6mCzP2Pm and PCBBiF, approximately corresponds to the energy difference between the LUMO level of 4,6mCzP2Pm and the HOMO level of PCBBiF. The light emission from Thin film 1 has a longer wavelength (lower energy) than light emission from Thin film 2 (4,6mCzP2Pm) and light emission from Thin film 3 (PCBBiF). Therefore, it can be said that the light emission from Thin film 1 is light emission from an exciplex formed by both the compounds. That is, 4,6mCzP2Pm and PCBBiF are compounds which form an exciplex.

### <Time-Resolved Fluorescence Measurement of Thin-Film Samples>

Next, the lifetime of light emission from each of the thin films described above was measured. A picosecond fluorescence lifetime measurement system (manufactured by Hamamatsu Photonics K.K.) was used for the measurement. The thin film was irradiated with pulsed laser, and emission of the thin film which attenuated from the laser irradiation underwent time-resolved measurement using a streak camera. A nitrogen gas laser with a wavelength of 337 nm was used as the pulsed laser. The thin film was irradiated with pulsed laser with a pulse width of 500 μs at a repetition rate of 10 Hz. By integrating data obtained by the repeated measurement, data with a high S/N ratio was obtained. The measurement was performed at room temperature (in an atmosphere kept at 23° C.).

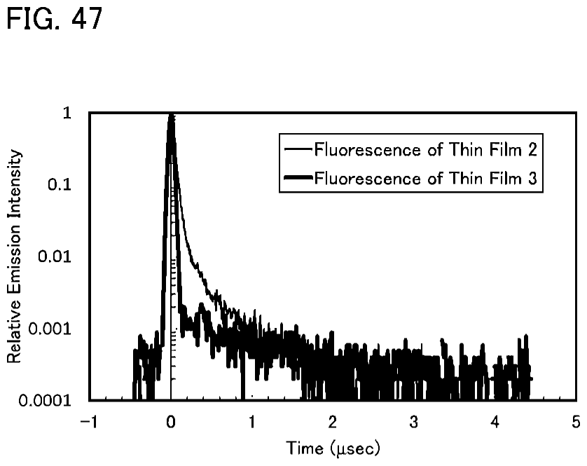

FIG. 46 shows the result of time-resolved fluorescence measurement of Thin film 1, and FIG. 47 shows the results of time-resolved fluorescence measurement of Thin film 2 and Thin film 3. In FIGS. 46 and 47, the vertical axis represents emission intensity normalized by the value at the time of pulsed laser irradiation. The horizontal axis represents time elapsed after the stop of the pulsed laser irradiation.

The attenuation curve shown in FIG. 46 was fitted with Formula 4.

$$\begin{matrix}[ Formula 4 ] & \\ L = {\sum }_{n = 1} {A}_{n} exp ( - \frac{t}{{a}_{n}} ) & ( 4 )\end{matrix}$$

In Formula 4, L and t represent normalized emission intensity and elapsed time, respectively. Fitting of the attenuation curve suggests that n is 1 or 2. These fitting results show that the emission components of Thin film 1 include an early fluorescent component having a fluorescence lifetime of 0.72 μs (also referred to as a prompt component) and a delayed fluorescent component having a fluorescence lifetime of 55 μs (also referred to as a delayed component). In addition, the ratio of the delayed fluorescent component in light from Thin film 1 was calculated to be 3.8%.

In contrast, as shown in the attenuation curves of Thin films 2 and 3 of FIG. 47, most of the emission components show a single-exponential decay and the early fluorescent component having short fluorescence lifetimes of approximately ten to several tens of nanoseconds is dominant. That is, the proportions of the delayed fluorescent components in Thin films 2 and 3 are lower than 1%, and substantially no delayed fluorescence is generated.

Note that an exciplex has a feature of having the S1 level and the T1 level that are close to each other. The delayed fluorescent component observed in Thin film 1 is caused by thermally activated delayed fluorescence due to intersystem crossing and reverse intersystem crossing between a singlet excited state and a triplet excited state of the exciplex. Observation of the delayed fluorescence emitted by Thin film 1 including two compounds shows that Thin film 1 includes compounds that form an exciplex.

### <Measurement of T1 Level>

Next, to obtain the T1 levels of the compounds used in the light-emitting layer 430 of Light-emitting element 1, the emission spectra of fabricated Thin films 2 and 3 were measured at a low temperature (10 K).

The measurement was performed at a measurement temperature of 10 K with a PL microscope, LabRAM HR-PL, produced by HORIBA, Ltd., a He—Cd laser having a wavelength of 325 nm as excitation light, and a CCD detector.

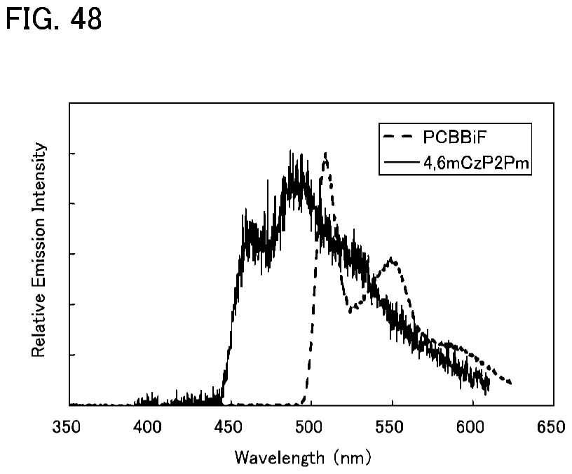

In the measurement method of the emission spectra, in addition to the normal measurement of emission spectra, the measurement of time-resolved emission spectra focusing on light emission with a long lifetime was also performed. Since in this measurement method of emission spectra, the measurement temperature was set at a low temperature (10K), in the normal measurement of emission spectra, in addition to fluorescence, which is the main emission component, phosphorescence was observed. Furthermore, in the measurement of time-resolved emission spectra focusing on light emission with a long lifetime, phosphorescence was mainly observed. FIG. 48 shows the time-resolved spectra of Thin films 2 and 3 measured at low temperature.

As shown in the measurement results of the emission spectra, the emission spectrum of 4,6mCzP2Pm has a peak (including a shoulder) of the fluorescent component on the shortest wavelength side at 459 nm, and the emission spectrum of PCBBiF has a peak (including a shoulder) of the phosphorescent component on the shortest wavelength side at 509 nm.

Thus, from the peak wavelengths, the T1 level of 4,6mCzP2Pm and the T1 level of PCBBiF were calculated to be 2.70 eV and 2.44 eV, respectively.

It is found from the above measurement results that the lower of the T1 level of 4,6mCzP2Pm and the T1 level of PCBBiF (i.e., the T1 level of PCBBiF (2.44 eV)) has energy that is larger than the emission energy (2.34 eV) by −0.2 eV or more and 0.4 eV or less, in the electroluminescence spectrum of Light-emitting element 1 in FIG. 44. This indicates that Light-emitting element 1 is a light-emitting element including compounds that form an exciplex capable of emitting light efficiently.

### <Results of CV Measurement>

The electrochemical characteristics (oxidation reaction characteristics and reduction reaction characteristics) of the above compounds were measured by cyclic voltammetry (CV) measurement. Note that for the measurement, an electrochemical analyzer (ALS model 600A or 600C, produced by BAS Inc.) was used, and measurement was performed on a solution obtained by dissolving each compound in N,N-dimethylformamide (abbreviation: DMF). In the measurement, the potential of a working electrode with respect to the reference electrode was changed within an appropriate range, so that the oxidation peak potential and the reduction peak potential were obtained. In addition, the HOMO and LUMO levels of each compound were calculated from the estimated redox potential of the reference electrode of −4.94 eV and the obtained peak potentials.

According to the CV measurement results, the oxidation potential and the reduction potential of 4,6mCzP2Pm are 0.95 V and −2.06 V, respectively. In addition, the HOMO level and the LUMO level of 4,6mCzP2Pm, which were calculated from the CV measurement results, are −5.89 eV and −2.88 eV, respectively. Thus, the LUMO level of 4,6mCzP2Pm is lower. The oxidation potential of PCBBiF is 0.42 V, and the reduction potential was −2.94 V. In addition, the HOMO level and the LUMO level of PCBBiF, which were calculated from the CV measurement results, are −5.36 eV and −2.00 eV, respectively. Thus, the HOMO level of PCBBiF is higher.

As described above, the LUMO level of 4,6mCzP2Pm is lower than that of PCBBiF, and the HOMO level of 4,6mCzP2Pm is lower than that of PCBBiF. Thus, in the case where the compounds are used in a light-emitting layer as in Light-emitting element 1, electrons and holes serving as carriers are efficiently injected from a pair of electrodes into 4,6mCzP2Pm and PCBBiF, respectively, so that 4,6mCzP2Pm and PCBBiF can form an exciplex.

The exciplex formed by 4,6mCzP2Pm and PCBBiF has the LUMO level in 4,6mCzP2Pm and the HOMO level in PCBBiF. The energy difference between the LUMO level and the HOMO level of the exciplex is 2.48 eV This value is substantially equal to emission energy calculated from the peak wavelength of the emission spectrum of Thin film 1 in FIG. 45 (2.38 eV) and emission energy calculated from the peak wavelength of the electroluminescence spectrum of Light-emitting element 1 in FIG. 44 (2.34 eV). These results imply that the emission spectrum in FIG. 45 and the electroluminescence spectrum in FIG. 44 exhibit emission due to the exciplex formed by 4,6mCzP2Pm and PCBBiF.

The energy difference between the LUMO level of 4,6mCzP2Pm and the HOMO level of PCBBiF (2.48 eV) is greater than the emission energy (2.34 eV) by −0.1 eV or more and 0.4 eV or less, in the electroluminescence spectrum of Light-emitting element 1 in FIG. 44. This indicates that Light-emitting element 1 is a light-emitting element including compounds that form an exciplex capable of emitting light efficiently.

### <Fabrication of Light-Emitting Elements 2 to 282>

Next, the structures and fabricating methods of Light-emitting elements 2 to 282 will be described below. Note that Light-emitting elements 2 to 282 are different from Light-emitting element 1 mainly in materials for the light-emitting layer 430 and the electron-transport layer 418, and regarding other steps, the fabricating methods for Light-emitting elements 2 to 282 are similar to the fabricating method of Light-emitting element 1. Thus, the details of the fabricating methods for Light-emitting elements 2 to 282 will not be described here. Tables 3 to 7 list the details of the element structures of Light-emitting elements 1 to 282. In addition, the structures and abbreviations of compounds used here are shown below. Note that in Tables 3 to 7, materials and structures of portions which are the same as those of the portions of Light-emitting element 1 are not shown. An ITSO film with a thickness of 110 nm was used for the electrode 401 of Light-emitting elements 2 to 198, and an ITSO film with a thickness of 70 nm was used for the electrode 401 of Light-emitting elements 199 to 282.

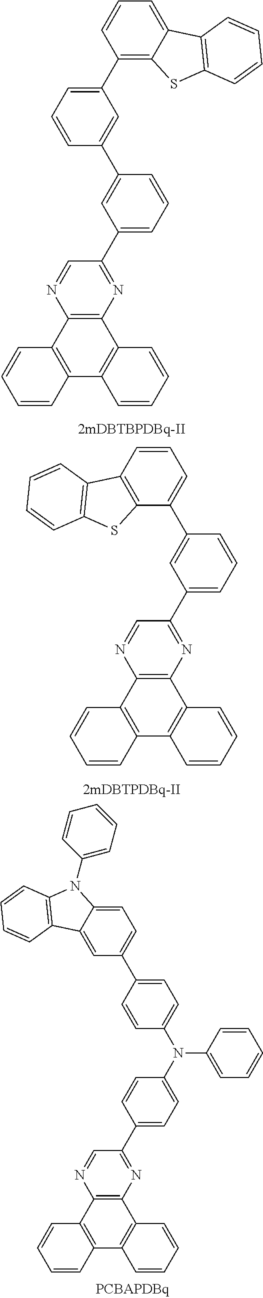

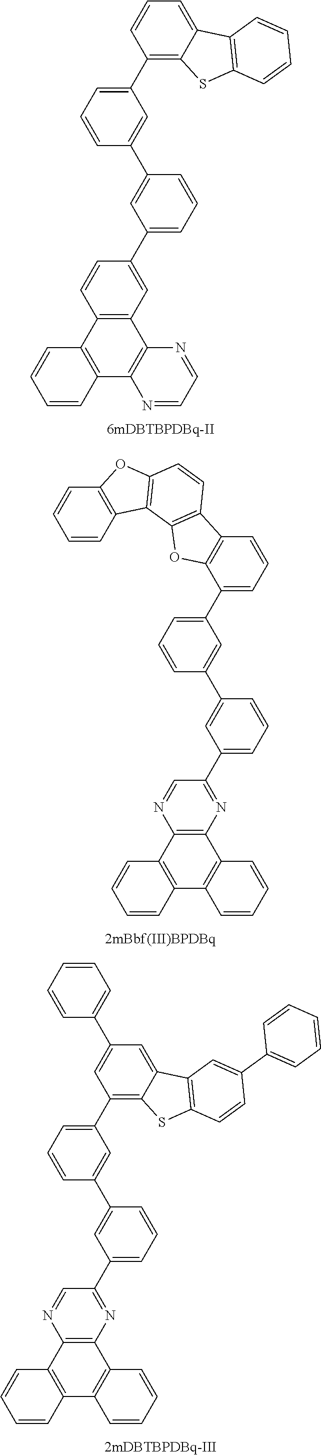 [SMILES: c1cc(-c2cccc(-c3cccc4c3sc3ccccc34)c2)cc(-c2ccc3c4ccccc4c4nccnc4c3c2)c1 ; c1cc(-c2cccc(-c3cccc4c3oc3c4ccc4oc5ccccc5c43)c2)cc(-c2cnc3c4ccccc4c4ccccc4c3n2)c1 ; c1ccc(-c2ccc3sc4c(-c5cccc(-c6cccc(-c7cnc8c9ccccc9c9ccccc9c8n7)c6)c5)cc(-c5ccccc5)cc4c3c2)cc1]

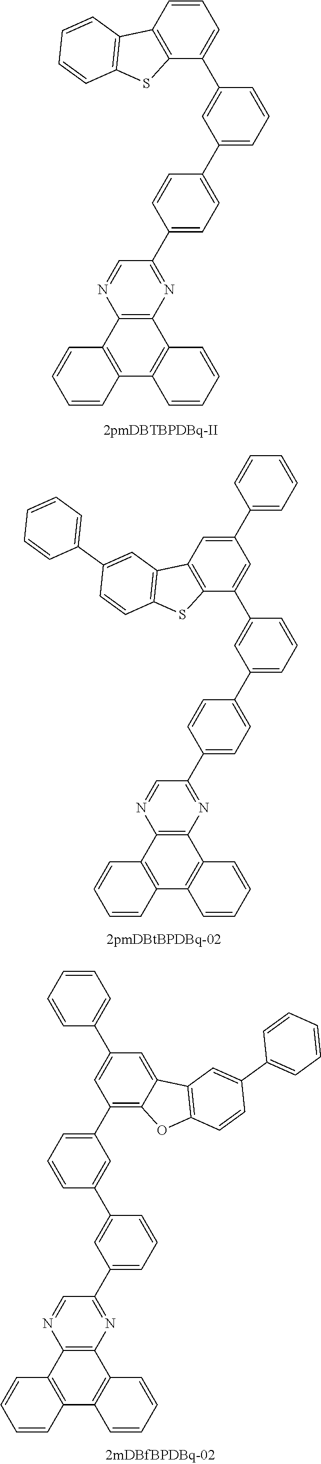 [SMILES: c1cc(-c2ccc(-c3cnc4c5ccccc5c5ccccc5c4n3)cc2)cc(-c2cccc3c2sc2ccccc23)c1 ; c1ccc(-c2ccc3sc4c(-c5cccc(-c6ccc(-c7cnc8c9ccccc9c9ccccc9c8n7)cc6)c5)cc(-c5ccccc5)cc4c3c2)cc1 ; c1ccc(-c2ccc3oc4c(-c5cccc(-c6cccc(-c7cnc8c9ccccc9c9ccccc9c8n7)c6)c5)cc(-c5ccccc5)cc4c3c2)cc1]

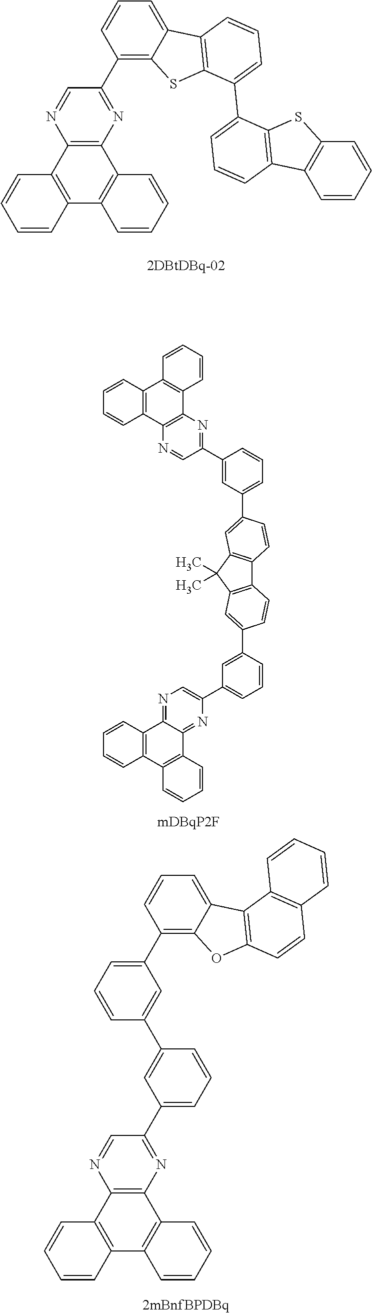 [SMILES: c1ccc2c(c1)sc1c(-c3cccc4c3sc3c(-c5cnc6c7ccccc7c7ccccc7c6n5)cccc34)cccc12 ; CC1(C)c2cc(-c3cccc(-c4cnc5c6ccccc6c6ccccc6c5n4)c3)ccc2-c2ccc(-c3cccc(-c4cnc5c6ccccc6c6ccccc6c5n4)c3)cc21 ; c1cc(-c2cccc(-c3cccc4c3oc3ccc5ccccc5c34)c2)cc(-c2cnc3c4ccccc4c4ccccc4c3n2)c1]

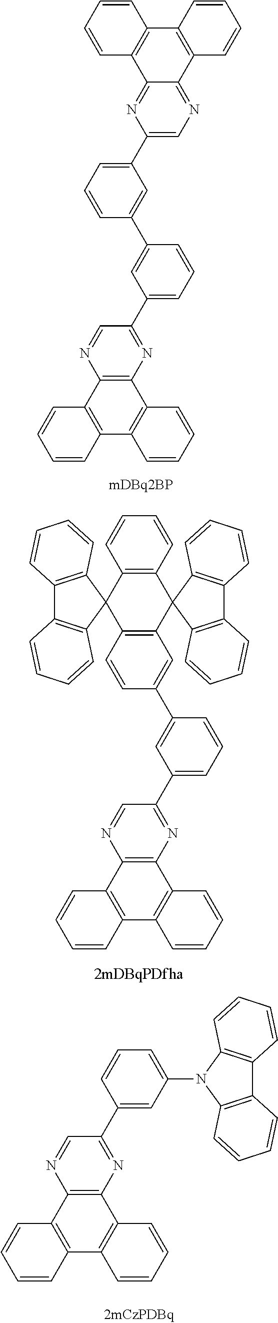 [SMILES: c1cc(-c2cccc(-c3cnc4c5ccccc5c5ccccc5c4n3)c2)cc(-c2cnc3c4ccccc4c4ccccc4c3n2)c1 ; c1cc(-c2ccc3c(c2)C2(c4ccccc4-c4ccccc42)c2ccccc2C32c3ccccc3-c3ccccc32)cc(-c2cnc3c4ccccc4c4ccccc4c3n2)c1 ; c1cc(-c2cnc3c4ccccc4c4ccccc4c3n2)cc(-n2c3ccccc3c3ccccc32)c1]

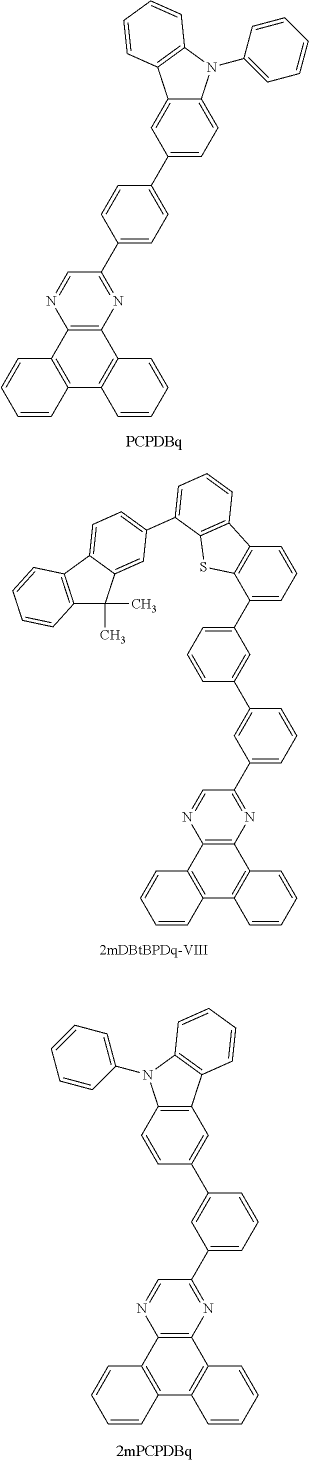 [SMILES: c1ccc(-n2c3ccccc3c3cc(-c4ccc(-c5cnc6c7ccccc7c7ccccc7c6n5)cc4)ccc32)cc1 ; CC1(C)c2ccccc2-c2ccc(-c3cccc4c3sc3c(-c5cccc(-c6cccc(-c7cnc8c9ccccc9c9ccccc9c8n7)c6)c5)cccc34)cc21 ; c1ccc(-n2c3ccccc3c3cc(-c4cccc(-c5cnc6c7ccccc7c7ccccc7c6n5)c4)ccc32)cc1]

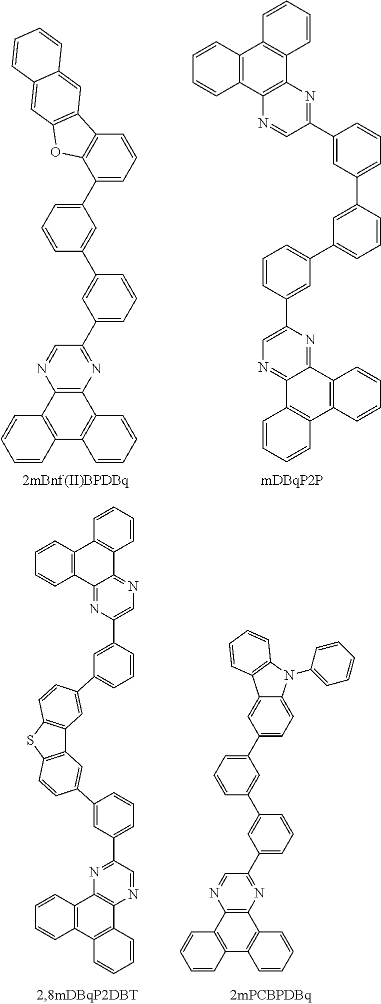 [SMILES: c1cc(-c2cccc(-c3cccc4c3oc3cc5ccccc5cc34)c2)cc(-c2cnc3c4ccccc4c4ccccc4c3n2)c1 ; c1cc(-c2cccc(-c3cnc4c5ccccc5c5ccccc5c4n3)c2)cc(-c2cccc(-c3cnc4c5ccccc5c5ccccc5c4n3)c2)c1 ; c1cc(-c2ccc3sc4ccc(-c5cccc(-c6cnc7c8ccccc8c8ccccc8c7n6)c5)cc4c3c2)cc(-c2cnc3c4ccccc4c4ccccc4c3n2)c1 ; c1ccc(-n2c3ccccc3c3cc(-c4cccc(-c5cccc(-c6cnc7c8ccccc8c8ccccc8c7n6)c5)c4)ccc32)cc1]

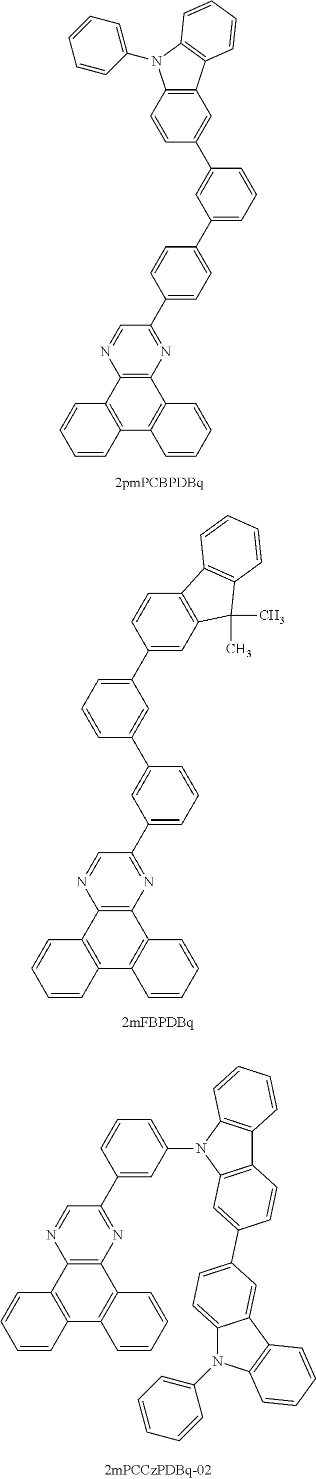 [SMILES: c1ccc(-n2c3ccccc3c3cc(-c4cccc(-c5ccc(-c6cnc7c8ccccc8c8ccccc8c7n6)cc5)c4)ccc32)cc1 ; CC1(C)c2ccccc2-c2ccc(-c3cccc(-c4cccc(-c5cnc6c7ccccc7c7ccccc7c6n5)c4)c3)cc21 ; c1ccc(-n2c3ccccc3c3cc(-c4ccc5c6ccccc6n(-c6cccc(-c7cnc8c9ccccc9c9ccccc9c8n7)c6)c5c4)ccc32)cc1]

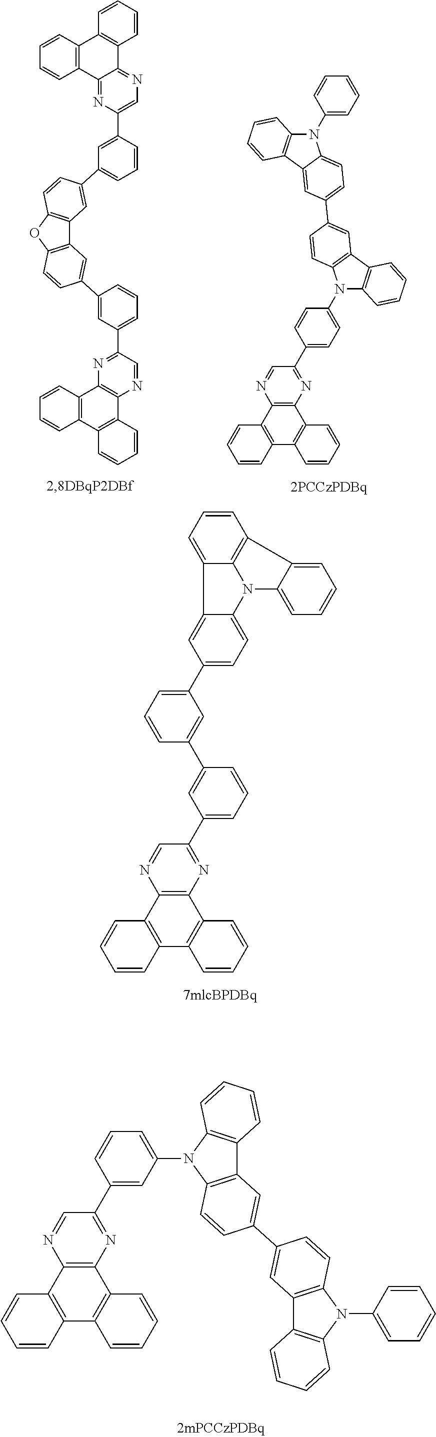 [SMILES: c1cc(-c2ccc3oc4ccc(-c5cccc(-c6cnc7c8ccccc8c8ccccc8c7n6)c5)cc4c3c2)cc(-c2cnc3c4ccccc4c4ccccc4c3n2)c1 ; c1ccc(-n2c3ccccc3c3cc(-c4ccc5c(c4)c4ccccc4n5-c4ccc(-c5cnc6c7ccccc7c7ccccc7c6n5)cc4)ccc32)cc1 ; c1cc(-c2cccc(-c3cnc4c5ccccc5c5ccccc5c4n3)c2)cc(-c2ccc3c(c2)c2cccc4c5ccccc5n3c42)c1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1]

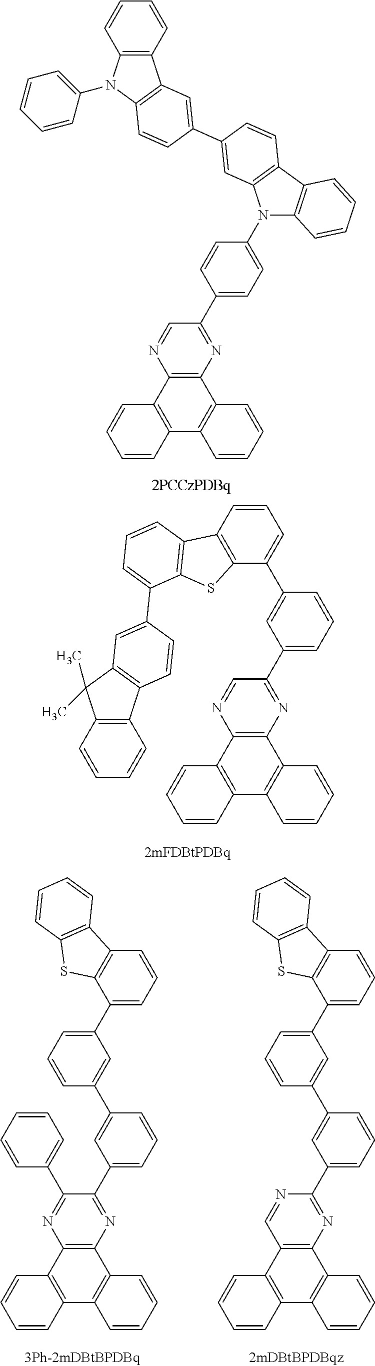 [SMILES: c1ccc(-n2c3ccccc3c3cc(-c4ccc5c6ccccc6n(-c6ccc(-c7cnc8c9ccccc9c9ccccc9c8n7)cc6)c5c4)ccc32)cc1 ; CC1(C)c2ccccc2-c2ccc(-c3cccc4c3sc3c(-c5cccc(-c6cnc7c8ccccc8c8ccccc8c7n6)c5)cccc34)cc21 ; c1ccc(-c2nc3c4ccccc4c4ccccc4c3nc2-c2cccc(-c3cccc(-c4cccc5c4sc4ccccc45)c3)c2)cc1 ; c1cc(-c2cccc(-c3cccc4c3sc3ccccc34)c2)cc(-c2ncc3c4ccccc4c4ccccc4c3n2)c1]

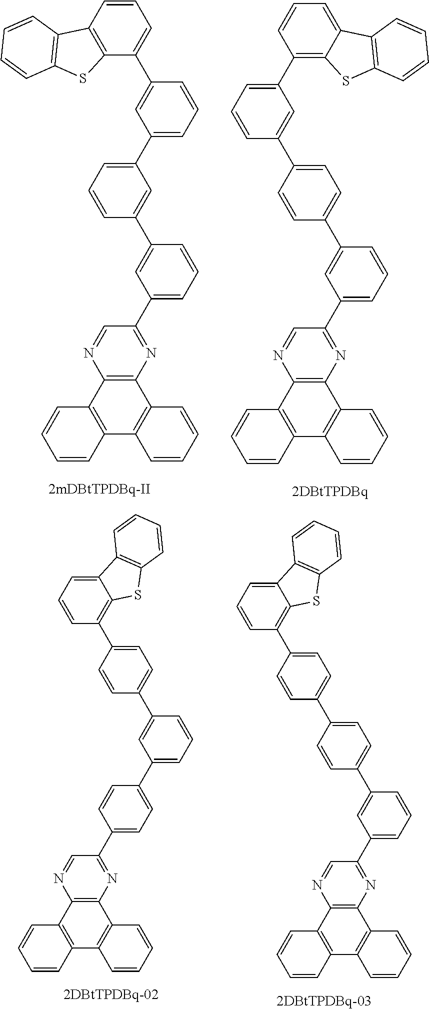

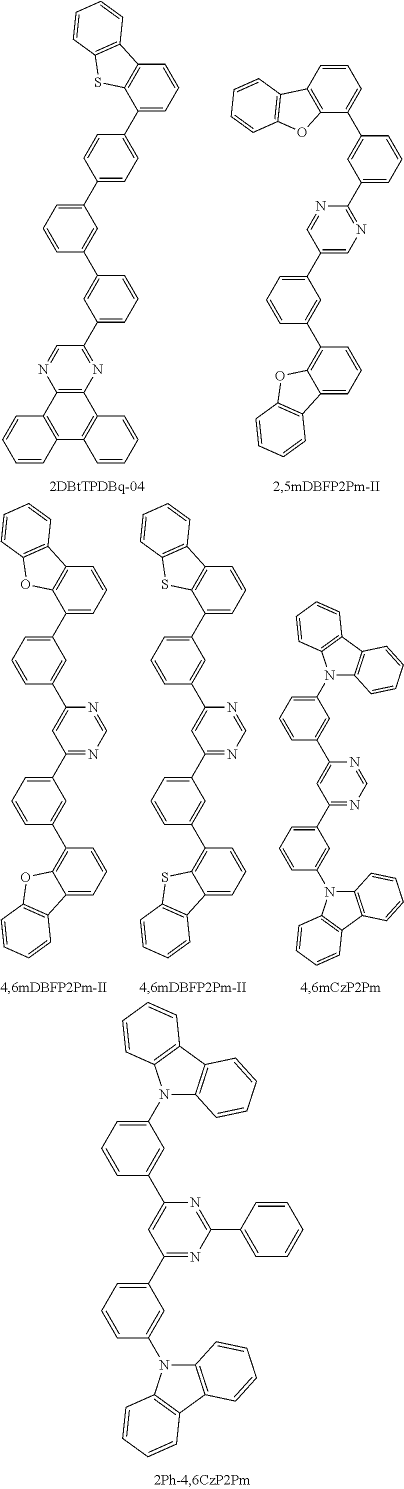

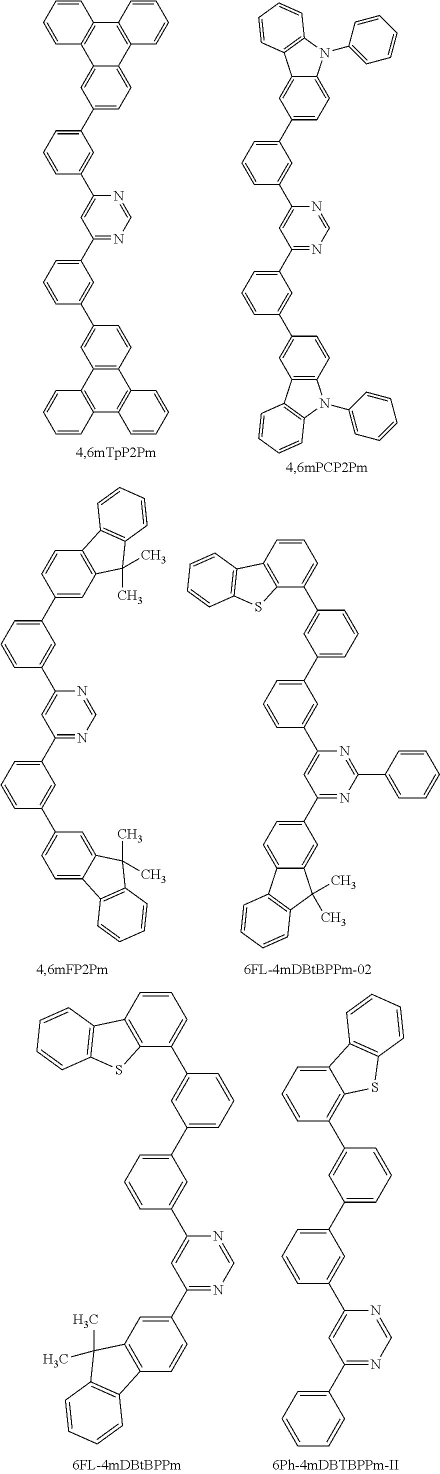

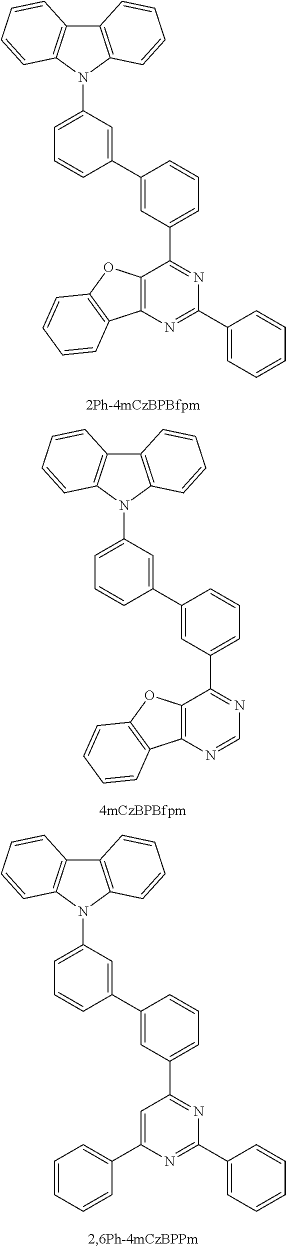 [SMILES: c1ccc(-c2nc(-c3cccc(-c4cccc(-n5c6ccccc6c6ccccc65)c4)c3)c3oc4ccccc4c3n2)cc1 ; c1cc(-c2cccc(-n3c4ccccc4c4ccccc43)c2)cc(-c2ncnc3c2oc2ccccc23)c1 ; c1ccc(-c2cc(-c3cccc(-c4cccc(-n5c6ccccc6c6ccccc65)c4)c3)nc(-c3ccccc3)n2)cc1]

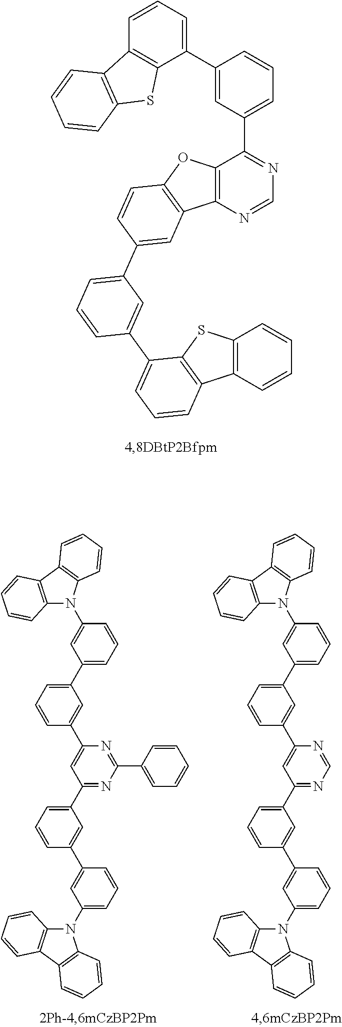 [SMILES: c1cc(-c2ccc3oc4c(-c5cccc(-c6cccc7c6sc6ccccc67)c5)ncnc4c3c2)cc(-c2cccc3c2sc2ccccc23)c1 ; c1ccc(-c2nc(-c3cccc(-c4cccc(-n5c6ccccc6c6ccccc65)c4)c3)cc(-c3cccc(-c4cccc(-n5c6ccccc6c6ccccc65)c4)c3)n2)cc1 ; c1cc(-c2cccc(-n3c4ccccc4c4ccccc43)c2)cc(-c2cc(-c3cccc(-c4cccc(-n5c6ccccc6c6ccccc65)c4)c3)ncn2)c1]

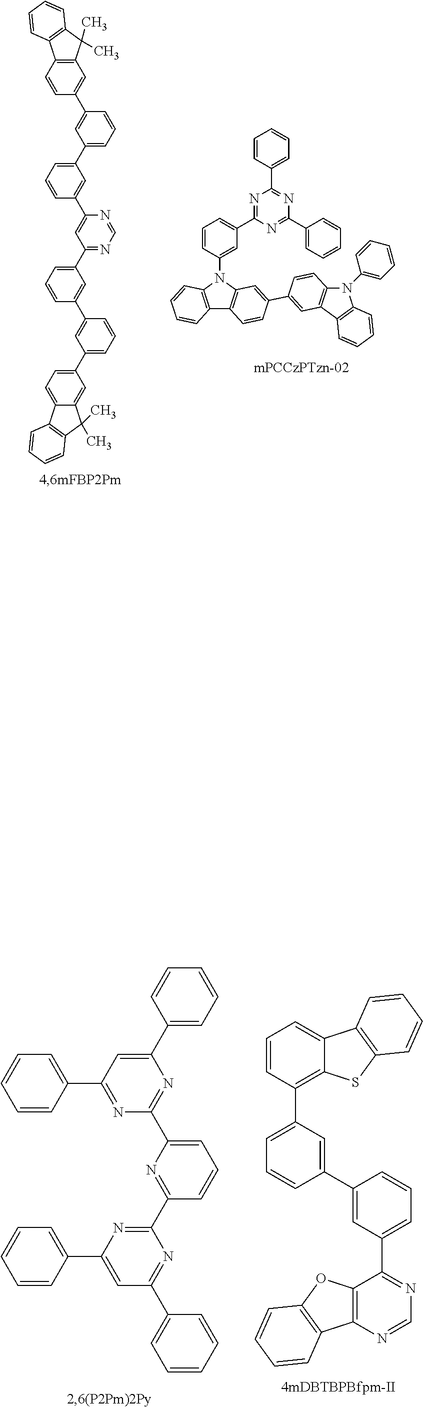 [SMILES: CC1(C)c2ccccc2-c2ccc(-c3cccc(-c4cccc(-c5cc(-c6cccc(-c7cccc(-c8ccc9c(c8)C(C)(C)c8ccccc8-9)c7)c6)ncn5)c4)c3)cc21 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2cc(-c3ccccc3)nc(-c3cccc(-c4nc(-c5ccccc5)cc(-c5ccccc5)n4)n3)n2)cc1 ; c1cc(-c2cccc(-c3cccc4c3sc3ccccc34)c2)cc(-c2ncnc3c2oc2ccccc23)c1]

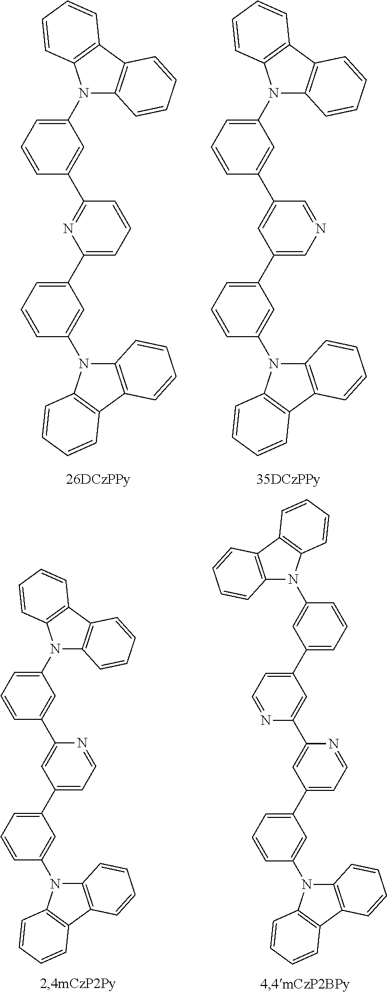 [SMILES: c1cc(-c2cccc(-c3cccc(-n4c5ccccc5c5ccccc54)c3)n2)cc(-n2c3ccccc3c3ccccc32)c1 ; c1cc(-c2cncc(-c3cccc(-n4c5ccccc5c5ccccc54)c3)c2)cc(-n2c3ccccc3c3ccccc32)c1 ; c1cc(-c2ccnc(-c3cccc(-n4c5ccccc5c5ccccc54)c3)c2)cc(-n2c3ccccc3c3ccccc32)c1 ; c1cc(-c2ccnc(-c3cc(-c4cccc(-n5c6ccccc6c6ccccc65)c4)ccn3)c2)cc(-n2c3ccccc3c3ccccc32)c1]

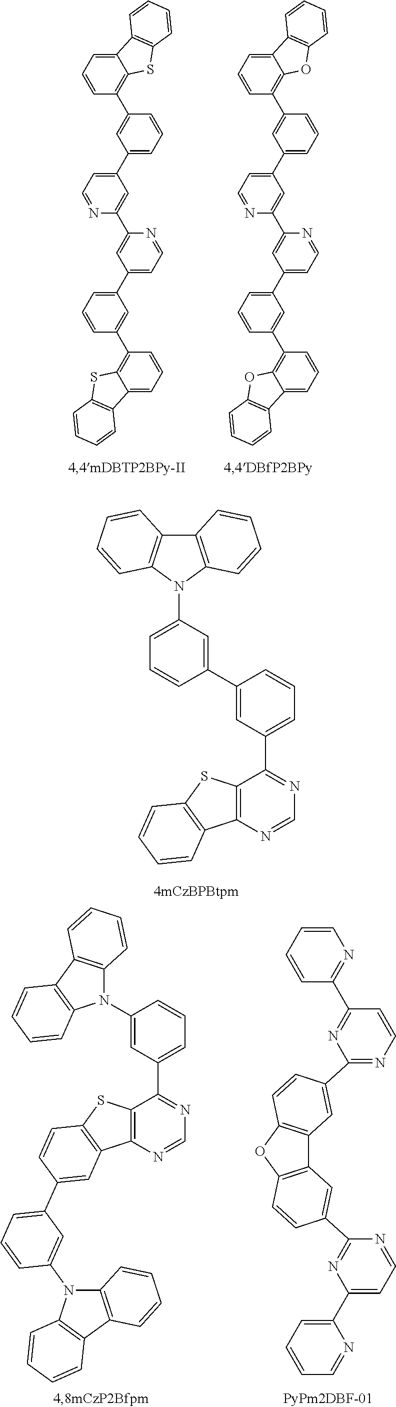 [SMILES: c1cc(-c2ccnc(-c3cc(-c4cccc(-c5cccc6c5sc5ccccc56)c4)ccn3)c2)cc(-c2cccc3c2sc2ccccc23)c1 ; c1cc(-c2ccnc(-c3cc(-c4cccc(-c5cccc6c5oc5ccccc56)c4)ccn3)c2)cc(-c2cccc3c2oc2ccccc23)c1 ; c1cc(-c2cccc(-n3c4ccccc4c4ccccc43)c2)cc(-c2ncnc3c2sc2ccccc23)c1 ; c1cc(-c2ccc3sc4c(-c5cccc(-n6c7ccccc7c7ccccc76)c5)ncnc4c3c2)cc(-n2c3ccccc3c3ccccc32)c1 ; c1ccc(-c2ccnc(-c3ccc4oc5ccc(-c6nccc(-c7ccccn7)n6)cc5c4c3)n2)nc1]

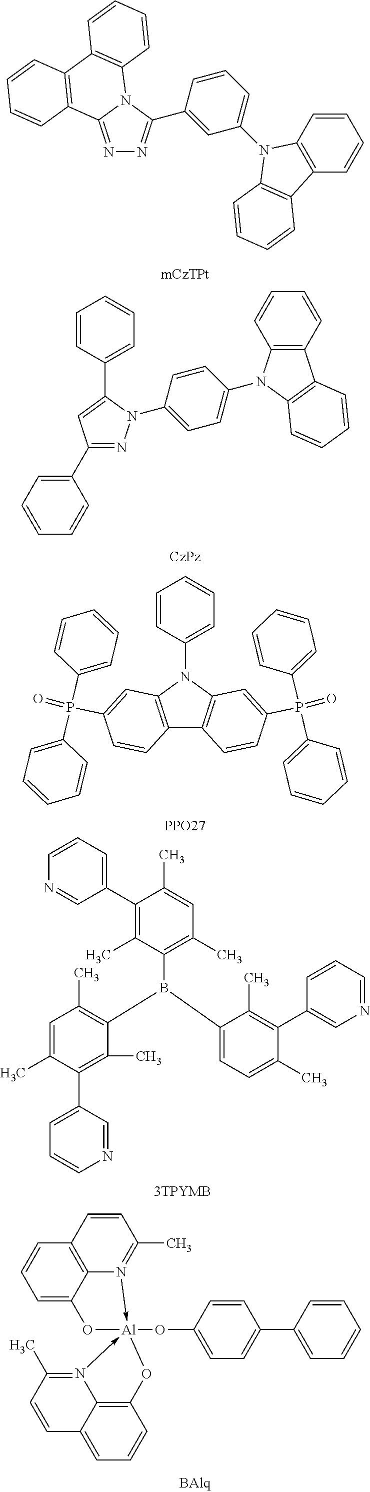

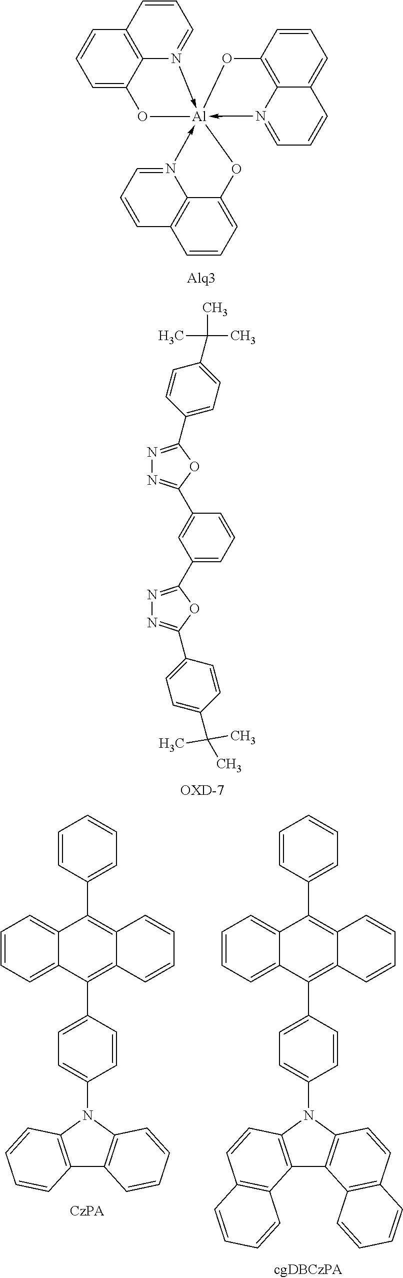

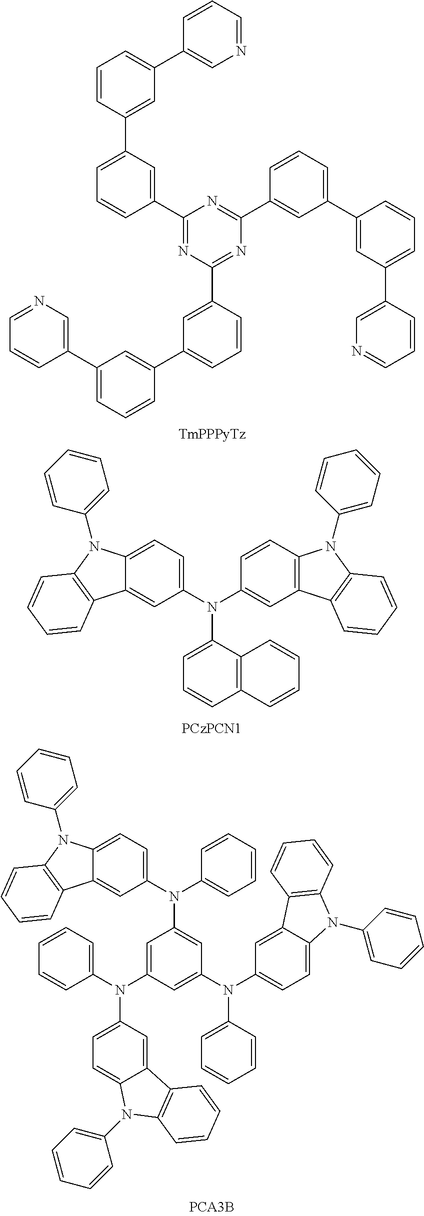 [SMILES: c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1 ; c1ccc(-n2c3ccccc3c3cc(N(c4ccc5c(c4)c4ccccc4n5-c4ccccc4)c4cccc5ccccc45)ccc32)cc1 ; c1ccc(N(c2cc(N(c3ccccc3)c3ccc4c(c3)c3ccccc3n4-c3ccccc3)cc(N(c3ccccc3)c3ccc4c(c3)c3ccccc3n4-c3ccccc3)c2)c2ccc3c(c2)c2ccccc2n3-c2ccccc2)cc1]

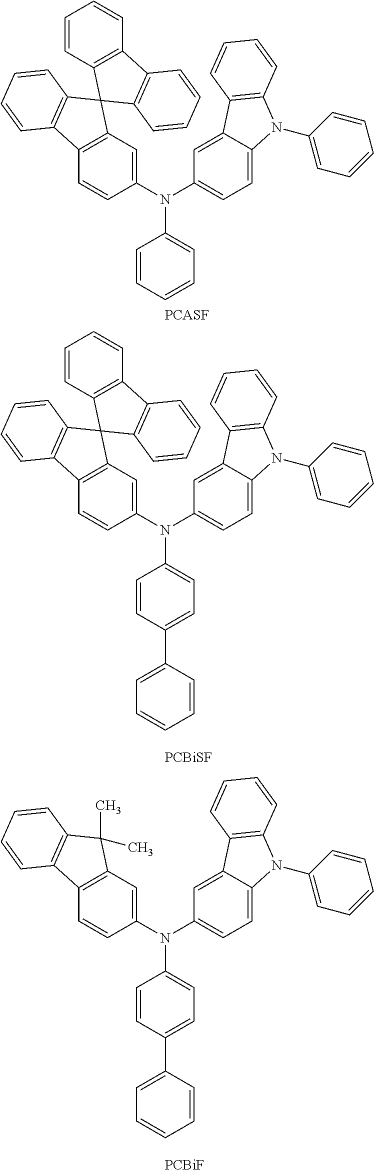

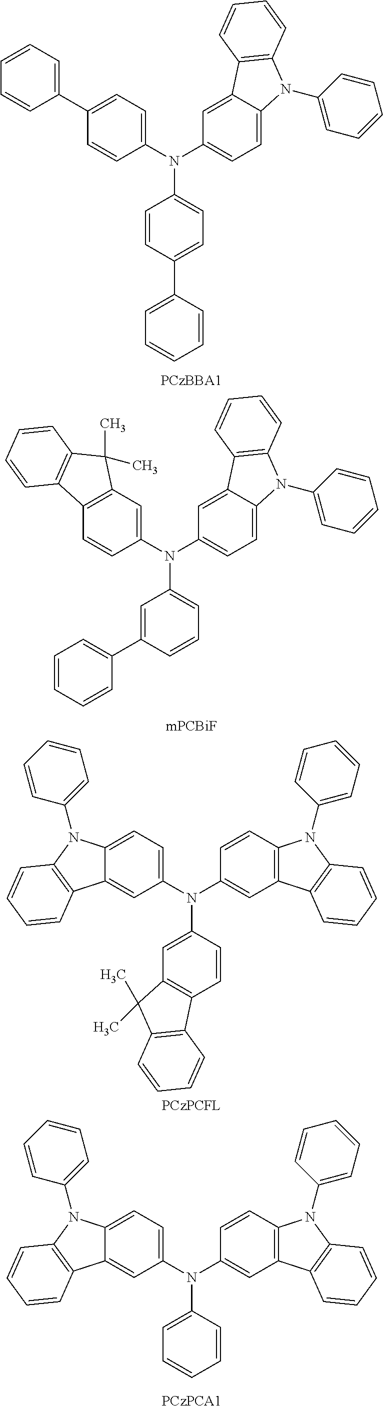

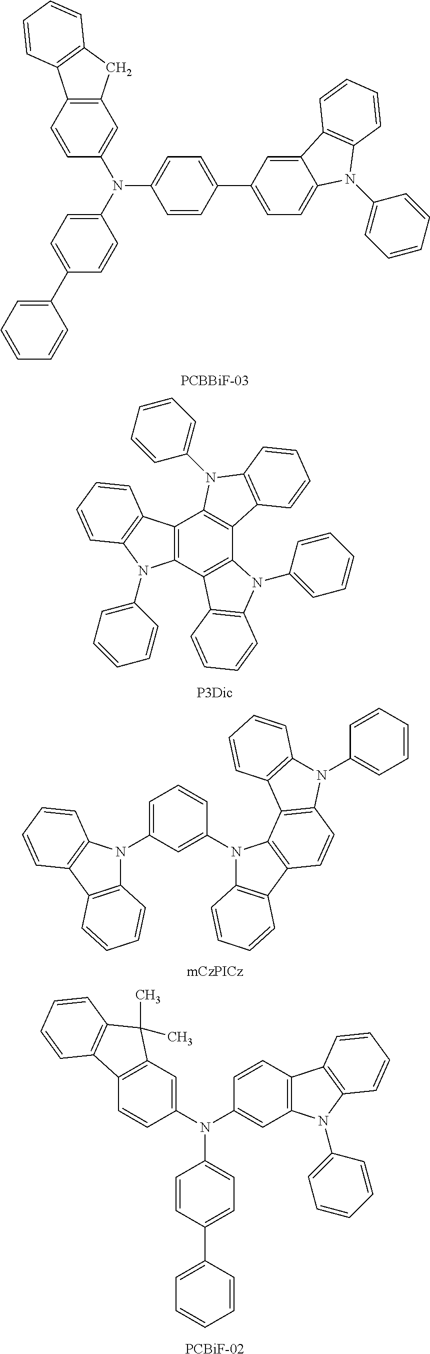

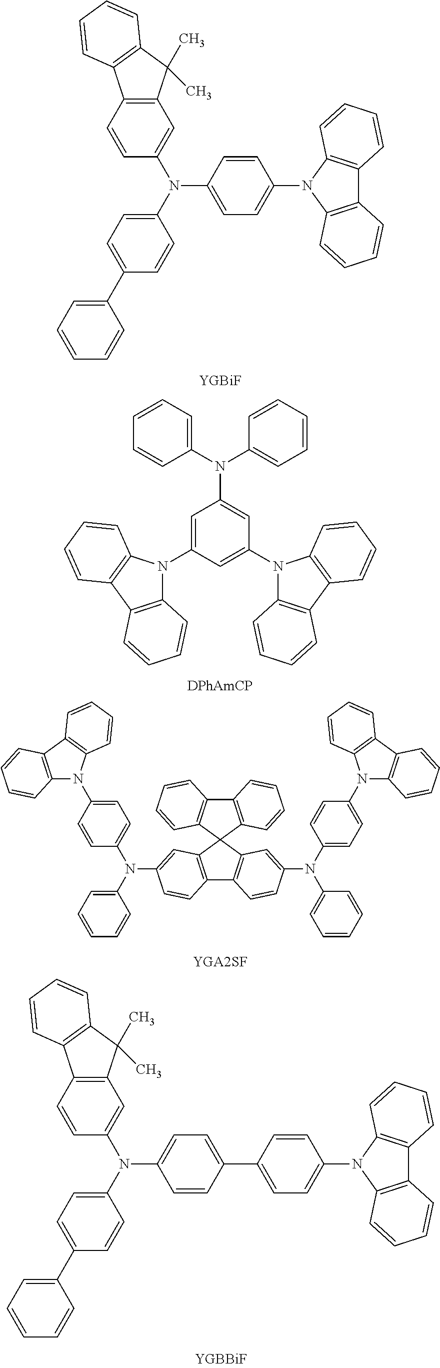 [SMILES: CC1(C)c2ccccc2-c2ccc(N(c3ccc(-c4ccccc4)cc3)c3ccc(-n4c5ccccc5c5ccccc54)cc3)cc21 ; c1ccc(N(c2ccccc2)c2cc(-n3c4ccccc4c4ccccc43)cc(-n3c4ccccc4c4ccccc43)c2)cc1 ; c1ccc(N(c2ccc(-n3c4ccccc4c4ccccc43)cc2)c2ccc3c(c2)C2(c4ccccc4-c4ccccc42)c2cc(N(c4ccccc4)c4ccc(-n5c6ccccc6c6ccccc65)cc4)ccc2-3)cc1 ; CC1(C)c2ccccc2-c2ccc(N(c3ccc(-c4ccccc4)cc3)c3ccc(-c4ccc(-n5c6ccccc6c6ccccc65)cc4)cc3)cc21]

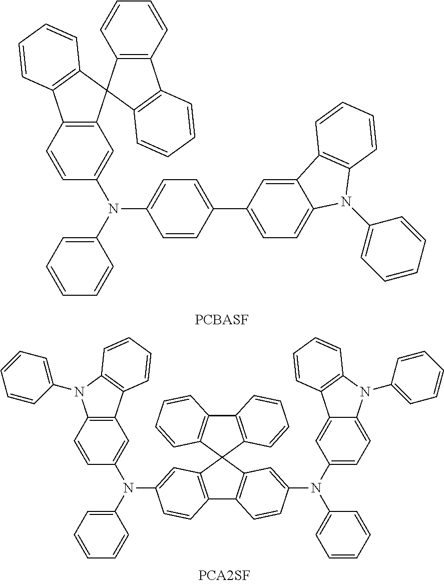 [SMILES: c1ccc(N(c2ccc(-c3ccc4c(c3)c3ccccc3n4-c3ccccc3)cc2)c2ccc3c(c2)C2(c4ccccc4-c4ccccc42)c2ccccc2-3)cc1 ; c1ccc(N(c2ccc3c(c2)C2(c4ccccc4-c4ccccc42)c2cc(N(c4ccccc4)c4ccc5c(c4)c4ccccc4n5-c4ccccc4)ccc2-3)c2ccc3c(c2)c2ccccc2n3-c2ccccc2)cc1]

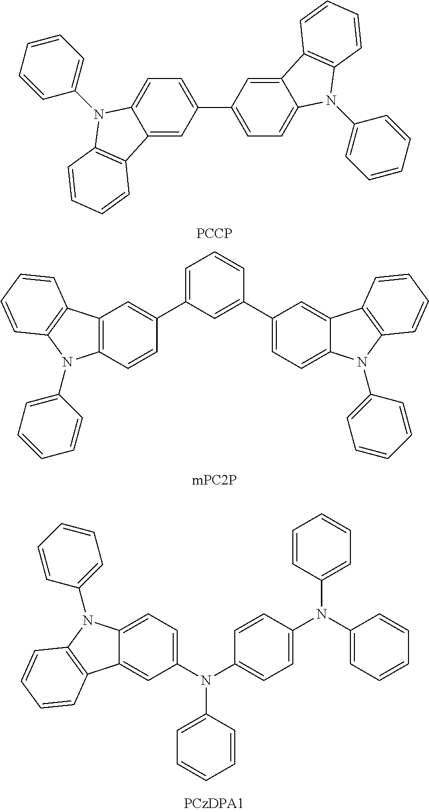

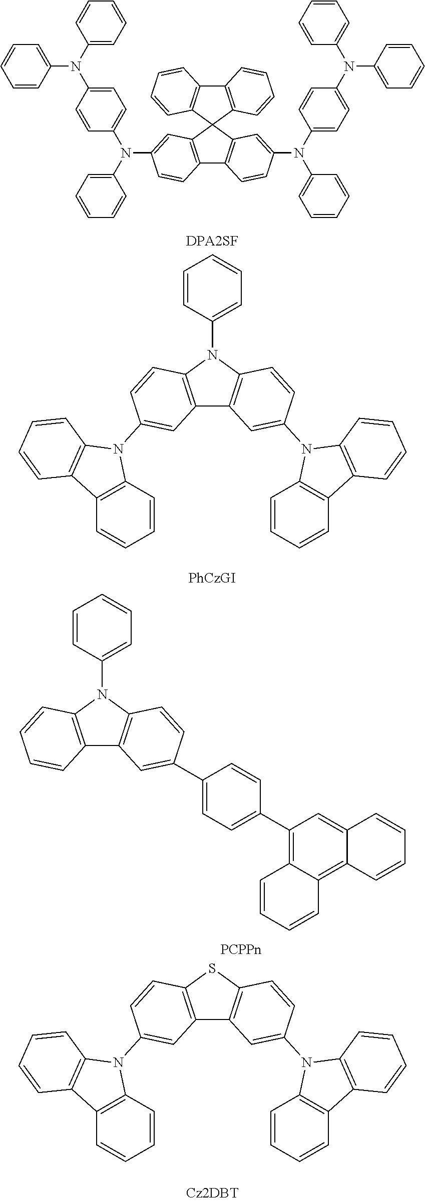

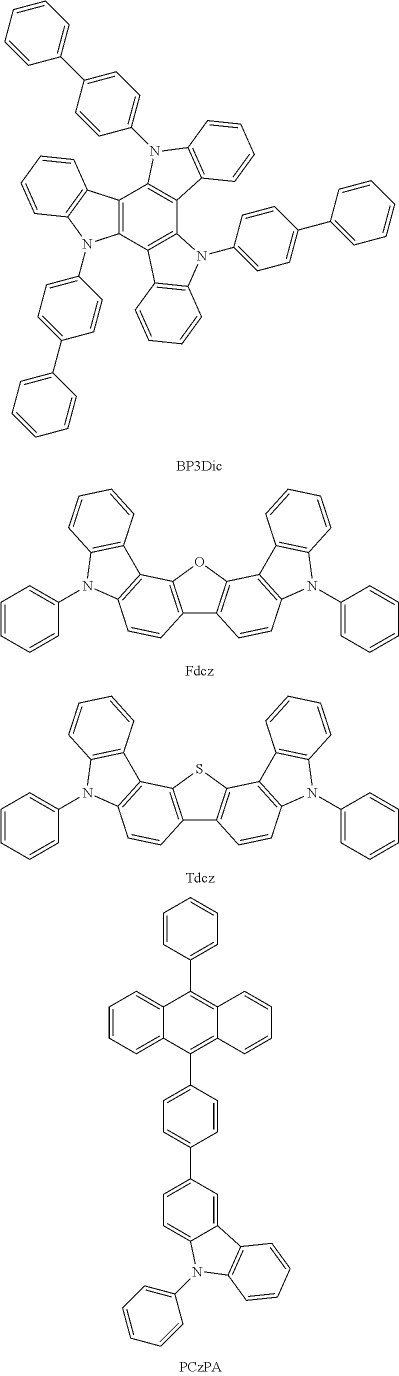 [SMILES: c1ccc(-c2ccc(-n3c4ccccc4c4c3c3c5ccccc5n(-c5ccc(-c6ccccc6)cc5)c3c3c5ccccc5n(-c5ccc(-c6ccccc6)cc5)c43)cc2)cc1 ; c1ccc(-n2c3ccccc3c3c4oc5c(ccc6c5c5ccccc5n6-c5ccccc5)c4ccc32)cc1 ; c1ccc(-n2c3ccccc3c3c4sc5c(ccc6c5c5ccccc5n6-c5ccccc5)c4ccc32)cc1 ; c1ccc(-c2c3ccccc3c(-c3ccc(-c4ccc5c(c4)c4ccccc4n5-c4ccccc4)cc3)c3ccccc23)cc1]

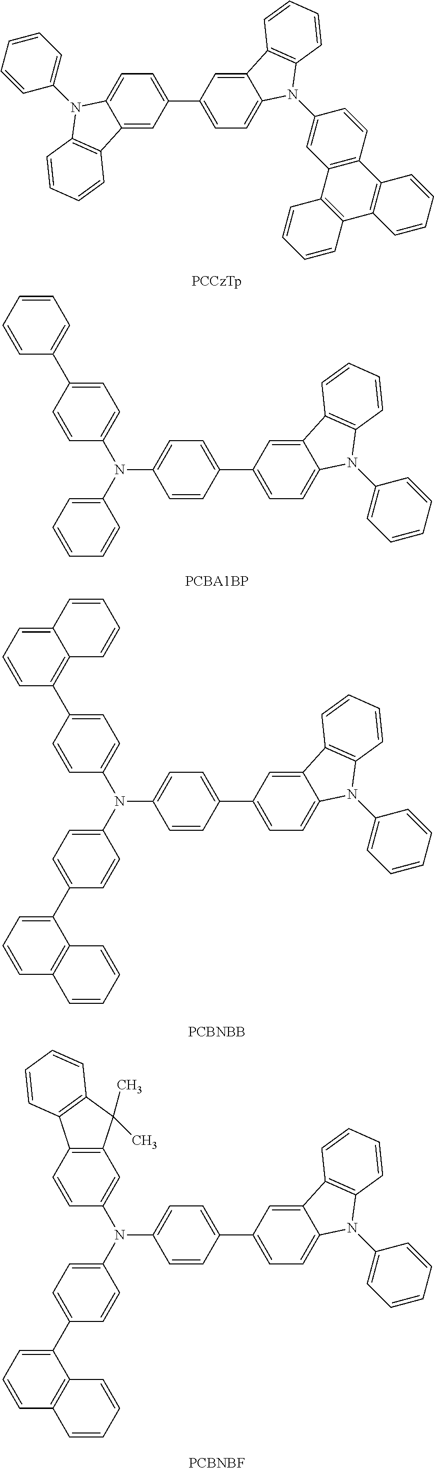

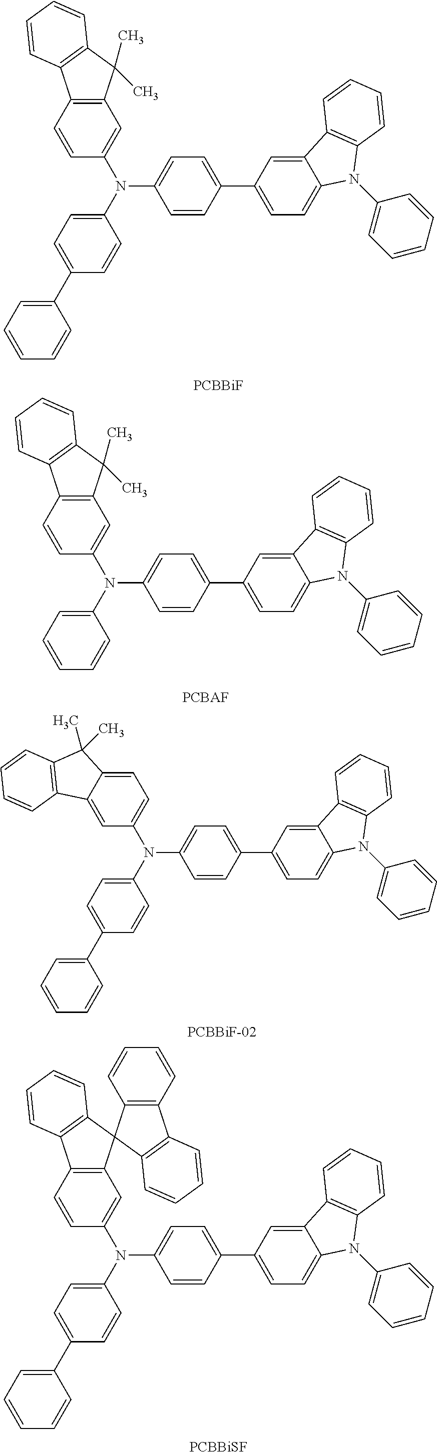

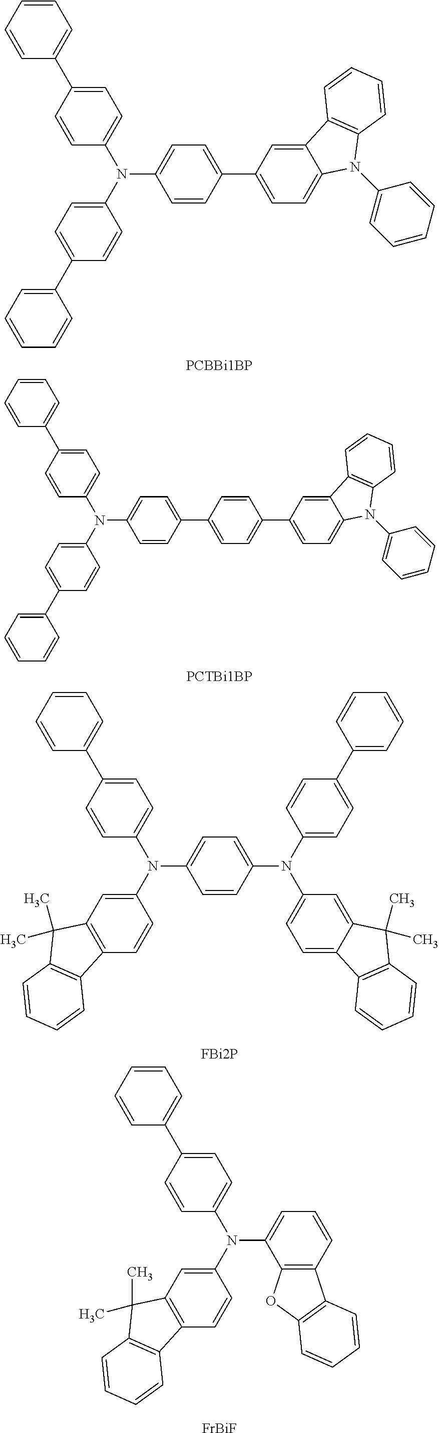

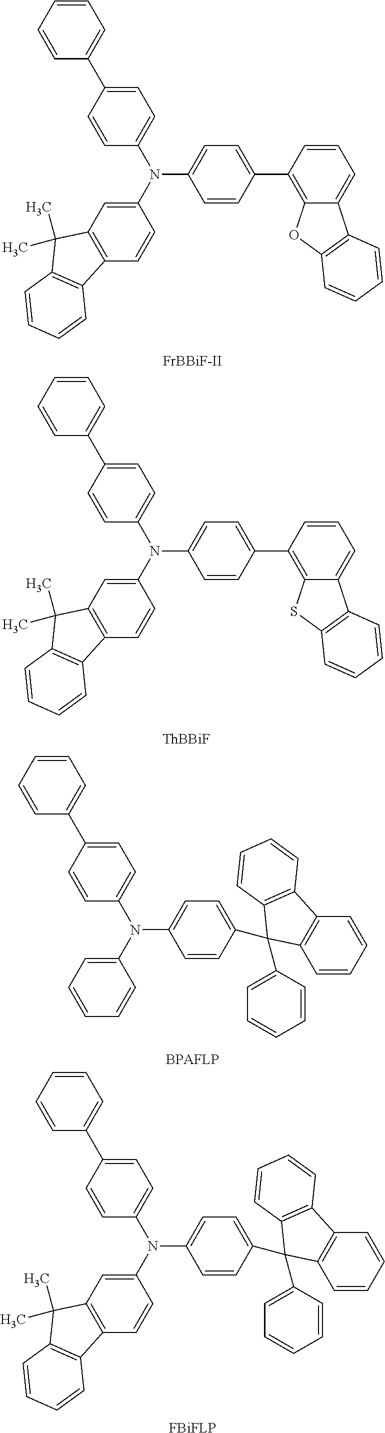

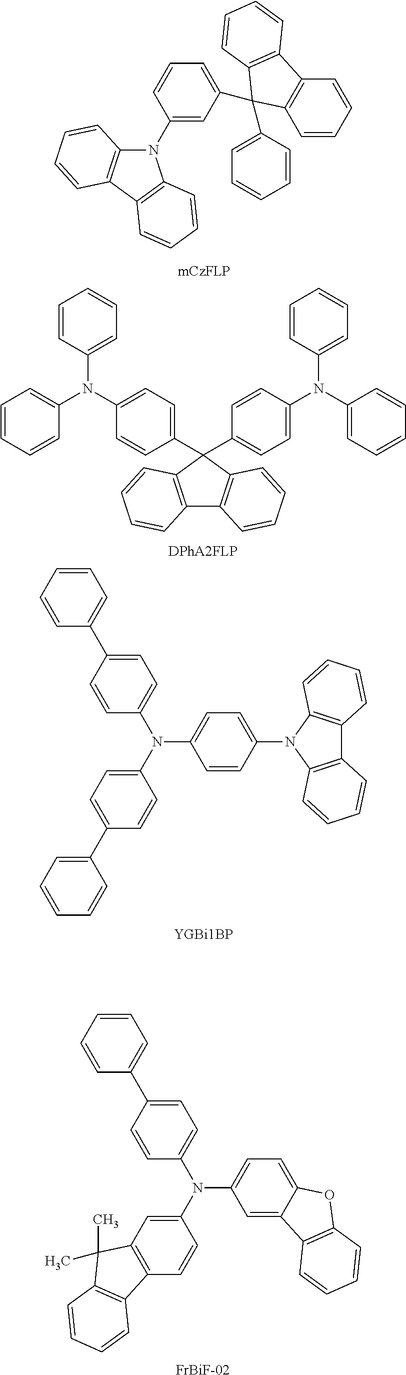

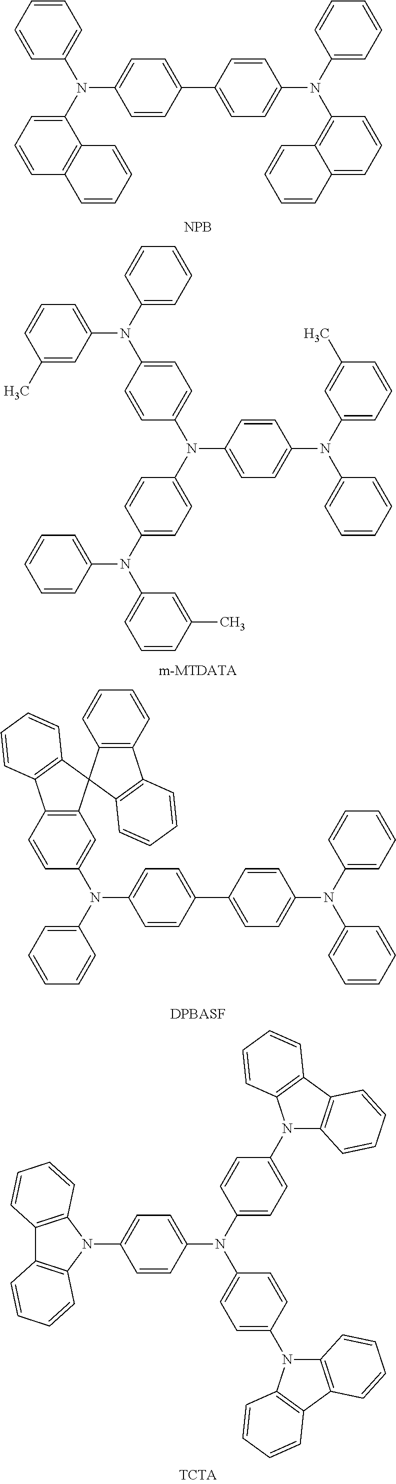

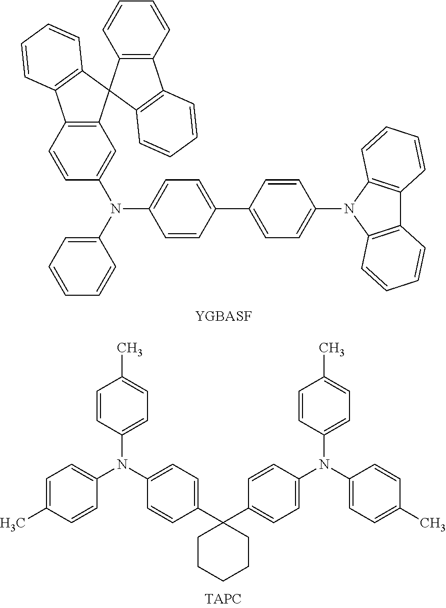

TABLE 3

| | Hole- | Hole- | | Weight | Electron- | | |
|---|---|---|---|---|---|---|---|
| | injection | transport | | ratio and | transport | Thickness | Thickness |
| Layer and | layer | layer | Light-emitting layer 430 | Thickness | layer | of ETL | of ETL |
| its Reference | 411 | 412 | (first compound:second compound) | of 430 | 418(1) | 418(1) | 418(2) |

| | | | | | | |
|---|---|---|---|---|---|---|
| Element 1 | 4,6mCzP2Pm | PCBBiF | | * 26) | 20 | 10 |
| Element 2 | PCBAPDBq | PCzPCN1 | | * 26) | 10 | 15 |
| Element 3 | 2mDBTPDBq-II | PCBA1BP | | * 26) | 5 | 15 |
| Element 4 | 2mDBTPDBq-II | PCzPCN1 | | * 26) | 5 | 15 |
| Element 5 | 2mDBTPDBq-II | PCBNBB | | * 26) | 15 | 15 |
| Element 6 | 2mDBTPDBq-II | PCBNBF | | * 26) | 5 | 15 |
| Element 7 | 2mDBTPDBq-II | PCA3B | * 21) | * 26) | 25 | 25 |
| Element 8 | 2mDBTPDBq-II | NPB | | * 26) | 10 | 20 |
| Element 9 | 2mDBTPDBq-II | YGA2SF | | * 26) | 10 | 20 |
| Element 10 | 2mDBTPDBq-II | DPA2SF | | * 26) | 20 | 20 |
| Element 11 | 2mDBTPDBq-II | PCA2SF | | * 26) | 10 | 20 |
| Element 12 | 2mDBTPDBq-II | PCASF | | * 26) | 10 | 15 |
| Element 13 | 2mDBTPDBq-II | FrBBiF-II | | * 26) | 10 | 15 |
| Element 14 | PPO27 | m-MTDATA | | * 26) | 15 | 15 |
| Element 15 | 3TPYMB | m-MTDATA | | * 26) | 15 | 15 |
| Element 16 | PPO27 | PCASF | | * 26) | 15 | 15 |
| Element 17 | 3TPYMB | PCASF | | * 26) | 15 | 15 |
| Element 18 | PPO27 | PCBBiF | | * 26) | 15 | 15 |
| Element 19 | 3TPYMB | PCBBiF | | * 26) | 15 | 15 |
| Element 20 | PPO27 | PCCP | | * 26) | 15 | 15 |
| Element 21 | 3TPYMB | PCCP | | * 26) | 15 | 15 |
| Element 22 | 2mDBTPDBq-II | m-MTDATA | | * 26) | 20 | 20 |
| Element 23 | 2mDBTBPDBq-II | NPB | | * 26) | 15 | 15 |
| Element 24 | 4,6mDBTP2Pm-II | NPB | | * 26) | 15 | 15 |
| Element 25 | 2mDBTBPDBq-II | PCASF | | * 26) | 15 | 15 |
| Element 26 | 4,6mDBTP2Pm-II | PCASF | | * 26) | 15 | 15 |
| Element 27 | 4,6mDBTP2Pm-II | PCCP | | * 26) | 15 | 15 |
| Element 28 | 2mDBTBPDBq-II | m-MTDATA | | * 26) | 15 | 15 |
| Element 29 | 4,6mDBTP2Pm-II | m-MTDATA | | * 26) | 15 | 15 |
| Element 30 | 4,6mCzP2Pm | PCASF | | * 26) | 15 | 15 |
| Element 31 | 4,6mCzP2Pm | PCA2SF | | * 26) | 15 | 15 |
| Element 32 | 6Ph-4mDBTBPPm-II | PCASF | | * 26) | 10 | 15 |
| Element 33 | PyPm2DBF-01 | PCBBiF | | * 26) | 10 | 15 |
| Element 34 | 4,6mDBTP2Pm-II | PCBiSF | | * 26) | 10 | 15 |
| Element 35 | 4,6mDBTP2Pm-II | PCBiF | | * 26) | 10 | 15 |
| Element 36 | 4,6mDBTP2Pm-II | mPCBiF | | * 26) | 10 | 15 |
| Element 37 | PCPDBq | PCASF | | * 26) | 10 | 15 |
| Element 38 | PCPDBq | PCA2SF | | * 26) | 10 | 15 |
| Element 39 | 4,6mDBFP2Pm-II | PCBBiF | | * 26) | 10 | 15 |
| Element 40 | 2,5mDBFP2Pm-II | PCBBiF | | * 26) | 10 | 15 |
| Element 41 | 4,6mCzP2Pm | P3Dic | | * 26) | 10 | 15 |
| Element 42 | 6Ph-4mDBTBPPm-II | PCBBiF | | * 26) | 10 | 15 |
| Element 43 | 6Ph-4mDBTBPPm-II | P3Dic | | * 26) | 10 | 15 |
| Element 44 | 4,6mCzP2Pm | FBiFLP | | * 26) | 10 | 15 |
| Element 45 | 2mDBTBPDBq-III | PCA2SF | | * 26) | 10 | 15 |
| Element 46 | 2pmDBTBPDBq-II | PCA2SF | | * 26) | 10 | 15 |
| Element 47 | 2pmDBtBPDBq-02 | PCA2SF | | * 26) | 10 | 15 |
| Element 48 | 4,6mDBTP2Pm-II | PCBNBB | | * 26) | 10 | 15 |
| Element 49 | 4,6mDBTP2Pm-II | PCBA1BP | | * 26) | 10 | 15 |
| Element 50 | 4,6mDBTP2Pm-II | PCA2SF | | * 26) | 10 | 15 |
| Element 51 | 4,6mCzP2Pm | PCBAF | | * 26) | 10 | 15 |
| Element 52 | 4,6mCzP2Pm | PCzBBA1 | | * 26) | 10 | 15 |
| Element 53 | 4,6mCzP2Pm | PCBBi1BP | | * 26) | 10 | 15 |
| Element 54 | 2mDBTBPDBq-II | PCBAF | | * 26) | 10 | 15 |
| Element 55 | 2mDBTBPDBq-II | PCBiF | | * 26) | 10 | 15 |
| Element 56 | 2mDBTBPDBq-II | PCzBBA1 | | * 26) | 10 | 15 |
| Element 57 | 2mDBTBPDBq-II | PCBBi1BP | | * 26) | 10 | 15 |
| Element 58 | 2mDBTBPDBq-III | PCBBiF | | * 26) | 10 | 15 |
| Element 59 | 2mDBfBPDBq-02 | PCBBiF | | * 26) | 10 | 15 |
| Element 60 | mDBq2BP | PCBiF | | * 26) | 10 | 15 |

TABLE 4

| | Hole- | Hole- | | Weight | Electron- | | |
|---|---|---|---|---|---|---|---|
| | injection | transport | | ratio and | transport | Thickness | Thickness |
| Layer and | layer | layer | Light-emitting layer 430 | Thickness | layer | of ETL | of ETL |
| its Reference | 411 | 412 | (first compound:second compound) | of 430 | 418(1) | 418(1) | 418(2) |

| | | | | | |
|---|---|---|---|---|---|
| Element 61 | mDBq2BP | PCA2SF | * 26) | 10 | 15 |
| Element 62 | 35DCzPPy | PCBBiF | * 26) | 15 | 10 |
| Element 63 | 4,4′mCzP2BPy | PCBBiF | * 26) | 15 | 10 |
| Element 64 | 4,6mCzP2Pm | FBi2P | * 26) | 15 | 10 |
| Element 65 | 35DCzPPy | FBi2P | * 26) | 15 | 10 |
| Element 66 | 4,4′mCzP2BPy | FBi2P | * 26) | 15 | 10 |
| Element 67 | 2,8mDBqP2DBT | PCA2SF | * 26) | 15 | 10 |
| Element 68 | 2,8DBqP2DBf | PCA2SF | * 26) | 15 | 10 |
| Element 69 | 35DCzPPy | PCBA1BP | * 26) | 15 | 10 |
| Element 70 | 35DCzPPy | P3Dic | * 26) | 15 | 10 |
| Element 71 | 4,6mCzP2Pm | DPBASF | * 26) | 15 | 10 |
| Element 72 | 4,6mCzP2Pm | YGBASF | * 26) | 15 | 10 |
| Element 73 | 4,6mCzP2Pm | PCTBi1BP | * 26) | 15 | 10 |
| Element 74 | 4,6mTpP2Pm | PCBBiF | none | 0 | 25 |
| Element 75 | 4mCzBPBfpm | PCCP | * 26) | 15 | 10 |
| Element 76 | 4mCzBPBfpm | PCA2SF | * 26) | 15 | 10 |
| Element 77 | 4mCzBPBfpm | FBi2P | * 26) | 15 | 10 |
| Element 78 | 4,4′mCzP2BPy | PCA2SF | * 26) | 15 | 10 |
| Element 79 | 2mDBqPDfha | PCA2SF | * 26) | 20 | 15 |
| Element 80 | 2DBtDBq-02 | PCA2SF | * 26) | 20 | 15 |
| Element 81 | 2mDBTBPDBq-II | DPA2SF | * 26) | 20 | 15 |
| Element 82 | 2mDBTBPDBq-II | BPAFLP | * 26) | 15 | 10 |
| Element 83 | 2mDBTBPDBq-II | PCA2SF | * 26) | 20 | 10 |
| Element 84 | 4,6mCzP2Pm | BPAFLP | * 26) | 20 | 10 |
| Element 85 | 6FL-4mDBtBPPm | PCBBiF | * 26) | 15 | 10 |
| Element 86 | 2mBnfBPDBq | PCBBiF | * 26) | 20 | 10 |
| Element 87 | 2DBtDBq-02 | PCBBiF | * 26) | 20 | 10 |
| Element 88 | 2mBnfBPDBq | FrBBiF-II | * 26) | 15 | 10 |
| Element 89 | BAlq | NPB | * 26) | 20 | 10 |
| Element 90 | mDBqP2F | PCBBiF | * 26) | 20 | 10 |
| Element 91 | 2mDBTBPDBq-VIII | FrBBiF-II | * 26) | 20 | 10 |
| Element 92 | 2mDBTBPDBq-II | FrBBiF-II | * 26) | 20 | 10 |
| Element 93 | 2mDBTBPDBq-VIII | PCBBiF | * 26) | 20 | 10 |
| Element 94 | 2mDBTBPDBq-II | PCBBiF | * 26) | 20 | 10 |
| Element 95 | 2mDBTBPDBq-VIII | FBi2P | * 26) | 20 | 10 |
| Element 96 | 2mDBTBPDBq-II | FBi2P | * 26) | 20 | 10 |
| Element 97 | 4,6mPCP2Pm | PCBBiF | * 26) | 20 | 10 |
| Element 98 | 4,6mCzP2Pm | mPC2P | * 26) | 20 | 10 |
| Element 99 | 4,6mPCP2Pm | mPC2P | * 26) | 20 | 10 |
| Element 100 | 4,6mPCP2Pm | PCCP | * 26) | 20 | 10 |
| Element 101 | 4,6mPCP2Pm | PCzPCA1 | * 26) | 20 | 10 |
| Element 102 | 4,6mFP2Pm | PCBBiF | * 26) | 20 | 10 |
| Element 103 | 4,6mDBTP2Pm-II | PCzPCA1 | * 26) | 20 | 10 |
| Element 104 | 4,6mFP2Pm | PCzPCA1 | * 26) | 20 | 10 |
| Element 105 | 6mDBTBPDBq-II | PCzPCA1 | * 26) | 20 | 10 |
| Element 106 | Alq3 | PCBBiF | * 26) | 20 | 10 |
| Element 107 | mDBqP2P | PCBBiF | * 26) | 20 | 10 |
| Element 108 | 6mDBTBPDBq-II | PCBBiF | * 26) | 20 | 10 |
| Element 109 | 6mDBTBPDBq-II | PCCP | * 26) | 20 | 10 |
| Element 110 | 2mDBTBPDBq-II | PCCP | * 26) | 20 | 10 |
| Element 111 | 2mFDBtPDBq | PCBBiF | * 26) | 20 | 10 |
| Element 112 | 2mDBTPDBq-II | PCBBiF | * 26) | 20 | 10 |
| Element 113 | IDE PH-02 | PCBBiF | * 26) | 20 | 10 |
| Element 114 | 4,6mCzP2Pm | FrBBiF-II | * 26) | 20 | 10 |
| Element 115 | IDE PH-02 | FrBBiF-II | * 26) | 20 | 10 |
| Element 116 | 4,6mCzP2Pm | PCBiF | * 26) | 20 | 10 |
| Element 117 | IDE PH-02 | PCBiF | * 26) | 20 | 10 |
| Element 118 | IDE PH-02 | PCzPCA1 | * 26) | 20 | 10 |
| Element 119 | mCzTPt | PCBBiF | * 26) | 20 | 10 |
| Element 120 | mCzTPt | FrBBiF-II | * 26) | 20 | 10 |

TABLE 5

| | Hole- | Hole- | | | Weight | Electron- | | |
|---|---|---|---|---|---|---|---|---|
| | injection | transport | | | ratio and | transport | Thickness | Thickness |
| Layer and | layer | layer | Light-emitting layer 430 | | Thickness | layer | of ETL | of ETL |
| its Reference | 411 | 412 | (first compound:second compound) | | of 430 | 418(1) | 418(1) | 418(2) |
| Element 121 | | | mCzTPt | PCBiF | | * 26) | 20 | 10 |
| Element 122 | | | mCzTPt | PCzPCA1 | | * 26) | 20 | 10 |
| Element 123 | | | 7mIcBPDBq | PCBBiF | | * 26) | 20 | 10 |
| Element 124 | | | 7mIcBPDBq | PCCP | | * 26) | 20 | 10 |
| Element 125 | | | 2mDBTBPDBq-II | PCBBiF-02 | | * 26) | 20 | 10 |
| Element 126 | | | 2Ph-4,6mCzP2Pm | PCBBiF | | * 26) | 20 | 10 |
| Element 127 | | | 2mDBTBPDBq-II | ThBBiF | | * 26) | 20 | 10 |
| Element 128 | | | 4,6mCzP2Pm | ThBBiF | | * 26) | 20 | 10 |
| Element 129 | | | 6FL-4mDBtBPPm-02 | PCBBiF | | * 26) | 20 | 10 |
| Element 130 | | | 6FL-4mDBtBPPm-02 | PCCP | | * 26) | 20 | 10 |
| Element 131 | | | 2mDBTBPDBq-II | PCBA1BP | | * 26) | 20 | 10 |
| Element 132 | | | 4,6mCzP2Pm | PCBA1BP | | * 26) | 20 | 10 |
| Element 133 | | | 2mDBTBPDBq-II | PCBNBB | | * 26) | 20 | 10 |
| Element 134 | | | 4,6mCzP2Pm | PCBNBB | | * 26) | 20 | 10 |
| Element 135 | | | 2mDBTBPDBq-II | PCzPCA1 | | * 26) | 20 | 10 |
| Element 136 | | | 4,6mCzP2Pm | PCzPCA1 | | * 26) | 20 | 10 |
| Element 137 | | | 2mDBTBPDBq-II | PCzPCN1 | | * 26) | 20 | 10 |
| Element 138 | | | 4,6mCzP2Pm | PCzPCN1 | | * 26) | 20 | 10 |
| Element 139 | | | 4mCzBPBfpm | PCzPCFL | | * 26) | 20 | 10 |
| Element 140 | | | 4,6mCzP2Pm | PCzPCFL | | * 26) | 20 | 10 |
| Element 141 | | | 2mFBPDBq | PCBBiF | * 21) | * 26) | 15 | 10 |
| Element 142 | | | 2mDBtTPDBq-II | PCBBiF | * 21) | * 26) | 15 | 10 |
| Element 143 | | | 2mBnf(II)BPDBq | PCBBiF | | * 26) | 20 | 10 |
| Element 144 | | | 2Ph-4,6mCzBP2Pm | PCBBiF | | * 26) | 20 | 15 |
| Element 145 | * 1) | * 6) | 35DCzPPy | TCTA | * 22) | * 26) | 15 | 15 |
| Element 146 | * 1) | * 7) | 35DCzPPy | PhCzG1 | * 22) | * 26) | 15 | 15 |
| Element 147 | * 1) | * 8) | 35DCzPPy | Cz2DBT | * 23) | * 26) | 15 | 15 |
| Element 148 | * 1) | * 7) | 4,6mCzP2Pm | PhCzG1 | * 22) | * 26) | 15 | 15 |
| Element 149 | * 1) | * 6) | 35DCzPPy | PCCP | * 22) | * 26) | 15 | 15 |
| Element 150 | * 1) | * 9) | 35DCzPPy | DPhA2FLP | * 22) | * 26) | 15 | 15 |
| Element 151 | * 1) | * 10) | 35DCzPPy | TAPC | * 22) | * 26) | 15 | 15 |
| Element 152 | * 1) | * 10) | 4,6mCzP2Pm | TAPC | * 22) | * 26) | 15 | 15 |
| Element 153 | | | 4mCzBPBtpm | PCBBiF | | * 26) | 20 | 10 |
| Element 154 | | * 11) | 4,6mCzP2Pm | PCCzTp | | * 26) | 20 | 10 |
| Element 155 | | | 2mPCCzPDBq-02 | PCBBiF | | * 26) | 20 | 10 |
| Element 156 | | | 2mPCCzPDBq | PCBBiF | | * 26) | 20 | 10 |
| Element 157 | | | 2PCCzPDBq | PCBBiF | | * 26) | 20 | 10 |
| Element 158 | | | 2PCCzPDBq-02 | PCBBiF | | * 26) | 20 | 10 |
| Element 159 | | | PCPDBq | PCBBiF | | * 26) | 20 | 10 |
| Element 160 | * 2) | * 12) | 4,6mDBTP2Pm-II | TCTA | * 24) | * 26) | 10 | 15 |
| Element 161 | * 2) | * 12) | TmPPPyTz | TCTA | * 24) | * 26) | 10 | 15 |
| Element 162 | * 2) | * 13) | TmPPPyTz | PCCP | * 24) | * 26) | 10 | 15 |
| Element 163 | * 2) | * 12) | 4,4′mCzP2BPy | TCTA | * 24) | * 26) | 10 | 15 |
| Element 164 | * 2) | * 12) | 4,4′mDBTP2BPy-II | TCTA | * 24) | * 26) | 10 | 15 |
| Element 165 | * 2) | * 12) | 4,4′DBfP2BPy | TCTA | * 24) | * 26) | 10 | 15 |
| Element 166 | * 3) | * 12) | 4,6mCzP2Pm | TCTA | | * 26) | 15 | 10 |
| Element 167 | * 3) | * 12) | 4,6mCzP2Pm | Cz2DBT | | * 26) | 15 | 10 |
| Element 168 | | | 2mDBTBPDBq-II | PCzPCFL | | * 26) | 20 | 10 |
| Element 169 | * 2) | * 9) | 4,6mCzP2Pm | DPhA2FLP | * 21) | * 26) | 15 | 15 |
| Element 170 | | | 2Ph-4mCzBPBfpm | PCBBiF | | * 26) | 20 | 10 |
| Element 171 | | | 4,6mDBTP2Pm-II | PCBBiF | | * 26) | 20 | 10 |
| Element 172 | | | 4,6mCzP2Pm | PCBBiF-03 | | * 26) | 20 | 10 |
| Element 173 | | | 2mPCPDBq | PCBBiF | | * 26) | 20 | 10 |
| Element 174 | | | 2mPCBPDBq | PCBBiF | | * 26) | 20 | 10 |
| Element 175 | | | 2pmPCBPDBq | PCBBiF | | * 26) | 20 | 10 |
| Element 176 | | | 3Ph-2mDBtBPDBq | PCBBiF | | * 26) | 20 | 10 |
| Element 177 | | | 2DBtTPDBq | PCBBiF | | * 26) | 20 | 10 |
| Element 178 | | | 2DBtTPDBq-02 | PCBBiF | | * 26) | 20 | 10 |
| Element 179 | | | 2DBtTPDBq-03 | PCBBiF | | * 26) | 20 | 10 |
| Element 180 | | | 2DBtTPDBq-04 | PCBBiF | | * 26) | 20 | 10 |

TABLE 6

| | Hole- | Hole- | | | Weight | Electron- | | |
|---|---|---|---|---|---|---|---|---|
| | injection | transport | | | ratio and | transport | Thickness | Thickness |
| Layer and | layer | layer | Light-emitting layer 430 | | Thickness | layer | of ETL | of ETL |
| its Reference | 411 | 412 | (first compound:second compound) | | of 430 | 418(1) | 418(1) | 418(2) |
| Element 181 | | | 4,6mCzP2Pm | BP3Dic | | * 26) | 20 | 10 |
| Element 182 | | | 4,6mCzP2Pm | PCBBiF-02 | | * 26) | 20 | 10 |
| Element 183 | | | 2mDBtBPDBqz | PCBBiF | | * 26) | 20 | 10 |
| Element 184 | | | 4,6mCzP2Pm | PCBBiSF | | * 26) | 20 | 10 |
| Element 185 | | | 4,6mCzP2Pm | FrBiF | | * 26) | 20 | 10 |
| Element 186 | | | 4,6mCzP2Pm | FrBiF-02 | | * 26) | 20 | 10 |
| Element 187 | | | 2mDBTBPDBq-II | PCBBiSF | | * 26) | 20 | 10 |
| Element 188 | | | 2mDBTBPDBq-II | 2PCCzPDBq | | * 26) | 20 | 10 |
| Element 189 | | | 2mDBTBPDBq-II | 2mPCCzPDBq | | * 26) | 20 | 10 |
| Element 190 | | ※14) | 4,6mCzP2Pm | PCPPn | | * 26) | 20 | 10 |
| Element 191 | | ※11) | 4,6mCzP2Pm | PCzPA | | * 26) | 20 | 10 |
| Element 192 | | | 4,6mCzP2Pm | PCA3B | | * 26) | 20 | 10 |
| Element 193 | | | 2mDBTBPDBq-II | PCA3B | | * 26) | 20 | 10 |
| Element 194 | | | 2mBbf(III)BPDBq | PCBBiF | | * 26) | 20 | 10 |
| Element 195 | | | 4,6mFP2Pm | PCCP | | * 26) | 20 | 10 |
| Element 196 | | | 2mCzPDBq | PCBBiF | | * 26) | 20 | 10 |
| Element 197 | | | 4,6mCzP2Pm | 2mPCCzPDBq | | * 26) | 20 | 10 |
| Element 198 | | | 4,6mCzP2Pm | 2PCCzPDBq | | * 26) | 20 | 10 |
| Element 199 | * 4) | * 15) | 4,6mCzBP2Pm | DPhAmCP | * 21) | * 26) | 10 | 15 |
| Element 200 | * 4) | * 16) | 4,6mCzBP2Pm | mCzPICz | * 21) | * 26) | 10 | 15 |
| Element 201 | * 5) | * 17) | 2,6(P2Pm)2Py | Tdcz | * 21) | * 26) | 15 | 25 |
| Element 202 | * 5) | * 17) | 4,6mCzBP2Pm | Tdcz | * 21) | * 26) | 15 | 25 |
| Element 203 | * 5) | * 17) | 4,6mCzP2Pm | Tdcz | * 21) | * 26) | 15 | 25 |
| Element 204 | * 5) | * 17) | 4mCzBPBfpm | Tdcz | * 21) | * 26) | 15 | 25 |
| Element 205 | | | 35DCzPPy | FrBBiF-II | | * 26) | 20 | 10 |
| Element 206 | | | 35DCzPPy | PCzPCFL | | * 26) | 20 | 10 |
| Element 207 | | | 4,6mPCP2Pm | FrBBiF-II | | * 26) | 20 | 10 |
| Element 208 | | | 4,6mPCP2Pm | PCzPCFL | | * 26) | 20 | 10 |
| Element 209 | | | 4,6mCzP2Pm | PCBASF | | * 26) | 20 | 10 |
| Element 210 | | | 4,6mCzP2Pm | PCBiSF | | * 26) | 20 | 10 |
| Element 211 | | | 2,4mCzP2Py | PCBBiF | | * 26) | 20 | 10 |
| Element 212 | | | 2,4mCzP2Py | PCBASF | | * 26) | 20 | 10 |
| Element 213 | | | 2,4mCzP2Py | PCBiSF | | * 26) | 20 | 10 |
| Element 214 | | | 4mCzBPBfpm | PCBBiF | | * 26) | 20 | 10 |
| Element 215 | | | 4mCzBPBfpm | PCBiF | | * 26) | 20 | 10 |
| Element 216 | | | 4mCzBPBfpm | PCASF | | * 26) | 20 | 10 |
| Element 217 | | | 4mCzBPBfpm | PCzPCA1 | | * 26) | 20 | 10 |
| Element 218 | | | 26DCzPPy | PCBBiF | | * 26) | 20 | 10 |
| Element 219 | | | 26DCzPPy | PCASF | | * 26) | 20 | 10 |
| Element 220 | | | 4,6mCzP2Pm | m-MTDATA | | * 26) | 20 | 10 |
| Element 221 | | | 4,6mCzP2Pm | mPCBiF | | * 26) | 20 | 10 |
| Element 222 | | | 4mCzBPBfpm | FrBBiF-II | | * 26) | 20 | 10 |
| Element 223 | | | 4,6mCzBP2Pm | PCBBiF | | * 26) | 20 | 10 |
| Element 224 | | | 4,6mCzBP2Pm | FrBBiF-II | | * 26) | 20 | 10 |
| Element 225 | | | 4,6mCzBP2Pm | PCASF | | * 26) | 20 | 10 |
| Element 226 | | | 4,6mCzBP2Pm | PCzPCFL | | * 26) | 20 | 10 |
| Element 227 | | | 4,6mFBP2Pm | PCBBiF | | * 26) | 20 | 10 |
| Element 228 | | | 4,6mCzP2Pm | YGBBiF | | * 26) | 20 | 10 |
| Element 229 | | | 4,4′mCzP2BPy | PCASF | | * 26) | 20 | 10 |
| Element 230 | | | 4,4′mCzP2BPy | FrBBiF-II | | * 26) | 20 | 10 |
| Element 231 | | | 4mCzBPBfpm | YGBBiF | | * 26) | 20 | 10 |
| Element 232 | | | 4mCzBPBfpm | FrBiF | | * 26) | 20 | 10 |
| Element 233 | | | 4mCzBPBfpm | FrBiF-02 | | * 26) | 20 | 10 |
| Element 234 | | | 4,6mCzP2Pm | Fdcz | | * 26) | 13 | 17 |
| Element 235 | | | 4,4′mCzP2BPy | mCzPICz | | * 26) | 13 | 17 |
| Element 236 | | | 4,4′mCzP2BPy | Fdcz | | * 26) | 13 | 17 |
| Element 237 | | | 4mCzBPBfpm | Fdcz | | * 26) | 20 | 10 |
| Element 238 | | | 2mDBTBPDBq-II | Fdcz | | * 26) | 20 | 10 |
| Element 239 | | | TmPPPyTz | PCBBiF | | * 26) | 20 | 10 |
| Element 240 | | | TmPPPyTz | FrBBiF-II | | * 26) | 20 | 10 |

TABLE 7

| | Hole- | Hole- | | | Weight | Electron- | | |
|---|---|---|---|---|---|---|---|---|
| | injection | transport | | | ratio and | transport | Thickness | Thickness |
| Layer and | layer | layer | Light-emitting layer 430 | | Thickness | layer | of ETL | of ETL |
| its Reference | 411 | 412 | (first compound:second compound) | | of 430 | 418(1) | 418(1) | 418(2) |
| Element 241 | | | TmPPPyTz | PCASF | | * 26) | 20 | 10 |
| Element 242 | | | TmPPPyTz | PCA2SF | | * 26) | 20 | 10 |
| Element 243 | | | CzPz | Fdcz | | * 26) | 20 | 10 |
| Element 244 | | | CzPz | P3Dic | | * 26) | 20 | 10 |
| Element 245 | | | CzPz | PCCP | | * 26) | 20 | 10 |
| Element 246 | | | 4,6mCzP2Pm | CzPz | | * 26) | 20 | 10 |
| Element 247 | | | 2mDBTBPDBq-II | PCBiF-02 | | * 26) | 20 | 10 |
| Element 248 | | | 4,6mCzP2Pm | PCBiF-02 | | * 26) | 20 | 10 |
| Element 249 | | * 18) | 4,6mCzP2Pm | mCzFLP | | * 26) | 20 | 10 |
| Element 250 | | | cgDBCzPA | PCBBiF | | * 26) | 20 | 10 |
| Element 251 | | | cgDBCzPA | PCBNBB | | * 26) | 20 | 10 |
| Element 252 | | | CzPA | PCBBiF | | * 26) | 20 | 10 |
| Element 253 | | | CzPA | PCBNBB | | * 26) | 20 | 10 |
| Element 254 | | * 19) | 2mDBTBPDBq-II | mCzFLP | | * 26) | 20 | 10 |
| Element 255 | * 4) | * 15) | 2,6(P2Pm)2Py | DPhAmCP | * 21) | * 26) | 15 | 15 |
| Element 256 | * 4) | * 16) | 2,6(P2Pm)2Py | mCzPICz | * 21) | * 26) | 15 | 15 |
| Element 257 | * 4) | * 16) | 4,6mCzP2Pm | mCzPICz | * 21) | * 26) | 15 | 15 |
| Element 258 | * 4) | * 15) | 4mCzBPBfpm | DPhAmCP | * 21) | * 26) | 10 | 15 |
| Element 259 | * 4) | * 16) | 4mCzBPBfpm | mCzPICz | * 21) | * 26) | 10 | 15 |
| Element 260 | none | * 20) | OXD-7 | TAPC | * 25) | * 26) | 50 | 0 |
| Element 261 | | | 4mDBTBPBfpm-II | PCBBiF | | * 26) | 20 | 10 |
| Element 262 | | | 4mDBTBPBfpm-II | PCASF | | * 26) | 20 | 10 |
| Element 263 | | | 4mDBTBPBfpm-II | PCzPCA1 | | * 26) | 20 | 10 |
| Element 264 | | | 4mDBTBPBfpm-II | PCBiF | | * 26) | 20 | 10 |
| Element 265 | | | 4,6mCzP2Pm | YGBiF | | * 26) | 20 | 10 |
| Element 266 | | | 4,6mCzP2Pm | YGBi1BP | | * 26) | 20 | 10 |
| Element 267 | | | mPCCzPTzn-02 | PCBBiF | | * 26) | 20 | 10 |
| Element 268 | | * 19) | 4,6mCzP2Pm | PCCP | | * 26) | 20 | 10 |
| Element 269 | | * 19) | 4,8mDBtP2Bfpm | PCCP | | * 26) | 20 | 10 |
| Element 270 | | * 19) | 4mDBTBPBfpm-II | PCCP | | * 26) | 20 | 10 |
| Element 271 | | | 4,8mCzP2Bfpm | DPA2SF | | * 26) | 20 | 10 |
| Element 272 | | | 4,8mCzP2Bfpm | PCzDPA1 | | * 26) | 20 | 10 |
| Element 273 | | | 4,6mCzP2Pm | DPA2SF | | * 26) | 20 | 10 |
| Element 274 | | | 4,6mCzP2Pm | PCzDPA1 | | * 26) | 20 | 10 |
| Element 275 | | | 4,8mDBtP2Bfpm | DPA2SF | | * 26) | 20 | 10 |
| Element 276 | | | 4,8mDBtP2Bfpm | PCzDPA1 | | * 26) | 20 | 10 |
| Element 277 | | | 4,6mDBTP2Pm-II | DPA2SF | | * 26) | 20 | 10 |
| Element 278 | | | 4,6mDBTP2Pm-II | PCzDPA1 | | * 26) | 20 | 10 |
| Element 279 | | | 4,8mCzP2Bfpm | PCBBiF | | * 26) | 20 | 10 |
| Element 280 | | * 13) | 4,8mCzP2Bfpm | PCCP | | * 26) | 20 | 10 |
| Element 281 | | * 13) | 4,6mCzP2Pm | PCCP | | * 26) | 20 | 10 |
| Element 282 | | | 4,8mDBtP2Bfpm | PCBBiF | | * 26) | 20 | 10 |

* 1) DBT3P-II:MoO₃ (1:0.5, 60 nm)
* 2) DBT3P-II:MoO₃ (1:0.5, 70 nm)
* 3) DBT3P-II:MoO₃ (1:0.5, 30 nm)
* 4) DBT3P-II:MoO₃ (1:0.5, 15 nm)
* 5) DBT3P-II:MoO₃ (1:0.5, 25 nm)
* 6) mCP
* 7) PCzGI
* 8) Cz2DBT
* 9) DPhA2FLP
* 10) TAPC
* 11) PCzPA
* 12) TCTA
* 13) PCCP
* 14) PCPPn
* 15) DPhAmCP
* 16) mCzPICz
* 17) Tdcz
* 18) DBT3P-II
* 19) mCzFLP
* 20) TAPC (50 nm)
* 21) 0.8:0.2, (30 nm)
* 22) 0.7:0.3, (30 nm)
* 23) 0.9:0.1, (30 nm)
* 24) 0.6:0.4, (40 nm)
* 25) 0.5:0.5, (50 nm)
* 26) first organic compound
* 27) 2mDBTBPDBq-II

### <Characteristics of Light-Emitting Element 1 to 282>

Tables 8 to 10 list the peak wavelengths of the electroluminescence spectra and the maximum external quantum efficiencies of Light-emitting elements 1 to 282.

TABLE 8

| | | maximum value of |
|---|---|---|
| | Peak wavelength | External Quantum |
| characteristics | of EL (nm) | Efficiency (%) |
| Element 1 | 530 | 20.1 |
| Element 2 | 534 | 3.7 |
| Element 3 | 540 | 2.1 |
| Element 4 | 570 | 4.3 |
| Element 5 | 518 | 1.7 |
| Element 6 | 530 | 1.9 |
| Element 7 | 575 | 3.1 |
| Element 8 | 546 | 1.6 |
| Element 9 | 552 | 3.1 |
| Element 10 | 604 | 4.8 |
| Element 11 | 578 | 7.9 |
| Element 12 | 553 | 3.8 |
| Element 13 | 516 | 1.7 |
| Element 14 | 558 | 4.8 |
| Element 15 | 548 | 5.9 |
| Element 16 | 500 | 4.0 |
| Element 17 | 617 | 0.4 |
| Element 18 | 500 | 2.0 |
| Element 19 | 622 | 0.3 |
| Element 20 | 445 | 0.6 |
| Element 21 | 619 | 0.2 |
| Element 22 | 615 | 2.7 |
| Element 23 | 537 | 1.7 |
| Element 24 | 529 | 1.0 |
| Element 25 | 551 | 6.4 |
| Element 26 | 544 | 10.8 |
| Element 27 | 490 | 1.6 |
| Element 28 | 607 | 2.8 |
| Element 29 | 566 | 3.3 |
| Element 30 | 545 | 15.0 |
| Element 31 | 558 | 11.0 |
| Element 32 | 520 | 1.7 |
| Element 33 | 536 | 1.8 |
| Element 34 | 544 | 10.9 |
| Element 35 | 546 | 12.3 |
| Element 36 | 544 | 9.9 |
| Element 37 | 539 | 2.2 |
| Element 38 | 567 | 1.9 |
| Element 39 | 520 | 3.4 |
| Element 40 | 471 | 1.3 |
| Element 41 | 528 | 7.7 |
| Element 42 | 505 | 1.3 |
| Element 43 | 513 | 3.8 |
| Element 44 | 510 | 8.7 |
| Element 45 | 570 | 10.1 |
| Element 46 | 583 | 5.4 |
| Element 47 | 580 | 4.4 |
| Element 48 | 501 | 1.2 |
| Element 49 | 526 | 3.9 |
| Element 50 | 552 | 6.2 |
| Element 51 | 529 | 17.7 |
| Element 52 | 541 | 15.2 |
| Element 53 | 520 | 15.9 |
| Element 54 | 537 | 2.9 |
| Element 55 | 550 | 6.4 |
| Element 56 | 546 | 4.0 |
| Element 57 | 525 | 2.1 |
| Element 58 | 532 | 2.6 |
| Element 59 | 528 | 2.2 |
| Element 60 | 549 | 2.7 |
| Element 61 | 584 | 4.2 |
| Element 62 | 411 | 3.0 |
| Element 63 | 447 | 1.2 |
| Element 64 | 555 | 8.6 |
| Element 65 | 438 | 2.9 |
| Element 66 | 508 | 1.5 |
| Element 67 | 580 | 3.5 |
| Element 68 | 578 | 5.5 |
| Element 69 | 405 | 1.0 |
| Element 70 | 402 | 1.4 |
| Element 71 | 540 | 12.9 |
| Element 72 | 508 | 6.4 |
| Element 73 | 509 | 4.0 |
| Element 74 | 513 | 1.6 |
| Element 75 | 510 | 6.7 |
| Element 76 | 567 | 10.9 |
| Element 77 | 567 | 7.2 |
| Element 78 | 510 | 1.3 |
| Element 79 | 564 | 11.4 |
| Element 80 | 594 | 4.7 |
| Element 81 | 586 | 4.9 |
| Element 82 | 504 | 1.7 |
| Element 83 | 581 | 11.2 |
| Element 84 | 506 | 4.0 |
| Element 85 | 514 | 1.7 |
| Element 86 | 546 | 2.8 |
| Element 87 | 549 | 1.2 |
| Element 88 | 503 | 1.1 |
| Element 89 | 523 | 2.0 |
| Element 90 | 534 | 1.5 |
| Element 91 | 507 | 1.4 |
| Element 92 | 521 | 1.6 |
| Element 93 | 535 | 2.0 |
| Element 94 | 543 | 2.8 |
| Element 95 | 576 | 5.2 |
| Element 96 | 578 | 5.0 |
| Element 97 | 508 | 2.7 |
| Element 98 | 490 | 1.3 |
| Element 99 | 434 | 1.0 |
| Element 100 | 456 | 1.2 |
| Element 101 | 546 | 7.9 |
| Element 102 | 498 | 1.5 |
| Element 103 | 551 | 10.3 |
| Element 104 | 552 | 4.3 |
| Element 105 | 556 | 9.8 |
| Element 106 | 542 | 1.5 |
| Element 107 | 541 | 1.8 |
| Element 108 | 537 | 4.2 |
| Element 109 | 485 | 1.4 |
| Element 110 | 498 | 2.1 |
| Element 111 | 540 | 2.2 |
| Element 112 | 542 | 2.3 |
| Element 113 | 490 | 1.3 |
| Element 114 | 513 | 10.6 |
| Element 115 | 465 | 1.1 |
| Element 116 | 552 | 15.7 |
| Element 117 | 526 | 1.7 |
| Element 118 | 542 | 4.4 |
| Element 119 | 432 | 2.3 |
| Element 120 | 434 | 3.5 |

TABLE 9

| | | maximum value of |
|---|---|---|
| | Peak wavelength | External Quantum |
| characteristics | of EL (nm) | Efficiency (%) |
| Element 121 | 437 | 1.6 |
| Element 122 | 442 | 1.2 |
| Element 123 | 534 | 2.4 |
| Element 124 | 491 | 1.3 |
| Element 125 | 536 | 1.7 |
| Element 126 | 512 | 1.6 |
| Element 127 | 507 | 1.3 |
| Element 128 | 520 | 8.6 |
| Element 129 | 504 | 2.2 |
| Element 130 | 471 | 1.5 |
| Element 131 | 543 | 1.9 |
| Element 132 | 537 | 14.3 |
| Element 133 | 528 | 1.5 |
| Element 134 | 508 | 1.9 |
| Element 135 | 583 | 8.5 |
| Element 136 | 558 | 11.3 |
| Element 137 | 579 | 5.8 |
| Element 138 | 564 | 8.0 |
| Element 139 | 579 | 10.2 |
| Element 140 | 564 | 10.3 |
| Element 141 | 526 | 1.9 |
| Element 142 | 537 | 2.6 |
| Element 143 | 531 | 1.3 |
| Element 144 | 504 | 1.1 |
| Element 145 | 440 | 0.2 |
| Element 146 | 440 | 0.2 |
| Element 147 | 407 | 0.7 |
| Element 148 | 445 | 1.3 |
| Element 149 | 441 | 0.2 |
| Element 150 | 438 | 0.3 |
| Element 151 | 441 | 0.3 |
| Element 152 | 515 | 6.6 |
| Element 153 | 539 | 16.1 |
| Element 154 | 492 | 3.1 |
| Element 155 | 549 | 4.2 |
| Element 156 | 555 | 6.0 |
| Element 157 | 524 | 2.9 |
| Element 158 | 542 | 1.8 |
| Element 159 | 524 | 2.0 |
| Element 160 | 496 | 1.6 |
| Element 161 | 522 | 4.8 |
| Element 162 | 506 | 8.6 |
| Element 163 | 462 | 0.6 |
| Element 164 | 455 | 0.7 |
| Element 165 | 453 | 0.7 |
| Element 166 | 528 | 5.7 |
| Element 167 | 504 | 1.5 |
| Element 168 | 584 | 8.6 |
| Element 169 | 497 | 2.2 |
| Element 170 | 537 | 4.8 |
| Element 171 | 536 | 9.7 |
| Element 172 | 537 | 12.2 |
| Element 173 | 539 | 1.9 |
| Element 174 | 540 | 2.2 |
| Element 175 | 536 | 1.6 |
| Element 176 | 526 | 2.2 |
| Element 177 | 537 | 2.5 |
| Element 178 | 540 | 1.9 |
| Element 179 | 529 | 1.9 |
| Element 180 | 539 | 2.3 |
| Element 181 | 520 | 8.5 |
| Element 182 | 535 | 13.0 |
| Element 183 | 485 | 0.9 |
| Element 184 | 536 | 15.7 |
| Element 185 | 511 | 6.3 |
| Element 186 | 532 | 14.7 |
| Element 187 | 543 | 2.7 |
| Element 188 | 495 | 4.9 |
| Element 189 | 504 | 1.6 |
| Element 190 | 444 | 1.1 |
| Element 191 | 440 | 3.3 |
| Element 192 | 555 | 7.2 |
| Element 193 | 565 | 4.2 |
| Element 194 | 543 | 3.3 |
| Element 195 | 454 | 1.1 |
| Element 196 | 545 | 2.3 |
| Element 197 | 507 | 2.5 |
| Element 198 | 491 | 4.7 |
| Element 199 | 438 | 0.1 |
| Element 200 | 448 | 0.1 |
| Element 201 | 507 | 1.1 |
| Element 202 | 505 | 1.5 |
| Element 203 | 514 | 2.7 |
| Element 204 | 509 | 1.9 |
| Element 205 | 426 | 2.7 |
| Element 206 | 448 | 1.3 |
| Element 207 | 484 | 1.3 |
| Element 208 | 553 | 10.4 |
| Element 209 | 535 | 15.1 |
| Element 210 | 552 | 17.1 |
| Element 211 | 448 | 1.3 |
| Element 212 | 436 | 1.3 |
| Element 213 | 459 | 1.2 |
| Element 214 | 549 | 18.6 |
| Element 215 | 557 | 17.0 |
| Element 216 | 551 | 16.6 |
| Element 217 | 563 | 11.1 |
| Element 218 | 431 | 1.3 |
| Element 219 | 435 | 0.8 |
| Element 220 | 611 | 1.4 |
| Element 221 | 546 | 15.7 |
| Element 222 | 537 | 11.4 |
| Element 223 | 527 | 6.8 |
| Element 224 | 507 | 1.6 |
| Element 225 | 541 | 9.4 |
| Element 226 | 553 | 14.4 |
| Element 227 | 504 | 1.5 |
| Element 228 | 528 | 7.7 |
| Element 229 | 499 | 1.3 |
| Element 230 | 444 | 1.4 |
| Element 231 | 536 | 10.7 |
| Element 232 | 526 | 5.2 |
| Element 233 | 540 | 10.1 |
| Element 234 | 536 | 15.9 |
| Element 235 | 438 | 0.7 |
| Element 236 | 500 | 1.3 |
| Element 237 | 537 | 13.0 |
| Element 238 | 523 | 2.8 |
| Element 239 | 552 | 15.4 |
| Element 240 | 545 | 11.6 |

TABLE 10

| | | maximum value of |
|---|---|---|
| | Peak wavelength | External Quantum |
| characteristics | of EL (nm) | Efficiency (%) |
| Element 241 | 555 | 11.0 |
| Element 242 | 575 | 5.6 |
| Element 243 | 396 | 1.6 |
| Element 244 | 395 | 1.5 |
| Element 245 | 405 | 1.3 |
| Element 246 | 498 | 1.2 |
| Element 247 | 552 | 2.7 |
| Element 248 | 546 | 17.1 |
| Element 249 | 438 | 1.1 |
| Element 250 | 487 | 1.6 |
| Element 251 | 466 | 2.5 |
| Element 252 | 481 | 1.9 |
| Element 253 | 450 | 2.8 |
| Element 254 | 438 | 1.0 |
| Element 255 | 444 | 0.4 |
| Element 256 | 457 | 0.7 |
| Element 257 | 472 | 2.0 |
| Element 258 | 457 | 1.6 |
| Element 259 | 485 | 3.3 |
| Element 260 | 601 | 1.5 |
| Element 261 | 538 | 16.6 |
| Element 262 | 557 | 12.6 |
| Element 263 | 567 | 10.8 |
| Element 264 | 554 | 14.6 |
| Element 265 | 525 | 11.8 |
| Element 266 | 516 | 6.1 |
| Element 267 | 545 | 14.4 |
| Element 268 | 511 | 6.4 |
| Element 269 | 524 | 3.7 |
| Element 270 | 519 | 4.4 |
| Element 271 | 597 | 3.3 |
| Element 272 | 597 | 2.3 |
| Element 273 | 576 | 5.2 |
| Element 274 | 577 | 4.0 |
| Element 275 | 591 | 3.6 |
| Element 276 | 594 | 3.1 |
| Element 277 | 566 | 4.3 |
| Element 278 | 570 | 3.8 |
| Element 279 | 545 | 20.3 |
| Element 280 | 531 | 10.3 |
| Element 281 | 512 | 3.8 |
| Element 282 | 542 | 15.1 |

Tables 11 to 15 list the measurement results of the HOMO levels, the LUMO levels, and the T1 levels of the compounds (the first organic compound and the second organic compound) used in the light-emitting layer 430 of Light-emitting elements 1 to 282, and the energy difference between the LUMO level of the first organic compound and the HOMO level of the second organic compound (abbreviation: ΔE_{E}). The methods for measuring the T1 levels, the HOMO levels, and the LUMO levels are the same as those described above. Note that in Tables 11 to 15, “-” represents being not able to be measured or being not yet measured.

TABLE 11

| | first organic | | | second organic | | | |
|---|---|---|---|---|---|---|---|
| | compound | | | compound | | | |
| physical | HOMO | LUMO | T1 | HOMO | LUMO | T1 | ΔE_{E} |
| property | (eV) | (eV) | (eV) | (eV) | (eV) | (eV) | (eV) |
| Element 1 | −5.89 | −2.88 | 2.70 | −5.36 | −2.00 | 2.44 | 2.48 |
| Element 2 | −5.47 | −2.91 | 2.18 | −5.19 | −2.13 | 2.21 | 2.29 |
| Element 3 | −6.22 | −2.94 | 2.40 | −5.43 | −1.99 | 2.46 | 2.49 |
| Element 4 | −6.22 | −2.94 | 2.40 | −5.19 | −2.13 | 2.21 | 2.25 |
| Element 5 | −6.22 | −2.94 | 2.40 | −5.43 | −2.22 | 2.21 | 2.49 |
| Element 6 | −6.22 | −2.94 | 2.40 | −5.37 | −2.23 | — | 2.43 |
| Element 7 | −6.22 | −2.94 | 2.40 | −5.16 | — | — | 2.22 |
| Element 8 | −6.22 | −2.94 | 2.40 | −5.38 | −2.18 | 2.30 | 2.44 |
| Element 9 | −6.22 | −2.94 | 2.40 | −5.35 | — | 2.35 | 2.41 |
| Element 10 | −6.22 | −2.94 | 2.40 | −5.10 | — | 2.32 | 2.16 |
| Element 11 | −6.22 | −2.94 | 2.40 | −5.19 | −2.06 | 2.33 | 2.25 |
| Element 12 | −6.22 | −2.94 | 2.40 | −5.30 | — | 2.48 | 2.36 |
| Element 13 | −6.22 | −2.94 | 2.40 | −5.42 | −2.23 | 2.39 | 2.48 |
| Element 14 | −6.15 | −2.60 | 2.80 | −4.98 | −2.22 | 2.56 | 2.38 |
| Element 15 | — | −2.63 | 2.81 | −4.98 | −2.22 | 2.56 | 2.35 |
| Element 16 | −6.15 | −2.60 | 2.80 | −5.30 | — | 2.48 | 2.70 |
| Element 17 | — | −2.63 | 2.81 | −5.30 | — | 2.48 | 2.67 |
| Element 18 | −6.15 | −2.60 | 2.80 | −5.36 | −2.00 | 2.44 | 2.76 |
| Element 19 | — | −2.63 | 2.81 | −5.36 | −2.00 | 2.44 | 2.73 |
| Element 20 | −6.15 | −2.60 | 2.80 | −5.63 | −1.96 | 2.65 | 3.03 |
| Element 21 | — | −2.63 | 2.81 | −5.63 | −1.96 | 2.65 | 3.00 |
| Element 22 | −6.22 | −2.94 | 2.40 | −4.98 | −2.22 | 2.56 | 2.04 |
| Element 23 | −6.22 | −2.95 | 2.41 | −5.38 | −2.18 | 2.30 | 2.43 |
| Element 24 | −6.22 | −2.83 | 2.62 | −5.38 | −2.18 | 2.30 | 2.56 |
| Element 25 | −6.22 | −2.95 | 2.41 | −5.30 | — | 2.48 | 2.35 |
| Element 26 | −6.22 | −2.83 | 2.62 | −5.30 | — | 2.48 | 2.48 |
| Element 27 | −6.22 | −2.83 | 2.62 | −5.63 | −1.96 | 2.65 | 2.80 |
| Element 28 | −6.22 | −2.95 | 2.41 | −4.98 | −2.22 | 2.56 | 2.03 |
| Element 29 | −6.22 | −2.83 | 2.62 | −4.98 | −2.22 | 2.56 | 2.16 |
| Element 30 | −5.89 | −2.88 | 2.70 | −5.30 | — | 2.48 | 2.42 |
| Element 31 | −5.89 | −2.88 | 2.70 | −5.19 | −2.06 | 2.33 | 2.31 |
| Element 32 | −6.21 | −2.76 | — | −5.30 | — | 2.48 | 2.54 |
| Element 33 | — | −2.81 | — | −5.36 | −2.00 | 2.44 | 2.55 |
| Element 34 | −6.22 | −2.83 | 2.62 | −5.29 | — | — | 2.47 |
| Element 35 | −6.22 | −2.83 | 2.62 | −5.26 | — | 2.45 | 2.44 |
| Element 36 | −6.22 | −2.83 | 2.62 | −5.28 | — | — | 2.45 |
| Element 37 | −5.83 | −2.93 | 2.21 | −5.30 | — | 2.48 | 2.37 |
| Element 38 | −5.83 | −2.93 | 2.21 | −5.19 | −2.06 | 2.33 | 2.26 |
| Element 39 | — | −2.78 | — | −5.36 | −2.00 | 2.44 | 2.58 |
| Element 40 | — | −2.66 | — | −5.36 | −2.00 | 2.44 | 2.70 |
| Element 41 | −5.89 | −2.88 | 2.70 | −5.51 | — | 2.76 | 2.63 |
| Element 42 | −6.21 | −2.76 | — | −5.36 | −2.00 | 2.44 | 2.60 |
| Element 43 | −6.21 | −2.76 | — | −5.51 | — | 2.76 | 2.75 |
| Element 44 | −5.89 | −2.88 | 2.70 | −5.42 | — | 2.46 | 2.54 |
| Element 45 | −6.04 | −2.94 | — | −5.19 | −2.06 | 2.33 | 2.25 |
| Element 46 | — | −2.97 | — | −5.19 | −2.06 | 2.33 | 2.23 |
| Element 47 | −6.03 | −2.97 | — | −5.19 | −2.06 | 2.33 | 2.22 |
| Element 48 | −6.22 | −2.83 | 2.62 | −5.43 | −2.22 | 2.21 | 2.60 |
| Element 49 | −6.22 | −2.83 | 2.62 | −5.43 | −1.99 | 2.46 | 2.61 |
| Element 50 | −6.22 | −2.83 | 2.62 | −5.19 | −2.06 | 2.33 | 2.37 |
| Element 51 | −5.89 | −2.88 | 2.70 | −5.38 | −1.99 | — | 2.50 |
| Element 52 | −5.89 | −2.88 | 2.70 | — | — | — | — |
| Element 53 | −5.89 | −2.88 | 2.70 | −5.42 | — | — | 2.54 |
| Element 54 | −6.22 | −2.95 | 2.41 | −5.38 | −1.99 | — | 2.43 |
| Element 55 | −6.22 | −2.95 | 2.41 | −5.26 | — | 2.45 | 2.31 |
| Element 56 | −6.22 | −2.95 | 2.41 | — | — | — | — |
| Element 57 | −6.22 | −2.95 | 2.41 | −5.42 | — | — | 2.47 |
| Element 58 | −6.04 | −2.94 | — | −5.36 | −2.00 | 2.44 | 2.42 |
| Element 59 | −6.24 | −2.94 | 2.27 | −5.36 | −2.00 | 2.44 | 2.42 |
| Element 60 | — | −2.93 | — | −5.26 | — | 2.45 | 2.34 |

TABLE 12

| | first organic | | | second organic | | | |
|---|---|---|---|---|---|---|---|
| | compound | | | compound | | | |
| physical | HOMO | LUMO | T1 | HOMO | LUMO | T1 | ΔE_{E} |
| property | (eV) | (eV) | (eV) | (eV) | (eV) | (eV) | (eV) |
| Element 61 | — | −2.93 | — | −5.19 | −2.06 | 2.33 | 2.27 |
| Element 62 | −5.90 | −2.39 | 2.75 | −5.36 | −2.00 | 2.44 | 2.97 |
| Element 63 | −5.94 | −2.66 | 2.77 | −5.36 | −2.00 | 2.44 | 2.70 |
| Element 64 | −5.89 | −2.88 | 2.70 | −5.13 | −2.06 | 2.43 | 2.25 |
| Element 65 | −5.90 | −2.39 | 2.75 | −5.13 | −2.06 | 2.43 | 2.74 |
| Element 66 | −5.94 | −2.66 | 2.77 | −5.13 | −2.06 | 2.43 | 2.47 |
| Element 67 | −6.07 | −2.93 | — | −5.19 | −2.06 | 2.33 | 2.26 |
| Element 68 | — | −2.94 | — | −5.19 | −2.06 | 2.33 | 2.25 |
| Element 69 | −5.90 | −2.39 | 2.75 | −5.43 | −1.99 | 2.46 | 3.05 |
| Element 70 | −5.90 | −2.39 | 2.75 | −5.51 | — | 2.76 | 3.13 |
| Element 71 | −5.89 | −2.88 | 2.70 | −5.28 | — | — | 2.40 |
| Element 72 | −5.89 | −2.88 | 2.70 | −5.40 | — | — | 2.52 |
| Element 73 | −5.89 | −2.88 | 2.70 | −5.46 | — | — | 2.58 |
| Element 74 | — | −2.79 | 2.47 | −5.36 | −2.00 | 2.44 | 2.57 |
| Element 75 | −5.91 | −2.97 | 2.68 | −5.63 | −1.96 | 2.65 | 2.66 |
| Element 76 | −5.91 | −2.97 | 2.68 | −5.19 | −2.06 | 2.33 | 2.22 |
| Element 77 | −5.91 | −2.97 | 2.68 | −5.13 | −2.06 | 2.43 | 2.16 |
| Element 78 | −5.94 | −2.66 | 2.77 | −5.19 | −2.06 | 2.33 | 2.54 |
| Element 79 | — | −2.95 | 2.41 | −5.19 | −2.06 | 2.33 | 2.24 |
| Element 80 | — | −3.00 | 2.31 | −5.19 | −2.06 | 2.33 | 2.19 |
| Element 81 | −6.22 | −2.95 | 2.41 | −5.10 | — | 2.32 | 2.15 |
| Element 82 | −6.22 | −2.95 | 2.41 | −5.51 | −2.04 | 2.49 | 2.56 |
| Element 83 | −6.22 | −2.95 | 2.41 | −5.19 | −2.06 | 2.33 | 2.24 |
| Element 84 | −5.89 | −2.88 | 2.70 | −5.51 | −2.04 | 2.49 | 2.63 |
| Element 85 | −6.23 | −2.81 | 2.47 | −5.36 | −2.00 | 2.44 | 2.55 |
| Element 86 | −6.13 | −2.95 | 2.40 | −5.36 | −2.00 | 2.44 | 2.41 |
| Element 87 | — | −3.00 | 2.31 | −5.36 | −2.00 | 2.44 | 2.36 |
| Element 88 | −6.13 | −2.95 | 2.40 | −5.42 | −2.23 | 2.39 | 2.47 |
| Element 89 | −5.79 | −2.62 | — | −5.38 | −2.18 | 2.30 | 2.76 |
| Element 90 | −6.04 | −2.93 | — | −5.36 | −2.00 | 2.44 | 2.43 |
| Element 91 | −6.11 | −2.94 | — | −5.42 | −2.23 | 2.39 | 2.48 |
| Element 92 | −6.22 | −2.95 | 2.41 | −5.42 | −2.23 | 2.39 | 2.47 |
| Element 93 | −6.11 | −2.94 | — | −5.36 | −2.00 | 2.44 | 2.42 |
| Element 94 | −6.22 | −2.95 | 2.41 | −5.36 | −2.00 | 2.44 | 2.41 |
| Element 95 | −6.11 | −2.94 | — | −5.13 | −2.06 | 2.43 | 2.19 |
| Element 96 | −6.22 | −2.95 | 2.41 | −5.13 | −2.06 | 2.43 | 2.18 |
| Element 97 | −5.81 | −2.77 | — | −5.36 | −2.00 | 2.44 | 2.59 |
| Element 98 | −5.89 | −2.88 | 2.70 | −5.80 | — | — | 2.92 |
| Element 99 | −5.81 | −2.77 | — | −5.80 | — | — | 3.03 |
| Element 100 | −5.81 | −2.77 | — | −5.63 | −1.96 | 2.65 | 2.86 |
| Element 101 | −5.81 | −2.77 | — | −5.19 | −2.02 | 2.50 | 2.42 |
| Element 102 | −6.15 | −2.78 | 2.47 | −5.36 | −2.00 | 2.44 | 2.58 |
| Element 103 | −6.22 | −2.83 | 2.62 | −5.19 | −2.02 | 2.50 | 2.36 |
| Element 104 | −6.15 | −2.78 | 2.47 | −5.19 | −2.02 | 2.50 | 2.41 |
| Element 105 | −6.23 | −2.86 | 2.53 | −5.19 | −2.02 | 2.50 | 2.33 |
| Element 106 | −5.76 | −2.80 | — | −5.36 | −2.00 | 2.44 | 2.56 |
| Element 107 | — | −2.96 | 2.39 | −5.36 | −2.00 | 2.44 | 2.40 |
| Element 108 | −6.23 | −2.86 | 2.53 | −5.36 | −2.00 | 2.44 | 2.50 |
| Element 109 | −6.23 | −2.86 | 2.53 | −5.63 | −1.96 | 2.65 | 2.77 |
| Element 110 | −6.22 | −2.95 | 2.41 | −5.63 | −1.96 | 2.65 | 2.68 |
| Element 111 | −6.09 | −2.95 | — | −5.36 | −2.00 | 2.44 | 2.41 |
| Element 112 | −6.22 | −2.94 | 2.40 | −5.36 | −2.00 | 2.44 | 2.42 |
| Element 113 | −5.89 | −2.78 | 2.75 | −5.36 | −2.00 | 2.44 | 2.58 |
| Element 114 | −5.89 | −2.88 | 2.70 | −5.42 | −2.23 | 2.39 | 2.54 |
| Element 115 | −5.89 | −2.78 | 2.75 | −5.42 | −2.23 | 2.39 | 2.65 |
| Element 116 | −5.89 | −2.88 | 2.70 | −5.26 | — | 2.45 | 2.38 |
| Element 117 | −5.89 | −2.78 | 2.75 | −5.26 | — | 2.45 | 2.49 |
| Element 118 | −5.89 | −2.78 | 2.75 | −5.19 | −2.02 | 2.50 | 2.41 |
| Element 119 | −5.91 | −2.39 | 2.51 | −5.36 | −2.00 | 2.44 | 2.97 |
| Element 120 | −5.91 | −2.39 | 2.51 | −5.42 | −2.23 | 2.39 | 3.03 |

TABLE 13

| | first organic | | | second organic | | | |
|---|---|---|---|---|---|---|---|
| | compound | | | compound | | | |
| physical | HOMO | LUMO | T1 | HOMO | LUMO | T1 | ΔE_{E} |
| property | (eV) | (eV) | (eV) | (eV) | (eV) | (eV) | (eV) |
| Element 121 | −5.91 | −2.39 | 2.51 | −5.26 | — | 2.45 | 2.87 |
| Element 122 | −5.91 | −2.39 | 2.51 | −5.19 | −2.02 | 2.50 | 2.80 |
| Element 123 | −5.93 | −2.86 | 2.46 | −5.36 | −2.00 | 2.44 | 2.50 |
| Element 124 | −5.93 | −2.86 | 2.46 | −5.63 | −1.96 | 2.65 | 2.77 |
| Element 125 | −6.22 | −2.95 | 2.41 | −5.41 | −2.18 | — | 2.46 |
| Element 126 | −5.91 | −2.88 | 2.71 | −5.36 | −2.00 | 2.44 | 2.48 |
| Element 127 | −6.22 | −2.95 | 2.41 | −5.44 | −2.24 | 2.40 | 2.49 |
| Element 128 | −5.89 | −2.88 | 2.70 | −5.44 | −2.24 | 2.40 | 2.56 |
| Element 129 | −6.23 | −2.80 | 2.46 | −5.36 | −2.00 | 2.44 | 2.56 |
| Element 130 | −6.23 | −2.80 | 2.46 | −5.63 | −1.96 | 2.65 | 2.83 |
| Element 131 | −6.22 | −2.95 | 2.41 | −5.43 | −1.99 | 2.46 | 2.48 |
| Element 132 | −5.89 | −2.88 | 2.70 | −5.43 | −1.99 | 2.46 | 2.55 |
| Element 133 | −6.22 | −2.95 | 2.41 | −5.43 | −2.22 | 2.21 | 2.48 |
| Element 134 | −5.89 | −2.88 | 2.70 | −5.43 | −2.22 | 2.21 | 2.55 |
| Element 135 | −6.22 | −2.95 | 2.41 | −5.19 | −2.02 | 2.50 | 2.24 |
| Element 136 | −5.89 | −2.88 | 2.70 | −5.19 | −2.02 | 2.50 | 2.31 |
| Element 137 | −6.22 | −2.95 | 2.41 | −5.19 | −2.13 | 2.21 | 2.24 |
| Element 138 | −5.89 | −2.88 | 2.70 | −5.19 | −2.13 | 2.21 | 2.31 |
| Element 139 | −5.91 | −2.97 | 2.68 | −5.14 | −2.05 | 2.42 | 2.17 |
| Element 140 | −5.89 | −2.88 | 2.70 | −5.14 | −2.05 | 2.42 | 2.26 |
| Element 141 | −6.11 | −2.94 | 2.42 | −5.36 | −2.00 | 2.44 | 2.42 |
| Element 142 | −6.19 | −2.94 | 2.41 | −5.36 | −2.00 | 2.44 | 2.42 |
| Element 143 | −6.03 | −2.95 | 2.31 | −5.36 | −2.00 | 2.44 | 2.41 |
| Element 144 | −5.89 | −2.80 | 2.73 | −5.36 | −2.00 | 2.44 | 2.56 |
| Element 145 | −5.90 | −2.39 | 2.75 | −5.50 | — | 2.75 | 3.12 |
| Element 146 | −5.90 | −2.39 | 2.75 | −5.75 | — | 2.84 | 3.37 |
| Element 147 | −5.90 | −2.39 | 2.75 | −5.86 | −2.33 | 2.91 | 3.47 |
| Element 148 | −5.89 | −2.88 | 2.70 | −5.75 | — | 2.84 | 2.87 |
| Element 149 | −5.90 | −2.39 | 2.75 | −5.63 | −1.96 | 2.65 | 3.24 |
| Element 150 | −5.90 | −2.39 | 2.75 | −5.53 | — | 2.76 | 3.15 |
| Element 151 | −5.90 | −2.39 | 2.75 | −5.43 | — | 2.88 | 3.05 |
| Element 152 | −5.89 | −2.88 | 2.70 | −5.43 | — | 2.88 | 2.55 |
| Element 153 | −5.90 | −2.96 | 2.63 | −5.36 | −2.00 | 2.44 | 2.40 |
| Element 154 | −5.89 | −2.88 | 2.70 | −5.60 | −2.23 | 2.64 | 2.72 |
| Element 155 | −5.69 | −2.99 | 2.40 | −5.36 | −2.00 | 2.44 | 2.37 |
| Element 156 | −5.63 | −2.98 | 2.40 | −5.36 | −2.00 | 2.44 | 2.38 |
| Element 157 | −5.63 | −3.98 | 2.31 | −5.36 | −2.00 | 2.44 | 1.38 |
| Element 158 | −5.68 | −2.97 | 2.33 | −5.36 | −2.00 | 2.44 | 2.39 |
| Element 159 | −5.83 | −2.93 | 2.21 | −5.36 | −2.00 | 2.44 | 2.43 |
| Element 160 | −6.22 | −2.83 | 2.62 | −5.50 | — | 2.75 | 2.68 |
| Element 161 | — | −3.00 | 2.70 | −5.50 | — | 2.75 | 2.50 |
| Element 162 | — | −3.00 | 2.70 | −5.63 | −1.96 | 2.65 | 2.63 |
| Element 163 | −5.94 | −2.66 | 2.77 | −5.50 | — | 2.75 | 2.85 |
| Element 164 | — | −2.63 | 2.64 | −5.50 | — | 2.75 | 2.88 |
| Element 165 | — | −2.60 | 2.65 | −5.50 | — | 2.75 | 2.90 |
| Element 166 | −5.89 | −2.88 | 2.70 | −5.50 | — | 2.75 | 2.62 |
| Element 167 | −5.89 | −2.88 | 2.70 | −5.86 | −2.33 | 2.91 | 2.98 |
| Element 168 | −6.22 | −2.95 | 2.41 | −5.14 | −2.05 | 2.42 | 2.19 |
| Element 169 | −5.89 | −2.88 | 2.70 | −5.53 | — | 2.76 | 2.65 |
| Element 170 | −5.91 | −2.97 | 2.73 | −5.36 | −2.00 | 2.44 | 2.39 |
| Element 171 | −6.22 | −2.83 | 2.62 | −5.36 | −2.00 | 2.44 | 2.53 |
| Element 172 | −5.89 | −2.88 | 2.70 | −5.36 | −1.97 | — | 2.48 |
| Element 173 | −5.83 | −2.93 | 2.40 | −5.36 | −2.00 | 2.44 | 2.43 |
| Element 174 | −5.84 | −2.94 | 2.39 | −5.36 | −2.00 | 2.44 | 2.42 |
| Element 175 | −5.84 | −2.96 | 2.28 | −5.36 | −2.00 | 2.44 | 2.40 |
| Element 176 | −6.18 | −2.91 | — | −5.36 | −2.00 | 2.44 | 2.45 |
| Element 177 | — | −2.99 | — | −5.36 | −2.00 | 2.44 | 2.37 |
| Element 178 | −6.15 | −2.96 | — | −5.36 | −2.00 | 2.44 | 2.40 |
| Element 179 | −6.15 | −2.95 | — | −5.36 | −2.00 | 2.44 | 2.41 |
| Element 180 | −6.16 | −2.94 | — | −5.36 | −2.00 | 2.44 | 2.42 |

TABLE 14

| | first organic | | | second organic | | | |
|---|---|---|---|---|---|---|---|
| | compound | | | compound | | | |
| physical | HOMO | LUMO | T1 | HOMO | LUMO | T1 | ΔE_{E} |
| property | (eV) | (eV) | (eV) | (eV) | (eV) | (eV) | (eV) |
| Element 181 | −5.89 | −2.88 | 2.70 | −5.51 | — | 2.68 | 2.63 |
| Element 182 | −5.89 | −2.88 | 2.70 | −5.41 | −2.18 | — | 2.53 |
| Element 183 | −6.19 | −2.76 | — | −5.36 | −2.00 | 2.44 | 2.60 |
| Element 184 | −5.89 | −2.88 | 2.70 | −5.40 | — | — | 2.52 |
| Element 185 | −5.89 | −2.88 | 2.70 | −5.48 | −2.06 | 2.50 | 2.60 |
| Element 186 | −5.89 | −2.88 | 2.70 | −5.38 | −2.14 | 2.47 | 2.50 |
| Element 187 | −6.22 | −2.95 | 2.41 | −5.40 | — | — | 2.45 |
| Element 188 | −6.22 | −2.95 | 2.41 | −5.63 | −3.98 | 2.31 | 2.68 |
| Element 189 | −6.22 | −2.95 | 2.41 | −5.63 | −2.98 | 2.40 | 2.68 |
| Element 190 | −5.89 | −2.88 | 2.70 | −5.80 | −2.24 | 2.47 | 2.92 |
| Element 191 | −5.89 | −2.88 | 2.70 | −5.79 | −2.70 | — | 2.91 |
| Element 192 | −5.89 | −2.88 | 2.70 | −5.16 | — | — | 2.28 |
| Element 193 | −6.22 | −2.95 | 2.41 | −5.16 | — | — | 2.21 |
| Element 194 | — | −2.95 | — | −5.36 | −2.00 | 2.44 | 2.41 |
| Element 195 | −6.15 | −2.78 | 2.47 | −5.63 | −1.96 | 2.65 | 2.85 |
| Element 196 | −5.91 | −2.98 | — | −5.36 | −2.00 | 2.44 | 2.38 |
| Element 197 | −5.89 | −2.88 | 2.70 | −5.63 | −2.98 | 2.40 | 2.75 |
| Element 198 | −5.89 | −2.88 | 2.70 | −5.63 | −3.98 | 2.31 | 2.75 |
| Element 199 | −5.89 | −2.80 | 2.74 | −5.66 | −2.04 | 2.88 | 2.86 |
| Element 200 | −5.89 | −2.80 | 2.74 | −5.62 | −1.95 | 2.81 | 2.82 |
| Element 201 | — | −2.78 | 2.81 | −5.63 | −2.03 | 2.76 | 2.85 |
| Element 202 | −5.89 | −2.80 | 2.74 | −5.63 | −2.03 | 2.76 | 2.83 |
| Element 203 | −5.89 | −2.88 | 2.70 | −5.63 | −2.03 | 2.76 | 2.75 |
| Element 204 | −5.91 | −2.97 | 2.68 | −5.63 | −2.03 | 2.76 | 2.66 |
| Element 205 | −5.90 | −2.39 | 2.75 | −5.42 | −2.23 | 2.39 | 3.04 |
| Element 206 | −5.90 | −2.39 | 2.75 | −5.14 | −2.05 | 2.42 | 2.75 |
| Element 207 | −5.81 | −2.77 | — | −5.42 | −2.23 | 2.39 | 2.66 |
| Element 208 | −5.81 | −2.77 | — | −5.14 | −2.05 | 2.42 | 2.37 |
| Element 209 | −5.89 | −2.88 | 2.70 | −5.41 | — | 2.45 | 2.53 |
| Element 210 | −5.89 | −2.88 | 2.70 | −5.29 | — | — | 2.41 |
| Element 211 | −5.88 | −2.57 | 2.77 | −5.36 | −2.00 | 2.44 | 2.79 |
| Element 212 | −5.88 | −2.57 | 2.77 | −5.41 | — | 2.45 | 2.84 |
| Element 213 | −5.88 | −2.57 | 2.77 | −5.29 | — | — | 2.72 |
| Element 214 | −5.91 | −2.97 | 2.68 | −5.36 | −2.00 | 2.44 | 2.39 |
| Element 215 | −5.91 | −2.97 | 2.68 | −5.26 | — | 2.45 | 2.29 |
| Element 216 | −5.91 | −2.97 | 2.68 | −5.30 | — | 2.48 | 2.33 |
| Element 217 | −5.91 | −2.97 | 2.68 | −5.19 | −2.02 | 2.50 | 2.22 |
| Element 218 | −5.86 | −2.42 | 2.72 | −5.36 | −2.00 | 2.43 | 2.94 |
| Element 219 | −5.86 | −2.42 | 2.72 | −5.30 | — | 2.48 | 2.88 |
| Element 220 | −5.89 | −2.88 | 2.70 | −4.98 | −2.22 | 2.56 | 2.10 |
| Element 221 | −5.89 | −2.88 | 2.70 | −5.28 | — | — | 2.40 |
| Element 222 | −5.91 | −2.97 | 2.68 | −5.42 | −2.23 | 2.39 | 2.45 |
| Element 223 | −5.89 | −2.80 | 2.74 | −5.36 | −2.00 | 2.44 | 2.56 |
| Element 224 | −5.89 | −2.80 | 2.74 | −5.42 | −2.23 | 2.39 | 2.62 |
| Element 225 | −5.89 | −2.80 | 2.74 | −5.30 | — | 2.48 | 2.50 |
| Element 226 | −5.89 | −2.80 | 2.74 | −5.14 | −2.05 | 2.42 | 2.34 |
| Element 227 | — | — | — | −5.36 | −2.00 | 2.44 | — |
| Element 228 | −5.89 | −2.88 | 2.70 | −5.41 | −2.17 | 2.39 | 2.53 |
| Element 229 | −5.94 | −2.66 | 2.77 | −5.30 | — | 2.48 | 2.65 |
| Element 230 | −5.94 | −2.66 | 2.77 | −5.42 | −2.23 | 2.39 | 2.77 |
| Element 231 | −5.91 | −2.97 | 2.68 | −5.41 | −2.17 | 2.39 | 2.44 |
| Element 232 | −5.91 | −2.97 | 2.68 | −5.48 | −2.06 | 2.50 | 2.51 |
| Element 233 | −5.91 | −2.97 | 2.68 | −5.38 | −2.14 | 2.47 | 2.41 |
| Element 234 | −5.89 | −2.88 | 2.70 | −5.58 | −1.98 | 2.80 | 2.70 |
| Element 235 | −5.94 | −2.66 | 2.77 | −5.62 | −1.95 | 2.81 | 2.96 |
| Element 236 | −5.94 | −2.66 | 2.77 | −5.58 | −1.98 | 2.80 | 2.93 |
| Element 237 | −5.91 | −2.97 | 2.68 | −5.58 | −1.98 | 2.80 | 2.61 |
| Element 238 | −6.22 | −2.95 | 2.41 | −5.58 | −1.98 | 2.80 | 2.63 |
| Element 239 | — | −3.00 | 2.70 | −5.36 | −2.00 | 2.44 | 2.36 |
| Element 240 | — | −3.00 | 2.70 | −5.42 | −2.23 | 2.39 | 2.42 |

TABLE 15

| | first organic | | | second organic | | | |
|---|---|---|---|---|---|---|---|
| | compound | | | compound | | | |
| physical | HOMO | LUMO | T1 | HOMO | LUMO | T1 | ΔE_{E} |
| property | (eV) | (eV) | (eV) | (eV) | (eV) | (eV) | (eV) |
| Element 241 | — | −3.00 | 2.70 | −5.30 | — | 2.47 | 2.30 |
| Element 242 | — | −3.00 | 2.70 | −5.19 | −2.06 | 2.33 | 2.19 |
| Element 243 | −5.90 | −2.17 | — | −5.58 | −1.98 | 2.80 | 3.42 |
| Element 244 | −5.90 | −2.17 | — | −5.51 | | 2.76 | 3.35 |
| Element 245 | −5.90 | −2.17 | — | −5.63 | −1.96 | 2.65 | 3.47 |
| Element 246 | −5.89 | −2.88 | 2.70 | −5.90 | −2.17 | — | 3.02 |
| Element 247 | −6.22 | −2.95 | 2.41 | −5.35 | −2.05 | 2.46 | 2.40 |
| Element 248 | −5.89 | −2.88 | 2.70 | −5.35 | −2.05 | 2.46 | 2.47 |
| Element 249 | −5.89 | −2.88 | 2.70 | −5.90 | — | 2.78 | 3.02 |
| Element 250 | −5.69 | −2.74 | 1.72 | −5.36 | −2.00 | 2.44 | 2.62 |
| Element 251 | −5.69 | −2.74 | 1.72 | −5.43 | −2.22 | 2.21 | 2.69 |
| Element 252 | −5.79 | −2.73 | 1.72 | −5.36 | −2.00 | 2.44 | 2.63 |
| Element 253 | −5.79 | −2.73 | 1.72 | −5.43 | −2.22 | 2.21 | 2.70 |
| Element 254 | −6.22 | −2.95 | 2.40 | −5.90 | — | 2.78 | 2.95 |
| Element 255 | — | −2.78 | 2.81 | −5.66 | −2.04 | 2.88 | 2.88 |
| Element 256 | — | −2.78 | 2.81 | −5.62 | −1.95 | 2.81 | 2.84 |
| Element 257 | −5.89 | −2.88 | 2.70 | −5.62 | −1.95 | 2.81 | 2.74 |
| Element 258 | −5.91 | −2.97 | 2.68 | −5.66 | −2.04 | 2.88 | 2.69 |
| Element 259 | −5.91 | −2.97 | 2.68 | −5.62 | −1.95 | 2.81 | 2.65 |
| Element 260 | — | −2.61 | — | −5.43 | — | 2.88 | 2.82 |
| Element 261 | −6.22 | −2.96 | 2.67 | −5.36 | −2.00 | 2.44 | 2.40 |
| Element 262 | −6.22 | −2.96 | 2.67 | −5.30 | — | 2.47 | 2.34 |
| Element 263 | −6.22 | −2.96 | 2.67 | −5.19 | −2.02 | 2.50 | 2.23 |
| Element 264 | −6.22 | −2.96 | 2.67 | −5.26 | — | 2.45 | 2.30 |
| Element 265 | −5.89 | −2.88 | 2.70 | −5.42 | −2.06 | — | 2.54 |
| Element 266 | −5.89 | −2.88 | 2.70 | −5.48 | −2.09 | — | 2.60 |
| Element 267 | −5.69 | −3.00 | 2.50 | −5.36 | −2.00 | 2.44 | 2.36 |
| Element 268 | −5.89 | −2.88 | 2.70 | −5.63 | −1.96 | 2.65 | 2.75 |
| Element 269 | −6.18 | −3.02 | 2.61 | −5.63 | −1.96 | 2.65 | 2.61 |
| Element 270 | −6.22 | −2.96 | 2.67 | −5.63 | −1.96 | 2.65 | 2.67 |
| Element 271 | −5.94 | −3.06 | — | −5.10 | — | 2.32 | 2.04 |
| Element 272 | −5.94 | −3.06 | — | −5.00 | — | — | 1.94 |
| Element 273 | −5.89 | −2.88 | 2.70 | −5.10 | — | 2.32 | 2.22 |
| Element 274 | −5.89 | −2.88 | 2.70 | −5.00 | — | — | 2.12 |
| Element 275 | −6.18 | −3.02 | 2.61 | −5.10 | — | 2.32 | 2.08 |
| Element 276 | −6.18 | −3.02 | 2.61 | −5.00 | — | — | 1.98 |
| Element 277 | −6.22 | −2.83 | 2.62 | −5.10 | — | 2.32 | 2.28 |
| Element 278 | −6.22 | −2.83 | 2.62 | −5.00 | — | — | 2.18 |
| Element 279 | −5.94 | −3.06 | — | −5.36 | −2.00 | 2.44 | 2.30 |
| Element 280 | −5.94 | −3.06 | — | −5.63 | −1.96 | 2.65 | 2.57 |
| Element 281 | −5.89 | −2.88 | 2.70 | −5.63 | −1.96 | 2.65 | 2.75 |
| Element 282 | −6.18 | −3.02 | 2.61 | −5.36 | −2.00 | 2.44 | 2.34 |

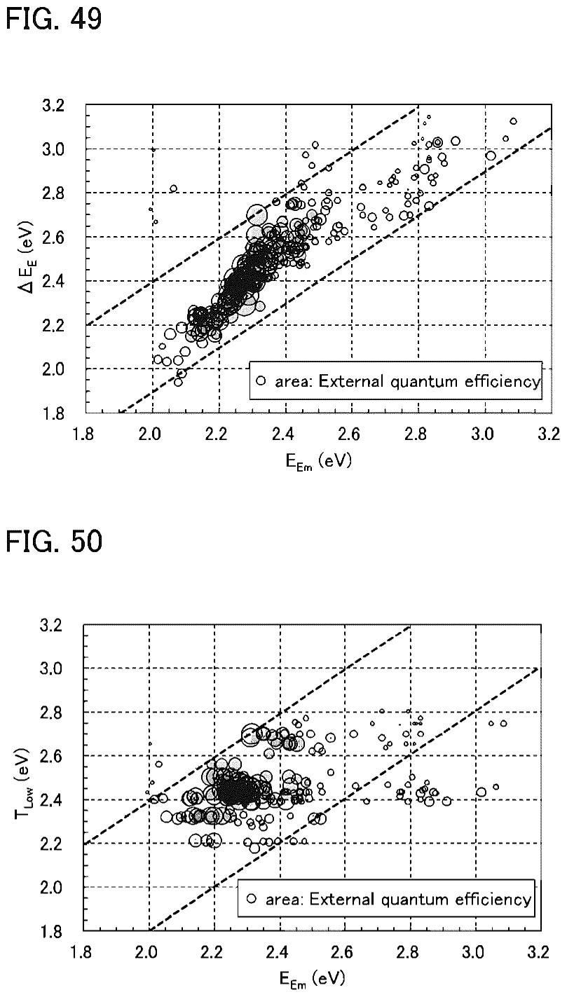

FIG. 49 shows the relation between the maximum external quantum efficiency (η_{QE}), emission energy obtained by conversion from the peak wavelength of the electroluminescence spectrum (abbreviation: E_{Em}), and the energy difference between the LUMO level of the first organic compound and the HOMO level of the second organic compound (ΔE_{E}), of Light-emitting elements 1 to 282. FIG. 50 shows the relation between the maximum external quantum efficiency (η_{QE}), emission energy obtained by conversion from the peak wavelength of the electroluminescence spectrum (abbreviation: E_{Em}), and the lower of the T1 level of the first organic compound and the T1 level of the second organic compound (abbreviation: T_{Low}), of Light-emitting elements 1 to 282. FIGS. 49 and 50 are bubble charts. In FIG. 49, the horizontal axis represents E_{Em}, the vertical axis represents ΔE_{E}, and η_{QE} is represented by the area of each bubble (circle) in the chart. In FIG. 50, the horizontal axis represents E_{Em}, the vertical axis represents T_{L}ow, and the area of each bubble (circle) represents η_{QE} in the chart.

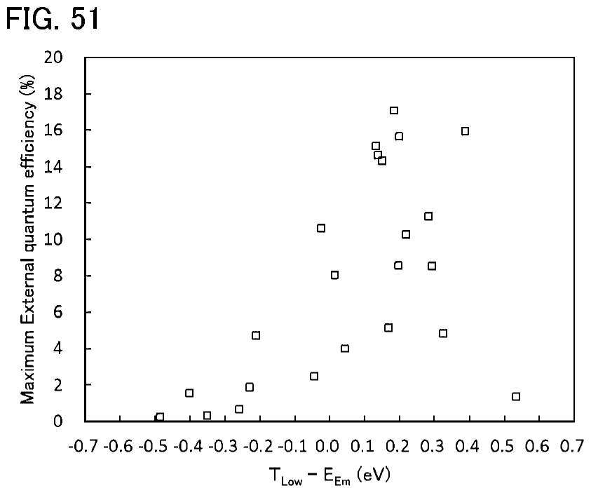

FIG. 51 shows the relation between the ΔT_{Low}−E_{Em} and the maximum external quantum efficiency of the light-emitting elements using BPAFLP for the hole-transport layer 412 and using 4,6mCzP2Pm as the first organic compound of the light-emitting layer 430 among the above light-emitting elements.

As shown in FIG. 49, there is a correlation between the emission energy (E_{Em}) and the energy difference between the LUMO level of the first organic compound and the HOMO level of the second organic compound (ΔE_{E}), of Light-emitting elements 1 to 282. This indicates that emission from Light-emitting elements 1 to 282 is derived from the exciplex.

When ΔE_{E} is less than E_{Em}−0.1 eV or greater than E_{Em}+0.4 eV, the external quantum efficiencies of the light-emitting elements are low.

For example, Light-emitting element 167 includes 4,6mCzP2Pm as the first organic compound and Cz2DBT as the second organic compound. Considering that the LUMO level of 4,6mCzP2Pm is −2.88 eV and the HOMO level of Cz2DBT is −5.86 eV, the ΔE_{E} of Light-emitting element 167 is found to be 2.98 eV Light-emitting element 181 includes 4,6mCzP2Pm as the first organic compound and BP3Dic as the second organic compound. The HOMO level of BP3Dic is −5.51 eV; thus, the ΔE_{E} of Light-emitting element 181 is found to be 2.63 eV. The E_{Em} and qQE of Light-emitting element 167 are 2.46 eV (504 nm) and 1.48%, respectively, and the E_{Em} and η_{QE} of Light-emitting element 181 are 2.38 eV (520 nm) and 8.53%, respectively. That is, the energy difference between the ΔE_{E} and E_{Em} of Light-emitting element 167 is 0.52 eV, and the external quantum efficiency of Light-emitting element 167 is low. In contrast, the energy difference between the ΔE_{E} and E_{Em} of Light-emitting element 181 is 0.25 eV, and the external quantum efficiency of Light-emitting element 181 is high.

According to the above results, ΔE_{E} is preferably greater than or equal to E_{Em}−0.1 eV and less than or equal to E_{E}m+0.4 eV (E_{Em}−0.1 eV ΔE_{E} E_{Em}+0.4 eV), in which case a light-emitting element can have high luminous efficiency.

As shown in FIG. 50, there is a correlation between the emission energy (E_{Em}) and the lower of the T1 level of the first organic compound and the T1 level of the second organic compound (T_{Low}), of Light-emitting elements 1 to 282. When T_{Low} has energy that is less than E_{Em}−0.2 eV or greater than E_{Em}+0.4 eV, the external quantum efficiencies are low.

For example, Light-emitting element 220 includes 4,6mCzP2Pm as the first organic compound and m-MTDATA as the second organic compound. Considering that the T1 levels of 4,6mCzP2Pm and m-MTDATA are 2.70 eV and 2.56 eV, respectively, the T_{Low} of Light-emitting element 220 is found to be 2.56 eV. Light-emitting element 136 includes 4,6mCzP2Pm as the first organic compound and PCzPCAI as the second organic compound. The T1 level of PCzPCA1 is 2.50 eV; thus, the T_{Low} of Light-emitting element 136 is found to be 2.50 eV The E_{Em} and η_{QE} of Light-emitting element 220 are 2.03 eV (611 nm) and 1.36%, respectively, and the E_{Em} and η_{QE} of Light-emitting element 136 are 2.22 eV (558 nm) and 11.27%, respectively. That is, the energy difference between the T_{Low} and E_{Em} of Light-emitting element 220 is 0.53 eV, and the external quantum efficiency of Light-emitting element 220 is low. In contrast, the energy difference between the T_{Low} and E_{Em} of Light-emitting element 136 is 0.32 eV, and the external quantum efficiency of Light-emitting element 136 is high.

As shown in FIG. 51, T_{Low} preferably has energy that is larger than E_{Em} by −0.2 eV or more and 0.4 eV or less, in which case a light-emitting element can have high luminous efficiency.

Furthermore, as in Light-emitting element 1 described above, ΔE_{E} is preferably greater than E_{E}m by −0.1 eV or more and 0.4 eV or less, and T_{Low} preferably has energy that is larger than E_{Em} by −0.2 eV or more and 0.4 eV or less, in which case a light-emitting element can have high luminous efficiency.

With the structure of one embodiment of the present invention, a light-emitting element with high luminous efficiency can be provided. With the structure of one embodiment of the present invention, a light-emitting element with a low drive voltage can be provided. With the structure of one embodiment of the present invention, a light-emitting element with low power consumption can be provided.

### EXPLANATION OF REFERENCE

ANO wiring, C1: capacitor, C2: capacitor, CSCOM: wiring, GD: driver circuit, GL: scan line, GL1: scan line, GL2: scan line, ML: wiring, SL1: signal line, SL2: signal line, SD: driver circuit, VCOM1: wiring, VCOM2: wiring, 300: display device, 302: pixel, 315: sealant, 331: alignment film, 332: alignment film, 335: structure body, 337: conductor, 339: conductive material, 350: liquid crystal element, 351: electrode, 351A: conductive film, 351B: reflective film, 351C: conductive film, 351H: opening, 352: electrode, 353: liquid crystal layer, 354: intermediate film, 370: substrate, 370D: functional film, 370P: functional film, 371: insulating film, 373: light-blocking layer, 375: coloring layer, 377: flexible printed board, 400: EL layer, 401: electrode, 401a: conductive layer, 401b: conductive layer, 401c: conductive layer, 402: electrode, 403: electrode, 403a: conductive layer, 403b: conductive layer, 404: electrode, 404a: conductive layer, 404b: conductive layer, 406: light-emitting unit, 408: light-emitting unit, 410: light-emitting unit, 411: hole-injection layer, 412: hole-transport layer, 413: electron-transport layer, 414: electron-injection layer, 415: charge generation layer, 416: hole-injection layer, 417: hole-transport layer, 418: electron-transport layer, 419: electron-injection layer, 420: light-emitting layer, 421: host material, 422: guest material, 423B: light-emitting layer, 423G: light-emitting layer, 423R: light-emitting layer, 424B: optical element, 424G: optical element, 424R: optical element, 425: light-blocking layer, 426B: region, 426G: region, 426R: region, 428B: region, 428G: region, 428R: region, 430: light-emitting layer, 431: organic compound, 432: organic compound, 433: guest material, 440: light-emitting layer, 441: host material, 4411: organic compound, 441_2: organic compound, 442: guest material, 445: partition, 450: light-emitting element, 460: light-emitting element, 462: light-emitting element, 464a: light-emitting element, 464b: light-emitting element, 466a: light-emitting element, 466b: light-emitting element, 470: light-emitting layer, 470a: light-emitting layer, 470b: light-emitting layer, 480: substrate, 482: substrate, 501A: insulating film, 501C: insulating film, 502: pixel portion, 505: bonding layer, 511B: conductive film, 511C: conductive film, 519B: terminal, 519C: terminal, 520: functional layer, 521: insulating film, 522: connection portion, 528: insulating film, 550: light-emitting element, 551: electrode, 552: electrode, 553: light-emitting layer, 570: substrate, 575: coloring layer, 581: transistor, 582: transistor, 585: transistor, 586: transistor, 600: display device, 601: signal line driver circuit portion, 602: pixel portion, 603: scan line driver circuit portion, 604: sealing substrate, 605: sealant, 607: region, 607a: sealing layer, 607b: sealing layer, 607c: sealing layer, 608: wiring, 609: FPC, 610: element substrate, 611: transistor, 612: transistor, 613: lower electrode, 614: partition, 616: EL layer, 617: upper electrode, 618: light-emitting element, 621: optical element, 622: light-blocking layer, 623: transistor, 624: transistor, 683: droplet discharge apparatus, 684: droplet, 685: layer, 801: pixel circuit, 802: pixel portion, 804: driver circuit portion, 804a: scan line driver circuit, 804b: signal line driver circuit, 806: protection circuit, 807: terminal portion, 852: transistor, 854: transistor, 862: capacitor, 872: light-emitting element, 1001: substrate, 1002: base insulating film, 1003: gate insulating film, 1006: gate electrode, 1007: gate electrode, 1008: gate electrode, 1020: interlayer insulating film, 1021: interlayer insulating film, 1022: electrode, 1024B: lower electrode, 1024G: lower electrode, 1024R: lower electrode, 1024Y: lower electrode, 1025: partition, 1026: upper electrode, 1028: EL layer, 1028B: light-emitting layer, 1028G: light-emitting layer, 1028R: light-emitting layer, 1028Y: light-emitting layer, 1029: sealing layer, 1031: sealing substrate, 1032: sealant, 1033: base material: 1034B: coloring layer, 1034G: coloring layer, 1034R: coloring layer, 1034Y: coloring layer, 1035: light-blocking layer, 1036: overcoat layer, 1037: interlayer insulating film, 1040: pixel portion, 1041: driver circuit portion, 1042: peripheral portion, 1400: droplet discharge apparatus, 1402: substrate, 1403: droplet discharge means, 1404: imaging means, 1405: head, 1406: space, 1407: control means, 1408: storage medium, 1409: image processing means, 1410: computer, 1411: marker, 1412: head, 1413: material supply source, 1414: material supply source, 2000: touch panel, 2001: touch panel, 2501: display device, 2502R: pixel, 2502t: transistor, 2503c: capacitor, 2503g: scan line driver circuit, 2503s: signal line driver circuit, 2503t: transistor, 2509: FPC, 2510: substrate, 2510a: insulating layer, 2510b: flexible substrate, 2510c: bonding layer, 2511: wiring, 2519: terminal, 2521: insulating layer, 2528: partition, 2550R: light-emitting element, 2560: sealing layer, 2567BM: light-blocking layer, 2567p: anti-reflective layer, 2567R: coloring layer, 2570: substrate, 2570a: insulating layer, 2570b: flexible substrate, 2570c: bonding layer, 2580R: light-emitting module: 2590: substrate, 2591: electrode, 2592: electrode, 2593: insulating layer, 2594: wiring, 2595: touch sensor, 2597: adhesive layer, 2598: wiring, 2599: connection layer, 2601: pulse voltage output circuit, 2602: current sensing circuit, 2603: capacitor, 2611: transistor, 2612: transistor, 2613: transistor, 2621: electrode, 2622: electrode, 3000: light-emitting device, 3001: substrate, 3003: substrate, 3005: light-emitting element, 3007: sealing region, 3009: sealing region, 3011: region, 3013: region, 3014: region, 3015: substrate, 3016: substrate, 3018: desiccant, 3500: multifunction terminal, 3502: housing, 3504: display portion, 3506: camera, 3508: lighting, 3600: light, 3602: housing, 3608: lighting, 3610: speaker, 7121: housing, 7122: display portion, 7123: keyboard, 7124: pointing device, 7200: head-mounted display, 7201: mounting portion, 7202: lends, 7203: main body, 7204: display portion, 7205: cable, 7206: battery, 7300: camera, 7301: housing, 7302: display portion, 7303: operation button, 7304: shutter button, 7305: connection portion, 7306: lends, 7400: finder, 7401: housing, 7402: display portion, 7403: button, 7500: head-mounted display, 7501: housing, 7502: display portion, 7503: operation button, 7504: fixing band, 7505: lends, 7510: head-mounted display, 7701: housing, 7702: housing, 7703: display portion, 7704: operation key, 7705: lends, 7706: joint, 8000: display module: 8501: lighting device, 8502: lighting device, 8503: lighting device, 8504: lighting device, 9000: housing, 9001: display portion, 9003: speaker, 9005: operation key, 9006: connection terminal, 9007: sensor, 9008: microphone, 9050: operation button, 9051: information, 9052: information, 9053: information, 9054: information, 9055: hinge, 9100: portable information terminal, 9101: portable information terminal, 9102: portable information terminal, 9200: portable information terminal, 9201: portable information terminal, 9300: television set, 9301: stand, 9311: remote controller, 9500: display device, 9501: display panel, 9502: display region, 9503: region, 9511: hinge, 9512: bearing, 9700: automobile, 9701: body, 9702: wheels, 9703: dashboard, 9704: light, 9710: display portion, 9711: display portion, 9712: display portion, 9713: display portion, 9714: display portion, 9715: display portion, 9721: display portion, 9722: display portion, 9723: display portion

This application is based on Japanese Patent Application serial no. 2016-055246 filed with Japan Patent Office on Mar. 18, 2016, the entire contents of which are hereby incorporated by reference.

1. A light-emitting element comprising:
a first electrode;
a light-emitting layer over the first electrode, the light-emitting layer comprising:
a first organic compound comprising:
a triazinyl group; and
a biphenyl group bonding to the triazinyl group; and
a second organic compound comprising a 9-phenyl-9H-carbazolyl group; and
a second electrode over the light-emitting layer,
wherein a combination of the first organic compound and the second organic compound is capable of forming an exciplex, and
wherein a lower of a lowest triplet excitation energy level of the first organic compound and a lowest triplet excitation energy level of the second organic compound has an energy that is larger than emission energy of the exciplex by −0.2 eV or more and 0.4 eV or less.

2. The light-emitting element according to claim 1, wherein an energy difference between a lowest unoccupied molecular orbital level of the first organic compound and a highest occupied molecular orbital level of the second organic compound is greater than emission energy of the exciplex by −0.1 eV or more and 0.4 eV or less.

3. The light-emitting element according to claim 1, further comprising:
a hole-injection layer over the first electrode,
wherein the hole-injection layer comprises a compound having one of a halogen group and a cyano group.

4. The light-emitting element according to claim 1, further comprising a guest material,
wherein the guest material is capable of emitting light, and
wherein the exciplex is capable of supplying excitation energy to the guest material.

5. The light-emitting element according to claim 4,
wherein the guest material comprises a fluorescent compound, and
wherein an emission spectrum of the exciplex includes a region overlapping with an absorption band of the guest material on a lowest energy side.

6. The light-emitting element according to claim 1,
wherein the first organic compound has an electron transporting property, and
wherein the second organic compound has a hole transporting property.

7. The light-emitting element according to claim 1,
wherein a highest occupied molecular orbital level of the first organic compound is lower than a highest occupied molecular orbital level of the second organic compound, and
wherein a lowest unoccupied molecular orbital level of the first organic compound is lower than a lowest unoccupied molecular orbital level of the second organic compound.

8. The light-emitting element according to claim 7, wherein an energy difference between the lowest unoccupied molecular orbital level of the first organic compound and the highest occupied molecular orbital level of the second organic compound is greater than an emission energy of the exciplex by −0.1 eV or more and 0.4 eV or less.

9. The light-emitting element according to claim 1, wherein the first organic compound further comprises a heteroaromatic group.

10. The light-emitting element according to claim 1, wherein the second organic compound further comprises a diarylamine group bonding to the 9-phenyl-9H-carbazolyl group.

11. A display device comprising:
the light-emitting element according to claim 1; and
a transistor electrically connected to the light-emitting element.

12. An electronic device comprising:
the display device according to claim 11; and
at least one of a housing and a touch sensor.

13. Alighting device comprising:
the light-emitting element according to claim 1; and
at least one of a housing and a touch sensor.
